(19) United States
(12) Patent Application Publication
(10) Pub. No.: US 2026/0339472 A1
(43) Pub. Date: Oct. 29, 2026

(54) TOUCH PANEL AND METHOD FOR MANUFACTURING TOUCH PANEL

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Hajime KIMURA, Atsugi, Kanagawa (JP)

(21) Appl. No.: 19/099,803

(22) PCT Filed: Jul. 27, 2023
(86) PCT No.: PCT/IB2023/057607

§ 371 Date: Jan. 30, 2025

(30) Foreign Application Priority Data
Aug. 10, 2022 (JP) 2022-127692
Aug. 24, 2022 (JP) 2022-133459

(51) Int. Cl. G06F 3/044; H10D 86/40; H10D 86/60

(52) U.S. Cl. CPC G06F 3/0446; H10D 86/423; H10D 86/443; H10D 86/60; G06F 2203/04103

(57) ABSTRACT

An inexpensive touch panel is provided. The touch panel includes a transistor, a sensing element, an interlayer insulating layer, a connection electrode, and a conductive particle, and the sensing element includes a pair of electrodes. The interlayer insulating layer includes an opening reaching a source electrode, a drain electrode, or a gate electrode of the transistor. The connection electrode is provided to include a region positioned in the opening. One of the pair of electrodes of the sensing element is provided to include a region overlapped by the connection electrode, and the connection electrode and the one of the pair of electrodes of the sensing element are electrically connected to each other through the conductive particle. The conductive particle is provided between the connection electrode and the one of the pair of electrodes of the sensing element so as to include a region positioned in the opening. In this manner, the connection electrode and the one of the pair of electrodes of the sensing element are electrically connected to each other through the conductive particle.

### TECHNICAL FIELD

One embodiment of the present invention relates to a touch panel and a manufacturing method thereof. One embodiment of the present invention relates to a display apparatus and a manufacturing method thereof. One embodiment of the present invention relates to an input device and a manufacturing method thereof. One embodiment of the present invention relates to a semiconductor device and a manufacturing method thereof. One embodiment of the present invention relates to an electronic device.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method for driving any of them, and a method for manufacturing any of them.

Note that in this specification and the like, a semiconductor device refers to a device that utilizes semiconductor characteristics, and means a circuit including a semiconductor element (a transistor, a diode, a photodiode, or the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display apparatus, a light-emitting apparatus, a lighting device, and an electronic device themselves are semiconductor devices and each of them includes a semiconductor device in some cases.

### BACKGROUND ART

Semiconductor devices that include transistors are applied to a wide range of electronic devices. In a display apparatus, for example, when transistors occupy smaller areas, the pixel size can be smaller and higher resolution can be achieved. Therefore, miniaturization of transistors has been required.

As devices requiring high-resolution display apparatuses, for example, devices for virtual reality (VR), augmented reality (AR), substitutional reality (SR), or mixed reality (MR) have been actively developed.

As the display apparatus, a light-emitting apparatus including an organic EL (Electro Luminescence) element or a light-emitting diode (LED) has been developed, for example.

Patent Document 1 discloses a high-resolution display apparatus using an organic EL element.

Another example of the display apparatus is a liquid crystal display apparatus including a liquid crystal element (also referred to as a liquid crystal device). An example is an active matrix liquid crystal display apparatus, in which pixel electrodes are arranged in a matrix and transistors are used as switching elements connected to respective pixel electrodes.

For example, an active matrix liquid crystal display apparatus in which transistors including a metal oxide in channel formation regions are used as switching elements connected to respective pixel electrodes is known (Patent Document 2 and Patent Document 3).

### REFERENCES

### Patent Documents

[Patent Document 1] PCT International Publication No. 2016/038508
[Patent Document 2] Japanese Published Patent Application No. 2007-123861
[Patent Document 3] Japanese Published Patent Application No. 2007-96055

### SUMMARY OF THE INVENTION

### Problems to be Solved by the Invention

When a display apparatus has a function other than the display function, the display apparatus can have higher functionality and higher added value. For example, when the display apparatus is provided with a touch sensor to be a touch panel, a user of the display apparatus can perform a touch operation. Thus, the convenience of the display apparatus can be improved. However, for example, a touch panel formed by mounting a touch sensor on a display apparatus has a higher manufacturing cost than a display apparatus that is not a touch panel, and thus is priced higher. Accordingly, a touch panel is preferably provided at low cost by reducing the manufacturing cost with an increase in manufacturing yield of the touch panel, for example.

In view of the above, an object of one embodiment of the present invention is to provide an inexpensive touch panel. Another object of one embodiment of the present invention is to provide a highly reliable touch panel. Another object of one embodiment of the present invention is to provide a touch panel capable of high-speed driving. Another object of one embodiment of the present invention is to provide a touch panel including a high-resolution display apparatus. Another object of one embodiment of the present invention is to provide a touch panel including a transistor having a minute size. Another object of one embodiment of the present invention is to provide a touch panel including a transistor with a high on-state current. Another object of one embodiment of the present invention is to provide a touch panel having favorable electrical characteristics. Another object of one embodiment of the present invention is to provide a novel touch panel. Another object of one embodiment of the present invention is to provide a display apparatus that is provided in any of the above touch panels. Another object of one embodiment of the present invention is to provide a semiconductor device that is provided in any of the above touch panels.

Another object of one embodiment of the present invention is to provide a method for manufacturing a touch panel with high yield. Another object of one embodiment of the present invention is to provide a method for manufacturing a touch panel with a simplified manufacturing process. Another object of one embodiment of the present invention is to provide a method for manufacturing a touch panel at low cost with high mass productivity. Another object of one embodiment of the present invention is to provide a method for manufacturing a highly reliable touch panel. Another object of one embodiment of the present invention is to provide a method for manufacturing a touch panel capable of high-speed driving. Another object of one embodiment of the present invention is to provide a method for manufacturing a touch panel including a high-resolution display apparatus. Another object of one embodiment of the present invention is to provide a method for manufacturing a touch panel including a transistor having a minute size. Another object of one embodiment of the present invention is to provide a method for manufacturing a touch panel including a transistor with a high on-state current. Another object of one embodiment of the present invention is to provide a method for manufacturing a touch panel having favorable electrical characteristics. Another object of one embodiment of the present invention is to provide a method for manufacturing a novel touch panel. Another object of one embodiment of the present invention is to provide a method for manufacturing a display apparatus that is provided in any of the above touch panels. Another object of one embodiment of the present invention is to provide a method for manufacturing a semiconductor device that is provided in any of the above touch panels.

Note that the description of these objects does not preclude the presence of other objects. One embodiment of the present invention does not necessarily achieve all these objects. Note that objects other than these can be derived from the description of the specification, the drawings, the claims, and the like.

### Means for Solving the Problems

One embodiment of the present invention is a touch panel including a first transistor, a sensing element, a first insulating layer, a second insulating layer, and a conductive particle. The first transistor includes a first conductive layer, a second conductive layer, a third conductive layer, a first semiconductor layer, and a third insulating layer. The sensing element includes a pair of electrodes. The first insulating layer is provided over the first conductive layer. The second conductive layer is provided over the first insulating layer. The first insulating layer includes a first opening reaching the first conductive layer. The second conductive layer includes a second opening including a region overlapping the first opening. The first semiconductor layer is provided to include a region in contact with the first conductive layer and a region in contact with the second conductive layer, and to include a region positioned in the first opening and the second opening. The third insulating layer is provided over the first semiconductor layer and the first insulating layer to include a region positioned in the first opening and the second opening. The third conductive layer is provided to include a region positioned in the first opening and a region positioned in the second opening, and to include a region facing the first semiconductor layer with the third insulating layer therebetween. The second insulating layer is provided over the third conductive layer and the first insulating layer. The first to third insulating layers include a third opening reaching the first conductive layer. One of the pair of electrodes includes a region overlapping the third opening. The first conductive layer and the one of the pair of electrodes are electrically connected to each other through the conductive particle. The conductive particle is provided between the first conductive layer and the one of the pair of electrodes to include a region positioned in the third opening.

In the above embodiment, the touch panel may include a fourth conductive layer, and the fourth conductive layer may be provided to include a region in contact with the first conductive layer and to include a region positioned in the third opening.

In the above embodiment, the touch panel may include a second transistor and a light-emitting element. The second transistor may include a fifth conductive layer, a sixth conductive layer, a seventh conductive layer, a second semiconductor layer, and the third insulating layer. The light-emitting element may include a pixel electrode, an EL layer over the pixel electrode, and a common electrode over the EL layer. The first insulating layer may be provided over the fifth conductive layer. The sixth conductive layer may be provided over the first insulating layer. The first insulating layer may include a fourth opening reaching the fifth conductive layer. The sixth conductive layer may include a fifth opening including a region overlapping the fourth opening. The second semiconductor layer may be provided to include a region in contact with the fifth conductive layer and a region in contact with the sixth conductive layer and to include a region positioned in the fourth opening and the fifth opening. The third insulating layer may be provided over the second semiconductor layer to include a region positioned in the fourth opening and the fifth opening. The seventh conductive layer may be provided to include a region positioned in the fourth opening and a region positioned in the fifth opening and to include a region facing the second semiconductor layer with the third insulating layer therebetween. The second insulating layer may be provided over the seventh conductive layer. The first to third insulating layers may include a sixth opening reaching the fifth conductive layer. The pixel electrode may be provided in the same layer as the fourth conductive layer to include a region in contact with the fifth conductive layer and to include a region positioned in the sixth opening.

Another embodiment of the present invention is a touch panel including a first transistor, a sensing element, a first insulating layer, a second insulating layer, a third insulating layer, a first conductive layer, and a conductive particle. The first transistor includes a second conductive layer, a third conductive layer, a fourth conductive layer, a first semiconductor layer, and a fourth insulating layer. The sensing element includes a pair of electrodes. The first insulating layer is provided over the second conductive layer. The third conductive layer is provided over the first insulating layer. The first insulating layer includes a first opening reaching the second conductive layer. The third conductive layer includes a second opening including a region overlapping the first opening. The first semiconductor layer is provided to include a region in contact with the second conductive layer and a region in contact with the third conductive layer, and to include a region positioned in the first opening and the second opening. The fourth insulating layer is provided over the first semiconductor layer and the first insulating layer to include a region positioned in the first opening and the second opening. The fourth conductive layer is provided to include a region positioned in the first opening and a region positioned in the second opening, and to include a region facing the first semiconductor layer with the fourth insulating layer therebetween. The second insulating layer is provided over the fourth conductive layer and the first insulating layer. The first conductive layer is provided over the second insulating layer and electrically connected to the second conductive layer. The third insulating layer is provided over the first conductive layer. The third insulating layer includes a third opening reaching the first conductive layer. One of the pair of electrodes includes a region overlapping the third opening. The first conductive layer and the one of the pair of electrodes are electrically connected to each other through the conductive particle. The conductive particle is provided between the first conductive layer and the one of the pair of electrodes to include a region positioned in the third opening.

In the above embodiment, the touch panel may include a second transistor and a light-emitting element. The second transistor may include a fifth conductive layer, a sixth conductive layer, a seventh conductive layer, a second semiconductor layer, and the fourth insulating layer. The light-emitting element may include a pixel electrode, an EL layer over the pixel electrode, and a common electrode over the EL layer. The first insulating layer may be provided over the fifth conductive layer. The sixth conductive layer may be provided over the first insulating layer. The first insulating layer may include a fourth opening reaching the fifth conductive layer. The sixth conductive layer may include a fifth opening including a region overlapping the fourth opening. The second semiconductor layer may be provided to include a region in contact with the fifth conductive layer and a region in contact with the sixth conductive layer and to include a region positioned in the fourth opening and the fifth opening. The fourth insulating layer may be provided over the second semiconductor layer to include a region positioned in the fourth opening and the fifth opening. The seventh conductive layer may be provided to include a region positioned in the fourth opening and a region positioned in the fifth opening and to include a region facing the second semiconductor layer with the fourth insulating layer therebetween. The second insulating layer may be provided over the seventh conductive layer. The pixel electrode may be provided in the same layer as the first conductive layer to be electrically connected to the fifth conductive layer. The third insulating layer may be provided to cover an end portion of the pixel electrode.

In the above embodiment, an adhesive layer including the conductive particle may be provided between the one of the pair of electrodes and the first conductive layer.

In the above embodiment, the first semiconductor layer and the second semiconductor layer may each include a metal oxide, and the metal oxide may include indium, zinc, and M (M is one or more kinds selected from aluminum, titanium, gallium, germanium, tin, yttrium, zirconium, lanthanum, cerium, neodymium, and hafnium).

Another embodiment of the present invention is a method for manufacturing a touch panel, including: forming a first conductive layer over a first substrate; forming a first insulating layer over the first conductive layer; forming a conductive film over the first insulating layer; forming a first opening reaching the first conductive layer in the first insulating layer, forming a second opening including a region overlapping the first opening in the conductive film, and forming a second conductive layer by processing the conductive film; forming a first semiconductor layer to include a region in contact with the first conductive layer and a region in contact with the second conductive layer and to include a region positioned in the first opening and the second opening; forming a second insulating layer over the first semiconductor layer and the first insulating layer to include a region positioned in the first opening and the second opening; forming a third conductive layer to include a region positioned in the first opening and the second opening and to include a region facing the first semiconductor layer with the second insulating layer therebetween; forming a third insulating layer over the third conductive layer and the first insulating layer; forming a third opening reaching the first conductive layer in the first to third insulating layers; forming, over a second substrate, a sensing element including a pair of electrodes; and bonding the first substrate and the second substrate to each other using an adhesive layer including a conductive particle so that the conductive particle includes a region positioned in the third opening and so that the first conductive layer and one of the electrodes of the sensing element are electrically connected to each other through the conductive particle.

In the above embodiment, after forming the third opening, a fourth conductive layer may be formed to include a region in contact with the first conductive layer and to include a region positioned in the third opening.

The above embodiment may include the steps of forming a fifth conductive layer concurrently with formation of the first conductive layer; forming the first insulating layer over the fifth conductive layer; forming a fourth opening reaching the fifth conductive layer in the first insulating layer concurrently with formation of the first opening, and forming a fifth opening including a region overlapping the fourth opening in the conductive film concurrently with formation of the second opening; forming a sixth conductive layer by processing the conductive film; forming a second semiconductor layer to include a region in contact with the fifth conductive layer and a region in contact with the sixth conductive layer and to include a region positioned in the fourth opening and the fifth opening, concurrently with formation of the first semiconductor layer; forming the second insulating layer over the second semiconductor layer to include a region positioned in the fourth opening and the fifth opening; forming a seventh conductive layer to include a region positioned in the fourth opening and the fifth opening and to include a region facing the second semiconductor layer with the second insulating layer therebetween, concurrently with formation of the third conductive layer; forming the third insulating layer over the seventh conductive layer; forming a sixth opening reaching the fifth conductive layer in the first to third insulating layers, concurrently with formation of the third opening; forming a pixel electrode to include a region in contact with the fifth conductive layer and to include a region positioned in the sixth opening, concurrently with formation of the fourth conductive layer; and forming an EL layer over the pixel electrode and forming a common electrode over the EL layer, thereby forming a light-emitting element including the pixel electrode, the EL layer, and the common electrode.

### Effect of the Invention

One embodiment of the present invention can provide an inexpensive touch panel. Another embodiment of the present invention can provide a highly reliable touch panel. Another embodiment of the present invention can provide a touch panel capable of high-speed driving. Another embodiment of the present invention can provide a touch panel including a high-resolution display apparatus. Another embodiment of the present invention can provide a touch panel including a transistor having a minute size. Another embodiment of the present invention can provide a touch panel including a transistor with a high on-state current. Another embodiment of the present invention can provide a touch panel having favorable electrical characteristics. Another embodiment of the present invention can provide a novel touch panel. Another embodiment of the present invention can provide a display apparatus that is provided in any of the above touch panels. Another embodiment of the present invention can provide a semiconductor device that is provided in any of the above touch panels.

Another embodiment of the present invention can provide a method for manufacturing a touch panel with high yield. Another embodiment of the present invention can provide a method for manufacturing a touch panel with a simplified manufacturing process. Another embodiment of the present invention can provide a method for manufacturing a touch panel at low cost with high mass productivity. Another embodiment of the present invention can provide a method for manufacturing a highly reliable touch panel. Another embodiment of the present invention can provide a method for manufacturing a touch panel capable of high-speed driving. Another embodiment of the present invention can provide a method for manufacturing a touch panel including a high-resolution display apparatus. Another embodiment of the present invention can provide a method for manufacturing a touch panel including a transistor having a minute size. Another embodiment of the present invention can provide a method for manufacturing a touch panel including a transistor with a high on-state current. Another embodiment of the present invention can provide a method for manufacturing a touch panel having favorable electrical characteristics. Another embodiment of the present invention can provide a method for manufacturing a novel touch panel. Another embodiment of the present invention can provide a method for manufacturing a display apparatus that is provided in any of the above touch panels. Another embodiment of the present invention can provide a method for manufacturing a semiconductor device that is provided in any of the above touch panels.

Note that the description of these effects does not preclude the presence of other effects. One embodiment of the present invention does not necessarily have all of these effects. Other effects can be derived from the description of the specification, the drawings, and the claims.

### BRIEF DESCRIPTION OF THE DRAWINGS

FIG. 1A and FIG. 1B are perspective views illustrating a structure example of a touch panel.

FIG. 2A is a block diagram illustrating a structure example of a display apparatus. FIG. 2B is a plan view illustrating a structure example of a pixel. FIG. 2C and FIG. 2D are circuit diagrams illustrating structure examples of a pixel.

FIG. 3A, FIG. 3B1, FIG. 3B2, FIG. 3C1, and FIG. 3C2 are circuit diagrams each illustrating a structure example of a pixel.

FIG. 4A and FIG. 4B are plan views illustrating a structure example of a touch panel.

FIG. 5A and FIG. 5B are plan views illustrating a structure example of a touch panel.

FIG. 6 is a cross-sectional view illustrating a structure example of a touch panel.

FIG. 7 is a cross-sectional view illustrating a structure example of a touch panel.

FIG. 8A and FIG. 8B are cross-sectional views illustrating structure examples of a conductive particle and its surroundings.

FIG. 9A and FIG. 9B are cross-sectional views illustrating structure examples of a conductive particle and its surroundings.

FIG. 10A is a plan view illustrating a structure example of a transistor. FIG. 10B is a cross-sectional view illustrating a structure example of the transistor.

FIG. 11A and FIG. 11B are plan views illustrating a structure example of a touch panel.

FIG. 12A and FIG. 12B are plan views illustrating a structure example of a touch panel.

FIG. 13 is a cross-sectional view illustrating a structure example of a touch panel.

FIG. 14 is a cross-sectional view illustrating a structure example of a touch panel.

FIG. 15A and FIG. 15B are plan views illustrating structure examples of a touch panel.

FIG. 16A and FIG. 16B are plan views illustrating a structure example of a touch panel.

FIG. 17A and FIG. 17B are plan views illustrating a structure example of a touch panel.

FIG. 18 is a cross-sectional view illustrating a structure example of a touch panel.

FIG. 19A and FIG. 19B are plan views illustrating a structure example of a touch panel.

FIG. 20 is a plan view illustrating a structure example of a touch panel.

FIG. 21 is a cross-sectional view illustrating a structure example of a touch panel.

FIG. 22 is a cross-sectional view illustrating a structure example of a touch panel.

FIG. 23A and FIG. 23B are plan views illustrating a structure example of a touch panel.

FIG. 24 is a plan view illustrating a structure example of a touch panel.

FIG. 25 is a cross-sectional view illustrating a structure example of a touch panel.

FIG. 26 is a cross-sectional view illustrating a structure example of a touch panel.

FIG. 27A and FIG. 27B are cross-sectional views illustrating structure examples of a conductive particle and its surroundings.

FIG. 28A and FIG. 28B are plan views illustrating a structure example of a touch panel.

FIG. 29 is a plan view illustrating a structure example of a touch panel.

FIG. 30 is a cross-sectional view illustrating a structure example of a touch panel.

FIG. 31 is a cross-sectional view illustrating a structure example of a touch panel.

FIG. 32A and FIG. 32B are plan views illustrating a structure example of a touch panel.

FIG. 33 is a cross-sectional view illustrating a structure example of a touch panel.

FIG. 34 is a cross-sectional view illustrating a structure example of a touch panel.

FIG. 35A and FIG. 35B are plan views illustrating structure examples of an input device. FIG. 35C is a plan view illustrating a structure example of an electrode.

FIG. 36A is a block diagram illustrating a structure example of a touch panel. FIG. 36B is a timing chart showing an example of a method for driving the touch panel.

FIG. 37A and FIG. 37B are perspective views illustrating structure examples of a touch panel.

FIG. 38A and FIG. 38B are perspective views illustrating structure examples of a touch panel.

FIG. 39A and FIG. 39B are block diagrams illustrating structure examples of a display apparatus.

FIG. 40 is a cross-sectional view illustrating a structure example of a touch panel.

FIG. 41 is a cross-sectional view illustrating a structure example of a touch panel.

FIG. 42 is a cross-sectional view illustrating a structure example of a touch panel.

FIG. 43 is a cross-sectional view illustrating a structure example of a touch panel.

FIG. 44 is a cross-sectional view illustrating a structure example of a touch panel.

FIG. 45 is a cross-sectional view illustrating a structure example of a touch panel.

FIG. 46 is a cross-sectional view illustrating a structure example of a touch panel.

FIG. 47A to FIG. 47D are cross-sectional views illustrating an example of a method for manufacturing a touch panel.

FIG. 48A to FIG. 48C are cross-sectional views illustrating an example of a method or manufacturing a touch panel.

FIG. 49A and FIG. 49B are cross-sectional views illustrating an example of a method for manufacturing a touch panel.

FIG. 50A and FIG. 50B are cross-sectional views illustrating an example of a method for manufacturing a touch panel.

FIG. 51A and FIG. 51B are cross-sectional views illustrating an example of a method for manufacturing a touch panel.

FIG. 52A to FIG. 52C are cross-sectional views illustrating an example of a method for manufacturing a touch panel.

FIG. 53A to FIG. 53D are cross-sectional views illustrating an example of a method for manufacturing a touch panel.

FIG. 54A to FIG. 54C are cross-sectional views illustrating an example of a method for manufacturing a touch panel.

FIG. 55A and FIG. 55B are cross-sectional views illustrating an example of a method for manufacturing a touch panel.

FIG. 56A and FIG. 56B are cross-sectional views illustrating an example of a method for manufacturing a touch panel.

FIG. 57A and FIG. 57B are cross-sectional views illustrating an example of a method for manufacturing a touch panel.

FIG. 58A to FIG. 58C are cross-sectional views illustrating an example of a method for manufacturing a touch panel.

FIG. 59A and FIG. 59B are cross-sectional views illustrating an example of a method for manufacturing a touch panel.

FIG. 60A and FIG. 60B are cross-sectional views illustrating an example of a method for manufacturing a touch panel.

FIG. 61A to FIG. 61C are plan views illustrating structure examples of a transistor.

FIG. 62A is a plan view illustrating a structure example of a transistor. FIG. 62B is a cross-sectional view illustrating a structure example of the transistor.

FIG. 63A is a plan view illustrating a structure example of a transistor. FIG. 63B is a cross-sectional view illustrating a structure example of the transistor.

FIG. 64A is a plan view illustrating a structure example of a transistor. FIG. 64B1 to FIG. 64B3 are cross-sectional views illustrating structure examples of the transistor.

FIG. 65A1 and FIG. 65A2 are plan views illustrating structure examples of a transistor. FIG. 65B is a cross-sectional view illustrating a structure example of the transistor.

FIG. 66A is a plan view illustrating a structure example of a transistor. FIG. 66B is a cross-sectional view illustrating a structure example of the transistor.

FIG. 67A is a plan view illustrating a structure example of a transistor. FIG. 67B is a cross-sectional view illustrating a structure example of the transistor.

FIG. 68A1 and FIG. 68A2 are plan views illustrating structure examples of a transistor. FIG. 68B is a cross-sectional view illustrating a structure example of the transistor.

FIG. 69A is a plan view illustrating a structure example of a transistor. FIG. 69B is a cross-sectional view illustrating a structure example of the transistor.

FIG. 70A is a plan view illustrating a structure example of a transistor. FIG. 70B1 and FIG. 70B2 are cross-sectional views illustrating structure examples of the transistor.

FIG. 71A and FIG. 71B are cross-sectional views illustrating structure examples of a transistor.

FIG. 72A and FIG. 72B are cross-sectional views illustrating structure examples of a transistor.

FIG. 73A and FIG. 73B are cross-sectional views illustrating structure examples of a transistor.

FIG. 74A is a plan view illustrating a structure example of a transistor. FIG. 74B is a cross-sectional view illustrating a structure example of the transistor.

FIG. 75A and FIG. 75B are plan views illustrating structure examples of a transistor.

FIG. 76A is a plan view illustrating a structure example of a transistor. FIG. 76B is a cross-sectional view illustrating a structure example of the transistor.

FIG. 77A is a plan view illustrating a structure example of a transistor. FIG. 77B is a cross-sectional view illustrating a structure example of the transistor.

FIG. 78A to FIG. 78G are plan views illustrating structure examples of pixels.

FIG. 79A to FIG. 79I are plan views illustrating structure examples of pixels.

FIG. 80A to FIG. 80D are diagrams illustrating examples of electronic devices.

FIG. 81A to FIG. 81E are diagrams illustrating examples of electronic devices.

FIG. 82A to FIG. 82G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases. Furthermore, a plurality of layers that can be formed in the same step are shown with the same hatching pattern in some cases.

The position, size, range, or the like of each component illustrated in drawings does not represent the actual position, size, range, or the like in some cases for easy understanding. Therefore, the disclosed invention is not necessarily limited to the position, size, range, and the like disclosed in drawings.

Note that the terms “film” and “layer” can be used interchangeably depending on the case or the circumstances. For example, the term “conductive layer” can be changed into the term “conductive film” in some cases. For another example, the term “insulating film” can be changed into the term “insulating layer” in some cases.

In this specification and the like, the term “island shape” refers to a state where two or more layers formed using the same material in the same step are physically separated from each other. For example, “island-shaped conductive layer” means a state where the conductive layer and its adjacent conductive layer are physically separated from each other.

In this specification and the like, the terms “electrode” and “wiring” do not limit the functions of the components. For example, an “electrode” is used as part of a “wiring” in some cases, and vice versa. Furthermore, the term “electrode” or “wiring” also includes the case where a plurality of “electrodes” or “wirings” are formed in an integrated manner, for example.

In this specification and the like, a structure in which at least light-emitting layers of light-emitting elements with different emission wavelengths are separately formed may be referred to as an SBS (Side By Side) structure. The SBS structure can optimize materials and structures of light-emitting elements and thus can extend freedom of choice of materials and structures, whereby the luminance and the reliability can be easily improved.

In this specification and the like, a light-emitting element (also referred to as a light-emitting device) includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). Note that carrier-injection layer, carrier-transport layer, and carrier-blocking layer cannot be clearly distinguished from each other in some cases depending on the cross-sectional shape, the characteristics, or the like. One layer may have two or three functions of the carrier-injection layer, the carrier-transport layer, and the carrier-blocking layer in some cases.

In this specification and the like, a tapered shape refers to such a shape that at least part of a side surface of a component is inclined with respect to a substrate surface or a formation surface. For example, a tapered shape preferably includes a region where the angle between the inclined side surface and the substrate surface or the formation surface (such an angle is also referred to as a taper angle) is less than 90°. Note that the side surface, the substrate surface, and the formation surface of the component are not necessarily completely flat, and may have a substantially planar shape with a small curvature or a substantially planar shape with slight unevenness.

In this specification and the like, in the case where a side surface of a layer has a tapered shape, an outermost portion of the side surface of the layer is referred to as an end portion of the layer unless otherwise specified. For example, in the case where an end portion of a bottom surface of a layer is positioned outward from an end portion of a top surface thereof, the end portion of the bottom surface is simply referred to as an end portion unless otherwise specified.

In this specification and the like, a plan view can be rephrased as a top view in some cases. Moreover, a plan diagram can be rephrased as a top diagram in some cases.

In this specification and the like, terms for describing arrangement, such as “over”, “under”, “left”, and “right”, are used for convenience in describing a positional relation between components with reference to drawings. The positional relation between components is changed as appropriate in accordance with the direction in which the components are described. Thus, without limitation to terms described in the specification, the description can be changed appropriately depending on the situation.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be referred to as a transistor including a metal oxide or an oxide semiconductor. Note that a metal oxide containing nitrogen is also referred to as a metal oxide in some cases. Furthermore, a metal oxide containing nitrogen may be referred to as a metal oxynitride.

### Embodiment 1

In this embodiment, a touch panel of one embodiment of the present invention, a manufacturing method thereof, and the like will be described with reference to drawings.

In this specification and the like, a touch panel refers to a display apparatus including a touch sensor. Here, a touch panel is one embodiment of an input/output device. Moreover, a touch sensor is one embodiment of an input device.

A touch panel of one embodiment of the present invention includes a first substrate and a second substrate. A transistor, an interlayer insulating layer over the transistor, and a display element (also referred to as a display device) over the interlayer insulating layer are provided over the first substrate. A sensing element (also referred to as a sensing device, a sensor element, or a sensor device) including a pair of electrodes is provided under the second substrate. The first substrate and the second substrate are bonded to each other with an adhesive layer.

The touch panel of one embodiment of the present invention is provided with an input device driver circuit (also referred to as a sensor driver circuit or a sensing element driver circuit) having a function of controlling the driving of the sensing element. The pair of electrodes of the sensing element are electrically connected to a source electrode, a drain electrode, or a gate electrode of a transistor provided in the input device driver circuit. Here, when the input device driver circuit is incorporated in the touch panel, instead of being provided externally, and transistors included in the input device driver circuit are formed in the same process as transistors provided in pixels including display elements, the manufacturing process of the touch panel of one embodiment of the present invention can be simplified. Thus, the touch panel of one embodiment of the present invention can be manufactured by a method with low cost and high mass productivity.

As a method for electrically connecting a source electrode, a drain electrode, or a gate electrode of the transistor provided over the first substrate to one or the other of the pair of electrodes of the sensing element provided over the second substrate, a method in which the first substrate and the second substrate are bonded to each other with an adhesive layer including a conductive particle can be given. However, this method cannot accurately control the position of the conductive particle in some cases. Accordingly, in some cases, for example, the conductive particle is not in contact with one or both of the source electrode, the drain electrode, or the gate electrode of the transistor and the one or the other of the pair of electrodes of the sensing element and thus cannot electrically connect them.

In view of the above, in the touch panel of one embodiment of the present invention, an opening reaching the source electrode, the drain electrode, or the gate electrode of the transistor is provided in the interlayer insulating layer provided over the source electrode, the drain electrode, and the gate electrode. Moreover, a connection electrode is provided to cover the opening. Accordingly, the connection electrode is provided to include a region in contact with the source electrode, the drain electrode, or the gate electrode and to include a region positioned in the opening. When a conductive particle is included in an adhesive layer so as to include a region positioned in the opening and the first substrate and the second substrate are bonded to each other with the adhesive layer, the conductive particle can be easily in contact with both the source electrode, the drain electrode, or the gate electrode and one or the other of the pair of electrodes of the sensing element, for example. Hence, the source electrode, the drain electrode, or the gate electrode can be easily electrically connected to one or the other of the pair of electrodes of the sensing element. In the above manner, the touch panel of one embodiment of the present invention can be manufactured by a high-yield method, and thus can be inexpensive. Furthermore, occurrence of a defect in which the source electrode, the drain electrode, or the gate electrode is not electrically connected to one or the other of the pair of electrodes of the sensing element can be inhibited, leading to an increase in reliability of the touch panel of one embodiment of the present invention.

### Structure Example 1 of Touch Panel

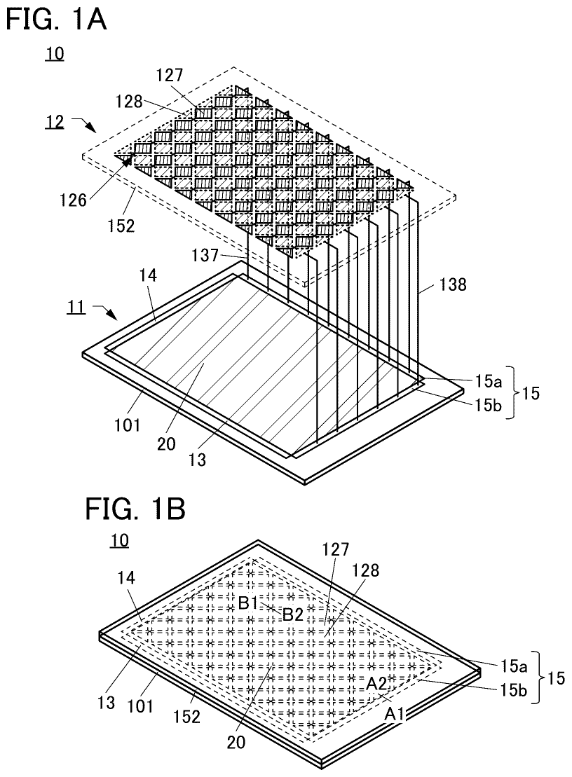

FIG. 1A is a perspective view illustrating a structure example of a touch panel 10. The touch panel 10 includes a display apparatus 11 and an input device 12 over the display apparatus 11. The input device 12 can be a touch sensor, for example.

The display apparatus 11 includes a substrate 101, and a display portion 20, a scan line driver circuit 13, a signal line driver circuit 14, and an input device driver circuit 15 are provided over the substrate 101. The input device driver circuit 15 includes a circuit 15a and a circuit 15b. FIG. 1A illustrates an example in which the scan line driver circuit 13, the signal line driver circuit 14, and the input device driver circuit 15 are incorporated in the display apparatus 11. Note that some of circuits included in the scan line driver circuit 13 may be externally provided, some of circuits included in the signal line driver circuit 14 may be externally provided, or some of circuits included in the input device driver circuit 15 may be externally provided.

The input device 12 includes a substrate 152, an electrode 127, and an electrode 128. The electrode 127 and the electrode 128 overlap each other with an insulating layer (not illustrated) therebetween in an intersection portion 126. The input device 12 includes a sensing element including the electrode 127 and the electrode 128 as a pair of electrodes. The sensing element can sense the approach or contact of a sensing target such as a finger or a stylus with the touch panel 10. The input device 12 can sense a touch operation by a capacitive sensing method, for example, and specifically, can detect a touch operation by a mutual capacitive sensing method. The input device 12 may detect a touch operation by a self-capacitive method, for example. Furthermore, the input device 12 may sense a touch operation by a resistive method, for example.

The electrode 127 and the electrode 128 included in the input device 12 each include a region overlapping the display portion 20. The display portion 20 displays an image by emitting light to the input device 12 side. Accordingly, for the electrode 127 and the electrode 128, a material having a high visible-light-transmitting property is used, for example. For example, In—Sn oxide (ITO), In—Sn—Si oxide (ITSO), In—Zn oxide, In—W—Zn oxide, or the like can be used for the electrode 127 and the electrode 128.

In FIG. 1A, the substrate 152 is denoted by a dashed line. The electrode 127 is electrically connected to the circuit 15a through a wiring 137, and the electrode 128 is electrically connected to the circuit 15b through a wiring 138.

In the example illustrated in FIG. 1A, the electrode 127, the electrode 128, the wiring 137, and the wiring 138 are provided under the substrate 152. That is, the electrode 127, the electrode 128, the wiring 137, and the wiring 138 are provided between the substrate 101 and the substrate 152. Here, for clarity of the drawing, part of the electrode 127 and part of the electrode 128 are denoted by solid lines in FIG. 1A. For example, a solid line that is parallel to a substrate surface of the substrate 152 and connected to a solid line perpendicular to a substrate surface of the substrate 101 and the substrate surface of the substrate 152 is included in the electrode 127 or the electrode 128.

The scan line driver circuit 13 and the signal line driver circuit 14 each have a function of controlling the driving of the display portion 20. The scan line driver circuit 13 and the signal line driver circuit 14 enable a desired image to be displayed on the display portion 20.

The input device driver circuit 15 has a function of controlling the driving of the input device 12. The input device driver circuit 15 has a function of detecting a touch position in the input device 12, for example. Note that the input device driver circuit 15 may be provided in the input device 12 instead of the display apparatus 11.

As described above, the input device driver circuit 15 includes the circuit 15a electrically connected to the electrode 127 and the circuit 15b electrically connected to the electrode 128. One of the circuit 15a and the circuit 15b functions as a pulse voltage output circuit, and the other of the circuit 15a and the circuit 15b functions as a current detection circuit. The functions and the like of the circuit 15a and the circuit 15b will be described below assuming that the circuit 15a functions as a pulse voltage output circuit and the circuit 15b functions as a current detection circuit.

In the case where the circuit 15a functions as a pulse voltage output circuit, the circuit 15a has a function of applying a pulse voltage to the wiring 137. When a pulse voltage is applied to the wiring 137, an electric field is generated between the electrode 127 and the electrode 128. When a sensing target approaches or touches the input device 12, the electric field is blocked by the sensing target.

In the case where the circuit 15b functions as a current detection circuit, the circuit 15b has a function of detecting a change in current value caused by blocking of the electric field. The circuit 15b can detect a touch position in the input device 12 by detecting a change in the current value, for example.

FIG. 1B illustrates the structure illustrated in FIG. 1A with the substrate 101 and the substrate 152 closer to each other than in FIG. 1A. In FIG. 1B, the substrate 101 and the substrate 152 are denoted by solid lines. In FIG. 1B, the display portion 20, the scan line driver circuit 13, the signal line driver circuit 14, the input device driver circuit 15, the electrode 127, and the electrode 128 are denoted by dashed lines. Note that for clarity of the drawing, the wiring 137 and the wiring 138 are not illustrated in FIG. 1B.

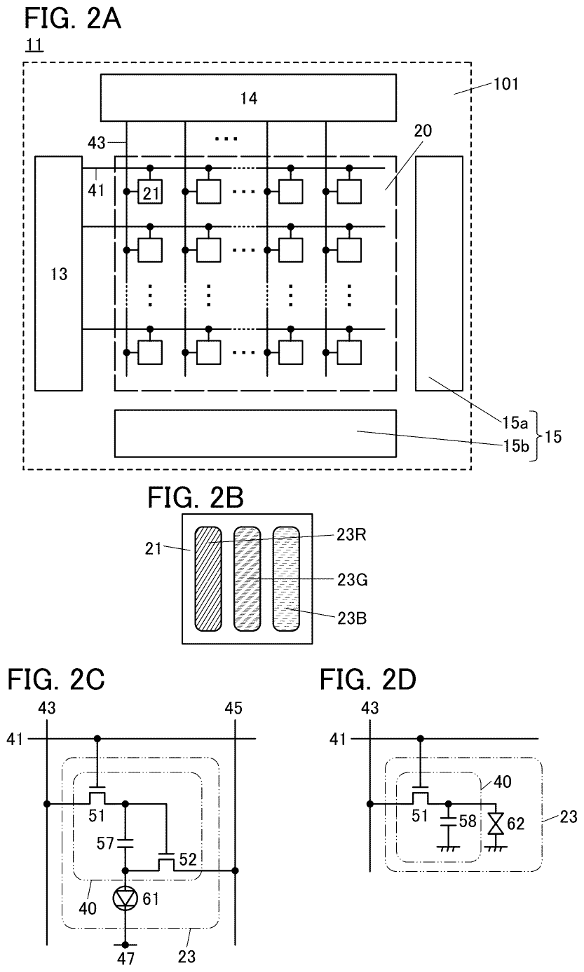

FIG. 2A is a block diagram illustrating a structure example of the display apparatus 11. As described above, the display apparatus 11 includes the substrate 101, and the display portion 20, the scan line driver circuit 13, the signal line driver circuit 14, and the input device driver circuit 15 are provided over the substrate 101. Pixels 21 are arranged in a matrix in the display portion 20.

Each of the pixels 21 is provided with a display element. The display apparatus 11 can display an image on the display portion 20 with the use of the display elements.

The pixel 21 is electrically connected to the scan line driver circuit 13 through a wiring 41 functioning as a scan line. The wiring 41 extends in the row direction of the matrix, for example. The scan line driver circuit 13 has a function of selecting the pixel 21 to which image data is to be written on a row-by-row basis, for example. The scan line driver circuit 13 can select the pixel 21 to which image data is to be written by outputting a scan signal to the scan line, for example.

The pixel 21 is electrically connected to the signal line driver circuit 14 through a wiring 43 functioning as a signal line. The wiring 43 extends in the column direction of the matrix, for example. The signal line driver circuit 14 has a function of generating image data. Image data is expressed as a signal (an image signal) and is supplied to the pixel 21 through the wiring 43. The signal line driver circuit 14 can write image data to all the pixels 21 included in a row selected by the scan line driver circuit 13, for example.

FIG. 2B is a plan view illustrating a structure example of the pixel 21. The pixel 21 includes a plurality of subpixels 23. FIG. 2B illustrates an example in which the pixel 21 includes a subpixel 23R, a subpixel 23G, and a subpixel 23B. Here, the planar shape of each of the subpixels illustrated in FIG. 2B corresponds to, for example, the planar shape of a region from which light is emitted. Although FIG. 2B illustrates the subpixel 23R, the subpixel 23G, and the subpixel 23B that have the same or substantially the same aperture ratio (also referred to as size), one embodiment of the present invention is not limited thereto. The aperture ratio of each of the subpixel 23R, the subpixel 23G, and the subpixel 23B can be determined as appropriate. The subpixel 23R, the subpixel 23G, and the subpixel 23B may have different aperture ratios, or two or more of the subpixel 23R, the subpixel 23G, and the subpixel 23B may have the same or substantially the same aperture ratio.

In this specification and the like, matters common to the subpixel 23R, the subpixel 23G, and the subpixel 23B, for example, are sometimes described using the term “subpixel 23” without any letter of the alphabet distinguishing these subpixels. As for other components that are distinguished from each other using letters of the alphabet, matters common to the components are sometimes described using reference numerals without the letters of the alphabet.

The pixel 21 illustrated in FIG. 2B employs stripe arrangement as the arrangement method of the subpixels 23. As the arrangement method of the subpixels 23, S-stripe arrangement, matrix arrangement, delta arrangement, Bayer arrangement, PenTile arrangement, or the like may be employed. Embodiment 3 can be referred to for examples of the planar shapes of the subpixels, arrangement of the subpixels, and the like.

The subpixel 23R, the subpixel 23G, and the subpixel 23B emit light of different colors. The subpixel 23R, the subpixel 23G, and the subpixel 23B are subpixels of three colors of red (R), green (G), and blue (B) or subpixels of three colors of yellow (Y), cyan (C), and magenta (M), for example. The pixel 21 may include four or more subpixels 23. For example, the pixel 21 may include subpixels of four colors of R, G, B, and white (W). As described above, in the touch panel 10, the pixel 21 includes a plurality of subpixels 23 that emit light of different colors, whereby the display portion 20 can display a full-color image. Note that the pixel 21 may include subpixels of R, G, B, and infrared light (IR).

FIG. 2C is a circuit diagram illustrating a structure example of the subpixel 23. The subpixel 23 illustrated in FIG. 2C includes a pixel circuit 40 and a light-emitting element 61. Here, a light-emitting element is one embodiment of a display element.

The pixel circuit 40 includes a transistor 51, a transistor 52, and a capacitor 57. That is, the pixel circuit 40 is a 2Tr1C-type pixel circuit.

One of a source and a drain of the transistor 51 is electrically connected to the wiring 43. The other of the source and the drain of the transistor 51 is electrically connected to a gate of the transistor 52. The gate of the transistor 52 is electrically connected to one electrode of the capacitor 57. A gate of the transistor 51 is electrically connected to the wiring 41.

One of a source and a drain of the transistor 52 is electrically connected to a wiring 45. The other of the source and the drain of the transistor 52 is electrically connected to the other electrode of the capacitor 57. The other electrode of the capacitor 57 is electrically connected to one electrode of the light-emitting element 61. The other electrode of the light-emitting element 61 is electrically connected to a wiring 47. Here, the one electrode of the light-emitting element 61 is also referred to as a pixel electrode. The wiring 47 can be shared between all the subpixels 23, for example; thus, the other electrode of the light-emitting element 61 can also be referred to as a common electrode.

As described above, the wiring 41 functions as a scan line, and the wiring 43 functions as a signal line. The wiring 45 and the wiring 47 each function as a power supply line. For example, in the case where a high power supply potential is supplied to the wiring 45, a low power supply potential is supplied to the wiring 47.

The transistor 51 has a function of a switch and is also referred to as a selection transistor. The transistor 51 has a function of controlling electrical continuity and electrical discontinuity between the wiring 43 and the gate of the transistor 52 on the basis of the potential of the wiring 41. When the transistor 51 is turned on, image data is written to the pixel circuit 40, and when the transistor 51 is turned off, the written image data is retained.

The transistor 52 has a function of controlling the amount of current flowing through the light-emitting element 61 and is also referred to as a driving transistor. The capacitor 57 has a function of retaining a gate potential of the transistor 52. The emission luminance of the light-emitting element 61 is controlled in accordance with a potential that corresponds to image data and is supplied to the gate of the transistor 52. Specifically, in the case where the wiring 45 is supplied with a high power supply potential and the wiring 47 is supplied with a low power supply potential, the amount of current flowing from the wiring 45 to the wiring 47 is controlled in accordance with the gate potential of the transistor 52, whereby the emission luminance of the light-emitting element 61 is controlled.

OS transistors are preferably used as the transistor 51 and the transistor 52. An OS transistor has higher field-effect mobility than a transistor including amorphous silicon, for example. Consequently, by using OS transistors as the transistor 51 and the transistor 52, the touch panel 10 can be driven at high speed.

In an OS transistor, a leakage current between a source and a drain in the off state (also referred to as an off-state current) is extremely low. Thus, by using an OS transistor as the transistor 51, charge accumulated in the capacitor 57 can be retained for a long period. Accordingly, image data written to the subpixel 23 can be retained for a long period, whereby the frequency of refresh operation (rewriting of image data to the subpixel 23) can be reduced. Thus, power consumption of the touch panel 10 can be reduced.

To increase the emission luminance of the light-emitting element 61, the amount of current fed through the light-emitting element 61 needs to be increased. To increase the current amount, it is necessary to increase the source-drain voltage of the transistor 52, which is a driving transistor. Since an OS transistor has higher breakdown voltage between a source and a drain than a transistor including silicon (also referred to as a Si transistor), high voltage can be applied between the source and the drain of the OS transistor. Accordingly, when an OS transistor is used as the transistor 52, the amount of current flowing through the light-emitting element 61 can be increased, so that the emission luminance of the light-emitting element 61 can be increased.

In the case where transistors are driven in a saturation region, a change in the source-drain current relative to a change in the gate-source voltage can be smaller in an OS transistor than in a Si transistor. Accordingly, when an OS transistor is used as the transistor 52, current flowing between the source and the drain can be set minutely by a change in the gate-source voltage. Hence, the amount of current flowing through the light-emitting element 61 can be controlled minutely. Therefore, the luminance of light emitted from the subpixel 23 can be controlled minutely. Accordingly, the number of gray levels represented by the subpixel 23 can be increased.

Regarding saturation characteristics of current flowing when transistors are driven in the saturation region, even when the source-drain voltage of an OS transistor increases gradually, a more stable current (saturation current) can be fed through the OS transistor than through a Si transistor. Thus, by using OS transistors as the transistors 52, a stable current can be fed through the light-emitting elements 61 even when the current-voltage characteristics vary between the light-emitting elements 61, for example. In other words, when the OS transistor is driven in the saturation region, the source-drain current hardly changes with an increase in the source-drain voltage; hence, the emission luminance of the light-emitting element 61 can be stable.

As described above, by using an OS transistor as the transistor 52, it is possible to inhibit black-level degradation, increase the emission luminance, increase the number of gray levels, and suppress variations in emission luminance between the light-emitting elements 61, for example.

Although the transistor 51 and the transistor 52 are n-channel transistors in FIG. 2C, one or both of the transistor 51 and the transistor 52 may be p-channel transistors. The same applies to other transistors described in this specification and the like.

As the light-emitting element 61, an OLED (Organic Light Emitting Diode) or a QLED (Quantum-dot Light Emitting Diode) is preferably used, for example. Examples of a light-emitting substance contained in the light-emitting element 61 include a substance that emits fluorescent light (a fluorescent material), a substance that emits phosphorescent light (a phosphorescent material), a substance that exhibits thermally activated delayed fluorescence (a thermally activated delayed fluorescent (TADF) material), and an inorganic compound (e.g., a quantum dot material). An LED such as a micro-LED (Light Emitting Diode) can also be used as the light-emitting element 61.

FIG. 2D is a circuit diagram illustrating a structure example of the subpixel 23. The subpixel 23 illustrated in FIG. 2D includes the pixel circuit 40 and a liquid crystal element 62. Here, a liquid crystal element is one embodiment of a display element. The pixel circuit 40 includes the transistor 51 and a capacitor 58.

One of the source and the drain of the transistor 51 is electrically connected to the wiring 43. The other of the source and the drain of the transistor 51 is electrically connected to one electrode of the liquid crystal element 62. The one electrode of the liquid crystal element 62 is electrically connected to one electrode of the capacitor 58. The gate of the transistor 51 is electrically connected to the wiring 41. As described above, the wiring 41 functions as a scan line, and the wiring 43 functions as a signal line.

The other electrode of the liquid crystal element 62 and the other electrode of the capacitor 58 are supplied with the same potential. The other electrode of the liquid crystal element 62 and the other electrode of the capacitor 58 can be supplied with a constant potential as a power supply potential, and can be supplied with a ground potential, for example. Here, the one electrode of the liquid crystal element 62 is also referred to as a pixel electrode. The other electrode of the liquid crystal element 62 can be shared by a plurality of the subpixels 23, and can be shared by all the subpixels 23, for example. Thus, the other electrode of the liquid crystal element 62 is also referred to as a common electrode.

As in the pixel circuit 40 illustrated in FIG. 2C, the transistor 51 has a function of a switch and is also referred to as a selection transistor. The transistor 51 has a function of controlling electrical continuity and electrical discontinuity between the wiring 43 and the pixel electrode of the liquid crystal element 62 on the basis of the potential of the wiring 41. As described above, when the transistor 51 is turned on, image data is written to the pixel circuit 40, and when the transistor 51 is turned off, the written image data is retained.

The capacitor 58 has a function of retaining the potential of the one electrode of the liquid crystal element 62. The alignment state of the liquid crystal element 62 is controlled in accordance with a potential that corresponds to image data and is supplied to the one electrode of the liquid crystal element 62.

As described above, an OS transistor is preferably used as the transistor 51. An OS transistor has higher field-effect mobility than a transistor including amorphous silicon, for example. Thus, by using an OS transistor as the transistor 51, the touch panel 10 can be driven at high speed.

As described above, a leakage current between a source and a drain in the off state (also referred to as an off-state current) is extremely low in an OS transistor. Thus, by using an OS transistor as the transistor 51, charge accumulated in the capacitor 58 can be retained for a long period. Accordingly, image data written to the subpixel 23 can be retained for a long period, whereby the frequency of the refresh operation (rewriting of image data to the subpixel 23) can be reduced. Thus, power consumption of the touch panel 10 can be reduced.

Although the transistor 51 is an n-channel transistor in FIG. 2D, the transistor 51 may be a p-channel transistor.

The display apparatus 11 can be a liquid crystal display apparatus, and specifically can be a transmissive liquid crystal display apparatus, for example. A transmissive liquid crystal display apparatus is a display apparatus that controls transmission and non-transmission of light by utilizing polarized light and an optical modulation action of liquid crystal. The optical modulation action of the liquid crystal is controlled by an electric field applied to the liquid crystal (including a horizontal electric field, a vertical electric field, and an oblique electric field). Note that the display apparatus 11 may be a reflective or transflective liquid crystal display apparatus.

The liquid crystal element 62 included in the display apparatus 11 can employ a variety of modes. For example, a vertical alignment (VA) mode or an FFS (Fringe Field Switching) mode can be employed. Examples of the VA mode include an MVA (Multi-Domain Vertical Alignment) mode, a PVA (Patterned Vertical Alignment) mode, and an ASV (Advanced Super View) mode. The liquid crystal element 62 can also employ a TN (Twisted Nematic) mode, an IPS (In-Plane-Switching) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, a guest-host mode, or the like.

Example of a liquid crystal that can be used for the liquid crystal element 62 include a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, and an anti-ferroelectric liquid crystal. Such a liquid crystal material exhibits a cholesteric phase, a smectic phase, a cubic phase, a chiral nematic phase, an isotropic phase, or the like depending on conditions. As the liquid crystal material, either a positive liquid crystal or a negative liquid crystal may be used, and an optimal liquid crystal material can be used depending on the mode or design to be used.

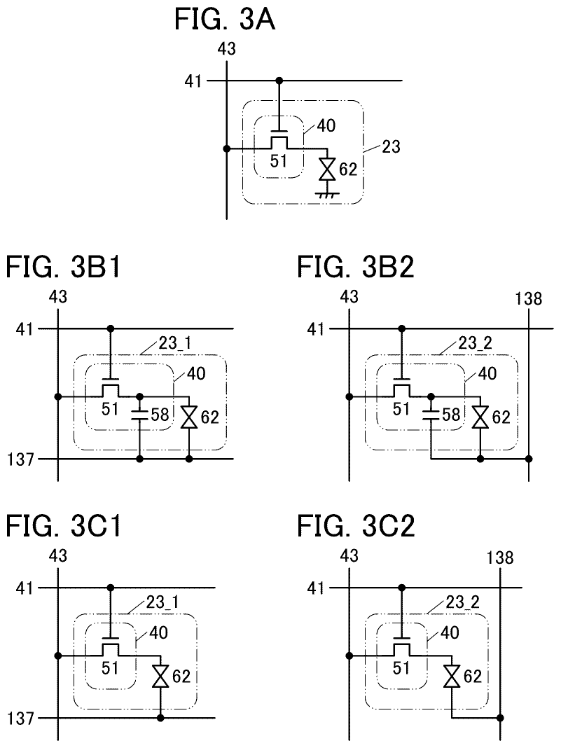

FIG. 3A shows a variation example of the subpixel 23 illustrated in FIG. 2D and illustrates an example in which the pixel circuit 40 does not include the capacitor 58. The capacitor 58 can be omitted as illustrated in FIG. 3A as long as the potential of the pixel electrode of the liquid crystal element 62 can be retained without providing the capacitor 58.

FIG. 3B1 and FIG. 3B2 show variation examples of the subpixel 23 illustrated in FIG. 2D. FIG. 3B1 illustrates an example in which the other electrode of the liquid crystal element 62 and the other electrode of the capacitor 58 are electrically connected to the wiring 137. As illustrated in FIG. 3B1, the wiring 137 can include a region extending in the direction parallel to the wiring 41 and can include a region overlapping the wiring 43. Here, the subpixel 23 illustrated in FIG. 3B1 is denoted as a subpixel 23_1.

FIG. 3B2 illustrates an example in which the other electrode of the liquid crystal element 62 and the other electrode of the capacitor 58 are electrically connected to the wiring 138. As illustrated in FIG. 3B2, the wiring 138 can include a region extending in the direction parallel to the wiring 43 and can include a region overlapping the wiring 41. Here, the subpixel 23 illustrated in FIG. 3B2 is denoted as a subpixel 23_2.

As illustrated in FIG. 1A, the wiring 137 is electrically connected to the electrode 127 included in the sensing element. Thus, in the subpixel 23 1, the potential of the other electrode of the liquid crystal element 62 and the potential of the other electrode of the capacitor 58 are equal to the potential of the electrode 127. The wiring 138 is electrically connected to the electrode 128 included in the sensing element. Thus, in the subpixel 23_2, the potential of the other electrode of the liquid crystal element 62 and the potential of the other electrode of the capacitor 58 are equal to the potential of the electrode 128. Accordingly, the touch panel 10 does not need to include a power supply circuit for supplying a potential to the other electrode of the liquid crystal element 62 and the other electrode of the capacitor 58.

The subpixel 23_1 illustrated in FIG. 3B1 and the subpixel 23_2 illustrated in FIG. 3B2 can be included in one display portion 20. In other words, some of the subpixels 23 provided in the display portion 20 can be the subpixels 23_1 and the others can be the subpixels 23 2. For example, half of the subpixels 23 provided in the display portion 20 can be the subpixels 23_1 and the other half can be the subpixels 23_2.

FIG. 3C1 and FIG. 3C2 show variation examples of the subpixel 23_1 illustrated in FIG. 3B1 and the subpixel 23_2 illustrated in FIG. 3B2, respectively, and illustrate examples in which the pixel circuit 40 does not include the capacitor 58. The capacitor 58 can be omitted as illustrated in FIG. 3C1 and FIG. 3C2 as long as the potential of the pixel electrode of the liquid crystal element 62 can be retained without providing the capacitor 58.

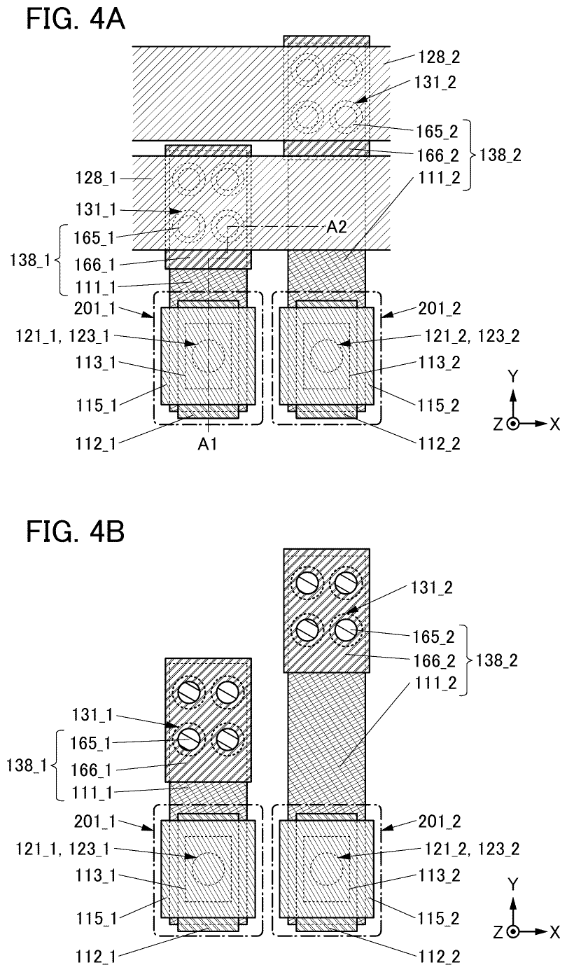

FIG. 4A is a plan view illustrating a structure example of part of the touch panel 10 and includes a portion indicated by the dashed-dotted line A1-A2 in FIG. 1B. FIG. 4A illustrates a structure example of the electrode 128, the wiring 138, and a transistor 201 provided in the input device driver circuit 15. Note that in FIG. 4A, some of the components, such as a substrate and an insulating layer, are not illustrated. Also in the following plan views, some components such as a substrate and an insulating layer are not illustrated, unless otherwise specified.

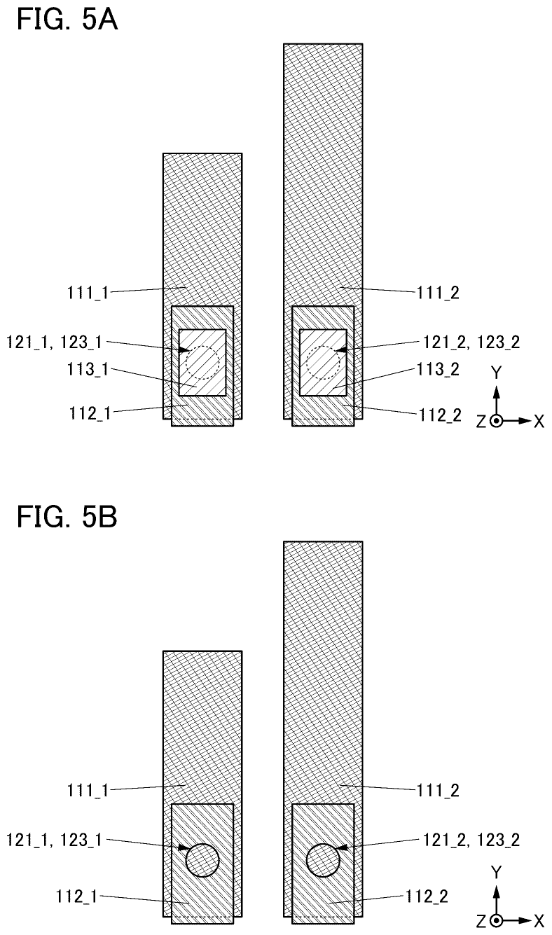

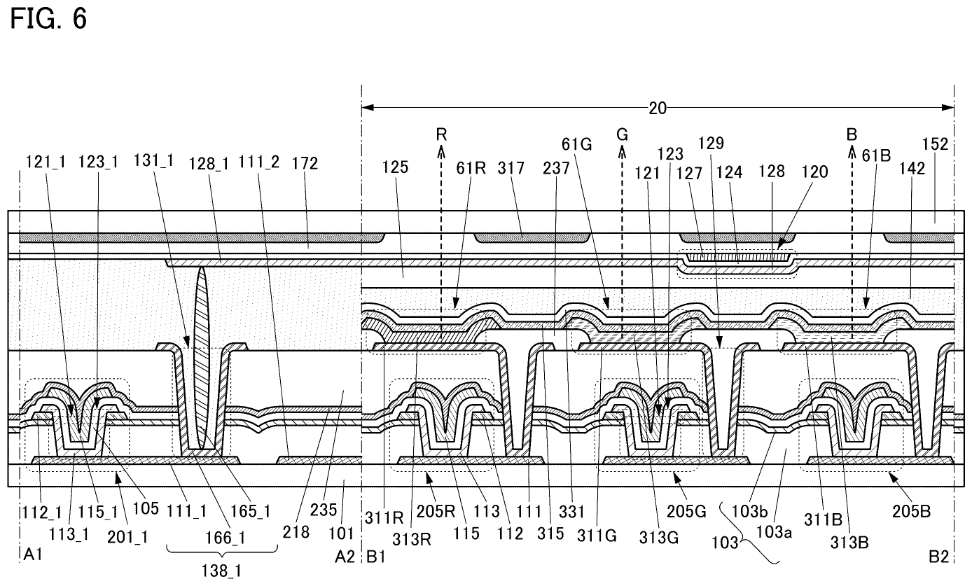

FIG. 4B, FIG. 5A, and FIG. 5B are plan views that omit some of the components illustrated in FIG. 4A. FIG. 6 is a cross-sectional view along the dashed-dotted line A1-A2 in FIG. 1B and FIG. 4A, the dashed-dotted line B1-B2 in FIG. 1B, and the like.

The transistor 201 is provided over the substrate 101. FIG. 4A illustrates structure examples of a transistor 201_1 and a transistor 201_2 as the transistor 201. Also in the following plan views illustrating a structure example of the transistor 201, the transistor 201_1 and the transistor 201 2 are illustrated as the transistor 201.

The transistor 201 includes a conductive layer 111, a conductive layer 112, a semiconductor layer 113, an insulating layer 105, and a conductive layer 115. Here, the conductive layer 111, the conductive layer 112, the semiconductor layer 113, and the conductive layer 115 in the transistor 201_1 are denoted as a conductive layer 111_1, a conductive layer 112_1, a semiconductor layer 113_1, and a conductive layer 115_1. The conductive layer 111, the conductive layer 112, the semiconductor layer 113, and the conductive layer 115 in the transistor 201_2 are denoted as a conductive layer 111_2, a conductive layer 112_2, a semiconductor layer 113_2, and a conductive layer 115_2.

The conductive layer 111 functions as one of a source electrode and a drain electrode of the transistor 201. The conductive layer 112 functions as the other of the source electrode and the drain electrode of the transistor 201. The insulating layer 105 functions as a gate insulating layer of the transistor 201. The conductive layer 115 functions as a gate electrode of the transistor 201.

In the semiconductor layer 113 between the source electrode and the drain electrode, the whole region overlapped by the gate electrode with the gate insulating layer therebetween functions as a channel formation region. In the semiconductor layer 113, a region in contact with the source electrode functions as a source region, and a region in contact with the drain electrode functions as a drain region.

The conductive layer 111 is provided over the substrate 101, an insulating layer 103 is provided over the substrate 101 and the conductive layer 111, and the conductive layer 112 is provided over the insulating layer 103. The insulating layer 103 can have a function of an interlayer insulating layer. The conductive layer 111 and the conductive layer 112 have an overlapping region with the insulating layer 103 therebetween. Here, the thickness of the insulating layer 103 functioning as an interlayer insulating layer can be larger than the thickness of the insulating layer 105 functioning as the gate insulating layer of the transistor 201.

The insulating layer 103 has an opening 121 reaching the conductive layer 111. The conductive layer 112 has an opening 123 reaching the opening 121. That is, the opening 123 includes a region overlapping the opening 121. Moreover, the opening 123 includes a region overlapping the conductive layer 111. Here, it is preferable that the conductive layer 112 not be provided in the opening 121. In other words, it is preferable that the conductive layer 112 be not in contact with a side surface of the insulating layer 103 on the opening 121 side. Note that the opening 121 and the opening 123 provided in the transistor 201_1 are denoted as an opening 121_1 and an opening 123_1, and the opening 121 and the opening 123 provided in the transistor 201_2 are denoted as an opening 121_2 and an opening 123_2.

FIG. 6 illustrates an example in which an end portion of the conductive layer 112 on the opening 123 side is aligned or substantially aligned with an end portion of the insulating layer 103 on the opening 121 side. In other words, the planar shape of the opening 123 is the same or substantially the same as the planar shape of the opening 121. Note that in this specification and the like, the end portion of the conductive layer 112 on the opening 123 side and an end portion of the opening 123 each refer to an end portion of the bottom surface of the conductive layer 112 on the opening 123 side. The bottom surface of the conductive layer 112 refers to the surface thereof on the insulating layer 103 side. The end portion of the insulating layer 103 on the opening 121 side and an end portion of the opening 121 each refer to an end portion of the top surface of the insulating layer 103 on the opening 121 side. The top surface of the insulating layer 103 refers to the surface thereof on the conductive layer 112 side. The planar shape of the opening 123 refers to the shape of the end portion of the bottom surface of the conductive layer 112 on the opening 123 side. The planar shape of the opening 121 refers to the shape of the end portion of the top surface of the insulating layer 103 on the opening 121 side.

In the case where end portions are aligned or substantially aligned with each other, the end portions can also be said to match or substantially match. In the case where end portions match or substantially match and the case where planar surface shapes are the same or substantially the same, it can be said that outlines of stacked layers at least partly overlap each other in a plan view. For example, the case of processing an upper layer and a lower layer with the use of the same mask pattern or mask patterns that are partly the same is included. Note that in some cases, the outlines do not completely overlap each other and the upper layer is positioned inward from the lower layer or the upper layer is positioned outward from the lower layer; such cases are also represented by the expression “end portions substantially match” or the expression “planar shapes are substantially the same”.

The opening 121 can be formed using a resist mask used for the formation of the opening 123, for example. Specifically, first, the conductive layer 111 is formed over the substrate 101, and then the insulating layer 103 over the substrate 101 and the conductive layer 111, a conductive film to be the conductive layer 112 in a later step over the insulating layer 103, and a resist mask over the conductive film are formed. Then, the opening 123 is formed in the conductive film using the resist mask and then the opening 121 is formed in the insulating layer 103 using the resist mask, whereby the end portion of the opening 121 and the end portion of the opening 123 can be aligned or substantially aligned with each other. With such a structure, the process can be simplified.

The semiconductor layer 113 includes a region positioned in the opening 121 and the opening 123 and is provided to cover the opening 121 and the opening 123. The semiconductor layer 113 has a shape along the shapes of the top surface and the side surface of the conductive layer 112, the side surface of the insulating layer 103, and the top surface of the conductive layer 111. The semiconductor layer 113 includes a region in contact with the top surface and the side surface of the conductive layer 112, the side surface of the insulating layer 103, and the top surface of the conductive layer 111, for example.

The semiconductor layer 113 preferably covers the end portion of the conductive layer 112 on the opening 123 side. For example, FIG. 6 illustrates a structure where an end portion of the semiconductor layer 113 is positioned over the conductive layer 112. In other words, the end portion of the semiconductor layer 113 is in contact with the top surface of the conductive layer 112.

Although the semiconductor layer 113 has a single-layer structure in FIG. 6, for example, one embodiment of the present invention is not limited thereto. The semiconductor layer 113 may have a stacked-layer structure of two or more layers.

The insulating layer 105 functioning as the gate insulating layer of the transistor 201 includes a region positioned in the opening 121 and the opening 123 and is provided to cover the opening 121 and the opening 123. The insulating layer 105 is provided over the semiconductor layer 113, the conductive layer 112, and the insulating layer 103. The insulating layer 105 can include a region in contact with the top surface and the side surface of the semiconductor layer 113, the top surface and the side surface of the conductive layer 112, and the top surface of the insulating layer 103. The insulating layer 105 has a shape along the shapes of the top surface of the insulating layer 103, the top surface and the side surface of the conductive layer 112, and the top surface and the side surface of the semiconductor layer 113.

The conductive layer 115 functioning as the gate electrode of the transistor 201 is provided over the insulating layer 105 and can include a region in contact with the top surface of the insulating layer 105. The conductive layer 115 includes a region overlapping the semiconductor layer 113 with the insulating layer 105 therebetween.

For example, as illustrated in FIG. 6, the conductive layer 115 is provided to include a region positioned in the opening 121 and a region positioned in the opening 123, and to include a region facing the semiconductor layer 113 with the insulating layer 105 therebetween. Moreover, in the example illustrated in FIG. 6, the conductive layer 115 includes regions overlapping the conductive layer 111 and the conductive layer 112 with the insulating layer 105 and the semiconductor layer 113 therebetween. The conductive layer 115 covers the entire semiconductor layer 113. With such a structure, a gate electric field can be applied to the entire semiconductor layer 113, which allows the transistor 201 to have better electrical characteristics, such as a higher on-state current.

The transistor 201 is what is called a top-gate transistor including the gate electrode above the semiconductor layer 113. Furthermore, since the bottom surface of the semiconductor layer 113 includes regions in contact with the source electrode and the drain electrode, the transistor 201 can be referred to as a TGBC (Top Gate Bottom Contact) transistor.

In the display portion 20, a transistor 205 is provided over the substrate 101. The transistor 205 can have the same structure as the transistor 201 and can be provided in the same layer as the transistor 201. Thus, the transistor 205 can be formed in the same process as the transistor 201.

For example, the conductive layer 111 of the transistor 205 functions as one of a source electrode and a drain electrode of the transistor 205. The conductive layer 112 of the transistor 205 functions as the other of the source electrode and the drain electrode of the transistor 205. The insulating layer 105 functions as a gate insulating layer of the transistor 205. The conductive layer 115 of the transistor 205 functions as a gate electrode of the transistor 205. Here, the transistor 205 corresponds to the transistor 52 illustrated in FIG. 2C, for example. Note that the transistor 51 can have the same structure as the transistor 205 and can be provided in the same layer as the transistor 205.

In the case where at least part of the input device driver circuit 15 is incorporated in the touch panel 10, the transistor 201 provided in the input device driver circuit 15 can be formed in the same process as the transistor 205 provided in the display portion 20. Accordingly, the touch panel 10 can be a touch panel with a simplified manufacturing process. Thus, the touch panel 10 can be manufactured by a method with low cost and high mass productivity. Note that as described above, some of the circuits included in the input device driver circuit 15 may be externally provided. For example, a circuit including a transistor, a capacitor, and the like that are included in the input device driver circuit 15 and are electrically connected to neither the electrode 127 nor the electrode 128 may be externally provided.

Note that in the case where at least part of the scan line driver circuit 13 is incorporated in the touch panel 10, transistors provided in the scan line driver circuit 13 can be formed in the same process as the transistor 205. In the case where at least part of the signal line driver circuit 14 is incorporated in the touch panel 10, transistors provided in the signal line driver circuit 14 can be formed in the same process as the transistor 205. In the above manner, the manufacturing process of the touch panel 10 can be simplified, and the touch panel 10 can be manufactured by a method with low cost and high mass productivity.

An insulating layer 218 is provided over the conductive layer 115 and the insulating layer 103 to cover the transistor 201 and the transistor 205. An insulating layer 235 is provided over the insulating layer 218. The insulating layer 218 and the insulating layer 235 function as interlayer insulating layers. In the display portion 20, the light-emitting element 61 is provided over the insulating layer 235, and a protective layer 331 is provided to cover the light-emitting element 61.

The light-emitting element 61 includes a pixel electrode 311 over the insulating layer 235, an island-shaped layer 313 over the pixel electrode 311, and a common electrode 315 over the island-shaped layer 313. The layer 313 includes at least a light-emitting layer. Note that the layer 313 can be referred to as an EL layer. The common electrode is also referred to as a counter electrode.

The insulating layer 103, the insulating layer 105, the insulating layer 218, and the insulating layer 235 includes an opening 129 reaching the conductive layer 111 of the transistor 205. The opening 129 can be formed by an etching method, for example. The pixel electrode 311 is provided to cover the opening 129. The pixel electrode 311 has a shape along the top surface and the side surface of the insulating layer 235, the side surface of the insulating layer 218, the side surface of the insulating layer 105, the side surface of the insulating layer 103, and the top surface of the conductive layer 111. The pixel electrode 311 includes a region in contact with the top surface and the side surface of the insulating layer 235, the side surface of the insulating layer 218, the side surface of the insulating layer 105, the side surface of the insulating layer 103, and the top surface of the conductive layer 111, for example. The pixel electrode 311 can be electrically connected to the conductive layer 111 of the transistor 205 in the opening 129.

An insulating layer 237 can be provided to cover the end portion of the pixel electrode 311. The insulating layer 237 functions as a partition (also referred to as a bank or a spacer). Providing the insulating layer 237 can prevent a contact between the pixel electrode 311 and the common electrode 315 to inhibit a short circuit in the light-emitting element 61. Note that although FIG. 6 illustrates a plurality of cross sections of the insulating layer 237, the insulating layer 237 is one continuous layer when the touch panel 10 is seen from above. In other words, the touch panel 10 can have a structure including one insulating layer 237, for example. Note that the touch panel 10 may include a plurality of insulating layers 237 that are separated from each other. The same applies to other cross-sectional views including the insulating layer 237.

A depressed portion is formed in the pixel electrode 311 to cover the opening 129, and the insulating layer 237 is embedded in the depressed portion. After the insulating layer 237 covering the end portion of the pixel electrode 311 and the opening 129 is formed, the layer 313 can be formed using a fine metal mask (FMM).

In FIG. 6, a light-emitting element 61R, a light-emitting element 61G, and a light-emitting element 61B are illustrated as the light-emitting element 61. Here, the pixel electrode 311 and the layer 313 included in the light-emitting element 61R are denoted as a pixel electrode 311R and a layer 313R. The pixel electrode 311 and the layer 313 included in the light-emitting element 61G are denoted as a pixel electrode 311G and a layer 313G. The pixel electrode 311 and the layer 313 included in the light-emitting element 61B are denoted as a pixel electrode 311B and a layer 313B. The common electrode 315 is provided over the layer 313R, the layer 313G, and the layer 313B. The common electrode 315 is shared by the light-emitting element 61R, the light-emitting element 61G, and the light-emitting element 61B. Here, the transistor 205 electrically connected to the pixel electrode 311R is denoted as a transistor 205R, the transistor 205 electrically connected to the pixel electrode 311G is denoted as a transistor 205G, and the transistor 205 electrically connected to the pixel electrode 311B is denoted as a transistor 205B.

The layer 313R, the layer 313G, and the layer 313B each include at least a light-emitting layer. For example, the layer 313R includes a light-emitting layer that emits red light, the layer 313G includes a light-emitting layer that emits green light, and the layer 313B includes a light-emitting layer that emits blue light. In other words, the layer 313R includes a light-emitting substance that emits red light, the layer 313G includes a light-emitting substance that emits green light, and the layer 313B includes a light-emitting substance that emits blue light. Accordingly, the light-emitting element 61R can emit red light, the light-emitting element 61G can emit green light, and the light-emitting element 61B can emit blue light.

The layer 313R, the layer 313G, and the layer 313B may each include one or more of a hole-injection layer, a hole-transport layer, a hole-blocking layer, a charge-generation layer, an electron-blocking layer, an electron-transport layer, and an electron-injection layer.

For example, the layer 313R, the layer 313G, and the layer 313B may each include a hole-injection layer, a hole-transport layer, a light-emitting layer, an electron-transport layer, and an electron-injection layer in this order. Alternatively, the layer 313R, the layer 313G, and the layer 313B may each include an electron-injection layer, an electron-transport layer, a light-emitting layer, a hole-transport layer, and a hole-injection layer in this order. Furthermore, an electron-blocking layer may be provided between the hole-transport layer and the light-emitting layer, or a hole-blocking layer may be provided between the electron-transport layer and the light-emitting layer.

For each of the light-emitting element 61R, the light-emitting element 61G, and the light-emitting element 61B, a single structure (a structure including only one light-emitting unit) or a tandem structure (a structure including a plurality of light-emitting units) may be employed. The light-emitting unit includes at least one light-emitting layer.

In the case where the light-emitting element 61R, the light-emitting element 61G, and the light-emitting element 61B have a tandem structure, preferably, the layer 313R includes a plurality of light-emitting units that emit red light, the layer 313G includes a plurality of light-emitting units that emit green light, and the layer 313B includes a plurality of light-emitting units that emit blue light. A charge-generation layer is preferably provided between the light-emitting units. In the case where the light-emitting element 61R, the light-emitting element 61G, and the light-emitting element 61B have a tandem structure, the layer 313R, the layer 313G, and the layer 313B can each include a first light-emitting unit, a charge-generation layer over the first light-emitting unit, and a second light-emitting unit over the charge-generation layer, for example.

The layer 313R, the layer 313G, and the layer 313B can each be formed by a vacuum evaporation method using a fine metal mask, for example. In a vacuum evaporation method using a fine metal mask, deposition is performed in an area wider than an opening of the fine metal mask in many cases. Thus, the layer 313R, the layer 313G, and the layer 313B can be formed in the area wider than the opening of the fine metal mask. The end portions of the layer 313R, the layer 313G, and the layer 313B each have a tapered shape. Here, the layer 313R, the layer 313G, and the layer 313B may be provided not only over the pixel electrode 311 but also over the insulating layer 237. Note that a sputtering method using a fine metal mask or an inkjet method may be used to form the layer 313R, the layer 313G, and the layer 313B.

The touch panel 10 has a top-emission structure. Light emitted from the light-emitting element 61R, the light-emitting element 61G, and the light-emitting element 61B is emitted to the substrate 152 side. Thus, for the substrate 152, a material having a high visible-light-transmitting property is preferably used. In contrast, there is no limitation on the light-transmitting property of a material used for the substrate 101.

For the common electrode 315, a material having a high visible-light-transmitting property is used. A material that reflects visible light is preferably used for each of the pixel electrode 311R, the pixel electrode 311G, and the pixel electrode 311B. For the pixel electrode 311 and the common electrode 315, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other example of the material include elements that belong to Group 1 and Group 2 of the periodic table and are not exemplified above (e.g., lithium, cesium, calcium, and strontium), rare earth metals such as europium and ytterbium, an alloy containing any of these elements in appropriate combination, and graphene.

An insulating layer 172, the electrode 127, an insulating layer 124, the electrode 128, and an insulating layer 125 are provided in this order on a surface of the substrate 152 on the substrate 101 side. Here, a sensing element including the electrode 127 and the electrode 128 as a pair of electrodes is referred to as a sensing element 120. The electrode 127 and the electrode 128 are provided not only in the display portion 20 but also in a region other than the display portion 20. In FIG. 6, out of the electrode 127 and the electrode 128, the electrode 128 is illustrated as an electrode provided in the region other than the display portion 20. Note that the insulating layer 124 is not included in the sensing element 120.

The insulating layer 103, the insulating layer 105, the insulating layer 218, and the insulating layer 235 include an opening 131 reaching the conductive layer 111 of the transistor 201. The opening 131 includes a region overlapped by the electrode 127 or the electrode 128. FIG. 6 illustrates the opening 131 including a region overlapped by the electrode 128. The opening 131 can be formed by an etching method, for example.

A conductive layer 166 is provided to cover the opening 131. The conductive layer 166 has a shape along the top surface and the side surface of the insulating layer 235, the side surface of the insulating layer 218, the side surface of the insulating layer 105, the side surface of the insulating layer 103, and the top surface of the conductive layer 111. The conductive layer 166 includes a region in contact with the top surface and the side surface of the insulating layer 235, the side surface of the insulating layer 218, the side surface of the insulating layer 105, the side surface of the insulating layer 103, and the top surface of the conductive layer 111, for example. The conductive layer 166 can be electrically connected to the conductive layer 111 of the transistor 201 in the opening 131. Here, the opening 131 reaching the conductive layer 111_1 is denoted as an opening 131_1, and the opening 131 reaching the conductive layer 111_2 is denoted as an opening 131_2. The conductive layer 166 provided to cover the opening 131_1 is denoted as a conductive layer 166_1, and the conductive layer 166 provided to cover the opening 131_2 is denoted as a conductive layer 166_2.

The opening 131 can be formed in the same step as the opening 129. The conductive layer 166 can be provided in the same layer as the pixel electrode 311. Thus, the conductive layer 166 can include the same material as the pixel electrode 311 and can be formed in the same step as the pixel electrode 311. For example, the conductive layer 166 and the pixel electrode 311 can be formed by processing the same conductive film.

FIG. 4A illustrates an example in which the conductive layer 111 extends in a first direction and the electrode 128 extends in a second direction perpendicular to the first direction. Here, as indicated by the coordinate axes, the first direction is the Y direction and the second direction is the X direction. Note that the first direction may be the X direction and the second direction may be the Y direction. Furthermore, a direction perpendicular to both the X direction and the Y direction is referred to as the Z direction. The Z direction is a direction perpendicular to the top surface of the substrate 101, for example, and is a height direction. The definition of the X direction, the Y direction, and the Z direction applies to some of the following drawings and does not apply to other drawings.

The substrate 101 and the substrate 152 are bonded to each other with an adhesive layer 142. For example, the protective layer 331 and the insulating layer 125 are bonded to each other with the adhesive layer 142. For the adhesive layer 142, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. A two-component-mixture-type resin may be used. Alternatively, an adhesive sheet may be used, for example.

The adhesive layer 142 includes a conductive particle 165. Thus, the conductive layer 166 provided on the substrate 101 side and the electrode 128 provided on the substrate 152 side can be electrically connected to each other through the conductive particle 165. For example, when the conductive layer 166 and the electrode 128 each include a region in contact with the conductive particle 165, the conductive layer 166 provided on the substrate 101 side and the electrode 128 provided on the substrate 152 side can be electrically connected to each other. As described above, the conductive layer 166 is electrically connected to the conductive layer 111 functioning as one of the source electrode and the drain electrode of the transistor 201. Accordingly, the conductive layer 111 and the electrode 128 are electrically connected to each other through the conductive layer 166 and the conductive particle 165. Therefore, the conductive layer 166 is also referred to as a connection electrode. Here, the conductive particle 165 and the electrode 128 that are electrically connected to the conductive layer 166_1 are denoted as a conductive particle 165_1 and an electrode 128_1, respectively. The conductive particle 165 and the electrode 128 that are electrically connected to the conductive layer 166_2 are denoted as a conductive particle 165_2 and an electrode 128_2, respectively.

In the example illustrated in FIG. 4A and FIG. 6, the wiring 138 includes at least parts of the conductive layer 111, the conductive layer 166, and the conductive particle 165. For example, the conductive layer 111 in a region overlapped by none of the conductive layer 112, the semiconductor layer 113, and the conductive layer 115, the conductive layer 166, and the conductive particle 165 can serve as the wiring 138. Here, the wiring 138 including at least parts of the conductive layer 111_1, the conductive layer 166_1, and the conductive particle 165_1 is denoted as a wiring 138_1. The wiring 138 including at least parts of the conductive layer 111_2, the conductive layer 166_2, and the conductive particle 165_2 is denoted as a wiring 138_2.

As the conductive particle 165, a particle of an organic resin, silica, or the like coated with a metal material can be used. Here, nickel or gold, for example, is preferably used as the metal material, in which case contact resistance can be reduced. As the conductive particle 165, it is preferable to use a particle coated with layers of two or more types of metal materials, such as a particle coated with nickel and further with gold.

Here, the conductive particle 165 is included in the adhesive layer 142 so as to include a region positioned in the opening 131. Thus, the conductive particle 165 is provided between the conductive layer 166 and the electrode 128 so as to include a region positioned in the opening 131. The conductive particle 165 provided in the opening 131 is more likely to avoid being out of contact with the conductive layer 166, for example, than the conductive particle 165 provided outside the opening 131. For example, even when the conductive particle 165 is provided at a position that is in the vicinity of the opening 131 but does not overlap the conductive layer 166 right after the substrate 101 and the substrate 152 are bonded to each other using the adhesive layer 142 including the conductive particle 165, the position of the conductive particle 165 is shifted owing to a step formed by the opening 131 and the conductive particle 165 enters the opening 131 in some cases. This can sometimes inhibit the conductive particle 165 from being out of contact with the conductive layer 166.

In the above manner, the conductive particle 165 can be easily in contact with both the conductive layer 166 and the electrode 128, for example. This facilitates electrical connection between the conductive layer 166 and the electrode 128. Here, both the conductive layer 111 and the conductive layer 112 of the transistor 201 function as the source electrode or the drain electrode of the transistor 201; the opening 131 that is formed to reach the conductive layer 111 can be made deeper than the opening 131 that is formed to reach the conductive layer 112 by the thickness of the insulating layer 103. Thus, when the opening 131 is formed to reach the conductive layer 111, the conductive particle 165 that has entered the opening 131 can be inhibited from leaving the opening 131 in some cases, for example, as compared with the case where the opening 131 is formed to reach the conductive layer 112.

The touch panel 10 does not necessarily include the conductive layer 166. In this case, the conductive layer 111 and the electrode 128 can be electrically connected to each other when the conductive particle 165 includes a region in contact with the conductive layer 111 in the opening 131, for example.

Although the example in which the electrode 128 and the conductive layer 111 of the transistor 201 are electrically connected to each other is described above, the electrode 127 and the conductive layer 111 of the transistor 201 can be electrically connected to each other in a similar manner. Specifically, the electrode 127 and the conductive layer 111 of the transistor 201 can be electrically connected to each other through the conductive layer 166 and the conductive particle 165 that include a region positioned in the opening 131 and a region overlapped by the electrode 127.

Accordingly, the electrode 127 and the conductive layer 111 of the transistor 201 can be easily electrically connected to each other. In addition, the electrode 128 and the conductive layer 111 of the transistor 201 can be easily electrically connected to each other. Hence, the touch panel 10 can be manufactured by a high-yield method and thus can be inexpensive. Furthermore, occurrence of a defect in which the conductive layer 111 of the transistor 201 is not electrically connected to the electrode 127 or the electrode 128 can be inhibited; thus, the touch panel 10 can be a highly reliable touch panel.

A light-blocking layer 317 may be provided on the surface of the substrate 152 on the substrate 101 side. In this case, a portion where the light-blocking layer 317 is provided is a non-display region. That is, in the display portion 20, a portion where the light-blocking layer 317 is not provided can serve as a display region.

The light-blocking layer 317 can be provided to overlap a region between adjacent light-emitting elements 61. Providing the light-blocking layer 317 can inhibit reflection of external light, for example, thereby increasing the contrast ratio of images displayed on the display portion 20. When the light-blocking layer 317 is provided closer to the substrate 152 than the electrode 127 and the electrode 128 are, components of the touch panel 10, such as the electrode 127 and the electrode 128, can be inhibited from being perceived by the user of the touch panel 10. Note that a structure without the light-blocking layer 317 may be employed. This can increase the extraction efficiency of light emitted from the light-emitting element 61.

To electrically connect the conductive layer 166 to the electrode 127 and the conductive layer 166 to the electrode 128, a portion where the insulating layer 237, the protective layer 331, and the insulating layer 125 are not provided is formed outside the display portion 20. For example, after the insulating layer 125 is formed over the entire surface of the substrate 152, part of the insulating layer 125 is removed by a photolithography method and an etching method, or the like, whereby part of the electrode 127 and part of the electrode 128 can be exposed.

The top surface of the conductive layer 166 may be covered with a mask so that the protective layer 331 is not formed over the conductive layer 166. As the mask, a metal mask (an area metal mask) may be used, or a tape or a film having adhesiveness or attachability may be used. The protective layer 331 is formed while the mask is placed, and then the mask is removed, whereby the conductive layer 166 can be kept exposed even after the protective layer 331 is formed. The insulating layer 125 can be formed by a similar method.

Accordingly, the touch panel 10 includes a region where the adhesive layer 142 is provided between the conductive layer 166 and each of the electrode 127 and the electrode 128 outside the display portion 20. Since the conductive layer 111 is provided under the conductive layer 166, the touch panel 10 can be regarded as including a region where the adhesive layer 142 is provided between the conductive layer 111 and the electrode 127 and a region where the adhesive layer 142 is provided between the conductive layer 111 and the electrode 128 outside the display portion 20. Moreover, the touch panel 10 includes a region where the adhesive layer 142 is provided between the insulating layer 235 and the electrode 127 and a region where the adhesive layer 142 is provided between the insulating layer 235 and the electrode 128. The touch panel 10 also includes a region where the adhesive layer 142 is provided between the insulating layer 235 and the insulating layer 124. Although FIG. 6 illustrates an example in which the insulating layer 237, the protective layer 331, and the insulating layer 125 are not provided in any region except the display portion 20, at least one of the insulating layer 237, the protective layer 331, and the insulating layer 125 may be provided in part of a region other than the display portion 20.

Transistors included in the scan line driver circuit 13, the signal line driver circuit 14, and the input device driver circuit 15 and transistors included in the display portion 20 may have the same structure or different structures. The structures of the plurality of transistors included in the scan line driver circuit 13, the signal line driver circuit 14, and the input device driver circuit 15 may all be the same or may be two or more types of structures.

FIG. 4B is a plan view illustrating a structure example in which the electrode 128_1 and the electrode 128_2 are omitted from the components illustrated in FIG. 4A. For example, as illustrated in FIG. 4B, a plurality of the openings 131_1 can be provided, and the conductive particle 165_1 can be provided in each of the openings 131_1. Similarly, a plurality of the openings 131_2 can be provided, and the conductive particle 165_2 can be provided in each of the openings 131_2. Providing the plurality of openings 131_1 can increase the total of the perimeters of the openings 131_1 in a plan view. This sometimes makes the conductive particle 165_1 likely to enter the openings 131_1. Similarly, providing the plurality of openings 131_2 sometimes makes the conductive particle 165_2 likely to enter the openings 131_2.

FIG. 5A is a plan view illustrating a structure example in which the conductive particle 165_1, the conductive particle 165_2, the conductive layer 166_1, the conductive layer 166_2, the openings 131_1, and the openings 131_2 are omitted from the components illustrated in FIG. 4B. FIG. 5B is a plan view illustrating a structure example in which the semiconductor layer 113_1 and the semiconductor layer 113_2 are omitted from the components illustrated in FIG. 5A. For example, as illustrated in FIG. 5B, the conductive layer 112 can entirely surround the periphery of the opening 121 in a plan view.

FIG. 4A, FIG. 4B, FIG. 5A, and FIG. 5B illustrate an example in which the planar shapes of the opening 121 and the opening 123 are circular shapes. FIG. 4A and FIG. 4B illustrate an example in which the planar shape of the opening 131 is a circular shape. In the case where the planar shapes of the opening 121, the opening 123, and the opening 131 are circular shapes, processing accuracy at the time of forming the opening 121, the opening 123, and the opening 131 can be increased, and the opening 121, the opening 123, and the opening 131 having minute sizes can be formed. Note that in this specification and the like, a circular shape is not necessarily a perfect circular shape. For example, the planar shapes of the opening 121, the opening 123, and the opening 131 may be elliptical shapes. The planar shape of the opening 129 can be a circular shape or an elliptical shape like the planar shape of the opening 131. Furthermore, although the planar shape of the conductive particle 165 is a circular shape in FIG. 4A and FIG. 4B, one embodiment of the present invention is not limited thereto, and the conductive particle 165 may have an elliptical planar shape, for example.

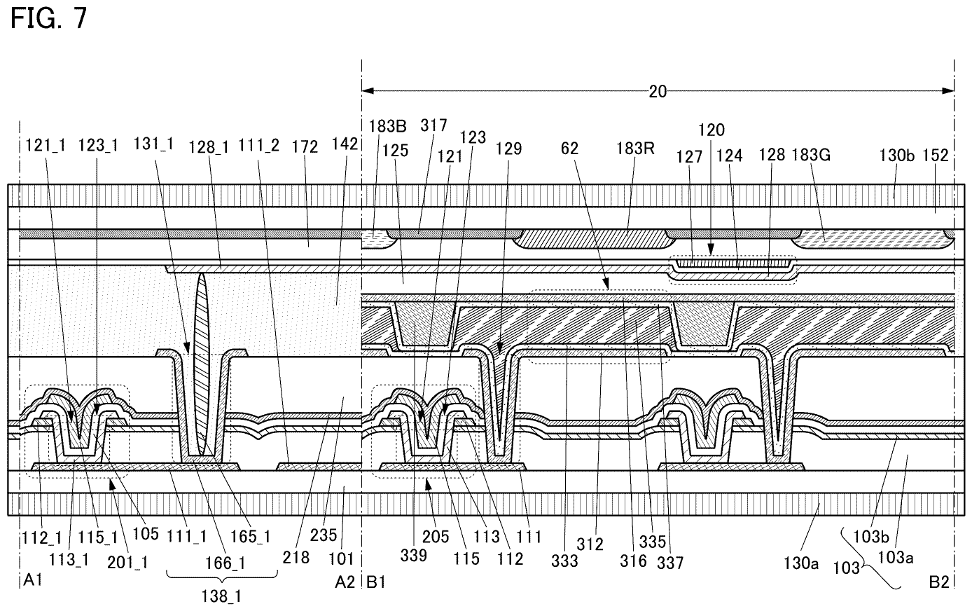

FIG. 7 shows a variation example of the structure illustrated in FIG. 6 and illustrates an example in which the liquid crystal element 62 is included as a display element. The liquid crystal element 62 is provided over the insulating layer 235 of the display portion 20. The transistor 205 corresponds to the transistor 51 illustrated in FIG. 2D, for example.

The liquid crystal element 62 includes a pixel electrode 312, a liquid crystal 335, and a common electrode 316. FIG. 7 illustrates an example in which the liquid crystal element 62 employs the VA mode, and the liquid crystal 335 is provided between the pixel electrode 312 and the common electrode 316. Here, a display apparatus including a liquid crystal element employing the VA mode is a vertical electric field liquid crystal display apparatus. Accordingly, the display apparatus 11 having the structure illustrated in FIG. 7 is a vertical electric field liquid crystal display apparatus.

The pixel electrode 312 is provided separately for each of the liquid crystal elements 62, and the common electrode 316 is shared by a plurality of the liquid crystal elements 62. Note that in the case where the liquid crystal element 62 employs the VA mode, the common electrode can also be referred to as a counter electrode.

In the example illustrated in FIG. 7, the pixel electrode 312 is provided to cover the opening 129. The pixel electrode 312 has a shape along the top surface and the side surface of the insulating layer 235, the side surface of the insulating layer 218, the side surface of the insulating layer 105, the side surface of the insulating layer 103, and the top surface of the conductive layer 111. The pixel electrode 312 includes a region in contact with the top surface and the side surface of the insulating layer 235, the side surface of the insulating layer 218, the side surface of the insulating layer 105, the side surface of the insulating layer 103, and the top surface of the conductive layer 111. The pixel electrode 312 can be electrically connected to the conductive layer 111 of the transistor 205 in the opening 129.

On the surface of the substrate 152 on the substrate 101 side, the light-blocking layer 317 and a coloring layer 183 (a coloring layer 183R, a coloring layer 183G, and a coloring layer 183B), the insulating layer 172, the electrode 127, the insulating layer 124, the electrode 128, the insulating layer 125, the common electrode 316, and an insulating layer 339 are provided in this order.

In the case where the display apparatus 11 is a transmissive liquid crystal display apparatus, a backlight can be provided on the outer side of the substrate 101 (the side opposite to the substrate 152), for example. Light that is emitted from the backlight and transmitted through the liquid crystal element 62 is extracted from the substrate 152 side, whereby an image can be displayed on the display portion 20. Therefore, a material having a high light-transmitting property is preferably used for the substrate 101 and the substrate 152. For the pixel electrode 312 and the common electrode 316, a conductive material having a high light-transmitting property, e.g., a conductive material having a high visible-light-transmitting property, is preferably used. Examples of the conductive material having a high light-transmitting property include indium oxide, indium tin oxide, indium zinc oxide, and zinc oxide. Moreover, a conductive oxide such as zinc oxide to which gallium is added can be used as the conductive material having a high light-transmitting property. Furthermore, graphene may be used as the conductive material having a high light-transmitting property. Graphene can be formed by reducing graphene oxide. For example, graphene can be formed by application of heat to graphene oxide.

For the pixel electrode 312 and the common electrode 316, a metal or an alloy that is thin enough to have a light-transmitting property can be used. For example, a metal such as gold, silver, platinum, magnesium, nickel, tungsten, chromium, molybdenum, iron, cobalt, copper, palladium, or titanium, or an alloy containing the metal can be used. Alternatively, a nitride or the like of the metal or the alloy may be used; for example, titanium nitride may be used. Two or more conductive layers each including the above-described material may be stacked.

In the case where the display apparatus 11 is a reflective liquid crystal display apparatus, for example, a conductive material having a high reflective property, e.g., a conductive material having a high visible-light-reflecting property, is preferably used for the pixel electrode 312. Examples of the conductive material having a high reflective property include a metal such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the conductive material having a high reflective property include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC).

A polarizing plate 130a is provided on the outer side of the substrate 101 (the side opposite to the substrate 152), and a polarizing plate 130b is provided on the outer side of the substrate 152 (the side opposite to the substrate 101). Although not illustrated, a backlight can be provided on the outer side of the polarizing plate 130a (the side opposite to the substrate 101), for example. The backlight emits white light, for example. Note that the polarizing plate 130a and the polarizing plate 130b are not necessarily provided. For example, in the case where the display apparatus 11 is a reflective liquid crystal display apparatus and the pixel electrode 312 is formed using a conductive material having a high visible-light-reflecting property, the polarizing plate 130a can be omitted.

The insulating layer 339 functions as a spacer, and the liquid crystal 335 can be placed not to overlap the insulating layer 339, for example. The insulating layer 339 has a function of controlling the thickness of the liquid crystal 335 by controlling the distance between the substrate 101 and the substrate 152. The insulating layer 339 is preferably provided to overlap the transistor 205, in which case a reduction in the aperture ratio due to the insulating layer 339 can be inhibited.

Although FIG. 7 illustrates an example in which the insulating layer 339 does not overlap the pixel electrode 312, the insulating layer 339 may overlap part of the pixel electrode 312. For example, the insulating layer 339 and the pixel electrode 312 may overlap each other in the opening 129. In a region where the insulating layer 339 overlaps part of the pixel electrode 312, the insulating layer 339 is provided between the pixel electrode 312 and the common electrode 316.

An alignment layer 333 can be provided to cover the pixel electrode 312, and an alignment layer 337 can be provided to cover the common electrode 316 and the insulating layer 339. In the case where the alignment layer 333 and the alignment layer 337 are provided, the liquid crystal 335 is provided between the alignment layer 333 and the alignment layer 337. The liquid crystal 335 includes a region in contact with the alignment layer 333 and a region in contact with the alignment layer 337. The alignment layer 337 in a region overlapping the insulating layer 339 can include a region in contact with the alignment layer 333.

The alignment layer 333 and the alignment layer 337 have a function of controlling the alignment of the liquid crystal 335. Note that the alignment layer 333 and the alignment layer 337 are not necessarily provided.

In the coloring layer 183, the transmittance of light with a specific wavelength is higher than the transmittance of light with other wavelengths. Thus, the coloring layer 183 has a function of transmitting light of a specific color. For example, the coloring layer 183R has a function of transmitting red light, the coloring layer 183G has a function of transmitting green light, and the coloring layer 183B has a function of transmitting blue light. Accordingly, providing the coloring layer 183R, the coloring layer 183G, and the coloring layer 183B, for example, in the display apparatus 11 makes the display portion 20 emit red light, green light, and blue light, for example. In this manner, the display apparatus 11 can perform full-color display.

A structure may be employed in which blue or violet light is employed for the light source and the coloring layer 183 is formed using a color conversion material that converts the blue or violet light into light of another color (e.g., red or green). As the color conversion material, a resin material in which a fluorescent material, a phosphorescent material, or quantum dots are dispersed can be used, for example. Note that at this time, the coloring layer 183 preferably has a stacked-layer structure of the color conversion material and a color filter from the backlight side.

The light-blocking layer 317 is provided to include a region overlapping the insulating layer 339. Moreover, the light-blocking layer 317 can be provided to include a region overlapping the opening 129. Providing the light-blocking layer 317 can inhibit light transmitted through the liquid crystal element 62 overlapped by the coloring layer 183R from passing through the adjacent coloring layer 183G or the adjacent coloring layer 183B, for example. In addition, providing the light-blocking layer 317 can inhibit reflection of external light, for example. Thus, the contrast ratio of images displayed on the display portion 20 can be increased. When the light-blocking layer 317 is provided closer to the substrate 152 than the electrode 127 and the electrode 128 are, components of the touch panel 10, such as the electrode 127 and the electrode 128, can be inhibited from being perceived by the user of the touch panel 10. Note that a structure without the light-blocking layer 317 may be employed. In that case, the luminance of images displayed on the display portion 20 can be increased. An end portion of the coloring layer 183 can include a region in contact with the light-blocking layer 317. Thus, the coloring layer 183 and the light-blocking layer 317 can be provided without any gap.

The insulating layer 172 functions as an overcoat that inhibits diffusion of a component contained in the coloring layer 183 into the electrode 127, the electrode 128, and the liquid crystal element 62, for example. Here, the insulating layer 172 is preferably made flat, in which case the electrode 127 is easily formed over the insulating layer 172. Note that the insulating layer 172 is not necessarily made flat. The insulating layer 172 can be an organic material, for example, and can specifically be an organic resin.

The insulating layer 125 is preferably made flat, in which case the common electrode 316 is also made flat to have high adhesion to the alignment layer 337, for example. Note that the insulating layer 125 is not necessarily made flat. The insulating layer 125 can be an organic material, for example, and can specifically be an organic resin.

The substrate 101 and the substrate 152 are bonded to each other with the adhesive layer 142. For example, the insulating layer 235 is bonded to the electrode 128 and the insulating layer 124 with the adhesive layer 142. Here, the adhesive layer 142 can be placed not to overlap the liquid crystal 335 and, for example, can be placed not to overlap the display portion 20.

In the example illustrated in FIG. 7, the conductive layer 166 can be provided in the same layer as the pixel electrode 312. Thus, the conductive layer 166 can include the same material as the pixel electrode 312 and can be formed in the same step as the pixel electrode 312. For example, the conductive layer 166 and the pixel electrode 312 can be formed by processing the same conductive film.

The substrate 101 and the substrate 152 are bonded to each other with the adhesive layer 142. For example, the insulating layer 235 is bonded to the electrode 128 and the insulating layer 124 with the adhesive layer 142. Here, the adhesive layer 142 can be placed not to overlap the liquid crystal 335 and, for example, can be placed not to overlap the display portion 20.

To electrically connect the conductive layer 166 to the electrode 127 and the conductive layer 166 to the electrode 128, a portion where the insulating layer 125 is not provided is formed outside the display portion 20. As in the touch panel 10 having the structure illustrated in FIG. 6, for example, the insulating layer 125 is formed over the entire surface of the substrate 152 and then part of the insulating layer 125 is removed by a photolithography method and an etching method, or the like, whereby part of the electrode 127 and part of the electrode 128 can be exposed. Although FIG. 7 illustrates an example in which the insulating layer 125 is not provided in any region except the display portion 20, the insulating layer 125 may be provided in part of a region other than the display portion 20.

Note that one electrode of the capacitor 58 and the other electrode of the capacitor 58 illustrated in FIG. 2D, FIG. 3B1, and FIG. 3B2, for example, can be provided in the same layer as the conductive layer 111, the conductive layer 112, or the conductive layer 115. For example, the one electrode of the capacitor 58 can be provided in the same layer as the conductive layer 111, the other electrode of the capacitor 58 can be provided in the same layer as the conductive layer 112, and the insulating layer 103 can serve as a dielectric layer of the capacitor 58. Here, the other electrode of the capacitor 58 and the common electrode 316 are led to the outside of the display portion 20, for example. The other electrode of the capacitor 58 and the common electrode 316 can be electrically connected to each other outside the display portion 20, for example, by a method similar to a method for electrically connecting the conductive layer 111 of the transistor 201 and the electrode 128. That is, the other electrode of the capacitor 58 and the common electrode 316 can be electrically connected to each other using the conductive layer 166 and the conductive particle 165, for example.

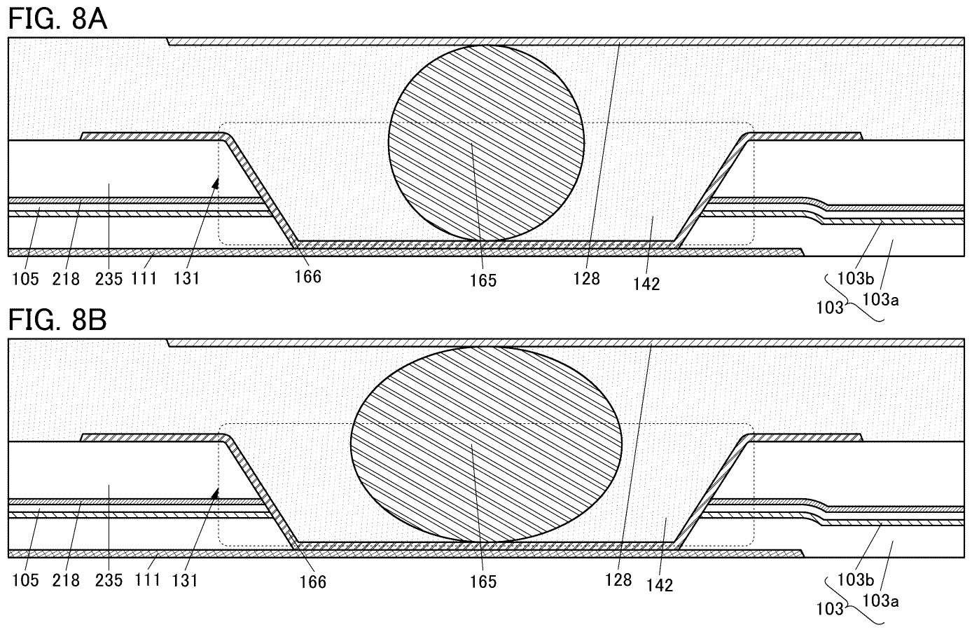

FIG. 8A and FIG. 8B are enlarged views illustrating structure examples of the conductive particle 165 illustrated in FIG. 6 and its surroundings. For convenience, the conductive particle 165 is shown to have an elliptical cross-sectional shape with a long axis in the direction perpendicular to the substrates in FIG. 6; however, in many actual cases, the cross-sectional shape is a circular shape as illustrated in FIG. 8A or an elliptical shape with a long axis component in the direction parallel to the substrates as illustrated in FIG. 8B.

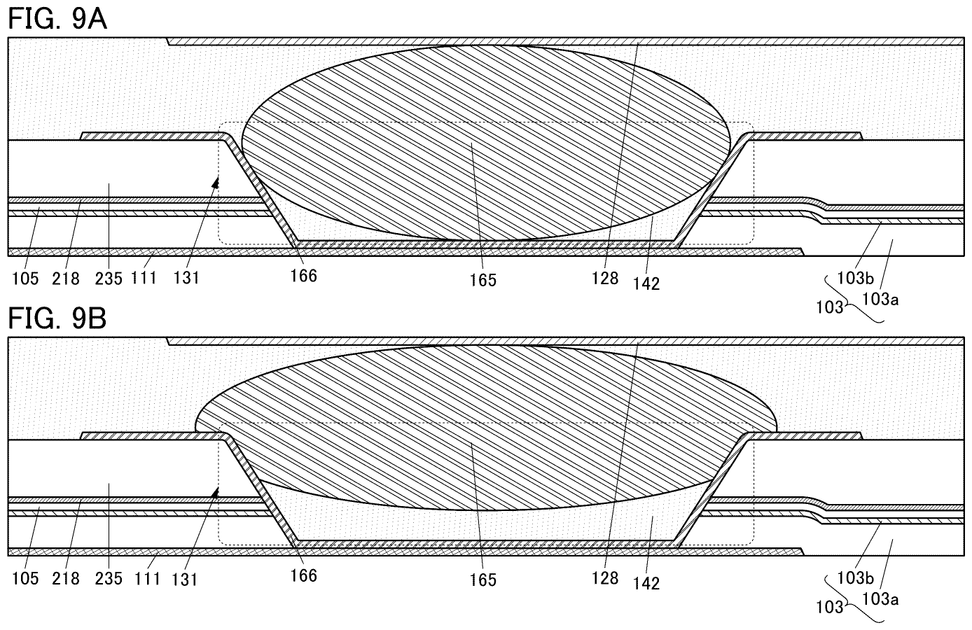

FIG. 9A shows a variation example of the structure illustrated in FIG. 8B and illustrates an example in which the conductive particle 165 includes a region in contact with not only the top surface of the conductive layer 166 but also the side surface of the conductive layer 166 in the opening 131. FIG. 9B shows a variation example of the structure illustrated in FIG. 9A and illustrates an example in which the conductive particle 165 is not in contact with the top surface of the conductive layer 166 in the opening 131. Although FIG. 9A illustrates an example in which the conductive particle 165 is not in contact with the top surface of the conductive layer 166 outside the opening 131, the conductive particle 165 may include a region in contact with the top surface of the conductive layer 166. Although FIG. 9B illustrates an example in which the conductive particle 165 includes a region in contact with the top surface of the conductive layer 166 outside the opening 131, the conductive particle 165 is not necessarily in contact with the top surface of the conductive layer 166. In the examples illustrated in FIG. 9A and FIG. 9B, the conductive particle 165 includes a region in contact with the side surface of the conductive layer 166 in the opening 131; thus, it can be said that the conductive particle 165 is fit in the opening 131.

The conductive particles 165 illustrated in FIG. 8A, FIG. 8B, FIG. 9A, and FIG. 9B can also be used as the conductive particle 165 illustrated in FIG. 7. The conductive particles 165 illustrated in FIG. 8A, FIG. 8B, FIG. 9A, and FIG. 9B can be used as all the conductive particles 165 described below.

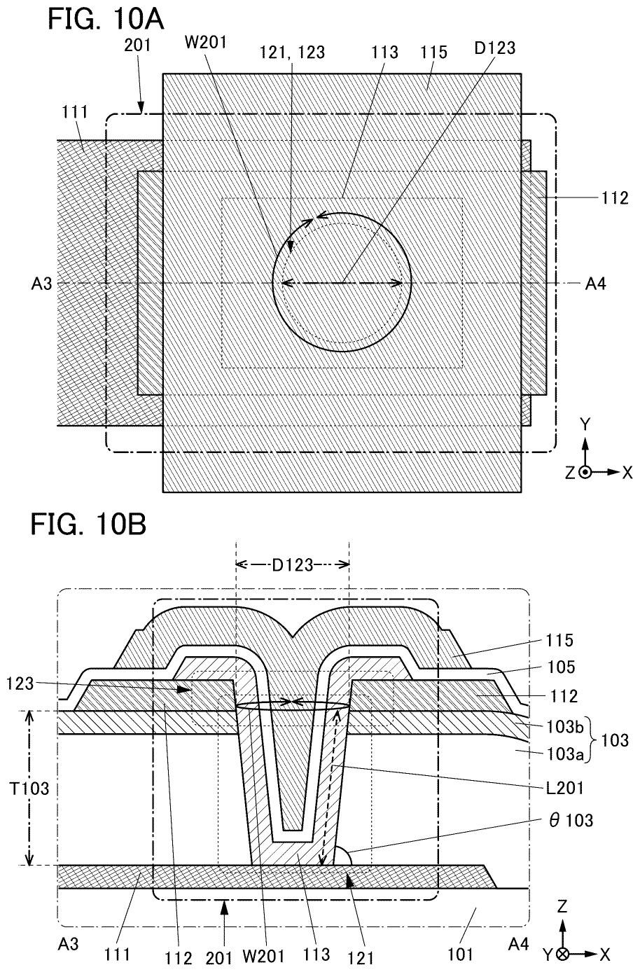

Here, the channel length and the channel width of the transistor 201 are described with reference to FIG. 10A and FIG. 10B. FIG. 10A is an enlarged plan view illustrating a structure example of the transistor 201 illustrated in FIG. 6 and FIG. 7 and its surroundings. FIG. 10B is a cross-sectional view along the dashed-dotted line A1-A2 in FIG. 10A. Note that the description of FIG. 10A and FIG. 10B can apply to the transistor 205, for example, by replacing “the transistor 201” with “the transistor 205”.

In FIG. 10A and FIG. 10B, the direction in which the conductive layer 111 extends is referred to as the X direction, and directions perpendicular to the X direction are referred to as the Y direction and the Z direction. The Z direction represents a height direction.

In the semiconductor layer 113, a region in contact with the conductive layer 111 functions as one of the source region and the drain region, a region in contact with the conductive layer 112 functions as the other of the source region and the drain region, and a region between the source region and the drain region functions as the channel formation region.

The channel length of the transistor 201 is a distance between the source region and the drain region. In FIG. 10B, a channel length L201 of the transistor 201 is indicated by a dashed double-headed arrow. In the cross-sectional view, the channel length L201 is a distance between an end portion of the region where the semiconductor layer 113 is in contact with the conductive layer 111 and an end portion of the region where the semiconductor layer 113 is in contact with the conductive layer 112.

Here, the channel length L201 of the transistor 201 corresponds to the length of the side surface of the insulating layer 103 on the opening 121 side when seen from the XZ plane. In other words, the channel length L201 is determined depending on a thickness T103 of the insulating layer 103 and an angle θ103 formed by the side surface of the insulating layer 103 on the opening 121 side and the formation surface of the insulating layer 103 (here, the top surface of the conductive layer 111), and is not affected by the performance of a light-exposure apparatus used for manufacturing the transistor. Thus, the channel length L201 can be a value smaller than the resolution limit of the light-exposure apparatus, so that a miniaturized transistor can be achieved. For example, the channel length L201 is preferably larger than or equal to 0.010 μm and smaller than 3.0 μm, further preferably larger than or equal to 0.050 μm and smaller than 3.0 μm, further preferably larger than or equal to 0.10 μm and smaller than 3.0 μm, further preferably larger than or equal to 0.15 μm and smaller than 3.0 μm, still further preferably larger than or equal to 0.20 μm and smaller than 3.0 μm, still further preferably larger than or equal to 0.20 μm and smaller than 2.5 μm, still further preferably larger than or equal to 0.20 μm and smaller than 2.0 μm, yet further preferably larger than or equal to 0.20 μm and smaller than 1.5 μm, yet further preferably larger than or equal to 0.30 μm and smaller than 1.5 μm, yet further preferably larger than or equal to 0.30 μm and smaller than or equal to 1.2 μm, yet still further preferably larger than or equal to 0.40 μm and smaller than or equal to 1.2 μm, yet still further preferably larger than or equal to 0.40 μm and smaller than or equal to 1.0 μm, yet still further preferably larger than or equal to 0.50 μm and smaller than or equal to 1.0 μm. In FIG. 10B, the thickness T103 of the insulating layer 103 is indicated by a dashed-dotted double-headed arrow.

The reduction in the channel length L201 can increase the on-state current of the transistor 201. Thus, the input device driver circuit 15 including the transistor 201 can be driven at high speed.

Note that when the transistor provided in the pixel 21 has a structure similar to that illustrated in FIG. 10A and FIG. 10B, the transistor included in the pixel 21 can be miniaturized, so that the pixel 21 can be miniaturized. Accordingly, the display apparatus 11 included in the touch panel 10 can be a high-resolution display apparatus. Furthermore, the reduction in the channel length can increase the on-state current of the transistor included in the pixel 21, whereby the touch panel 10 can be driven at high speed.

By adjusting the thickness T103 and the angle θ103 of the insulating layer 103, the channel length L201 can be controlled.

The thickness T103 of the insulating layer 103 is preferably larger than or equal to 0.01 μm and smaller than 3.0 μm, further preferably larger than or equal to 0.05 μm and smaller than 3.0 μm, further preferably larger than or equal to 0.10 μm and smaller than 3.0 μm, further preferably larger than or equal to 0.15 μm and smaller than 3.0 μm, still further preferably larger than or equal to 0.20 μm and smaller than 3.0 μm, still further preferably larger than or equal to 0.20 μm and smaller than 2.5 μm, still further preferably larger than or equal to 0.20 μm and smaller than 2.0 μm, yet further preferably larger than or equal to 0.20 μm and smaller than 1.5 μm, yet further preferably larger than or equal to 0.30 μm and smaller than 1.5 μm, yet further preferably larger than or equal to 0.30 μm and smaller than or equal to 1.2 μm, yet still further preferably larger than or equal to 0.40 μm and smaller than or equal to 1.2 μm, yet still further preferably larger than or equal to 0.40 μm and smaller than or equal to 1.0 μm, yet still further preferably larger than or equal to 0.50 μm and smaller than or equal to 1.0 μm.

The side surface of the insulating layer 103 on the opening 121 side preferably has a tapered shape. The angle θ103 formed by the side surface of the insulating layer 103 on the opening 121 side and the formation surface of the insulating layer 103 (here, the top surface of the conductive layer 111) is preferably less than 90°. By reducing the angle θ103, the coverage with a layer (e.g., the semiconductor layer 113) provided over the insulating layer 103 can be improved. However, reducing the angle θ103 might reduce the contact area between the semiconductor layer 113 and the conductive layer 111 and increase the contact resistance between the semiconductor layer 113 and the conductive layer 111. The angle θ103 is preferably greater than or equal to 45° and less than 90°, further preferably greater than or equal to 50° and less than 90°, further preferably greater than or equal to 55° and less than 90°, further preferably greater than or equal to 60° and less than 90°, further preferably greater than or equal to 60° and less than or equal to 85°, still further preferably greater than or equal to 65° and less than or equal to 85°, yet further preferably greater than or equal to 65° and less than or equal to 80°, yet still further preferably greater than or equal to 70° and less than or equal to 80°. When the angle θ103 is within the above range, the coverage with the layer (e.g., the semiconductor layer 113) formed over the conductive layer 111 and the insulating layer 103 can be improved while the channel length of the transistor 201 is reduced; hence, occurrence of defects such as step disconnection or a void in the layer can be inhibited. In addition, the contact resistance between the semiconductor layer 113 and the conductive layer 111 can be lowered.

In this specification and the like, step disconnection refers to a phenomenon in which a layer, a film, or an electrode is split because of the shape of the formation surface (e.g., a step).

Although FIG. 10B illustrates the structure in which the side surface of the insulating layer 103 on the opening 121 side is linear in the cross-sectional view, one embodiment of the present invention is not limited thereto. In the cross-sectional view, the side surface of the insulating layer 103 on the opening 121 side may be curved, or the side surface may include both a linear region and a curved region.

The channel width of the transistor 201 is the width of the source region or the width of the drain region in a direction orthogonal to the channel length direction. In other words, the channel width is the width of the region where the semiconductor layer 113 is in contact with the conductive layer 111 or the width of the region where the semiconductor layer 113 is in contact with the conductive layer 112 in the direction orthogonal to the channel length direction. Here, the channel width of the transistor 201 is described as the width of the region where the semiconductor layer 113 is in contact with the conductive layer 112 in the direction orthogonal to the channel length direction. In FIG. 10A and FIG. 10B, a channel width W201 of the transistor 201 is indicated by a solid double-headed arrow. In the plan view, the channel width W201 is the length of the end portion of the bottom surface of the conductive layer 112 on the opening 123 side.

The channel width W201 depends on the planar shape of the opening 123. In FIG. 10A and FIG. 10B, a width D123 of the opening 123 is indicated by a dashed double-dotted double-headed arrow. In the plan view, the width D123 represents the short side of the smallest rectangle that is circumscribed around the opening 123. In the case where the opening 123 is formed by a photolithography method, the width D123 of the opening 123 is larger than or equal to the resolution limit of a light-exposure apparatus. For example, the width D123 is preferably larger than or equal to 0.20 μm and smaller than 5.0 μm, further preferably larger than or equal to 0.20 μm and smaller than 4.5 μm, further preferably larger than or equal to 0.20 μm and smaller than 4.0 μm, further preferably larger than or equal to 0.20 μm and smaller than 3.5 μm, still further preferably larger than or equal to 0.20 μm and smaller than 3.0 μm, still further preferably larger than or equal to 0.20 μm and smaller than 2.5 μm, still further preferably larger than or equal to 0.20 μm and smaller than 2.0 μm, yet further preferably larger than or equal to 0.20 μm and smaller than 1.5 μm, yet further preferably larger than or equal to 0.30 μm and smaller than 1.5 μm, yet further preferably larger than or equal to 0.30 μm and smaller than or equal to 1.2 μm, yet still further preferably larger than or equal to 0.40 μm and smaller than or equal to 1.2 μm, yet still further preferably larger than or equal to 0.40 μm and smaller than or equal to 1.0 μm, yet still further preferably larger than or equal to 0.50 μm and smaller than or equal to 1.0 μm. Note that when the planar shape of the opening 123 is circular, the width D123 corresponds to the diameter of the opening 123, and the channel width W201 can be equal to the perimeter of the opening 123 in a plan view and calculated to be “D123×π”.

### Structure Example 2 of Touch Panel

Structure examples of a touch panel having a structure partly different from those in FIG. 4A, FIG. 6, FIG. 7, and the like will be described below. Note that the descriptions overlapping with FIG. 4A, FIG. 6, FIG. 7, and the like will be omitted in some cases.

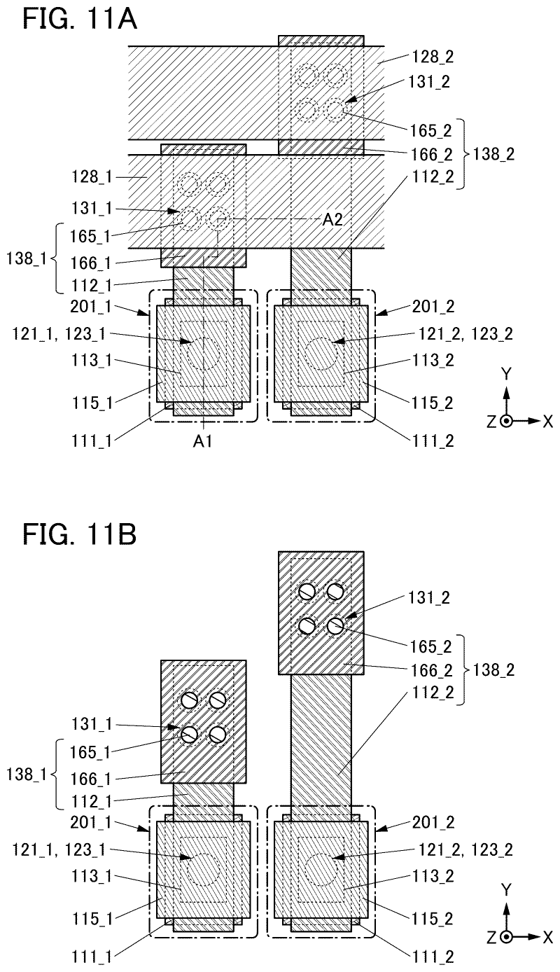

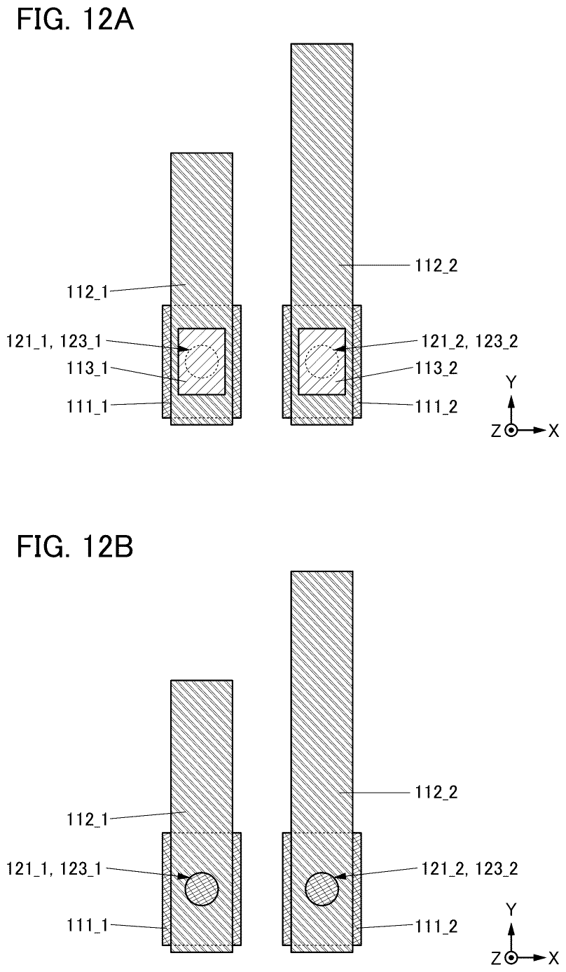

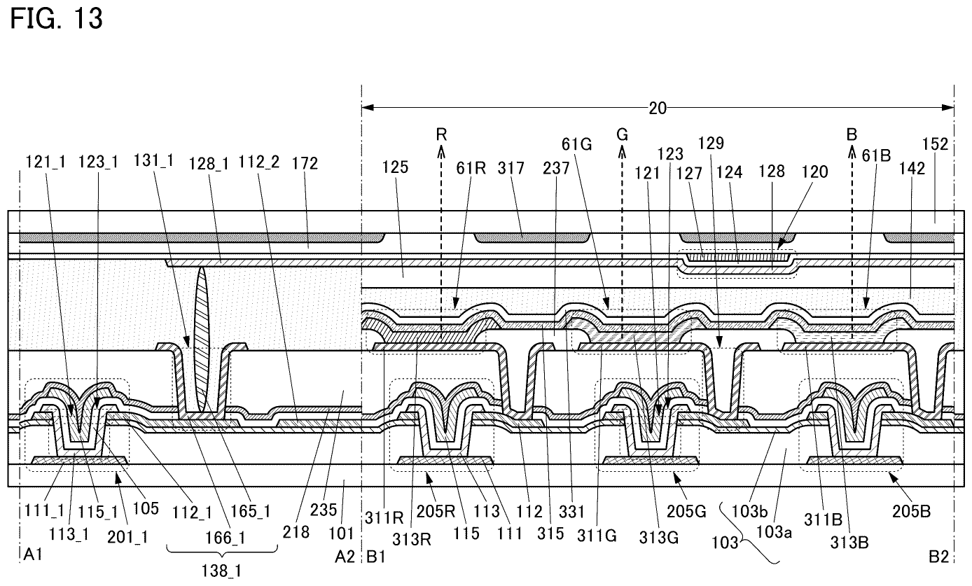

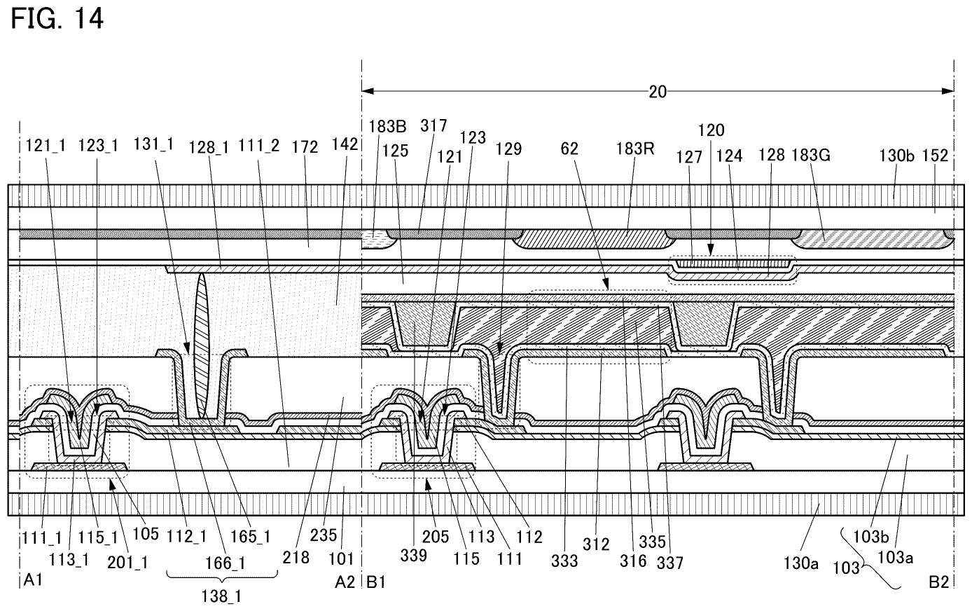

FIG. 11A, FIG. 11B, FIG. 12A, FIG. 12B, FIG. 13, and FIG. 14 show variation examples of the structures illustrated in FIG. 4A, FIG. 4B, FIG. 5A, FIG. 5B, FIG. 6, and FIG. 7, respectively. FIG. 11A, FIG. 11B, FIG. 13, FIG. 14, and the like illustrate examples in which the opening 129 and the opening 131 are provided in the insulating layer 105, the insulating layer 218, and the insulating layer 235 to reach the conductive layer 112.

For example, in the examples illustrated in FIG. 13 and FIG. 14, the conductive layer 166 is provided to include a region in contact with the conductive layer 112 of the transistor 201 in the opening 131, and the conductive layer 112 and the electrode 128 are electrically connected to each other through the conductive layer 166 and the conductive particle 165. In the example illustrated in FIG. 13, the pixel electrode 311 is provided to include a region in contact with the conductive layer 112 of the transistor 205 in the opening 129. In the example illustrated in FIG. 14, the pixel electrode 312 is provided to include a region in contact with the conductive layer 112 of the transistor 205 in the opening 129. Note that the conductive layer 166 is not necessarily provided. In that case, the conductive layer 112 and the electrode 128 can be electrically connected to each other when the conductive particle 165 includes a region in contact with the conductive layer 112 in the opening 131, for example.

For example, in the examples illustrated in FIG. 13 and FIG. 14, the opening 129 and the opening 131 do not need to be formed in the insulating layer 103. Thus, the insulating layer 103 does not need to be etched at the time of forming the opening 129 and the opening 131. Accordingly, the opening 129 and the opening 131 can be easily formed.

Note that the opening 131 may be provided in the insulating layer 218 and the insulating layer 235 to reach the conductive layer 115 of the transistor 201. In that case, the conductive layer 166 is provided to include a region in contact with the conductive layer 115 in the opening 131, for example, and the conductive layer 115 and the electrode 128 are electrically connected to each other through the conductive layer 166 and the conductive particle 165. In this case, the opening 129 can be provided in the insulating layer 105, the insulating layer 218, and the insulating layer 235 to reach the conductive layer 112. Note that the opening 129 may be provided in the insulating layer 103, the insulating layer 105, the insulating layer 218, and the insulating layer 235 to reach the conductive layer 111. In addition, the conductive layer 166 is not necessarily provided. In that case, the conductive layer 115 and the electrode 128 can be electrically connected to each other when the conductive particle 165 includes a region in contact with the conductive layer 115 in the opening 131, for example.

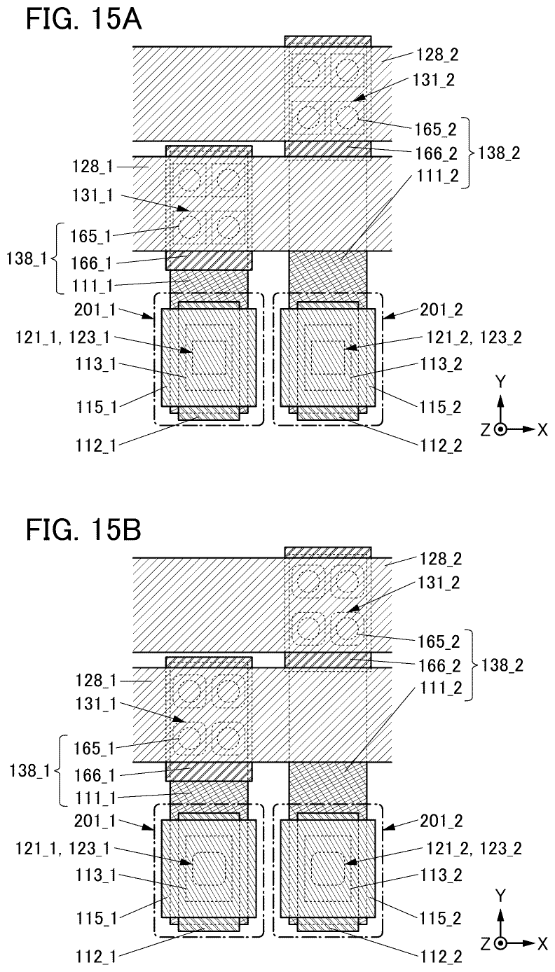

FIG. 15A shows a variation example of the structure illustrated in FIG. 4A and illustrates an example in which the planar shapes of the opening 121, the opening 123, and the opening 131 are squares. Note that the planar shapes of the opening 121, the opening 123, and the opening 131 may each be a rectangle, a diamond, a parallelogram, or a quadrangle other than these. Alternatively, the planar shapes of the opening 121, the opening 123, and the opening 131 may each be a triangle or a polygon such as a pentagon.

FIG. 15B shows a variation example of the structure illustrated in FIG. 15A and illustrates an example in which the planar shapes of the opening 121, the opening 123, and the opening 131 are squares with rounded corners. Note that the planar shapes of the opening 121, the opening 123, and the opening 131 can each be any of the shapes in the above description of FIG. 15A with rounded vertices.

In the case where the opening 121, the opening 123, and the opening 131 each have the planar shape illustrated in FIG. 15A or FIG. 15B, there are regions where the side surface of the insulating layer 103 in the opening 121, the side surface of the conductive layer 112 in the opening 123, and the side surfaces of the insulating layer 103, the insulating layer 105, the insulating layer 218, and the insulating layer 235 in the opening 131 are not curved but flat. Thus, the coverage with the semiconductor layer 113, the insulating layer 105, and the conductive layer 115 can be improved in the opening 121 and the opening 123. Furthermore, the coverage with the conductive layer 166 can be improved in the opening 131.

Note that in each of FIG. 15A and FIG. 15B, the opening 121, the opening 123, and the opening 131 have all the same type of shape; however, for example, the type of shape of the opening 131 may be different from the types of shapes of the opening 121 and the opening 123. The planar shape of the conductive particle 165 is a circle in the examples illustrated in FIG. 15A and FIG. 15B; however, the planar shape of the conductive particle 165 is not limited to a circle. For example, the planar shape of the conductive particle 165 may be of the same type as a shape that the opening 121, the opening 123, and the opening 131 can have.

The shapes of the opening 121, the opening 123, and the opening 131 described with FIG. 15A and the shapes of the opening 121, the opening 123, and the opening 131 described with FIG. 15B can be used for all of the following openings 121, openings 123, and openings 131.

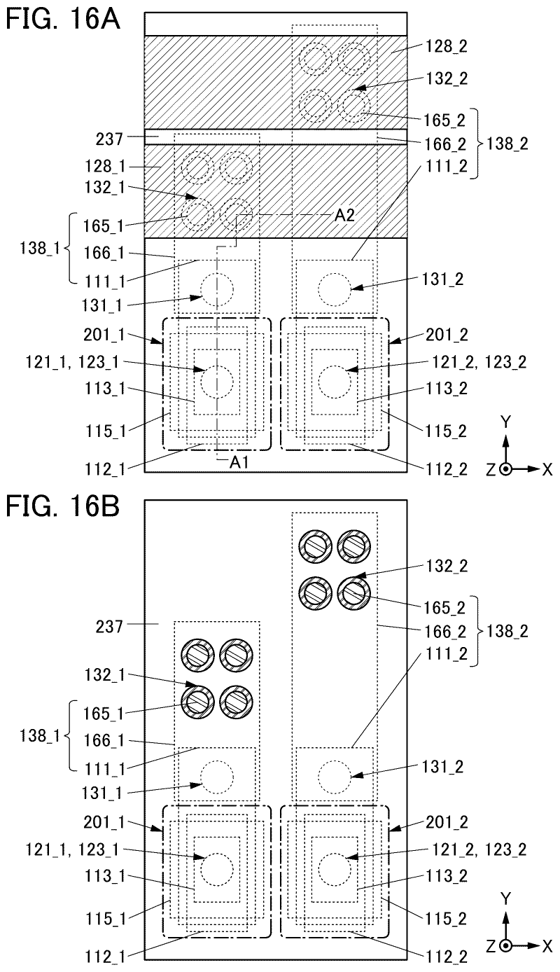

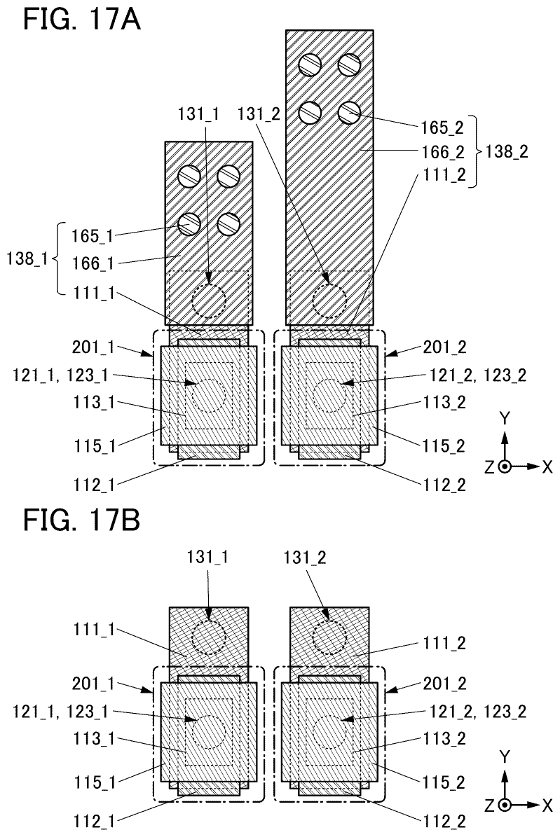

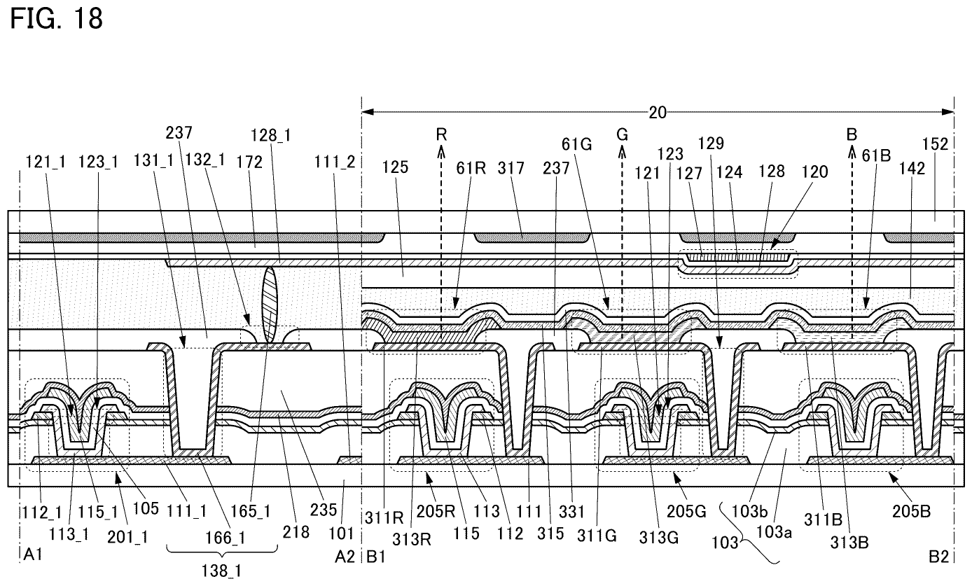

FIG. 16A is a plan view illustrating a structure example of part of the touch panel 10 and shows a variation example of the structure illustrated in FIG. 4A. FIG. 16B, FIG. 17A, and FIG. 17B are plan views that omit some of the components illustrated in FIG. 16A. FIG. 18 is a cross-sectional view along the dashed-dotted line A1-A2 in FIG. 1B and FIG. 16A, the dashed-dotted line B1-B2 in FIG. 1B, and the like.

FIG. 16A and FIG. 18 illustrate an example in which the insulating layer 237 is provided over the conductive layer 166. Specifically, the insulating layer 237 is provided to cover an end portion of the conductive layer 166, for example. This can inhibit the conductive layer 166 from being short-circuited with another conductive layer. Note that the plan view in FIG. 16A illustrates the insulating layer 237.

An opening 132 that reaches the conductive layer 166 and includes a region overlapped by the electrode 127 or the electrode 128 is provided in the insulating layer 237, and the conductive particle 165 is provided to include a region positioned in the opening 132. Specifically, the conductive particle 165 is included in the adhesive layer 142 so as to include a region positioned in the opening 132, whereby the conductive particle 165 can be provided between the conductive layer 166 and the electrode 127 or the electrode 128 so as to include a region positioned in the opening 132. For example, in FIG. 18, out of the electrode 127 and the electrode 128, the electrode 128 is illustrated as an electrode including a region overlapping the opening 132. As an example, FIG. 18 illustrates the conductive particle 165 provided between the conductive layer 166 and the electrode 128.

In the case where the insulating layer 237 including the opening 132 is provided over the conductive layer 166, even when the conductive particle 165 is provided around but outside the opening 132 right after the substrate 101 and the substrate 152 are bonded to each other using the adhesive layer 142 including the conductive particle 165, for example, the position of the conductive particle 165 is shifted owing to a step formed by the opening 132 and the conductive particle 165 enters the opening 132 in some cases. Accordingly, the conductive particle 165 can sometimes be inhibited from being out of contact with the conductive layer 166.

In the above manner, the touch panel 10 having the structure illustrated in FIG. 16A and FIG. 18 can be manufactured by a high-yield method and thus can be inexpensive. The touch panel 10 having the structure illustrated in FIG. 16A and FIG. 18 can have high reliability. Note that the opening 132 reaching the conductive layer 166_1 is denoted as an opening 132_1, and the opening 132 reaching the conductive layer 166_2 is denoted as an opening 132_2.

Here, the opening 131 reaching the conductive layer 111 can be filled with the insulating layer 237. Accordingly, unevenness with a large level difference can be eliminated from the bonding surface, so that bonding between the substrate 101 and the substrate 152 can be easily performed in some cases. In the case where the conductive particle 165 is not provided in the opening 131 and the opening 131 is filled with the insulating layer 237, for example, the electrode 128 does not need to overlap the opening 131. Note that the opening 132 may be provided to include a region overlapping the opening 131.

FIG. 16B is a plan view illustrating a structure example in which the electrode 128_1 and the electrode 128_2 are omitted from the components illustrated in FIG. 16A. For example, as illustrated in FIG. 16B, a plurality of the openings 132_1 can be provided, and the conductive particle 165_1 can be provided in each of the openings 132_1. Similarly, a plurality of the openings 132_2 can be provided, and the conductive particle 165_2 can be provided in each of the openings 132_2. Providing the plurality of openings 132_1 can increase the total of the perimeters of the openings 132_1 in a plan view. This sometimes makes the conductive particle 165_1 likely to enter the openings 132_1. Similarly, providing the plurality of openings 132_2 sometimes makes the conductive particle 165_2 likely to enter the openings 132_2.

Although the planar shape of the opening 132 is a circle in the examples illustrated in FIG. 16A and FIG. 16B, the planar shape of the opening 132 can be of the same type as a shape that the opening 131 can have.

FIG. 17A is a plan view illustrating a structure example in which the insulating layer 237 is omitted from the components illustrated in FIG. 16B. FIG. 17B is a plan view illustrating a structure example in which the conductive particle 165 and the conductive layer 166 are omitted from the components illustrated in FIG. 17A. For example, as illustrated in FIG. 17A, the length of the conductive layer 166_1 in the Y direction and the length of the conductive layer 166_2 in the Y direction can be different from each other. For another example, as illustrated in FIG. 17B, the length of the conductive layer 111_1 in the Y direction and the length of the conductive layer 111_2 in the Y direction can be equal to each other.

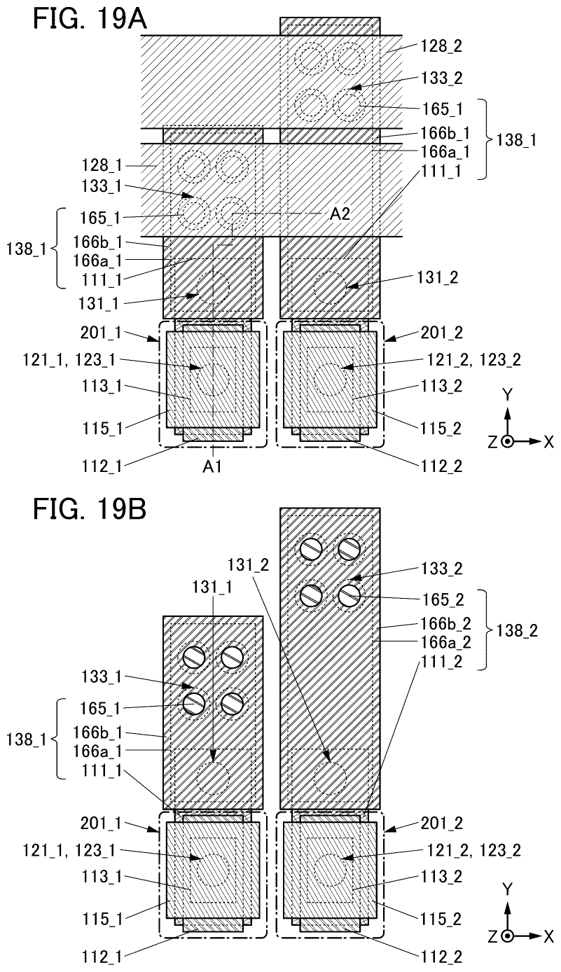

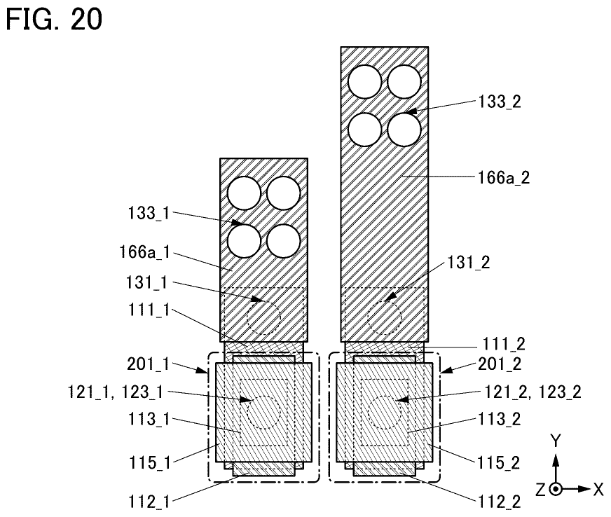

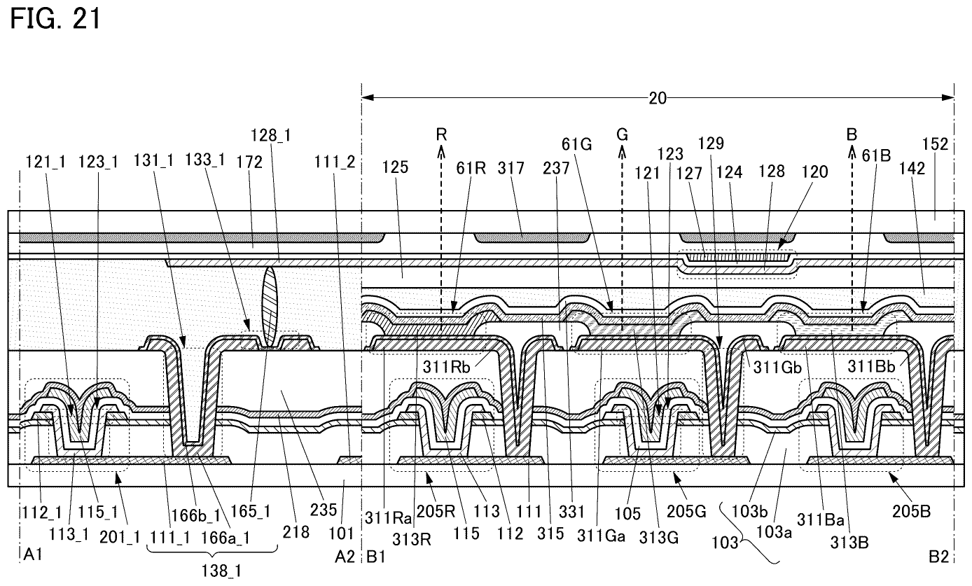

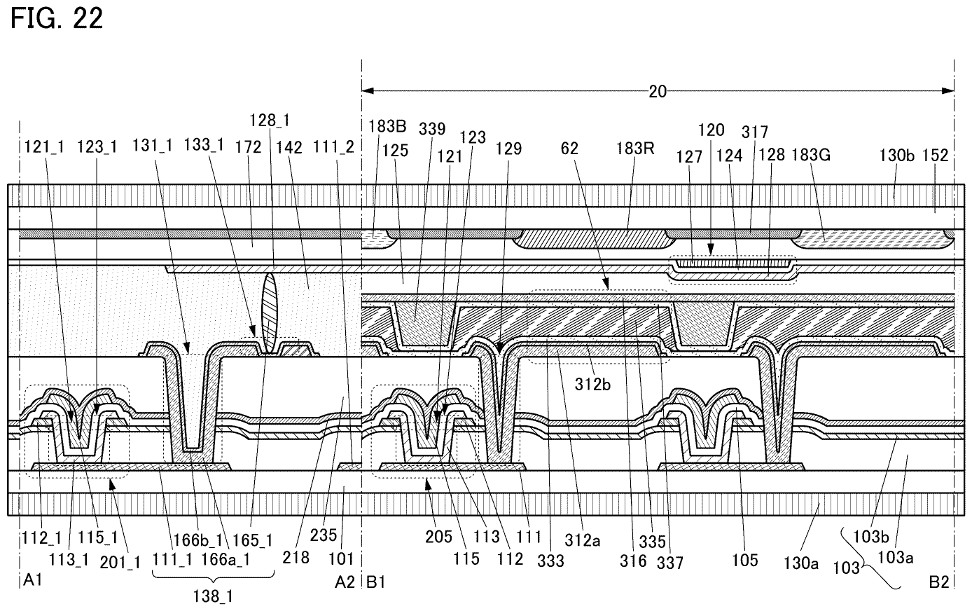

FIG. 19A is a plan view illustrating a structure example of part of the touch panel 10 illustrated in FIG. 1B and shows a variation example of the structure illustrated in FIG. 4A. FIG. 19B and FIG. 20 are plan views that omit some of the components illustrated in FIG. 19A. FIG. 21 and FIG. 22 are cross-sectional views along the dashed-dotted line A1-A2 in FIG. 1B and FIG. 19A, the dashed-dotted line B1-B2 in FIG. 1B, and the like. FIG. 21 illustrates an example in which the light-emitting element 61 is provided as a display element. FIG. 22 illustrates an example in which the liquid crystal element 62 is provided as a display element.

FIG. 19A, FIG. 21, and FIG. 22 illustrate an example in which the conductive layer 166 has a stacked-layer structure of a conductive layer 166a and a conductive layer 166b over the conductive layer 166a. For example, an opening 133 is provided in the conductive layer 166a, and the conductive layer 166b can be provided to cover the conductive layer 166a including the opening 133. Note that the conductive layer 166a and the conductive layer 166b that are part of the conductive layer 166_1 are denoted as a conductive layer 166a_1 and a conductive layer 166b_1, respectively, and the conductive layer 166a and the conductive layer 166b that are part of the conductive layer 166_2 are denoted as a conductive layer 166a_2 and a conductive layer 166b_2, respectively. The opening 133 provided in the conductive layer 166a_1 is denoted an opening 133_1, and the opening 133 provided in the conductive layer 166a_2 is denoted as an opening 133_2.

When the conductive layer 166 has such a structure, the thickness of the conductive layer 166 in a region overlapped by the opening 133 can be smaller than that of the conductive layer 166 in the other regions. That is, the conductive layer 166 has a depressed portion in the region overlapped by the opening 133. Thus, when the conductive particle 165 is provided to include a region positioned in the depressed portion, the conductive particle 165 can sometimes be inhibited from being out of contact with at least one of the conductive layer 166 and the electrode 128, for example. Even when the conductive particle 165 is provided in a region that is in the vicinity of the depressed portion but is not in contact with at least one of the conductive layer 166 and the electrode 128 right after the substrate 101 and the substrate 152 are bonded to each other using the adhesive layer 142 including the conductive particle 165, for example, the position of the conductive particle 165 is shifted owing to a step formed by the depressed portion and the conductive particle 165 enters the depressed portion in some cases. Accordingly, the conductive particle 165 can sometimes be inhibited from being out of contact with at least one of the conductive layer 166 and the electrode 128, for example. In the above manner, the touch panel 10 having the structure illustrated in FIG. 19A and FIG. 21 and the touch panel 10 having the structure illustrated in FIG. 19A and FIG. 22 can be manufactured by a high-yield method and thus can be inexpensive. The touch panel 10 having the structure illustrated in FIG. 19A and FIG. 21 and the touch panel 10 having the structure illustrated in FIG. 19A and FIG. 22 can have high reliability.

Here, the opening 133 can be deeper as the conductive layer 166a has a larger thickness and the conductive layer 166b has a smaller thickness, that is, the difference in thickness between the conductive layer 166a and the conductive layer 166b is larger; hence, the depressed portion can be deeper. This is preferable, in which case the conductive particle 165 that has entered the depressed portion can be inhibited from exiting from the depressed portion, for example. For example, the thickness of the conductive layer 166b is preferably smaller than or equal to that of the conductive layer 166a, further preferably smaller than or equal to ½ that of the conductive layer 166a. Note that the conductive layer 166 may have a stacked-layer structure of three or more layers, and the opening 133 may be provided in some of the layers. For example, in the case where the conductive layer 166 has a three-layer stacked structure, the opening 133 may be provided only in the uppermost layer, or the opening 133 may be provided in the uppermost layer and a layer under the uppermost layer (a layer between the uppermost layer and the lowermost layer). Here, even in the case where the conductive layer 166 has a stacked-layer structure of three or more layers, the thicknesses of the layers in the conductive layer 166 are preferably controlled so that the opening 133 becomes deeper.

As described above, the pixel electrode 311R, the pixel electrode 311G, and the pixel electrode 311B illustrated in FIG. 21 can be provided in the same layer as the conductive layer 166. Thus, in the case where the conductive layer 166 has a stacked-layer structure of the conductive layer 166a and the conductive layer 166b over the conductive layer 166a, the pixel electrode 311R can have a stacked-layer structure of a pixel electrode 311Ra and a pixel electrode 311Rb over the pixel electrode 311Ra. For example, the pixel electrode 311Rb can cover the pixel electrode 311Ra. The pixel electrode 311G can have a stacked-layer structure of a pixel electrode 311Ga and a pixel electrode 311Gb over the pixel electrode 311Ga, and the pixel electrode 311Gb can cover the pixel electrode 311Ga, for example. Furthermore, the pixel electrode 311B can have a stacked-layer structure of a pixel electrode 311Ba and a pixel electrode 311Bb over the pixel electrode 311Ba, and the pixel electrode 311Bb can cover the pixel electrode 311Ba, for example.

The materials for the conductive layer 166a, the pixel electrode 311Ra, the pixel electrode 311Ga, and the pixel electrode 311Ba may be the same as or different from those for the conductive layer 166b, the pixel electrode 311Rb, the pixel electrode 311Gb, and the pixel electrode 311Bb. For example, a material that reflects visible light can be used for all of the conductive layer 166a, the conductive layer 166b, the pixel electrode 311Ra, the pixel electrode 311Rb, the pixel electrode 311Ga, the pixel electrode 311Gb, the pixel electrode 311Ba, and the pixel electrode 311Bb. Alternatively, a material that reflects visible light can be used for the conductive layer 166a, the pixel electrode 311Ra, the pixel electrode 311Ga, and the pixel electrode 311Ba, and a material that transmits visible light can be used for the conductive layer 166b, the pixel electrode 311Rb, the pixel electrode 311Gb, and the pixel electrode 311Bb.

The pixel electrode 312 illustrated in FIG. 22 can be provided in the same layer as the conductive layer 166, as described above. Thus, in the case where the conductive layer 166 has a stacked-layer structure of the conductive layer 166a and the conductive layer 166b over the conductive layer 166a, the pixel electrode 312 can have a stacked-layer structure of a pixel electrode 312a and a pixel electrode 312b over the pixel electrode 3112a. For example, the pixel electrode 312b can cover the pixel electrode 312a.

The materials for the conductive layer 166a and the pixel electrode 312a may be the same as or different from those for the conductive layer 166b and the pixel electrode 312b.

In the case where the conductive particle 165 is provided in the depressed portion of the conductive layer 166, the conductive particle 165 does not need to be provided in the opening 131. In this case, the electrode 127 and the electrode 128 can be placed not to overlap the opening 131. Note that even in the case where the conductive particle 165 is provided in the depressed portion of the conductive layer 166, the electrode 127 or the electrode 128 may be provided to include a region overlapping the opening 131 and the conductive particle 165 may be provided in the opening 131.

FIG. 19B is a plan view illustrating a structure example in which the electrode 128 1 and the electrode 128_2 are omitted from the components illustrated in FIG. 19A. For example, as illustrated in FIG. 19B, a plurality of the openings 133_1 can be provided, and the conductive particle 165_1 can be provided in each of the openings 133_1. Similarly, a plurality of the openings 133_2 can be provided, and the conductive particle 165_2 can be provided in each of the openings 133_2. Providing the plurality of openings 133_1 can increase the total of the perimeters of the openings 133_1 in a plan view. This sometimes makes the conductive particle 165_1 likely to enter the openings 133_1. Similarly, providing the plurality of openings 133_2 sometimes makes the conductive particle 165_2 likely to enter the openings 133_2.

FIG. 20 is a plan view illustrating a structure example in which the conductive particle 165 and the conductive layer 166b are omitted from the components illustrated in FIG. 19B. Although the planar shape of the opening 133 is a circle in the examples illustrated in FIG. 19A, FIG. 19B, and FIG. 20, the planar shape of the opening 133 can be of the same type as a shape that the opening 131 can have.

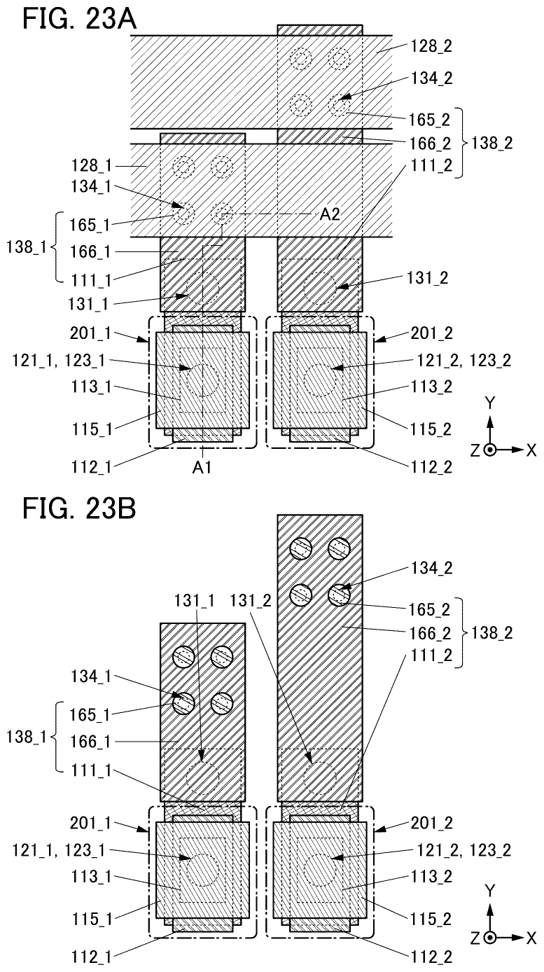

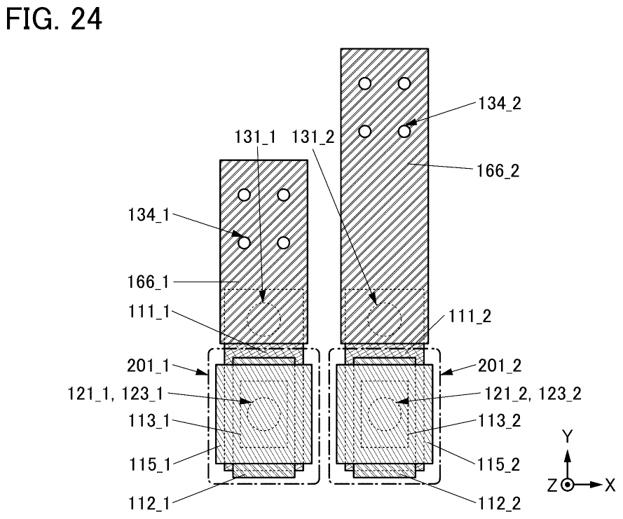

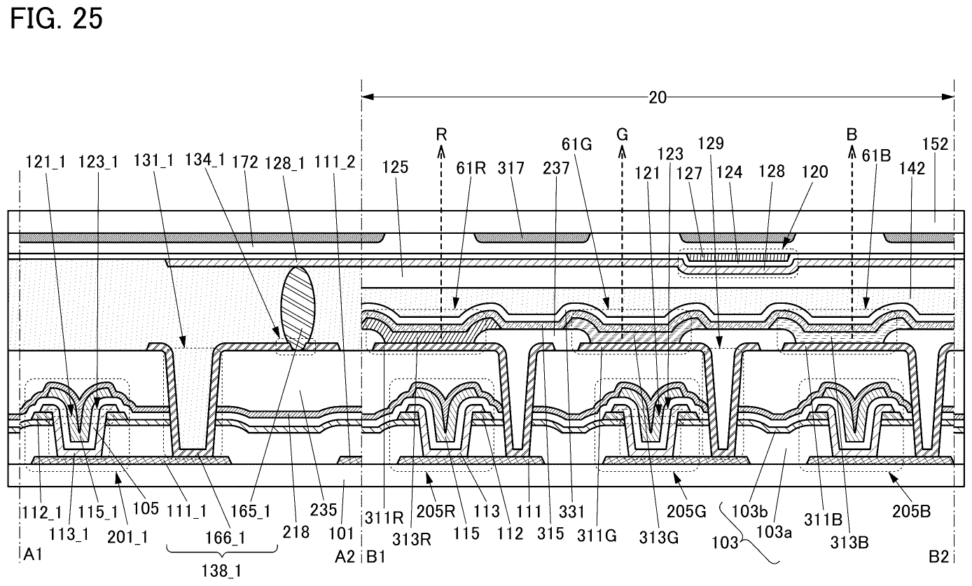

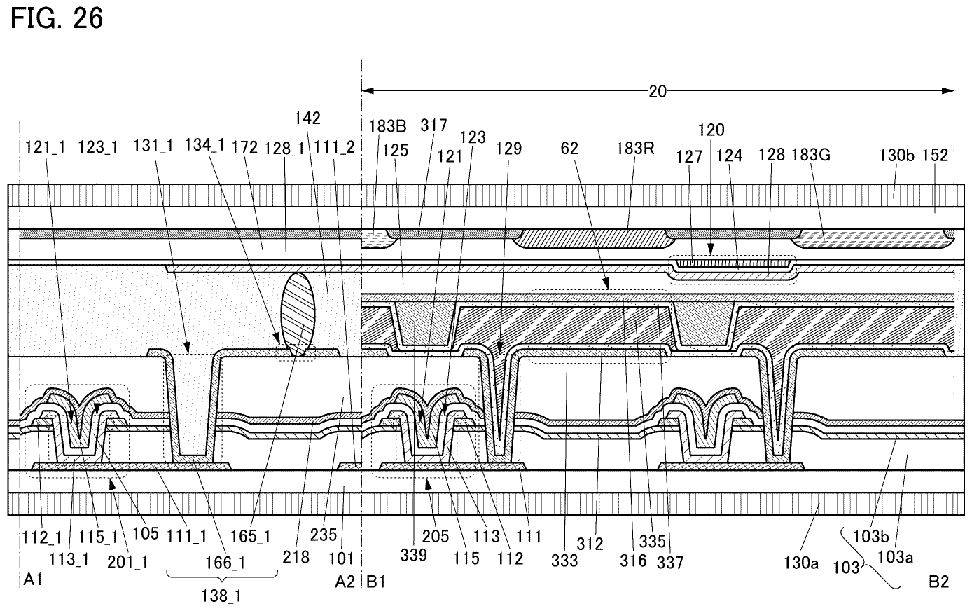

FIG. 23A is a plan view illustrating a structure example of part of the touch panel 10 illustrated in FIG. 1B and shows a variation example of the structure illustrated in FIG. 4A. FIG. 23B and FIG. 24 are plan views that omit some of the components illustrated in FIG. 23A. FIG. 25 and FIG. 26 are cross-sectional views along the dashed-dotted line A1-A2 in FIG. 1B and FIG. 23A, the dashed-dotted line B1-B2 in FIG. 1B, and the like. FIG. 25 illustrates an example in which the light-emitting element 61 is provided as a display element. FIG. 26 illustrates an example in which the liquid crystal element 62 is provided as a display element.

FIG. 23A, FIG. 25, and FIG. 26 illustrate examples in which an opening 134 reaching the insulating layer 235 is provided in the conductive layer 166. Note that the opening 134 provided in the conductive layer 166_1 is denoted as an opening 134_1, and the opening 134 provided in the conductive layer 166_2 is denoted as an opening 134_2.

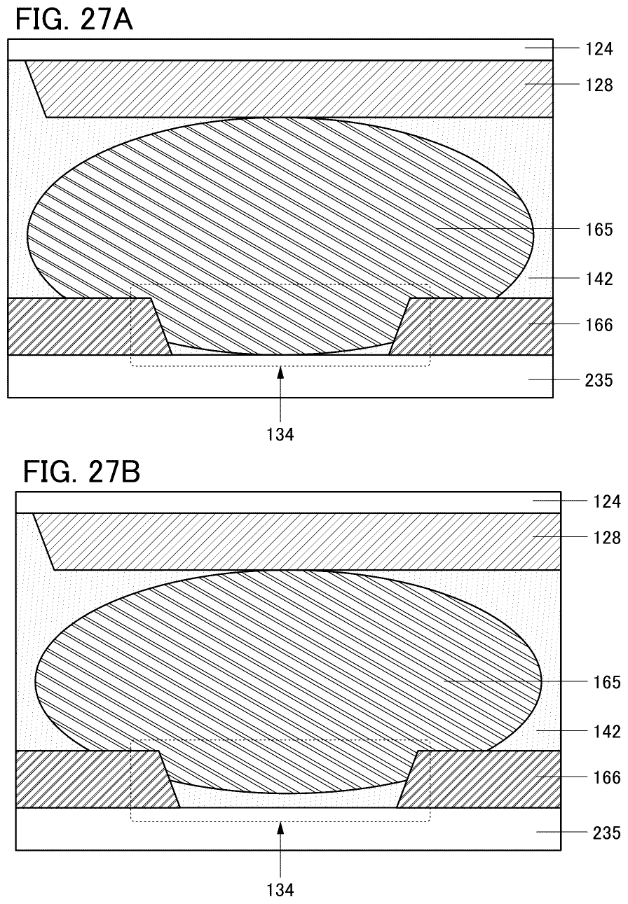

FIG. 27A and FIG. 27B are enlarged views illustrating structure examples of the conductive particle 165 illustrated in FIG. 25 and its surroundings. Note that the structures illustrated in FIG. 27A and FIG. 27B can also be applied to the touch panel having the structure illustrated in FIG. 26. As illustrated in FIG. 27A and FIG. 27B, the conductive particle 165 include a region positioned in the opening 134, and is provided to include a region in contact with the side surface of the conductive layer 166, for example. That is, the conductive particle 165 is provided to be fit in the opening 134. Specifically, the conductive particle 165 is included in the adhesive layer 142 so as to be fit in the opening 134, whereby the conductive particle 165 can be provided to be fit in the opening 134. In the case where the conductive particle 165 is provided to be fit in the opening 134, even when the conductive particle 165 is provided in a region that is in the vicinity of the opening 134 but is not in contact with the electrode 128 or the like right after the substrate 101 and the substrate 152 are bonded to each other using the adhesive layer 142 including the conductive particle 165, for example, the position of the conductive particle 165 is shifted owing to a step formed by the opening 134 and the conductive particle 165 enters the opening 134 in some cases. Accordingly, the conductive particle 165 can sometimes be inhibited from being out of contact with the electrode 128, for example.

In the above manner, the touch panel 10 having the structure illustrated in FIG. 23A, FIG. 25, and the like and the touch panel 10 having the structure illustrated in FIG. 23A, FIG. 26, and the like can be manufactured by a high-yield method and thus can be inexpensive. The touch panel 10 having the structure illustrated in FIG. 23A, FIG. 25, and the like and the touch panel 10 having the structure illustrated in FIG. 23A, FIG. 26, and the like can have high reliability. Here, FIG. 27A illustrates an example in which the conductive particle 165 includes a region in contact with the insulating layer 235 in the opening 134, and FIG. 27B illustrates an example in which the conductive particle 165 is not in contact with the insulating layer 235 in the opening 134. Although FIG. 27A and FIG. 27B illustrate an example in which the conductive particle 165 includes a region in contact with the top surface of the conductive layer 166 outside the opening 134, the conductive particle 165 is not necessarily in contact with the top surface of the conductive layer 166.

In the case where the conductive particle 165 is provided in the opening 134 in the conductive layer 166, the conductive particle 165 does not need to be provided in the opening 131. In this case, the electrode 127 and the electrode 128 can be placed not to overlap the opening 131. Note that even in the case where the conductive particle 165 is provided in the opening 134, the electrode 127 or the electrode 128 may be provided to include a region overlapping the opening 131 and the conductive particle 165 may be provided in the opening 131.

FIG. 23B is a plan view illustrating a structure example in which the electrode 128 1 and the electrode 128_2 are omitted from the components illustrated in FIG. 23A. For example, as illustrated in FIG. 23B, a plurality of the openings 134_1 can be provided, and the conductive particle 165_1 can be provided in each of the openings 134_1. Similarly, a plurality of the openings 134_2 can be provided, and the conductive particle 165_2 can be provided in each of the openings 134_2. Providing the plurality of openings 134_1 can increase the total of the perimeters of the openings 134_1 in a plan view. This sometimes makes the conductive particle 165_1 likely to be fit in the openings 134_1. Similarly, providing the plurality of openings 134_2 sometimes makes the conductive particle 165_2 likely to be fit in the openings 134_2.

As described above, the conductive particle 165 can be provided to include a region in contact with the side surface of the conductive layer 166 in the opening 134. Thus, as illustrated in FIG. 23B, the area of the conductive particle 165 can be made larger than the area of the opening 134 in the plan view. For example, the conductive particle 165 can cover the entire opening 134 in the plan view. Note that in the structure illustrated in FIG. 9B, for example, the area of the conductive particle 165 is larger than the area of the opening 131 in the plan view. For example, the conductive particle 165 covers the entire opening 131 in the plan view.

FIG. 24 is a plan view illustrating a structure example in which the conductive particle 165 is omitted from the components illustrated in FIG. 23B. Although the planar shape of the opening 134 is a circle in the examples illustrated in FIG. 23A, FIG. 23B, and FIG. 24, the planar shape of the opening 134 can be of the same type as a shape that the opening 131 can have.

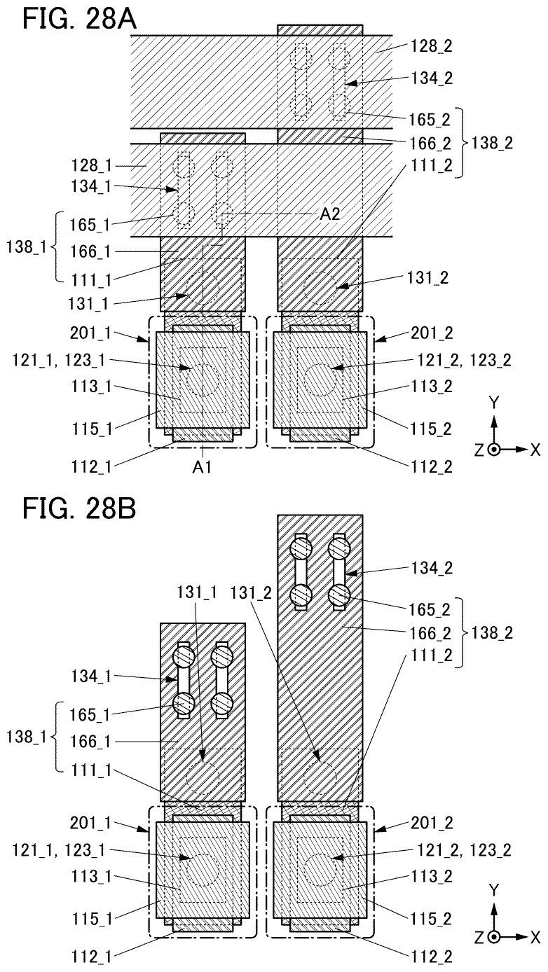

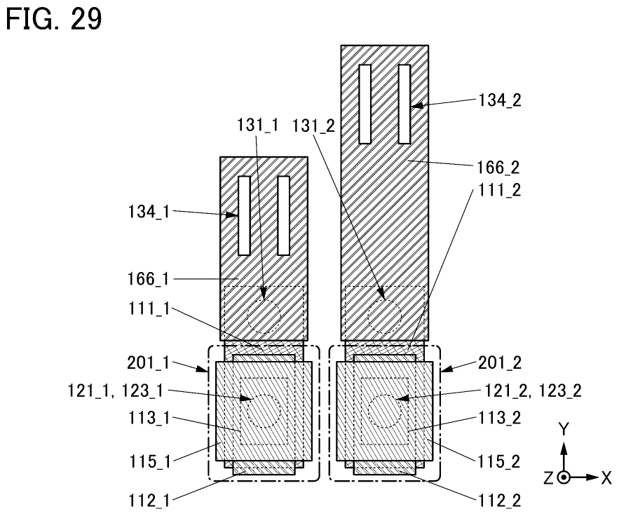

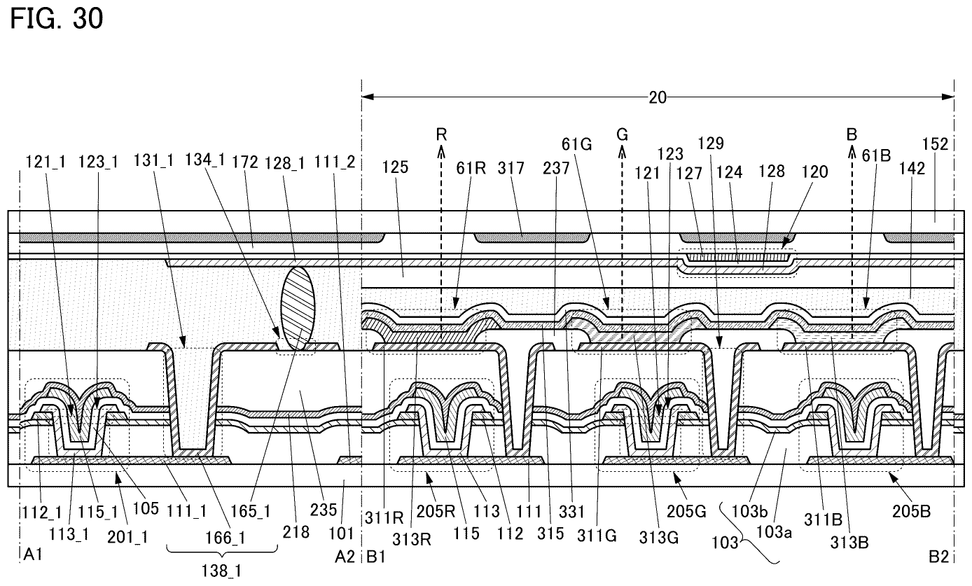

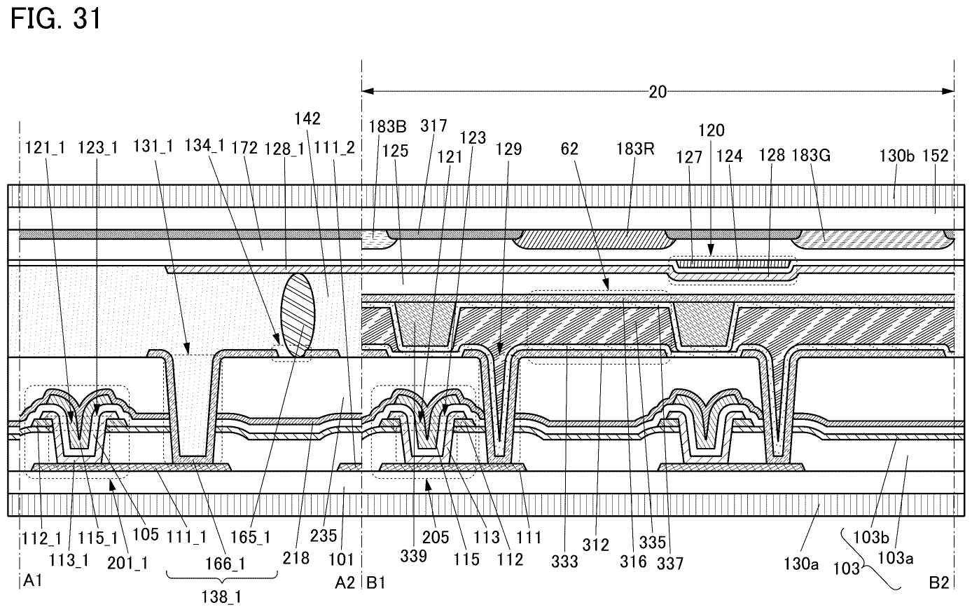

FIG. 28A, FIG. 28B, FIG. 29, FIG. 30, and FIG. 31 show variation examples of the structures illustrated in FIG. 23A, FIG. 23B, FIG. 24, FIG. 25, and FIG. 26, respectively, and illustrate examples in which a plurality of conductive particles 165 are fit in one opening 134. In this case, as illustrated in FIG. 28A and FIG. 28B, the opening 134 can include a region not overlapped by the conductive particle 165. FIG. 28A, FIG. 28B, and FIG. 29 illustrate examples in which the planar shape of the opening 134 is rectangular. Note that the planar shape of the opening 134 may be a rectangular shape with rounded corners, for example. Alternatively, the surface shape of the opening 134 can be the same type of shape as the shape the opening 131 can have.

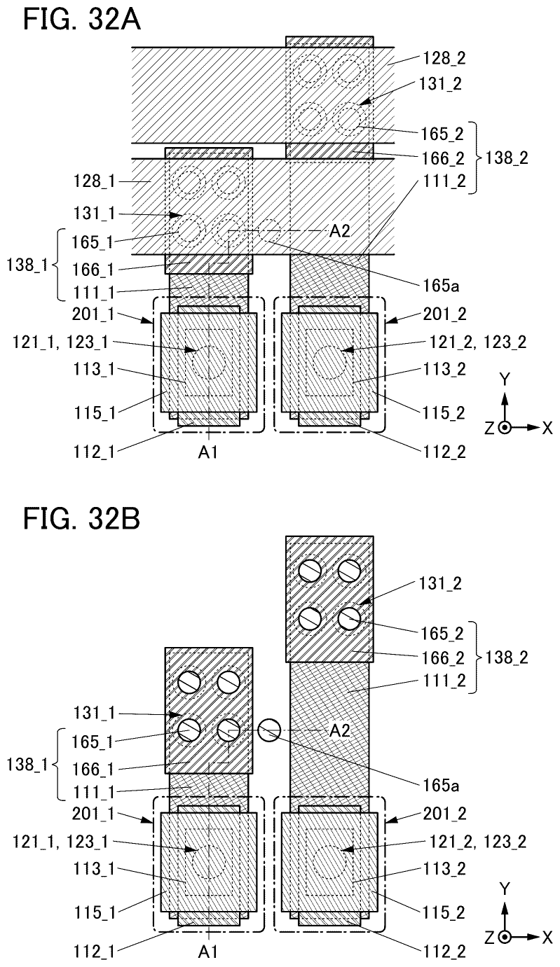

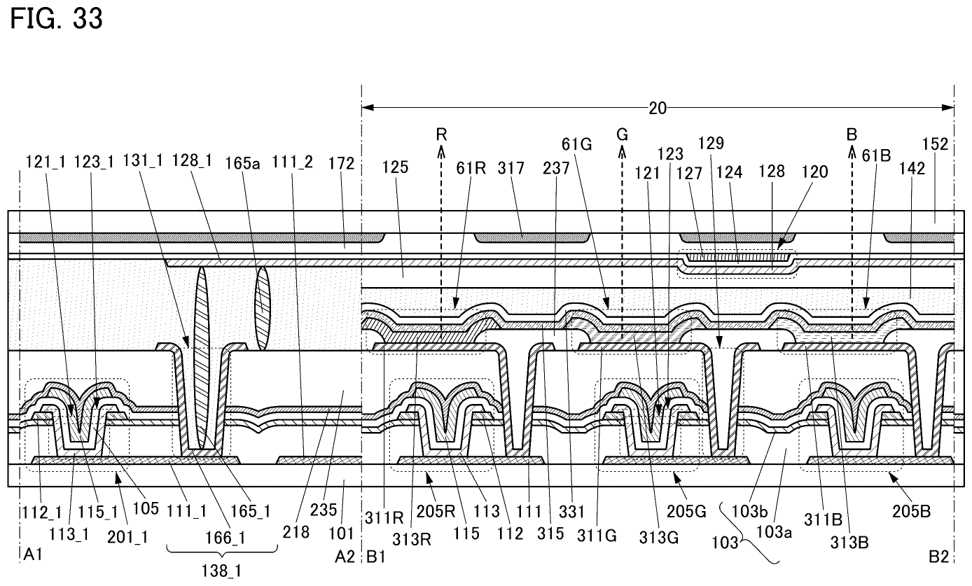

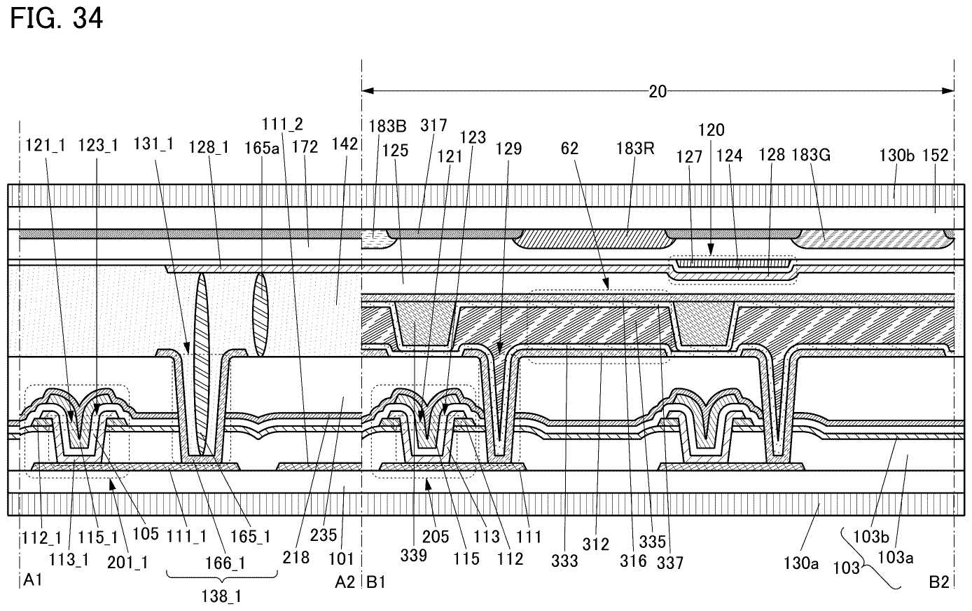

FIG. 32A, FIG. 32B, FIG. 33, and FIG. 34 show variation examples of the structures illustrated in FIG. 4A, FIG. 4B, FIG. 6, and FIG. 7, respectively, and illustrate examples in which the conductive particle 165a is provided in a region not overlapping the conductive layer 166. In the examples illustrated in FIG. 33 and FIG. 34, the conductive particle 165a includes regions in contact with the electrode 128 and the insulating layer 235 but does not include a region in contact with the conductive layer 166. Even in the case where such a conductive particle 165a is present in the touch panel 10, the touch panel 10 can be driven without a malfunction, for example.

### Structure Example of Input Device

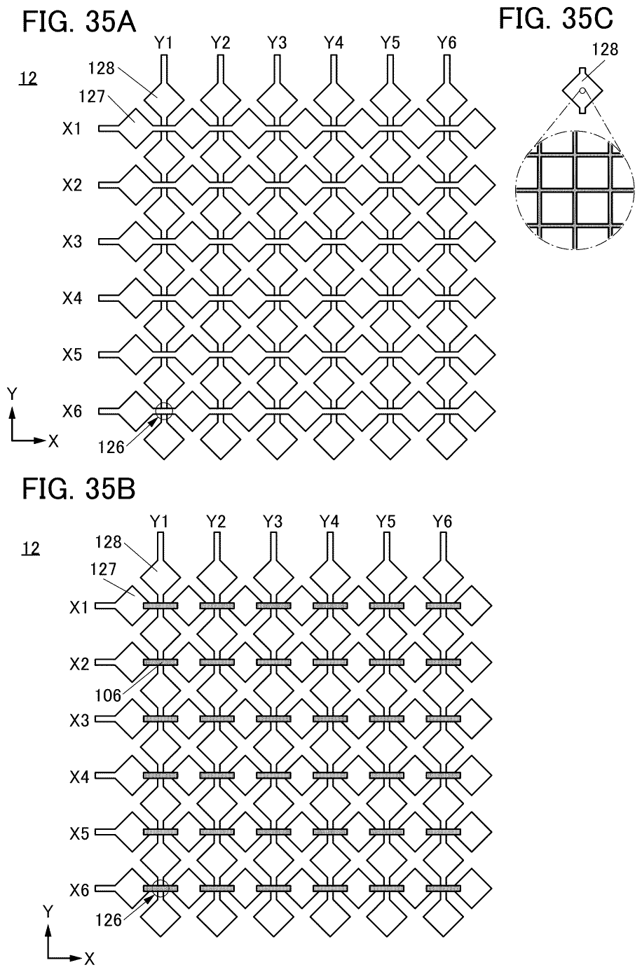

FIG. 35A is a plan view illustrating a structure example of the input device 12 and illustrates the electrodes 127 and the electrodes 128.

The electrodes 127 and the electrodes 128 extend in respective directions perpendicular to each other. In FIG. 35A, the direction in which the electrodes 127 extend is referred to as the X direction, and the direction in which the electrodes 128 extend is referred to as the Y direction. The electrodes 127 are arranged in the Y direction, and the electrodes 128 are arranged in the X direction.

The electrodes 127 form a plurality of wirings X, and the electrodes 128 form a plurality of wirings Y. FIG. 35A illustrates a wiring X1 to a wiring X6 as the wirings X and a wiring Y1 to a wiring Y6 as the wirings Y. Hereinafter, a simple expression “wiring X” is used to describe the matter common to the wiring X1 to the wiring X6, and a simple expression “wiring Y” is used to describe the matter common to the wiring Y1 to the wiring Y6. Note that the number of wirings X and the number of wirings Y are just examples and can be set as appropriate in accordance with the size of the display portion 20, the required wiring density of the input device 12, and the like.

The wiring X has a shape in which portions that are long and narrow in the X direction and rhombic portions are alternately connected to each other. The wiring Y has a shape in which portions that are long and narrow in the Y direction and rhombic portions are alternately connected to each other. The portion of the wiring X that is long and narrow in the X direction intersects with the portion of the wiring Y that is long and narrow in the Y direction. The portion at the intersection is the intersection portion 126.

FIG. 6, FIG. 7, FIG. 13, FIG. 14, FIG. 18, FIG. 21, FIG. 22, FIG. 25, FIG. 26, FIG. 30, FIG. 31, FIG. 33, and FIG. 34 described above illustrate examples in which the input device 12 has the structure illustrated in FIG. 35A.

FIG. 35B shows a variation example of the structure illustrated in FIG. 35A and illustrates an example in which the rhombic electrodes 127 are electrically connected to each other through the conductive layer 106. In the example illustrated in FIG. 35B, the conductive layer 106 intersects with the portion of the electrode 128 that is long and narrow in the Y direction. The portion at the intersection is the intersection portion 126.

The conductive layer 106 can be provided not to overlap the display region of the display portion 20 illustrated in FIG. 1A, for example. Thus, in the case where the touch panel 10 includes the light-emitting element 61, a material having a low light-transmitting property with respect to light emitted from the light-emitting element 61 can be used for the conductive layer 106. In the case where the touch panel 10 includes the liquid crystal element 62, a material having a low light-transmitting property with respect to light emitted from a light source such as a backlight can be used for the conductive layer 106. For the conductive layer 106, a material having a low visible-light-transmitting property can be used, for example. Examples of materials that can be used for the conductive layer 106 include a metal and an alloy. Examples of materials that can be used for the conductive layer 106 include a metal such as aluminum, titanium, chromium, nickel, copper, yttrium, zirconium, molybdenum, silver, tantalum, and tungsten, and an alloy containing any of these metals as its main component. For the conductive layer 106, a single-layer structure or a stacked-layer structure including a film containing any of these materials can be used. When a conductive film including a relatively low-resistance metal or alloy is used as the conductive layer 106 in this manner, the touch operation sensitivity of the input device 12 can be increased, for example. Note that for the conductive layer 106, a material that can be used for the electrode 127 or the electrode 128, specifically, a material having a high visible-light-transmitting property, for example, may be used.

In the example illustrated in FIG. 35B, the electrode 127 and the electrode 128 can be provided in the same layer. Thus, the electrode 127 and the electrode 128 can include the same material and can be formed in the same step. For example, the electrode 127 and the electrode 128 can be formed by processing the same conductive film.

Here, as the electrode 127 and the electrode 128, a conductive film that is processed to be thin enough not to be perceived by the user of the touch panel 10 may be used. For example, such a conductive film is preferably processed into a lattice pattern (a mesh pattern), in which case the user of the display apparatus 11 is less likely to perceive the electrode 127 and the electrode 128. At this time, the conductive film preferably has a portion with a width greater than or equal to 30 nm and less than or equal to 100 μm, preferably greater than or equal to 50 nm and less than or equal to 50 μm, further preferably greater than or equal to 50 nm and less than or equal to 20 μm. A conductive film having a pattern width of 10 μm or less, which is extremely difficult for the user to perceive, is particularly preferable.

FIG. 35C is an enlarged view illustrating a structure example in which a lattice-shaped conductive film is used as the electrode 128. Here, the electrode 127 can also have a structure similar to that illustrated in FIG. 35C. When the electrode 127 and the electrode 128 have a lattice shape as illustrated in FIG. 35C, the conductive film included in the electrode 127 and the conductive film included in the electrode 128 can be provided not to overlap the light-emitting element 61 or the liquid crystal element 62. Thus, in the case where the touch panel 10 includes the light-emitting element 61, a material having a low light-transmitting property with respect to light emitted from the light-emitting element 61 can be used for the electrode 127 and the electrode 128. In the case where the touch panel 10 includes the liquid crystal element 62, a material having a low light-transmitting property with respect to light emitted from a light source such as a backlight can be used for the electrode 127 and the electrode 128. For the electrode 127 and the electrode 128 illustrated in FIG. 35C, a material having a low visible-light-transmitting property can be used, for example. Specifically, a material that can be used for the conductive layer 106, such as a metal or an alloy, can be used.

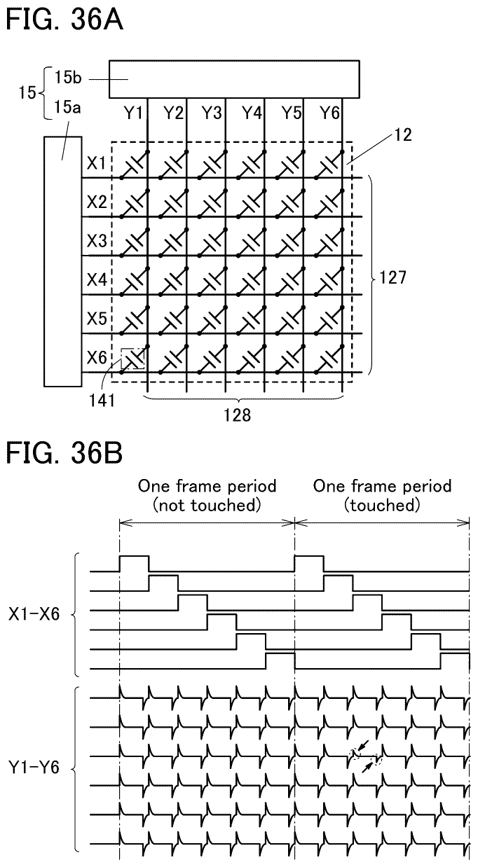

FIG. 36A is a block diagram illustrating a structure example of the input device 12. FIG. 36A illustrates an example in which the input device 12 is a mutual capacitive input device. FIG. 36A also illustrates the input device driver circuit 15. FIG. 36A illustrates an example in which the electrodes 127 form the wiring X1 to the wiring X6 and the electrodes 128 form the wiring Y1 to the wiring Y6. A capacitor 141 is formed by the electrode 127 and the electrode 128. As described above, the electrode 127 is electrically connected to the circuit 15a included in the input device driver circuit 15, and the electrode 128 is electrically connected to the circuit 15b.

The circuit 15a is a circuit that functions as a pulse voltage output circuit as described above and applies a pulse voltage sequentially to the wiring X1 to the wiring X6. By application of a pulse voltage to the wiring X1 to the wiring X6, an electric field is generated between the electrode 127 and the electrode 128 that form the capacitor 141. By utilizing a change in the capacitance of the capacitor 141 caused by blocking of an electric field generated between the electrode 127 and the electrode 128 by a sensing target, for example, the approach or contact of the sensing target can be detected.

The circuit 15b is a circuit that functions as a current detection circuit as described above and detects a change in the current value of any of the wiring Y1 to the wiring Y6 caused by a change in the capacitance of the capacitor 141. Current can be detected using an integrator circuit, for example. Note that the circuit 15a may function as a current detection circuit and the circuit 15b may function as a pulse voltage output circuit as described above.

FIG. 36B is a timing chart showing an example of a driving method of the input device 12 illustrated in FIG. 36A. In the example illustrated in FIG. 36B, position detection of a sensing target is performed in one frame period. The example illustrated in FIG. 36B shows the following two cases: the case where a sensing target is not detected (not touched) and the case where a sensing target is detected (touched). Note that voltage values corresponding to detected current values of the wiring Y1 to the wiring Y6 are shown as waveforms.

In the example illustrated in FIG. 36B, a pulse voltage is sequentially applied to the wiring X1 to the wiring X6, and the waveforms of the wiring Y1 to the wiring Y6 change in accordance with the pulse voltage. When there is no approach or contact of a sensing target, the waveforms of the wiring Y1 to the wiring Y6 change uniformly in accordance with changes in the voltages of the wiring X1 to the wiring X6. Meanwhile, the current value of the wiring Y at the position where a sensing target approaches or touches decreases, and thus the waveform of the voltage value corresponding to the current value also changes.

In this manner, the circuit 15b can detect a change in the capacitance of the capacitor 141 by detecting a change in the current value of the wiring Y. Accordingly, the input device driver circuit 15 can sense the approach or contact of a sensing target.

### Structure Example 3 of Touch Panel

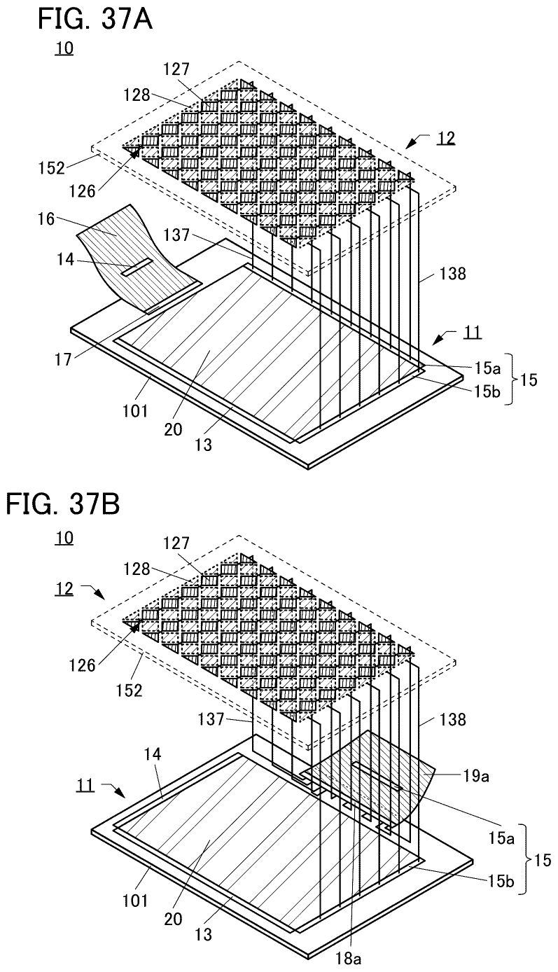

Although FIG. 1A, for example, illustrates an example in which all of the scan line driver circuit 13, the signal line driver circuit 14, the circuit 15a, and the circuit 15b are incorporated in the touch panel 10, one embodiment of the present invention is not limited thereto. FIG. 37A illustrates an example in which the signal line driver circuit 14 is externally provided.

In the example illustrated in FIG. 37A, the display apparatus 11 includes a connection portion 17, and an FPC (Flexible Printed Circuit) 16 is electrically connected to the connection portion 17. The signal line driver circuit 14 is mounted on the FPC 16 by a COF(Chip On Film) method, for example. The signal line driver circuit 14 can be an integrated circuit (IC), for example.

The connection portion 17 is electrically connected to the pixels provided in the display portion 20. That is, the pixels and the signal line driver circuit 14 are electrically connected to each other through the connection portion 17. The connection portion 17 can be provided with an anisotropic conductive connector, for example.

FIG. 37B illustrates an example in which the circuit 15a is externally provided. In the example illustrated in FIG. 37B, the display apparatus 11 includes a connection portion 18a, and an FPC 19a is electrically connected to the connection portion 18a. The circuit 15a is mounted on the FPC 19a by a COF method, for example. The circuit 15a can be an IC, for example. Note that the connection portion 18a may be provided in the input device 12.

The connection portion 18a is electrically connected to the electrode 127. That is, the electrode 127 and the circuit 15a are electrically connected to each other through the connection portion 18a. The connection portion 18a can be provided with an anisotropic conductive connector, for example.

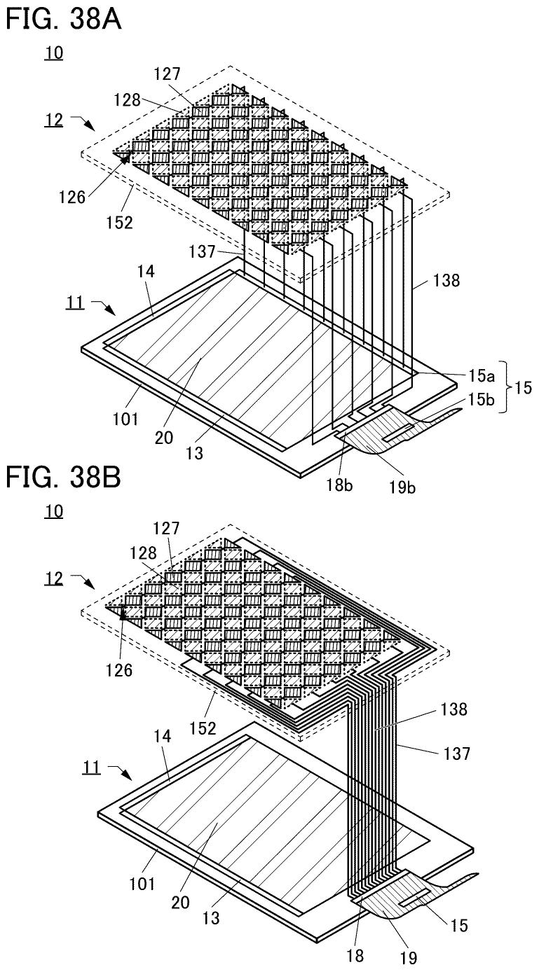

FIG. 38A illustrates an example in which the circuit 15b is externally provided. In the example illustrated in FIG. 38A, the display apparatus 11 includes a connection portion 18b, and an FPC 19b is electrically connected to the connection portion 18b. The circuit 15b is mounted on the FPC 19b by a COF method, for example. The circuit 15b can be an IC, for example. Note that the connection portion 18b may be provided in the input device 12.

The connection portion 18b is electrically connected to the electrode 128. That is, the electrode 128 and the circuit 15b are electrically connected to each other through the connection portion 18b. The connection portion 18b can be provided with an anisotropic conductive connector, for example.

FIG. 38B illustrates an example in which the input device driver circuit 15 is mounted on an FPC 19 by a COF method as an IC in which the circuit 15a and the circuit 15b are integrated. In the example illustrated in FIG. 38B, the display apparatus 11 includes a connection portion 18, and the FPC 19 is electrically connected to the connection portion 18. Note that the connection portion 18 may be provided in the input device 12.

The connection portion 18 is electrically connected to the electrode 127 and the electrode 128. That is, the electrode 127 and the input device driver circuit 15 are electrically connected to each other through the connection portion 18, and the electrode 128 and the input device driver circuit 15 are electrically connected to each other through the connection portion 18. The connection portion 18 can be provided with an anisotropic conductive connector, for example.

Note that the scan line driver circuit 13 may be externally provided. Alternatively, the signal line driver circuit 14 and one or both of the circuit 15a and the circuit 15b may be externally provided. Further alternatively, all of the scan line driver circuit 13, the signal line driver circuit 14, and the input device driver circuit 15 may be externally provided.

FIG. 6, FIG. 7, FIG. 13, FIG. 14, FIG. 18, FIG. 21, FIG. 22, FIG. 25, FIG. 26, FIG. 30, FIG. 31, FIG. 33, and FIG. 34 illustrate examples in which the circuit 15b electrically connected to the electrode 128 is incorporated in the touch panel 10. In this case, the transistor 201 that is electrically connected to the electrode 128 and provided in the circuit 15b is provided over the substrate 101. Meanwhile, in the case where the circuit 15b is externally provided as illustrated in FIG. 38A, for example, the transistor 201 is provided at a position not overlapping the substrate 101. In this case, for example, a wiring (also referred to as a lead wiring) electrically connected to the source electrode, the drain electrode, or the gate electrode of the transistor 201 is provided over the substrate 101. The opening 131 is provided to reach the lead wiring, and the conductive layer 166 and the conductive particle 165 are provided to include a region positioned in the opening 131. Thus, the source electrode, the drain electrode, or the gate electrode of the transistor 201 is electrically connected to the electrode 128. In the case where the circuit 15a is externally provided, the source electrode, the drain electrode, or the gate electrode of the transistor 201 provided in the circuit 15a is electrically connected to the electrode 127 in a similar manner.

Note that some of components of at least one of the scan line driver circuit 13, the signal line driver circuit 14, and the input device driver circuit 15 (the circuit 15a and the circuit 15b) may be incorporated in the touch panel 10 and the other components may be externally provided. For example, among the transistors included in the input device driver circuit 15, the transistor 201 electrically connected to the electrode 127 or the electrode 128 may be incorporated in the touch panel 10 and the other transistors may be externally provided as an IC.

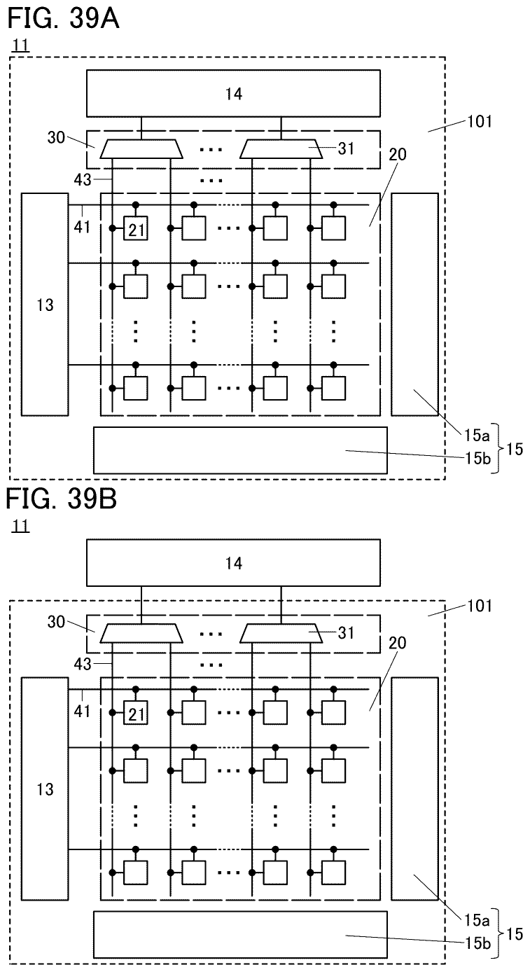

FIG. 39A shows a variation example of the structure illustrated in FIG. 2A and illustrates an example in which the touch panel 10 includes a demultiplexer circuit 31. FIG. 39A illustrates an example in which the touch panel 10 includes a plurality of the demultiplexer circuits 31, and the plurality of demultiplexer circuits 31 are collectively referred to as a demultiplexer circuit group 30.

An input terminal of the demultiplexer circuit 31 is electrically connected to the signal line driver circuit 14. An output terminal of the demultiplexer circuit 31 is electrically connected to the pixels 21 through the wiring 43. Here, the demultiplexer circuit 31 can have one input terminal and two or more output terminals, for example. FIG. 39A illustrates an example in which the demultiplexer circuit 31 has two output terminals.

The demultiplexer circuit 31 has a function of outputting image data generated by the signal line driver circuit 14, from one of the output terminals of the demultiplexer circuit 31. Providing the demultiplexer circuit 31 in the touch panel 10 can reduce the number of wirings connected to the signal line driver circuit 14. Note that out of the output terminals of the demultiplexer circuit 31, the output terminal that outputs image data can be determined by a control circuit (not illustrated). The control circuit may be incorporated in the touch panel 10 or may be externally provided as an IC, for example.

FIG. 39B shows a variation example of the structure illustrated in FIG. 39A and illustrates an example in which the signal line driver circuit 14 is provided outside the substrate 101, that is, the signal line driver circuit 14 is externally provided. Note that not only the signal line driver circuit 14 but also the demultiplexer circuit 31 may be externally provided as an IC, for example.

A transistor included in the demultiplexer circuit 31 can have the same structure as the transistor 201 illustrated in FIG. 6, FIG. 7, FIG. 13, FIG. 14, FIG. 18, FIG. 21, FIG. 22, FIG. 25, FIG. 26, FIG. 30, FIG. 31, FIG. 33, and FIG. 34. In this case, the transistor included in the demultiplexer circuit 31 can be formed in the same process as the transistor 201. For example, when all of the transistor included in the demultiplexer circuit 31, the transistor 201, and the transistor 205 have the same structure, these transistors can be formed in the same process. In the above manner, the manufacturing process of the touch panel 10 can be simplified, and the touch panel 10 can be manufactured by a method with low cost and high mass productivity. Note that the structure of the transistor included in the demultiplexer circuit 31 may be different from the structure of the transistor included in the scan line driver circuit 13, the signal line driver circuit 14, the input device driver circuit 15, or the display portion 20.

### Structure Example of Display Portion

The touch panel 10 including the display portion 20 having a structure different from those in FIG. 6, FIG. 7, FIG. 13, and FIG. 14, for example, will be described below.

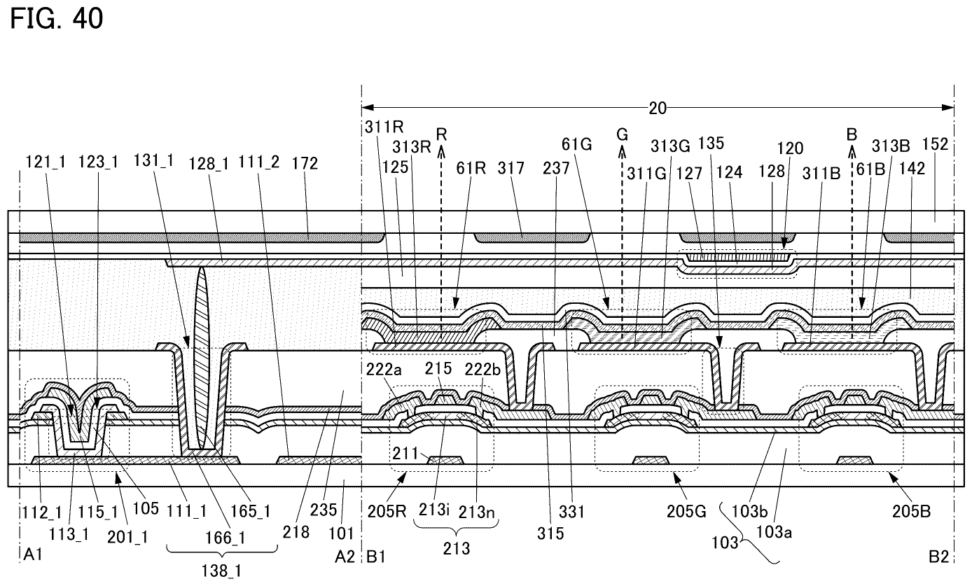

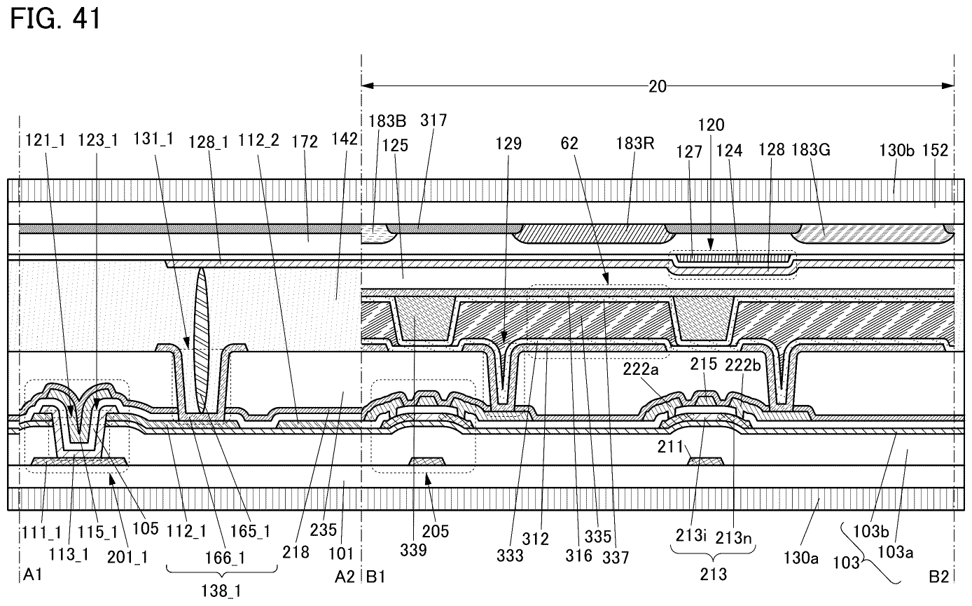

FIG. 40 and FIG. 41 show variation examples of the structures illustrated in FIG. 6 and FIG. 14, respectively, and differ in the structure of the transistor 205, for example.

The transistor 205 illustrated in FIG. 40 and FIG. 41 includes a semiconductor layer 213, the insulating layer 105 functioning as a gate insulating layer, a conductive layer 215 functioning as a gate electrode, a conductive layer 222a functioning as one of a source electrode and a drain electrode, and a conductive layer 222b functioning as the other of the source electrode and the drain electrode. Moreover, the transistor 201 can include a conductive layer 211. In this case, the conductive layer 215 functions as a first gate electrode, and the conductive layer 211 functions as a second gate electrode. In addition, the insulating layer 105 functions as a first gate insulating layer, and the insulating layer 103 functions as a second gate insulating layer.

The conductive layer 211 is provided over the substrate 101, and the insulating layer 103 is provided over the substrate 101 and the conductive layer 211. The semiconductor layer 213 is provided over the insulating layer 103 to include a region overlapping the conductive layer 211, and the insulating layer 105 is provided over the insulating layer 103 and the semiconductor layer 213. The conductive layer 215 is provided over the insulating layer 105 to include a region overlapping the conductive layer 211 and the semiconductor layer 213.

The semiconductor layer 213 includes a channel formation region 213i and a pair of low-resistance regions 213n. Here, a first opening reaching one of the pair of low-resistance regions 213n and a second opening reaching the other of the pair of low-resistance regions 213n are provided in the insulating layer 105. The semiconductor layer 213 and the conductive layer 222a are electrically connected to each other through the first opening, and the semiconductor layer 213 and the conductive layer 222b are electrically connected to each other through the second opening. For example, the one of the pair of low-resistance regions 213n and the conductive layer 222a are in contact with each other in the first opening, and the other of the pair of low-resistance regions 213n and the conductive layer 222b are in contact with each other in the second opening.

The conductive layer 211 can be provided in the same layer as the conductive layer 111. Thus, the conductive layer 211 can include the same material as the conductive layer 111 and can be formed in the same step as the conductive layer 111. For example, the conductive layer 111 and the conductive layer 211 can be formed by processing the same conductive film. In addition, the semiconductor layer 213 can be provided in the same layer as the semiconductor layer 113. Thus, the semiconductor layer 213 can include the same material as the semiconductor layer 113 and can be formed in the same step as the semiconductor layer 113. For example, the semiconductor layer 113 and the semiconductor layer 213 can be formed by processing the same semiconductor film. Furthermore, the conductive layer 215, the conductive layer 222a, and the conductive layer 222b can be provided in the same layer as the conductive layer 115. Thus, the semiconductor layer 213 can include the same material as the semiconductor layer 113 and can be formed in the same step as the semiconductor layer 113. Thus, the conductive layer 215, the conductive layer 222a, and the conductive layer 222b can include the same material as the conductive layer 115 and can be formed in the same step as the conductive layer 115. For example, the conductive layer 115, the conductive layer 215, the conductive layer 222a, and the conductive layer 222b can be formed by processing the same conductive film.

Here, the semiconductor layer 113 and the semiconductor layer 213 may include different materials. For example, silicon such as LTPS may be used for the semiconductor layer 113, and a metal oxide may be used for the semiconductor layer 213. When silicon such as LTPS is used for the semiconductor layer 113, the transistor 201 can have improved field-effect mobility. Thus, for example, the input device driver circuit 15 can be driven at high speed. When a metal oxide is used for the semiconductor layer 213, that is, an OS transistor is used as the transistor 205, an image written to the pixel where the transistor 205 is provided can be retained for a long period. Thus, the frequency of refresh operation can be reduced, so that power consumption of the touch panel 10 can be reduced. In the case where the touch panel 10 includes the light-emitting element 61, the use of an OS transistor as the transistor 205 makes it possible to inhibit black-level degradation, increase the emission luminance, increase the number of gray levels, and suppress variations in emission luminance between the light-emitting elements 61, for example, as described above. Here, when the semiconductor layer 113 and the semiconductor layer 213 are formed in different steps, the material included in the semiconductor layer 113 and the material included in the semiconductor layer 213 can be different from each other.

In the case where the transistor 205 includes the conductive layer 211, the transistor 205 has a structure where the channel formation region 213i is sandwiched between the two gate electrodes. In this case, the two gate electrodes may be electrically connected to each other and supplied with the same signal to drive the transistor 205. Alternatively, a potential for controlling the threshold voltage may be supplied to one of the two gate electrodes and a potential for driving may be supplied to the other to control the threshold voltage of the transistor 205.

A transistor having the same structure as the transistor 205 illustrated in FIG. 40 and FIG. 41 may be provided in at least one of the scan line driver circuit 13, the signal line driver circuit 14, the input device driver circuit 15, and the demultiplexer circuit 31. For example, the transistor 201 may have the same structure as the transistor 205 illustrated in FIG. 40 and FIG. 41.

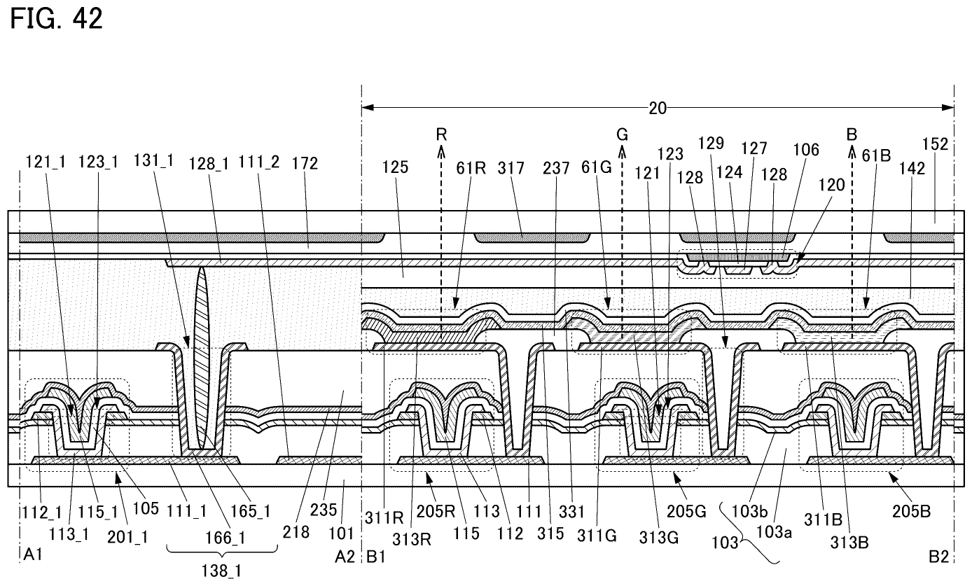

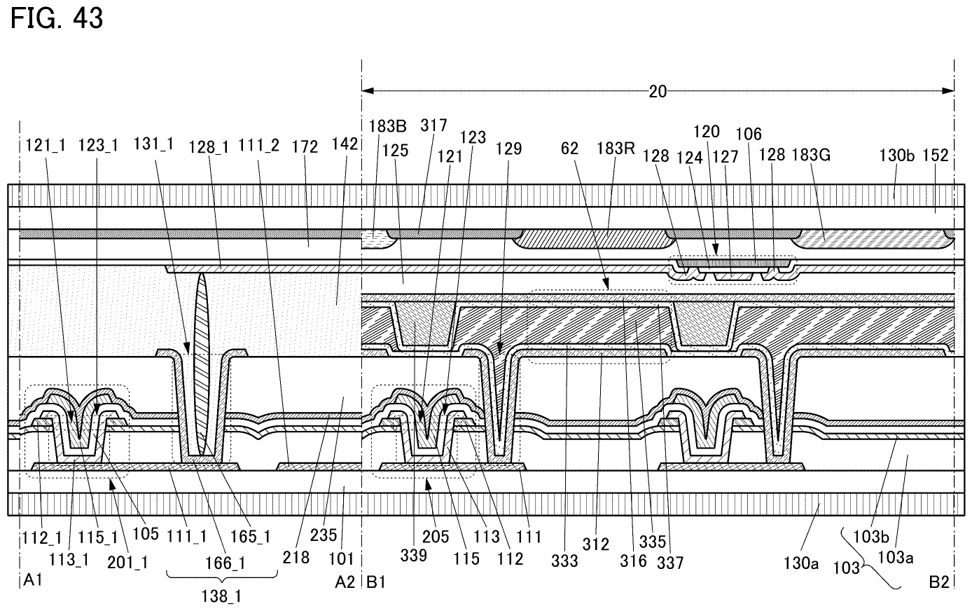

FIG. 42 and FIG. 43 show variation examples of the structures illustrated in FIG. 6 and FIG. 7, respectively, and illustrate examples in which the electrode 127 and the electrode 128 are provided in the same layer and the electrodes 128 are electrically connected to each other through the conductive layer 106 including a region overlapping the electrode 127. That is, in FIG. 42 and FIG. 43, the structure of the input device 12 corresponds to the structure illustrated in FIG. 35B.

In the sensing element 120 illustrated in FIG. 42 and FIG. 43, an opening reaching the conductive layer 106 is provided in the insulating layer 124. The conductive layer 106 is electrically connected through the opening to two electrodes 128 provided to sandwich the electrode 127.

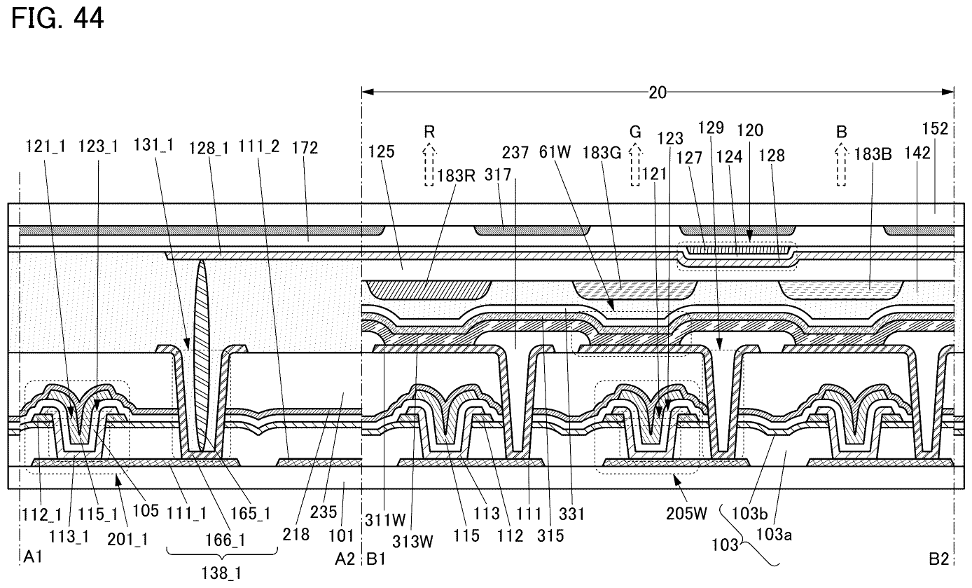

FIG. 44 shows a variation example of the structure illustrated in FIG. 6 and illustrates an example in which a light-emitting element 61W is provided instead of the light-emitting element 61R, the light-emitting element 61G, and the light-emitting element 61B and the coloring layer 183 (the coloring layer 183R, the coloring layer 183G, and the coloring layer 183B) is provided. Here, the transistor 205 provided in the touch panel 10 having the structure illustrated in FIG. 44 is denoted as a transistor 205W.

In the display portion 20 illustrated in FIG. 44, one light-emitting element 61W includes a region overlapped by one of the coloring layer 183R, the coloring layer 183G, and the coloring layer 183B. Note that the coloring layers 183 that transmit light with different wavelengths may overlap each other in a region other than the light-emitting region of the light-emitting element 61W. Thus, the light-blocking layer 317 can be omitted while a decrease in the contrast ratio of images displayed on the display portion 20 is inhibited.

The light-emitting element 61W includes a pixel electrode 311W as the pixel electrode 311 and a layer 313W as the layer 313. The layer 313W including a light-emitting layer can emit white light, for example. The coloring layer 183R can transmit red light, the coloring layer 183G can transmit green light, and the coloring layer 183B can transmit blue light, for example. Accordingly, the display portion 20 can emit red light, green light, and blue light, for example, to perform full-color display.

When the distance between the light-emitting element 61W and the coloring layer 183 is shortened, light emitted from the light-emitting element 61W can be inhibited from not passing through the coloring layer 183 and from entering the adjacent coloring layer 183. As a result, the contrast ratio of images displayed on the display portion 20 can be increased. Accordingly, the coloring layer 183 is preferably provided on a surface of the insulating layer 125 on the substrate 101 side, for example. Here, the insulating layer 125 is preferably made flat, in which case the coloring layer 183 is easily formed over the insulating layer 125. Alternatively, the coloring layer 183 may be provided on a surface of the protective layer 331 on the substrate 152 side, for example. In this case, the protective layer 331 is preferably made flat, in which case the coloring layer 183 is easily formed. For example, the use of an organic material for the protective layer 331 allows the protective layer 331 to be flat. Note that the coloring layer 183 may be provided on the surface of the substrate 152 on the substrate 101 side. In this case, an end portion of the coloring layer 183 can include a region in contact with the light-blocking layer 317.

As illustrated in FIG. 44, the layer 313W can be a continuous layer that is not divided for each light-emitting element 61W. Accordingly, the manufacturing process of the touch panel 10 can be simplified as compared with the case where the layer 313W is divided for each light-emitting element 61W. Note that the layer 313W may be divided for each light-emitting element 61W. In this case, a leakage current (also referred to as a lateral leakage current or a side leakage current) can be inhibited from flowing between adjacent light-emitting elements 61W through the layer 313W. This can inhibit unintended light emission (also referred to as crosstalk) of the light-emitting element 61W, so that the contrast of images displayed on the display portion 20 can be increased and high-quality images can be displayed on the display portion 20.

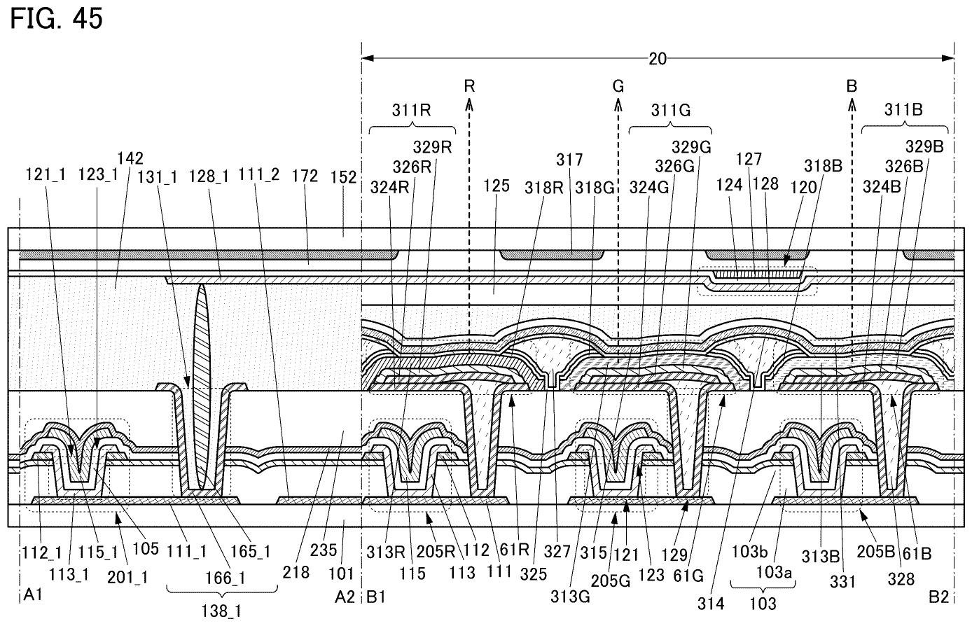

FIG. 45 shows a variation example of the structure illustrated in FIG. 6 and differs in the structures of the light-emitting element 61R, the light-emitting element 61G, and the light-emitting element 61B, for example. In addition, the structures of the pixel electrode 311R, the pixel electrode 311G, and the pixel electrode 311B are different from those in FIG. 6. Furthermore, FIG. 45 is different from FIG. 6 in that the insulating layer 237 is not provided, the layer 313 covers the top surface and the side surface of the pixel electrode 311, and a layer 328, an insulating layer 325, an insulating layer 327, and a common layer 314 are provided.

As illustrated in FIG. 45, the pixel electrode 311 included in the light-emitting element 61 has a stacked-layer structure of a conductive layer 324, a conductive layer 326 over the conductive layer 324, and a conductive layer 329 over the conductive layer 326. Here, the conductive layer 324, the conductive layer 326, and the conductive layer 329 of the pixel electrode 311R are denoted as a conductive layer 324R, a conductive layer 326R, and a conductive layer 329R. The conductive layer 324, the conductive layer 326, and the conductive layer 329 of the pixel electrode 311G are denoted as a conductive layer 324G, a conductive layer 326G, and a conductive layer 329G. The conductive layer 324, the conductive layer 326, and the conductive layer 329 of the pixel electrode 311B are denoted as a conductive layer 324B, a conductive layer 326B, and a conductive layer 329B.

The conductive layer 324 is electrically connected to the conductive layer 111 of the transistor 205 through the opening 129 provided in the insulating layer 103, the insulating layer 105, the insulating layer 218, and the insulating layer 235. Here, the conductive layer 166 can be provided in the same layer as the conductive layer 324. Thus, the conductive layer 166 can include the same material as the conductive layer 324 and can be formed in the same step as the conductive layer 324. For example, the conductive layer 166 and the conductive layer 324 can be formed by processing the same conductive film.

An end portion of the conductive layer 326 is positioned inward from an end portion of the conductive layer 324 and an end portion of the conductive layer 329. In other words, the end portion of the conductive layer 326 is positioned over the conductive layer 324, and the top surface and the side surface of the conductive layer 326 are covered with the conductive layer 329.

For the conductive layer 324, no particular limitations are imposed on the properties of transmitting and reflecting visible light. As the conductive layer 324, a conductive layer having a visible-light-transmitting property or a conductive layer having a visible-light-reflecting property can be used. As the conductive layer having a visible-light-transmitting property, an oxide conductive layer can be used, for example. Specifically, In—Si—Sn oxide (ITSO) can be suitably used for the conductive layer 324. For the conductive layer having a visible-light-reflecting property, it is possible to use, for example, a metal such as aluminum, magnesium, titanium, chromium, nickel, copper, yttrium, zirconium, silver, tin, zinc, silver, platinum, gold, molybdenum, tantalum, or tungsten or an alloy containing the metal as its main component. Examples of the alloy that can be used for the conductive layer 324 include an aluminum-containing alloy such as an alloy of aluminum, nickel, and lanthanum (Al—Ni—La), and a silver-containing alloy such as an alloy of silver and magnesium and an alloy of silver, palladium, and copper (APC: Ag—Pd—Cu). The conductive layer 324 may have a stacked-layer structure of a conductive layer having a visible-light-transmitting property and a conductive layer having visible-light-reflecting property over the conductive layer. For the conductive layer 324, a material with high adhesion to the formation surface of the conductive layer 324 (here, the insulating layer 235) is preferably used. Accordingly, film separation of the conductive layer 324 can be inhibited.

As the conductive layer 326, a conductive layer having a visible-light-reflecting property can be used. The conductive layer 326 may have a stacked-layer structure of a conductive layer having a visible-light-transmitting property and a conductive layer having a visible-light-reflecting property over the conductive layer. For the conductive layer 326, a material that can be used for the conductive layer 324 can be used. Specifically, a stacked-layer structure of In—Si—Sn oxide (ITSO) and an alloy of silver, palladium, and copper (APC) over the In—Si—Sn oxide (ITSO) can be suitably used for the conductive layer 326.

For the conductive layer 329, a material that can be used for the conductive layer 324 can be used. As the conductive layer 329, a conductive layer having a visible-light-transmitting property can be used, for example. Specifically, In—Si—Sn oxide (ITSO) can be used for the conductive layer 329.

In the case where a material that is easily oxidized is used for the conductive layer 326, a material that is not easily oxidized is used for the conductive layer 329 and the conductive layer 326 is covered with the conductive layer 329, whereby oxidation of the conductive layer 326 can be inhibited. In addition, precipitation of a metal component included in the conductive layer 326 can be inhibited. For example, in the case where a material containing silver is used for the conductive layer 326, In—Si—Sn oxide (ITSO) can be suitably used for the conductive layer 329. Thus, oxidation of the conductive layer 326 can be inhibited, and precipitation of silver can be inhibited.

Depressed portions are formed in the conductive layer 324R, the conductive layer 324G, and the conductive layer 324B so as to cover the opening 129. The layer 328 is embedded in each of the depressed portions.

The layer 328 has a planarization function for the depressed portions of the conductive layer 324R, the conductive layer 324G, and the conductive layer 324B. The conductive layer 326R electrically connected to the conductive layer 324R is provided over the conductive layer 324R and the layer 328. The conductive layer 326G electrically connected to the conductive layer 324G is provided over the conductive layer 324G and the layer 328. The conductive layer 326B electrically connected to the conductive layer 324B is provided over the conductive layer 324B and the layer 328. Accordingly, regions overlapping the depressed portions of the conductive layer 324R, the conductive layer 324G, and the conductive layer 324B can function as the light-emitting regions, increasing the aperture ratio of the pixels.

The layer 328 may be an insulating layer or a conductive layer. Any of a variety of inorganic insulating materials, organic insulating materials, and conductive materials can be used for the layer 328 as appropriate. Specifically, the layer 328 is preferably formed using an insulating material and is particularly preferably formed using an organic insulating material.

In the case where the layer 328 is a conductive layer, the layer 328 can function as part of a pixel electrode.

The layer 328 can also be used in the display portion 20 illustrated in drawings other than FIG. 45. For example, instead of the insulating layer 237, the layer 328 can be embedded in at least part of the depressed portions of the pixel electrode 311R, the pixel electrode 311G, and the pixel electrode 311B. As another example, the layer 328 can be embedded in at least part of the depressed portion of the conductive layer 166 illustrated in FIG. 21, FIG. 25, or FIG. 30.

FIG. 45 illustrates an example where an end portion of the layer 313 is positioned outward from an end portion of the pixel electrode 311. The layer 313 is formed to cover the end portion of the pixel electrode 311. Such a structure enables the entire top surface of the pixel electrode 311 to be a light-emitting region; hence, the aperture ratio can be increased as compared with the structure where the end portion of the island-shaped layer 313 is positioned inward from the end portion of the pixel electrode 311. Covering the side surface of the pixel electrode 311 with the layer 313 can inhibit contact between the pixel electrode 311 and the common electrode 315, thereby inhibiting a short circuit of the light-emitting element 61.

The insulating layer 237 is not provided between the pixel electrode 311 and the layer 313. Thus, the distance between adjacent light-emitting elements 61 can be shortened. Accordingly, the display portion 20 can have high resolution and high definition. In addition, a mask for forming the insulating layer is not needed, which leads to a reduction in manufacturing cost of the touch panel.

The layer 313 can be formed by a photolithography method and an etching method, for example. Specifically, a film to be the layer 313 is formed across a plurality of pixel electrodes 311 that have been formed for respective subpixels. Next, a mask layer is formed over the film to be the layer 313, and a resist mask is formed over the mask layer by a photolithography method. After that, the mask layer and the film to be the layer 313 are processed by an etching method, for example, and the resist mask is removed. For example, the mask layer employs a two-layer structure of a first mask layer and a second mask layer over the first mask layer. In this case, a resist mask is formed over the second mask layer and the second mask layer is processed. Then, the resist mask is removed. After that, the first mask layer and the film to be the layer 313 are processed using the second mask layer as a hard mask, for example. In this manner, one island-shaped layer 313 is formed for every pixel electrode 311. Thus, the layer 313 can be divided into island-shaped layers 313 for respective subpixels. By performing a series of steps from the formation of the film to be the layer 313 to the processing of the film three times, for example, the layer 313R, the layer 313G, and the layer 313B can be separately formed.

In this specification and the like, a mask layer (also referred to as a sacrificial layer) refers to a layer that is positioned above at least a light-emitting layer (specifically, a layer processed into an island shape among layers included in an EL layer) and has a function of protecting the light-emitting layer in the manufacturing process.

When the island-shaped layer 313 is formed without using a fine metal mask, the formed layer 313 can have a minute size. Providing the island-shaped layer 313 for each light-emitting element 61 can inhibit a leakage current between the adjacent light-emitting elements 61. This can inhibit crosstalk due to unintended light emission, so that a touch panel including a display apparatus with extremely high contrast can be achieved. In particular, a touch panel including a display apparatus having high current efficiency at low luminance can be achieved.

In this specification and the like, a device fabricated using a metal mask or a fine metal mask (FMM) is sometimes referred to as a device having an MM (metal mask) structure. In this specification and the like, a device fabricated without using a metal mask or an FMM is sometimes referred to as a device having an MML (metal maskless) structure.

In the case where the island-shaped layer 313 is formed without using a fine metal mask, a surface of the layer 313 is exposed in the manufacturing process of the touch panel. For this reason, the layer 313R, the layer 313G, and the layer 313B each preferably include a carrier-transport layer over a light-emitting layer. Alternatively, the layer 313R, the layer 313G, and the layer 313B each preferably include a carrier-blocking layer over the light-emitting layer. Alternatively, the layer 313R, the layer 313G, and the layer 313B each preferably include a carrier-blocking layer over the light-emitting layer, and a carrier-transport layer over the carrier-blocking layer. Accordingly, the light-emitting layer can be inhibited from being exposed on the outermost surface, thereby reducing damage to the light-emitting layer. As a result, the reliability of the light-emitting element 61 can be increased.

In the case where the light-emitting element 61 has a tandem structure where, for example, the layer 313 includes a first light-emitting unit, a charge-generation layer over the first light-emitting unit, and a second light-emitting unit over the charge-generation layer, a surface of the second light-emitting unit is exposed in the manufacturing process of the touch panel. For this reason, the second light-emitting unit preferably includes a carrier-transport layer over a light-emitting layer. Alternatively, the second light-emitting unit preferably includes a carrier-blocking layer over the light-emitting layer. Alternatively, the second light-emitting unit preferably includes a carrier-blocking layer over the light-emitting layer, and a carrier-transport layer over the carrier-blocking layer. Accordingly, the light-emitting layer can be inhibited from being exposed on the outermost surface, thereby reducing damage to the light-emitting layer. As a result, the reliability of the light-emitting element 61 can be increased. Note that in the case where three or more light-emitting units are provided, the uppermost light-emitting unit preferably includes one or both of a carrier-transport layer and a carrier-blocking layer over a light-emitting layer.

The upper temperature limits of the compounds contained in the layer 313R, the layer 313G, and the layer 313B are each preferably higher than or equal to 100° C. and lower than or equal to 180° C., further preferably higher than or equal to 120° C. and lower than or equal to 180° C., still further preferably higher than or equal to 140° C. and lower than or equal to 180° C.. For example, the glass transition points (Tg) of these compounds are each preferably higher than or equal to 100° C. and lower than or equal to 180° C., further preferably higher than or equal to 120° C. and lower than or equal to 180° C., still further preferably higher than or equal to 140° C. and lower than or equal to 180° C.. This inhibits a reduction in light emission efficiency and a decrease in lifetime that are due to damage to the layer 313R, the layer 313G, and the layer 313B by heat applied in a process.

In a region between the adjacent light-emitting elements 61, the insulating layer 325 and the insulating layer 327 over the insulating layer 325 are provided. Although FIG. 45 illustrates a plurality of cross sections of the insulating layer 325 and the insulating layer 327, the insulating layer 325 and the insulating layer 327 are each one continuous layer when the display portion 20 is seen from above. In other words, the display portion 20 illustrated in FIG. 45 can include one insulating layer 325 and one insulating layer 327, for example. Note that the display portion 20 illustrated in FIG. 45 may include a plurality of insulating layers 325 that are separated from each other, and may include a plurality of insulating layers 327 that are separated from each other.

The insulating layer 325 preferably includes regions in contact with the side surfaces of the layer 313R, the layer 313G, and the layer 313B. When the insulating layer 325 includes regions in contact with the layer 313R, the layer 313G, and the layer 313B, film separation of the layer 313R, the layer 313G, and the layer 313B can be inhibited. When the insulating layer 325 is closely attached to the layer 313B, the layer 313G, and the layer 313R, the effect of fixing or bonding the adjacent layers 313 by the insulating layer 325 is obtained. As a result, the reliability of the light-emitting element 61 can be increased. In addition, the yield of the light-emitting element 61 can be increased.

For the insulating layer 325, a material that can be used for the protective layer 331 can be used, and an inorganic material can be used, for example. It is particularly preferable to use aluminum oxide for the protective layer 331, in which case the etching selectivity of the insulating layer 325 to the layer 313 can be increased to protect the layer 313.

The insulating layer 325 preferably has a function of a barrier insulating layer against at least one of water and oxygen. Alternatively, the insulating layer 325 preferably has a function of inhibiting diffusion of at least one of water and oxygen. Alternatively, the insulating layer 325 preferably has a function of capturing or fixing (also referred to as gettering) at least one of water and oxygen. Note that in this specification and the like, a barrier insulating layer refers to an insulating layer having a barrier property. A barrier property in this specification and the like refers to a function of inhibiting diffusion of a targeted substance (also referred to as a function of less easily transmitting the substance).

When the insulating layer 325 has a function of a barrier insulating layer or a gettering function, entry of impurities (typically, at least one of water and oxygen) that might diffuse into the light-emitting element from the outside can be inhibited. With this structure, a highly reliable light-emitting element and a highly reliable touch panel can be provided.

The insulating layer 327 is provided over the insulating layer 325 to fill a depressed portion defined by the insulating layer 325. The insulating layer 327 can be configured to overlap the side surface and part of the top surface of each of the layer 313R, the layer 313G, and the layer 313B with the insulating layer 325 therebetween. The insulating layer 327 preferably covers at least part of the side surface of the insulating layer 325. Providing the insulating layer 325 and the insulating layer 327 enables a gap between the adjacent island-shaped layers to be filled, whereby unevenness of the formation surface of a layer provided over the island-shaped layers, e.g., the common electrode 315, can be reduced and the coverage with the layer can be improved. This can inhibit a connection defect due to step disconnection. In addition, an increase in electric resistance, which is caused by local thinning of the common electrode 315 due to the step, can be inhibited. The top surface of the insulating layer 327 preferably has a shape with higher planarity, but may have a projecting portion, a convex surface, a concave surface, or a depressed portion.

An insulating layer including an organic material can be suitably used as the insulating layer 327. As the organic material, a photosensitive organic resin is preferably used, and for example, a photosensitive resin composite including an acrylic resin is preferably used. Note that in this specification and the like, an acrylic resin refers to not only a polymethacrylic acid ester or a methacrylic resin, but also all the acrylic polymer in a broad sense in some cases. Note that the materials that can be used for the insulating layer 327 can also be used for the layer 328.

A mask layer 318R is positioned over the layer 313R included in the light-emitting element 61R, a mask layer 318G is positioned over the layer 313G included in the light-emitting element 61G, and a mask layer 318B is positioned over the layer 313B included in the light-emitting element 61B. The mask layer 318 is provided to surround the light-emitting region. In other words, the mask layer 318 has an opening in a portion overlapping the light-emitting region. The mask layer 318R is a remaining part of a mask layer provided over the layer 313R at the time of forming the layer 313R. Similarly, the mask layer 318G is a remaining part of the mask layer provided at the time of forming the layer 313G, and the mask layer 318B is a remaining part of the mask layer provided at the time of forming the layer 313B. In this manner, the mask layer used to protect the layer 313 in manufacture of the touch panel may partly remain in the touch panel of one embodiment of the present invention.

Although the mask layer 318 has a single-layer structure in FIG. 45, the mask layer 318 may have a stacked-layer structure. For example, the mask layer 318 may have a two-layer structure or a stacked-layer structure of three or more layers. After the formation of the film to be the layer 313, a first mask layer and a second mask layer over the first mask layer are formed as mask layers in some cases. After that, the layer 313R, the layer 313G, and the layer 313B are formed using the mask layers, the second mask layer is removed, and then an opening reaching the layer 313 is formed in the first mask layer in some cases. In that case, the mask layer 318 remaining in the touch panel 10 has a single-layer structure. In other words, the mask layer 318 may include a smaller number of layers than the mask layer formed in the manufacturing process of the touch panel 10.

In the display portion 20 illustrated in FIG. 45, the common layer 314 is provided over the layer 313R, the layer 313G, the layer 313B, and the insulating layer 327 and the common electrode 315 is provided over the common layer 314. Like the common electrode 315, the common layer 314 is shared by the light-emitting element 61R, the light-emitting element 61G, and the light-emitting element 61B. In the case where the light-emitting element 61 includes the common layer 314, the layer 313 and the common layer 314 can be collectively referred to as an EL layer. Note that the common layer 314 is not necessarily included in the EL layer.

The common layer 314 includes an electron-injection layer or a hole-injection layer, for example. Alternatively, the common layer 314 may include a stack of an electron-transport layer and an electron-injection layer, or may include a stack of a hole-transport layer and a hole-injection layer. Here, a structure can be employed in which the layer included in the common layer 314 is not included in the layer 313. For example, when the common layer 314 includes an electron-injection layer, the layer 313 does not necessarily include an electron-injection layer. When the common layer 314 includes a hole-injection layer, the layer 313 does not necessarily include a hole-injection layer.

In the case where the common layer 314 is provided in the touch panel, the common electrode 315 can be formed successively after the formation of the common layer 314, without a step of etching or the like intervening between these formation steps. For example, after the common layer 314 is formed in a vacuum, the common electrode 315 can be formed in a vacuum without exposing the substrate 101 to the air. In other words, the common layer 314 and the common electrode 315 can be successively formed in a vacuum. Accordingly, the lower surface of the common electrode 315 can be a clean surface, as compared with the case where the common layer 314 is not provided in the touch panel. Thus, in the case where the surface of the layer 313 is exposed to the air after the formation of the layer 313, the common layer 314 is preferably provided in the touch panel.

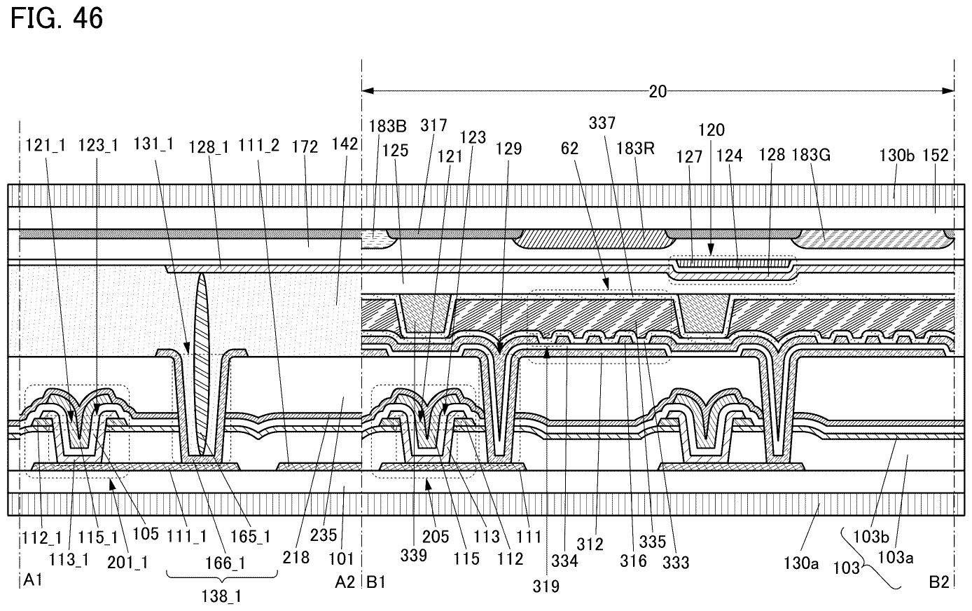

FIG. 46 shows a variation example of the structure illustrated in FIG. 7 and illustrates an example in which the common electrode 316 is provided on the substrate 101 side.

FIG. 46 illustrates an example in which an insulating layer 334 is provided over the pixel electrode 312 and the insulating layer 235, the common electrode 316 is provided over the insulating layer 334, and the alignment layer 333 is provided over the common electrode 316 and the insulating layer 334. A slit 319 is provided in the common electrode 316 to overlap the pixel electrode 312. The insulating layer 334 is provided to cover the pixel electrode 312, and the alignment layer 333 is provided to cover the common electrode 316.

The liquid crystal element 62 illustrated in FIG. 46 is a liquid crystal element employing the FFS mode. Here, a display apparatus including a liquid crystal element employing the FFS mode is a horizontal electric field liquid crystal display apparatus. Accordingly, the display apparatus 11 having the structure illustrated in FIG. 46 is a horizontal electric field liquid crystal display apparatus.

Here, for the insulating layer 334, a material similar to the material that can be used for the insulating layer 105 can be used, for example. Moreover, for the insulating layer 334, a material similar to the material that can be used for the insulating layer 103 can be used, for example. In the example illustrated in FIG. 46, the thickness of the insulating layer 125 is preferably large so that an electric field generated by the electrode 128 and an electric field generated by the electrode 127 do not affect the driving of the liquid crystal element 62.

The above-described structures can be employed in appropriate combination. For example, in the touch panel 10 having the structure illustrated in FIG. 6, FIG. 21, FIG. 25, FIG. 30, or FIG. 33, the insulating layer 237 can be provided to overlap part of the conductive layer 166. For another example, in the touch panel 10 having the structure illustrated in FIG. 13 or FIG. 14, the conductive layer 166 can have a stacked-layer structure of two or more layers. The structure of the transistor 205 illustrated in FIG. 40 and FIG. 41 can also be applied to the transistor 205 illustrated in FIG. 13, FIG. 14, FIG. 18, FIG. 21, FIG. 22, FIG. 25, FIG. 26, FIG. 30, FIG. 31, FIG. 33, or FIG. 34. The structure of the sensing element 120 illustrated in FIG. 42 and FIG. 43 can also be applied to the sensing element 120 illustrated in FIG. 13, FIG. 14, FIG. 18, FIG. 21, FIG. 22, FIG. 25, FIG. 26, FIG. 30, FIG. 31, FIG. 33, or FIG. 34. The structure of the light-emitting element 61 illustrated in FIG. 44 and FIG. 45 can also be applied to the light-emitting element 61 illustrated in FIG. 18, FIG. 21, FIG. 25, FIG. 30, or FIG. 33. The structure of the liquid crystal element 62 illustrated in FIG. 46 can also be applied to the liquid crystal element 62 illustrated in FIG. 14, FIG. 22, FIG. 26, FIG. 31, FIG. 34, FIG. 41, or FIG. 43.

### Components of Touch Panel

Components included in the touch panel of this embodiment will be described below.

### Semiconductor Layer 113

There is no particular limitation on a semiconductor material that can be used for the semiconductor layer 113. For example, a single-element semiconductor or a compound semiconductor can be used. As the single-element semiconductor, silicon or germanium can be used, for example. Examples of the compound semiconductor include gallium arsenide and silicon germanium. As the compound semiconductor, an organic substance having semiconductor characteristics or a metal oxide having semiconductor characteristics can be used. These semiconductor materials may contain an impurity as a dopant.

There is no particular limitation on the crystallinity of a semiconductor material used for the semiconductor layer 113, and any of an amorphous semiconductor and a semiconductor having crystallinity (a single crystal semiconductor, a polycrystalline semiconductor, a microcrystalline semiconductor, or a semiconductor partly including crystal regions) may be used. A semiconductor having crystallinity is preferably used, in which case deterioration of the transistor characteristics can be inhibited.

Silicon can be used for the semiconductor layer 113. Examples of silicon include single crystal silicon, polycrystalline silicon, microcrystalline silicon, and amorphous silicon. An example of polycrystalline silicon is low-temperature polysilicon (LTPS).

A transistor using amorphous silicon in the semiconductor layer 113 can be formed over a large glass substrate, and can be manufactured at low cost. A transistor using polycrystalline silicon in the semiconductor layer 113 has high field-effect mobility and enables high-speed driving. A transistor using microcrystalline silicon in the semiconductor layer 113 has higher field-effect mobility and enables higher speed driving than a transistor using amorphous silicon.

The semiconductor layer 113 preferably includes a metal oxide (an oxide semiconductor). Examples of the metal oxide that can be used for the semiconductor layer 113 include indium oxide, gallium oxide, and zinc oxide. The metal oxide preferably contains at least indium (In) or zinc (Zn). The metal oxide preferably contains two or three selected from indium, an element M, and zinc. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more kinds selected from aluminum, gallium, yttrium, and tin.

For the semiconductor layer 113, it is possible to use, for example, indium oxide, indium zinc oxide (In—Zn oxide), indium tin oxide (In—Sn oxide), indium titanium oxide (In—Ti oxide), indium aluminum zinc oxide (In—Al—Zn oxide, also referred to as IAZO), indium tin zinc oxide (In—Sn—Zn oxide, also referred to as ITZO (registered trademark)), indium titanium zinc oxide (In—Ti—Zn oxide), indium gallium zinc oxide (In—Ga—Zn oxide, also referred to as IGZO), indium gallium tin oxide (In—Ga—Sn oxide, also referred to as IGTO), indium gallium tin zinc oxide (In—Ga—Sn—Zn oxide), indium tin gallium oxide (In—Sn—Ga oxide), or indium gallium aluminum zinc oxide (In—Ga—Al—Zn oxide, also referred to as IGAZO or IAGZO). Alternatively, indium tin oxide containing silicon or the like can be used. Alternatively, the above-described oxide having an amorphous structure can be used. For example, indium oxide having an amorphous structure, indium tin oxide having an amorphous structure, or the like can be used.

The element M is particularly preferably one or more kinds selected from gallium, aluminum, yttrium, and tin. In particular, the element M is preferably gallium.

Here, the composition of the metal oxide included in the semiconductor layer 113 greatly affects the electrical characteristics and reliability of the transistor 201.

For example, a metal oxide with a higher indium content enables the transistor to have a higher on-state current.

In the case where In—Zn oxide is used for the semiconductor layer 113, a metal oxide in which the atomic proportion of indium is higher than or equal to that of zinc is preferably used. For example, it is possible to use a metal oxide in which the atomic ratio of metal elements is In:Zn=1:1, In:Zn=2:1, In:Zn=3:1, In:Zn=4:1, In:Zn=5:1, In:Zn=7:1, In:Zn=10:1, or the neighborhood thereof.

In the case where In-Sn oxide is used for the semiconductor layer 113, a metal oxide in which the atomic proportion of indium is higher than or equal to that of tin is preferably used. For example, it is possible to use a metal oxide in which the atomic ratio of metal elements is In:Sn=1:1, In:Sn=2:1, In:Sn=3:1, In:Sn=4:1, In:Sn=5:1, In:Sn=7:1, In:Sn=10:1, or the neighborhood thereof.

In the case where In-M-Zn oxide is used for the semiconductor layer 113, a metal oxide in which the atomic proportion of indium in the metal elements is higher than that of the element M can be used. It is further preferable to use a metal oxide in which the atomic proportion of zinc is higher than that of the element M. For the semiconductor layer 113, it is possible to use a metal oxide with metal elements in any of the following atomic ratios, for example: In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, and the vicinity thereof.

In the case where a plurality of metal elements are contained as the element M, the sum of the atomic ratios of the metal elements can be the atomic ratio of the element M. In the case of In—Ga—Al—Zn oxide in which gallium and aluminum are contained as the element M, for example, the sum of the atomic ratio of gallium and the atomic ratio of aluminum can be the atomic ratio of the element M. The atomic ratio between indium, the element M, and zinc is preferably within the ranges described above.

It is preferable to use a metal oxide in which the proportion of the number of indium atoms to the number of atoms of the metal elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, further preferably higher than or equal to 35 atomic % and lower than or equal to 90 atomic %, still further preferably higher than or equal to 40 atomic % and lower than or equal to 90 atomic %, still further preferably higher than or equal to 45 atomic % and lower than or equal to 90 atomic %, yet further preferably higher than or equal to 50 atomic % and lower than or equal to 80 atomic %, yet further preferably higher than or equal to 60 atomic % and lower than or equal to 80 atomic %, yet still further preferably higher than or equal to 70 atomic % and lower than or equal to 80 atomic %. For example, in the case where In—Ga—Zn oxide is used for the semiconductor layer 113, the proportion of the number of indium atoms to the total number of the atoms of indium, the element M, and zinc is preferably within the ranges given above.

In this specification and the like, the proportion of the number of indium atoms to the number of atoms of the metal elements contained is sometimes referred to as indium content percentage. The same applies to other metal elements.

A metal oxide with a higher indium content percentage enables a transistor to have a higher on-state current. By using such a transistor as a transistor required to have a high on-state current, a touch panel having excellent electrical characteristics can be provided.

To analyze the composition of a metal oxide, for example, energy dispersive X-ray spectroscopy (EDX), X-ray photoelectron spectroscopy (XPS), inductively coupled plasma-mass spectrometry (ICP-MS), inductively coupled plasma-atomic emission spectroscopy (ICP-AES), or the like can be used. Alternatively, any of these methods may be combined with each other for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A composition in the neighborhood in this specification and the like includes the range of ±30 % of an intended atomic ratio. For example, in the case of describing an atomic ratio of In:M:Zn=4:2:3 or a composition in the neighborhood thereof, the case is included where the atomic ratio of the element M is greater than or equal to 1 and less than or equal to 3 and the atomic ratio of zinc is greater than or equal to 2 and less than or equal to 4 with the atomic ratio of indium being 4. In the case of describing an atomic ratio of In:M:Zn=5:1:6 or a composition in the neighborhood thereof, the case is included where the atomic ratio of M is greater than 0.1 and less than or equal to 2 and the atomic ratio of zinc is greater than or equal to 5 and less than or equal to 7 with the atomic ratio of indium being 5. In the case of describing an atomic ratio of In:M:Zn=1:1:1 or a composition in the neighborhood thereof, the case is included where the atomic ratio of M is greater than 0.1 and less than or equal to 2 and the atomic ratio of zinc is greater than 0.1 and less than or equal to 2 with the atomic ratio of indium being 1.

For the formation of a metal oxide, a sputtering method or an atomic layer deposition (ALD) method can be suitably used. Note that in the case where the metal oxide is formed by a sputtering method, the atomic ratio of the metal oxide may be different from the atomic ratio of a target. In particular, the atomic ratio of zinc in the metal oxide is lower than the atomic ratio of zinc in the target in some cases. Specifically, the atomic ratio of zinc contained in the metal oxide may be approximately 40 % to 90 % of the atomic ratio of zinc contained in the target.

Here, the reliability of a transistor is described. One of indicators of evaluating the reliability of a transistor is a GBT (Gate Bias Temperature) stress test in which a state of applying an electric field to a gate is maintained. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where irradiation with light is performed are respectively referred to as a PBTIS (Positive Bias Temperature Illumination Stress) test and an NBTIS (Negative Bias Temperature Illumination Stress) test.

In an n-channel transistor, a positive potential is supplied to a gate in putting the transistor in an on state (a state where current flows); thus, the amount of change in threshold voltage in the PBTS test is one important item to be focused on as an indicator of the reliability of the transistor.

With the use of a metal oxide that does not contain gallium or has a low gallium content percentage in the semiconductor layer 113, the transistor can have high reliability against positive bias application. In other words, the amount of change in the threshold voltage of the transistor in the PBTS test can be small. In the case of using a metal oxide that contains gallium, the gallium content percentage is preferably lower than the indium content percentage. Thus, a transistor with high reliability can be achieved.

One of the factors in change in the threshold voltage in the PBTS test is a defect state at the interface between a semiconductor layer and a gate insulating layer or in the vicinity of the interface. As the density of defect states increases, degradation in the PBTS test becomes significant. Generation of the defect states can be inhibited by reducing the gallium content percentage in a region of the semiconductor layer that is in contact with the gate insulating layer.

The following can be given as an example of the reason why the amount of change in the threshold voltage in the PBTS test can be reduced when a metal oxide that does not contain gallium or has a low gallium content percentage is used for the semiconductor layer. Gallium contained in the metal oxide has a property of attracting oxygen more easily than another metal element (e.g., indium or zinc) does. Thus, when, at the interface between a metal oxide containing a large amount of gallium and the gate insulating layer, gallium is bonded to excess oxygen in the gate insulating layer, trap sites of carriers (here, electrons) are probably generated easily. This might cause the change in the threshold voltage when a positive potential is supplied to a gate and carriers are trapped at the interface between the semiconductor layer and the gate insulating layer.

Specifically, in the case where In—Ga—Zn oxide is used for the semiconductor layer 113, a metal oxide in which the atomic proportion of indium is higher than the atomic proportion of gallium can be used for the semiconductor layer 113. It is further preferable to use a metal oxide in which the atomic proportion of zinc is higher than the atomic proportion of gallium. In other words, a metal oxide in which the atomic ratios of the metal elements satisfy In>Ga and Zn>Ga is preferably used for the semiconductor layer 113.

For the semiconductor layer 113, it is possible to use a metal oxide with metal elements in any of the following atomic ratios, for example: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, and the neighborhood thereof.

For the semiconductor layer 113, it is preferable to use a metal oxide in which the proportion of the number of indium atoms to the number of atoms of the metal elements contained is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, further preferably higher than or equal to 0.1 atomic % and lower than or equal to 30 atomic %, still further preferably higher than or equal to 0.1 atomic % and lower than or equal to 25 atomic %, still further preferably higher than or equal to 0.1 atomic % and lower than or equal to 20 atomic %, yet further preferably higher than or equal to 0.1 atomic % and lower than or equal to 15 atomic %, yet still further preferably higher than or equal to 0.1 atomic % and lower than or equal to 10 atomic %. The reduction in the gallium content percentage in the semiconductor layer enables the transistor to be highly resistant to the PBTS test. Note that an oxygen vacancy (Vo) is less likely to be generated in the metal oxide when the metal oxide contains gallium.

A metal oxide not containing gallium may be used for the semiconductor layer 113. For example, In-Zn oxide can be used for the semiconductor layer 113. In that case, when the atomic ratio of indium to the metal elements contained in the metal oxide is increased, the field-effect mobility of the transistor can be increased. By contrast, when the atomic ratio of zinc to the metal elements contained in the metal oxide is increased, the metal oxide has high crystallinity; thus, a change in the electrical characteristics of the transistor can be inhibited and the reliability can be increased. Alternatively, a metal oxide that contains neither gallium nor zinc, such as indium oxide, may be used for the semiconductor layer 113. The use of a metal oxide not containing gallium can make a change in the threshold voltage particularly in the PBTS test extremely small.

For example, an oxide containing indium and zinc can be used for the semiconductor layer 113. At that time, for example, a metal oxide with metal elements in an atomic ratio of In:Zn=2:3, In:Zn=4:1, or the neighborhood thereof can be used.

Although the case of using gallium is described as a typical example, the same applies to the case where the element M is used instead of gallium. A metal oxide in which the atomic proportion of indium is higher than the atomic proportion of the element M is preferably used for the semiconductor layer 113. Furthermore, a metal oxide in which the atomic proportion of zinc is higher than the atomic proportion of the element M is preferably used.

With the use of a metal oxide that has a low content percentage of the element M in the semiconductor layer 113, the transistor can have high reliability against positive bias application. With the use of the transistor as a transistor that is required to have high reliability against positive bias application, a highly reliable touch panel can be provided.

Next, the reliability of a transistor against light is described.

Light incidence on a transistor may change electrical characteristics of the transistor. In particular, a transistor provided in a region on which light can be incident preferably exhibits a small variation in electrical characteristics under light irradiation and has high reliability against light. The reliability against light can be evaluated with the amount of change in threshold voltage in a NBTIS test, for example.

The high content percentage of the element M in the metal oxide enables the transistor to be highly reliable against light. In other words, the amount of change in the threshold voltage of the transistor in the NBTIS test can be small. Specifically, in a metal oxide in which the atomic proportion of the element M is higher than or equal to the atomic proportion of indium, the band gap is increased and accordingly the amount of change in the threshold voltage of the transistor in the NBTIS test can be reduced. The band gap of the metal oxide in the semiconductor layer 113 is preferably greater than or equal to 2.0 eV, further preferably greater than or equal to 2.5 eV, further preferably greater than or equal to 3.0 eV, still further preferably greater than or equal to 3.2 eV, still further preferably greater than or equal to 3.3 eV, yet further preferably greater than or equal to 3.4 eV, yet still further preferably greater than or equal to 3.5 eV.

For example, for the semiconductor layer 113, a metal oxide with metal elements in any of the following atomic ratios can be used: In:M:Zn=1:1:1, In:M:Zn=1:1:1.2, In:M:Zn=1:3:2, In:M:Zn=1:3:3, In:M:Zn=1:3:4, and the neighborhood thereof.

For the semiconductor layer 113, in particular, it is preferable to use a metal oxide in which the proportion of the number of atoms of the element M to the number of atoms of the metal elements contained is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, still further preferably higher than or equal to 40 atomic % and lower than or equal to 60 atomic %, yet still further preferably higher than or equal to 50 atomic % and lower than or equal to 60 atomic %.

In the case where an In—Ga—Zn oxide is used for the semiconductor layer 113, a metal oxide in which the atomic proportion of indium in the metal elements is lower than or equal to that of gallium can be used. For example, a metal oxide with metal elements in any of the following atomic ratios can be used: In:Ga:Zn=1:1:1, In:Ga:Zn=1:1:1.2, In:Ga:Zn=1:3:2, In:Ga:Zn=1:3:3, In:Ga:Zn=1:3:4, and the neighborhood thereof.

For the semiconductor layer 113, in particular, it is preferable to use a metal oxide in which the proportion of the number of gallium atoms to the number of the metal elements contained is higher than or equal to 20 atomic % and lower than or equal to 60 atomic %, preferably higher than or equal to 20 atomic % and lower than or equal to 50 atomic %, further preferably higher than or equal to 30 atomic % and lower than or equal to 50 atomic %, still further preferably higher than or equal to 40 atomic % and lower than or equal to 60 atomic %, yet still further preferably higher than or equal to 50 atomic % and lower than or equal to 60 atomic %.

With the use of a metal oxide that has a high content percentage of the element M in the semiconductor layer 113, the transistor can have high reliability against light. With the use of the transistor as a transistor that is required to have high reliability against light, a highly reliable touch panel can be provided.

As described above, electrical characteristics and reliability of a transistor depend on the composition of the metal oxide used for the semiconductor layer 113. Thus, by changing the composition of the metal oxide in accordance with the electrical characteristics and reliability required for the transistor, the touch panel can have both excellent electrical characteristics and high reliability.

The semiconductor layer 113 may have a stacked-layer structure including two or more metal oxide layers. The two or more metal oxide layers included in the semiconductor layer 113 may have the same composition or substantially the same compositions. Employing a stacked-layer structure of metal oxide layers having the same composition can reduce the manufacturing cost because the metal oxide layers can be formed using the same sputtering target, for example.

The two or more metal oxide layers included in the semiconductor layer 113 may have different compositions. For example, a stacked-layer structure of a first metal oxide layer having In:M:Zn=1:3:4 [atomic ratio] or a composition in the neighborhood thereof and a second metal oxide layer that is provided over the first metal oxide layer and has In:M:Zn=1:1:1 [atomic ratio] or a composition in the neighborhood thereof can be suitably used. Gallium or aluminum is particularly preferably used as the element M. A stacked-layer structure of any one selected from indium oxide, indium gallium oxide, and IGZO and any one selected from IAZO, IAGZO, and ITZO (registered trademark) may be employed, for example.

As the semiconductor layer 113, a metal oxide layer having crystallinity is preferably used. For example, a metal oxide layer having a CAAC (c-axis aligned crystal) structure, a polycrystalline structure, a nano-crystal (nc) structure, or the like can be used. With the use of a metal oxide layer having crystallinity as the semiconductor layer 113, the density of defect states in the semiconductor layer 113 can be reduced, thereby achieving a highly reliable touch panel.

The higher the crystallinity of the metal oxide layer 113 used as the semiconductor layer is, the lower the density of defect states in the semiconductor layer 113 can be. By contrast, the use of a metal oxide layer having low crystallinity enables a transistor to flow a large amount of current.

In the case where the metal oxide layer is formed by a sputtering method, the higher the substrate temperature (the stage temperature) in the formation is, the higher the crystallinity of the metal oxide layer can be. The crystallinity of the metal oxide layer can be increased as the proportion of a flow rate of an oxygen gas to the whole deposition gas (also referred to as oxygen flow rate ratio) used in the formation is higher.

The semiconductor layer 113 may have a stacked-layer structure of two or more metal oxide layers having different crystallinities. For example, a stacked-layer structure of a first metal oxide layer and a second metal oxide layer provided over the first metal oxide layer can be employed; the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer 113 may have the same composition or substantially the same compositions. Employing a stacked-layer structure of metal oxide layers having the same composition can reduce the manufacturing cost because the metal oxide layers can be formed using the same sputtering target, for example. For example, with the use of the same sputtering target and different oxygen flow rate ratios, a stacked-layer structure of two or more metal oxide layers having different crystallinities can be formed. The two or more metal oxide layers included in the semiconductor layer 113 may have different compositions.

The thickness of the semiconductor layer 113 is preferably greater than or equal to 3 nm and less than or equal to 100 nm, further preferably greater than or equal to 5 nm and less than or equal to 100 nm, further preferably greater than or equal to 10 nm and less than or equal to 100 nm, further preferably greater than or equal to 10 nm and less than or equal to 70 nm, still further preferably greater than or equal to 15 nm and less than or equal to 70 nm, still further preferably greater than or equal to 15 nm and less than or equal to 50 nm, yet further preferably greater than or equal to 20 nm and less than or equal to 50 nm, yet further preferably greater than or equal to 20 nm and less than or equal to 40 nm, yet still further preferably greater than or equal to 25 nm and less than or equal to 40 nm.

The substrate temperature at the time of forming the semiconductor layer 113 is preferably higher than or equal to room temperature (25° C.) and lower than or equal to 200° C., further preferably higher than or equal to room temperature and lower than or equal to 130° C. With the substrate temperature in the above range, the bending or warpage of the substrate can be inhibited in the case where a large-area glass substrate is used.

Here, oxygen vacancies that might be formed in the semiconductor layer 113 will be described.

In the case where an oxide semiconductor is used for the semiconductor layer 113, hydrogen contained in the oxide semiconductor reacts with oxygen bonded to a metal atom to be water, and thus an oxygen vacancy (Vo) is sometimes formed in the oxide semiconductor. In some cases, a defect that is an oxygen vacancy into which hydrogen enters (hereinafter referred to as VoH) functions as a donor and generates an electron serving as a carrier. In other cases, bonding of part of hydrogen to oxygen bonded to a metal atom generates an electron serving as a carrier. Thus, a transistor including an oxide semiconductor that includes a large amount of hydrogen is likely to have normally-on characteristics. Moreover, hydrogen in an oxide semiconductor is easily transferred by stress such as heat or an electric field; thus, the reliability of the transistor might be reduced when the oxide semiconductor includes a large amount of hydrogen.

VoH can function as a donor of an oxide semiconductor. However, it is difficult to evaluate the defect quantitatively. Thus, the oxide semiconductor is sometimes evaluated not by its donor concentration but by its carrier concentration. Therefore, in this specification and the like, the carrier concentration assuming the state where an electric field is not applied is sometimes used as the parameter of the oxide semiconductor, instead of the donor concentration. That is, “carrier concentration” described in this specification and the like can be replaced with “donor concentration” in some cases.

Accordingly, in the case where an oxide semiconductor is used for the semiconductor layer 113, the amount of VoH in the semiconductor layer 113 is preferably reduced as much as possible so that the semiconductor layer 113 becomes a highly purified intrinsic or substantially highly purified intrinsic semiconductor layer. In order to obtain such an oxide semiconductor with sufficiently reduced VoH, it is important to remove impurities such as water and hydrogen in the oxide semiconductor (this treatment is sometimes referred to as dehydration or dehydrogenation treatment) and supply oxygen to the oxide semiconductor to fill oxygen vacancies (Vo). When an oxide semiconductor with sufficiently reduced impurities such as VoH is used for a channel formation region of a transistor, stable electrical characteristics can be given. Supplying oxygen to an oxide semiconductor to fill oxygen vacancies (Vo) is sometimes referred to as oxygen adding treatment.

In the case where an oxide semiconductor is used for the semiconductor layer 113, the carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹²cm⁻³. Note that the lower limit of the carrier concentration of the oxide semiconductor in the region functioning as the channel formation region is not particularly limited and can be, for example, 1×10⁻⁹ cm⁻³.

The semiconductor layer 113 may include a layered material functioning as a semiconductor. The layered material generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of transition metal chalcogenide that can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### Insulating layer 103

For the insulating layer 103, an inorganic insulating material or an organic insulating material can be used. The insulating layer 103 may have a stacked-layer structure of an inorganic insulating material and an organic insulating material.

For the insulating layer 103, an inorganic insulating material can be suitably used. As the inorganic insulating material, one or more of an oxide, an oxynitride, a nitride oxide, and a nitride can be used. For the insulating layer 103, for example, one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride can be used.

Note that in this specification and the like, an oxynitride refers to a material that contains more oxygen than nitrogen in its composition. A nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

The contents of oxygen and nitrogen can be analyzed using secondary ion mass spectrometry (SIMS) or X-ray photoelectron spectroscopy (XPS). When the content percentage of a target element is high (e.g., higher than or equal to 0.5 atomic %, or higher than or equal to 1 atomic %), XPS is suitable. By contrast, when the content percentage of a target element is low (e.g., lower than or equal to 1 atomic %, or lower than or equal to 0.5 atomic %), SIMS is suitable. To compare the contents of elements, analysis with a combination of SIMS and XPS is preferably used.

The insulating layer 103 may have a stacked-layer structure of two or more layers. FIG. 6 and FIG. 7, for example, illustrate a structure where the insulating layer 103 has a stacked-layer structure of an insulating layer 103a and an insulating layer 103b over the insulating layer 103a. For each of the insulating layer 103a and the insulating layer 103b, the above-described material that can be used for the insulating layer 103 can be used. Note that the insulating layer 103a and the insulating layer 103b may be formed using the same material or different materials. Note that the insulating layer 103a may have a stacked-layer structure of two or more layers. The insulating layer 103b may have a stacked-layer structure of two or more layers.

The thickness of the insulating layer 103a can be larger than that of the insulating layer 103b. The film formation speed (also referred to as film formation rate) of the insulating layer 103a is preferably high, and is preferably higher than that of the insulating layer 103b, for example. In particular, the film formation speed of the insulating layer 103a is preferably high in the case where the thickness of the insulating layer 103a is large. By increasing the film formation speed of the insulating layer 103a, the productivity can be increased. The film formation speed can be increased by increasing power at the time of forming the insulating layer 103a, for example.

The stress of the insulating layer 103a is preferably low. When the thickness of the insulating layer 103a is increased, the stress of the insulating layer 103a is increased, so that warpage of the substrate might be caused. By making the stress of the insulating layer 103a low, a problem in the process caused by stress, such as warpage of the substrate, can be inhibited from arising.

The insulating layer 103b functions as a blocking layer that inhibits release of gas from the insulating layer 103a. For the insulating layer 103b, a material that does not easily allow diffusion of gas is preferably used. The insulating layer 103b preferably includes a region having a higher film density than the insulating layer 103a. The insulating layer 103b having a higher film density can have a higher blocking property. For example, a material containing more nitrogen than the insulating layer 103a can be used for the insulating layer 103b. The insulating layer 103b having a higher content of nitrogen can have a higher blocking property.

The insulating layer 103b can be thinner than the insulating layer 103a as long as the insulating layer 103b has a thickness that is sufficient for the function of a blocking layer that inhibits release of gas from the insulating layer 103a. The film formation speed of the insulating layer 103b is preferably low, and is preferably lower than that of the insulating layer 103a, for example. When the film formation speed of the insulating layer 103b is made low, the insulating layer 103b can have a higher film density and thus can have a higher blocking property. Moreover, when the substrate temperature at the time of forming the insulating layer 103b is increased, the insulating layer 103b can have a higher film density and thus can have a higher blocking property.

The film density can be evaluated by Rutherford backscattering spectrometry (RBS) or X-ray reflection (XRR), for example. A difference in film density can be evaluated using a cross-sectional transmission electron microscopy (TEM) image in some cases. In TEM observation, a transmission electron (TE) image is dark-colored (dark) when the film density is high, and a transmission electron (TE) image is pale (bright) when the film density is low. Therefore, in the transmission electron (TE) image, the insulating layer 103b is sometimes shown as a dark-colored (dark) image compared to the insulating layer 103a. Note that since the insulating layer 103a and the insulating layer 103b have different film densities even when including the same materials, it is sometimes possible to identify the boundary between the insulating layer 103a and the insulating layer 103b by a difference in contrast in a cross-sectional TEM image.

The insulating layer 103b may include a region where the hydrogen concentration in the film is lower than that in the insulating layer 103a. The difference in hydrogen concentration between the insulating layer 103a and the insulating layer 103b can be evaluated by secondary ion mass spectrometry (SIMS), for example.

Here, the insulating layer 103 will be specifically described using a structure where a metal oxide is used for the semiconductor layer 113 as an example.

In the case where an oxide semiconductor is used for the semiconductor layer 113, an inorganic insulating material can be suitably used for each of the insulating layer 103a and the insulating layer 103b.

An oxide or an oxynitride is preferably used for the insulating layer 103a. A film from which oxygen is released by heating is preferably used for the insulating layer 103a. For the insulating layer 103a, a silicon oxide or a silicon oxynitride can be suitably used, for example.

Oxygen release from the insulating layer 103a enables oxygen supply from the insulating layer 103a to the semiconductor layer 113. The oxygen supply from the insulating layer 103a to the semiconductor layer 113, particularly to the channel formation region of the semiconductor layer 113, can reduce oxygen vacancies (Vo) and VoH in the semiconductor layer 113. Thus, the transistor included in the touch panel 10 can have favorable electrical characteristics and high reliability. The insulating layer 103a preferably has a high oxygen diffusion coefficient. A high oxygen diffusion coefficient of the insulating layer 103a facilitates diffusion of oxygen in the insulating layer 103a, so that oxygen can be efficiently supplied from the insulating layer 103a to the semiconductor layer 113. Examples of treatment for supplying oxygen to the semiconductor layer 113 include heat treatment in an oxygen-containing atmosphere and plasma treatment in an oxygen-containing atmosphere.

The amount of impurities (e.g., water and hydrogen) released from the insulating layer 103a itself is preferably small. A reduction in the amount of impurities released from the insulating layer 103a inhibits diffusion of impurities into the semiconductor layer 113. Consequently, the transistor included in the touch panel 10 can have favorable electrical characteristics and high reliability.

For the insulating layer 103a, silicon oxide or silicon oxynitride formed by a plasma-enhanced chemical vapor deposition (PECVD) method can be suitably used, for example. In that case, a mixed gas including a gas containing silicon and a gas containing oxygen is preferably used as a source gas. As the gas containing silicon, one or more of silane, disilane, trisilane, and silane fluoride can be used, for example. As the gas containing oxygen, one or more of oxygen (O₂), ozone (O₃), dinitrogen monoxide (N₂O), nitric oxide (NO), and nitrogen dioxide (NO₂) can be used, for example. Note that by increasing power at the time of forming the insulating layer 103a, the amount of impurities (e.g., water and hydrogen) released from the insulating layer 103a can be reduced.

The insulating layer 103b is preferably less likely to transmit oxygen. The insulating layer 103b functions as a blocking layer that inhibits release of oxygen from the insulating layer 103a. Moreover, the insulating layer 103b is preferably less likely to transmit hydrogen. The insulating layer 103b functions as a blocking layer that inhibits diffusion of hydrogen into the semiconductor layer 113 from the outside of the transistor through the insulating layer 103. The insulating layer 103b preferably has a high film density. The insulating layer 103b having a higher film density can have a higher blocking property against oxygen and hydrogen. The film density of the insulating layer 103b is preferably higher than that of the insulating layer 103a. In the case where silicon oxide or silicon oxynitride is used for the insulating layer 103a, silicon nitride, silicon nitride oxide, or aluminum oxide can be suitably used for the insulating layer 103b, for example. The insulating layer 103b preferably includes a region containing more nitrogen than the insulating layer 103a, for example. For example, a material containing more nitrogen than the insulating layer 103a can be used for the insulating layer 103b. A nitride or a nitride oxide is preferably used for the insulating layer 103b. For example, silicon nitride or silicon nitride oxide can be suitably used for the insulating layer 103b.

When oxygen contained in the insulating layer 103a is diffused upward from a region of the insulating layer 103a that is not in contact with the semiconductor layer 113 (e.g., the top surface of the insulating layer 103a), the amount of oxygen supplied from the insulating layer 103a to the semiconductor layer 113 might be reduced. Providing the insulating layer 103b over the insulating layer 103a can inhibit diffusion of oxygen contained in the insulating layer 103a from the region of the insulating layer 103a that is not in contact with the semiconductor layer 113. Accordingly, the amount of oxygen supplied from the insulating layer 103a to the semiconductor layer 113 is increased, whereby oxygen vacancies (Vo) and VoH in the semiconductor layer 113 can be reduced. Consequently, the transistor included in the touch panel 10 can have favorable electrical characteristics and high reliability.

The conductive layer 112 is oxidized by oxygen contained in the insulating layer 103a and has high resistance in some cases. Moreover, when the conductive layer 112 is oxidized by oxygen contained in the insulating layer 103a, the amount of oxygen supplied from the insulating layer 103a to the semiconductor layer 113 is reduced in some cases. Providing the insulating layer 103b over the insulating layer 103a can inhibit the conductive layer 112 from being oxidized and having high resistance. Furthermore, the amount of oxygen supplied from the insulating layer 103a to the semiconductor layer 113 is increased, whereby oxygen vacancies (Vo) and VoH in the semiconductor layer 113 can be reduced. Thus, the transistor included in the touch panel 10 can have favorable electrical characteristics and high reliability.

Hydrogen diffused in the semiconductor layer 113 reacts with an oxygen atom contained in an oxide semiconductor to be water, and thus sometimes forms an oxygen vacancy (Vo). Furthermore, VoH is formed and the carrier concentration is increased in some cases. Providing the insulating layer 103b over the insulating layer 103a can reduce oxygen vacancies (Vo) and VoH in the semiconductor layer 113. Thus, the transistor included in the touch panel 10 can have favorable electrical characteristics and high reliability.

The insulating layer 103b preferably has a thickness that is sufficient for the function of a blocking layer against oxygen and hydrogen. When the thickness of the insulating layer 103b is small, the function of a blocking layer deteriorates in some cases. Meanwhile, when the thickness of the insulating layer 103b is large, a region of the semiconductor layer 113 in contact with the insulating layer 103a is narrowed and the amount of oxygen supplied from the insulating layer 103a to the semiconductor layer 113 is sometimes reduced. The thickness of the insulating layer 103b may be smaller than that of the insulating layer 103a. The thickness of the insulating layer 103b is preferably larger than or equal to 5 nm and smaller than or equal to 100 nm, further preferably larger than or equal to 5 nm and smaller than or equal to 70 nm, further preferably larger than or equal to 10 nm and smaller than or equal to 70 nm, still further preferably larger than or equal to 10 nm and smaller than or equal to 50 nm, yet further preferably larger than or equal to 20 nm and smaller than or equal to 50 nm, yet still further preferably larger than or equal to 20 nm and smaller than or equal to 40 nm. When the thickness of the insulating layer 103b is within the above range, oxygen vacancies (Vo) and VoH in the semiconductor layer 113, in particular, in the channel formation region, can be reduced. Thus, the transistor included in the touch panel 10 can have favorable electrical characteristics and high reliability.

The amount of impurities (e.g., water and hydrogen) released from the insulating layer 103b itself is preferably small. A reduction in the amount of impurities released from the insulating layer 103b inhibits diffusion of impurities into the semiconductor layer 113. Thus, the transistor included in the touch panel 10 can have favorable electrical characteristics and high reliability.

In the transistor 201, a region of the semiconductor layer 113 in contact with the insulating layer 103 can function as the channel formation region. That is, oxygen is selectively supplied to the channel formation region, so that oxygen vacancies (Vo) and VoH can be reduced. Consequently, the transistor included in the touch panel 10 can have favorable electrical characteristics and high reliability.

### Conductive Layer 111, Conductive Layer 112, and Conductive Layer 115

The conductive layer 111 and the conductive layer 112 functioning as the source electrode and the drain electrode and the conductive layer 115 functioning as the gate electrode can each be formed using one or more of chromium, copper, aluminum, magnesium, gold, silver, zinc, molybdenum, tantalum, titanium, tungsten, manganese, nickel, iron, cobalt, molybdenum, and niobium; or an alloy containing one or more of the above-described metals as its components. For the conductive layer 111, the conductive layer 112, and the conductive layer 115, a low-resistance conductive material containing one or more of copper, silver, gold, and aluminum can be suitably used. Copper or aluminum is particularly preferable because of its high mass-productivity.

For the conductive layer 111, the conductive layer 112, and the conductive layer 115, a metal oxide (also referred to as an oxide conductor) can be used. Examples of the oxide conductor (OC) include In—Sn oxide (ITO), In—W oxide, In—W—Zn oxide, In—Ti oxide, In—Ti—Sn oxide, In—Zn oxide, In—Sn—Si oxide (ITSO), and In—Ga—Zn oxide.

Here, an oxide conductor (OC) is described. For example, when an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

Each of the conductive layer 111, the conductive layer 112, and the conductive layer 115 may have a stacked-layer structure of a conductive layer including the above-described oxide conductor (metal oxide) and a conductive layer including a metal or an alloy. The use of the conductive layer including a metal or an alloy can reduce the wiring resistance.

A Cu—X alloy film (Xis Mn, Ni, Cr, Fe, Co, Mo, Ta, or Ti) may be used for the conductive layer 111, the conductive layer 112, and the conductive layer 115. The use of a Cu-X alloy film enables the manufacturing cost to be reduced because a wet etching process can be used in the processing.

Note that the conductive layer 111, the conductive layer 112, and the conductive layer 115 may be formed using the same material or different materials.

Here, the conductive layer 111 and the conductive layer 112 will be specifically described using a structure where a metal oxide is used for the semiconductor layer 113 as an example.

When an oxide semiconductor is used for the semiconductor layer 113, the conductive layer 111 and the conductive layer 112 are oxidized by oxygen contained in the semiconductor layer 113 and have high resistance in some cases. The conductive layer 111 and the conductive layer 112 are oxidized by oxygen contained in the insulating layer 103a and have high resistance in some cases. Moreover, when the conductive layer 111 and the conductive layer 112 are oxidized by oxygen contained in the semiconductor layer 113, the amount of oxygen vacancy (Vo) in the semiconductor layer 113 is increased in some cases. When the conductive layer 111 and the conductive layer 112 are oxidized by oxygen contained in the insulating layer 103a, the amount of oxygen supplied from the insulating layer 103a to the semiconductor layer 113 might be reduced.

A material that is less likely to be oxidized is preferably used for the conductive layer 111 and the conductive layer 112. An oxide conductor is preferably used for the conductive layer 111 and the conductive layer 112. For example, In—Sn oxide (ITO) or In—Sn—Si oxide (ITSO) can be suitably used. A nitride conductor may be used for the conductive layer 111 and the conductive layer 112. Examples of the nitride conductor include tantalum nitride and titanium nitride. The conductive layer 111 and the conductive layer 112 may each have a stacked-layer structure of the above-described materials.

With the use of a material that is less likely to be oxidized for the conductive layer 111 and the conductive layer 112, the conductive layer 111 and the conductive layer 112 can be inhibited from being oxidized by oxygen contained in the semiconductor layer 113 or oxygen contained in the insulating layer 103a and having higher resistance. Furthermore, it is possible to increase the amount of oxygen supplied from the insulating layer 103a to the semiconductor layer 113 while an increase in oxygen vacancies (Vo) in the semiconductor layer 113 is suppressed. Accordingly, oxygen vacancies (Vo) and VoH in the semiconductor layer 113 can be reduced. Thus, the transistor included in the touch panel 10 can have favorable electrical characteristics and high reliability. Note that the conductive layer 111 and the conductive layer 112 may be formed using the same material or different materials.

### Insulating Layer 105

The insulating layer 105 functioning as the gate insulating layer preferably has a low defect density. With the insulating layer 105 having a low defect density, the transistor can have favorable electrical characteristics. In addition, the insulating layer 105 preferably has high withstand voltage. With the insulating layer 105 having high withstand voltage, the transistor included in the touch panel 10 can have high reliability.

For the insulating layer 105, one or more of an insulating oxide, an insulating oxynitride, an insulating nitride oxide, and an insulating nitride can be used, for example. For the insulating layer 105, one or more of silicon oxide, silicon oxynitride, silicon nitride oxide, silicon nitride, aluminum oxide, aluminum oxynitride, aluminum nitride oxide, aluminum nitride, hafnium oxide, hafnium oxynitride, gallium oxide, gallium oxynitride, yttrium oxide, yttrium oxynitride, and Ga-Zn oxide can be used. The insulating layer 105 may be either a single layer or a stacked layer. The insulating layer 105 may have a stacked-layer structure of an oxide and a nitride.

A miniaturized transistor including a thin gate insulating layer may have a high leakage current. When a high dielectric constant material (also referred to as a high-k material) is used for the gate insulating layer, the voltage at the time of driving of the transistor can be lowered while the physical thickness is maintained. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

The amount of impurities (e.g., water and hydrogen) released from the insulating layer 105 itself is preferably small. A reduction in the amount of impurities released from the insulating layer 105 inhibits diffusion of impurities into the semiconductor layer 113. Thus, the transistor included in the touch panel 10 can have favorable electrical characteristics and high reliability.

The insulating layer 105 is formed over the semiconductor layer 113, and thus is preferably a film formed under conditions where damage to the semiconductor layer 113 is small. For example, the insulating layer 105 is preferably formed under conditions where the film formation speed is sufficiently low, specifically, under conditions where the film formation speed is lower than that of the insulating layer 103b. For example, when the insulating layer 105 is formed by a PECVD method under a low-power condition, damage to the semiconductor layer 113 can be small.

Here, the insulating layer 105 will be specifically described using a structure where a metal oxide is used for the semiconductor layer 113 as an example.

To improve the properties of the interface with the semiconductor layer 113, an oxide is preferably used for the insulating layer 105. For example, one or more of silicon oxide and silicon oxynitride can be suitably used for the insulating layer 105. A film from which oxygen is released by heating is further preferably used as the insulating layer 105.

Note that the insulating layer 105 may have a stacked-layer structure. The insulating layer 105 can have a stacked-layer structure of an oxide film on the side in contact with the semiconductor layer 113 and a nitride film on the side in contact with the conductive layer 115. For example, one or more of silicon oxide and silicon oxynitride can be suitably used for the oxide film. Silicon nitride can be suitably used for the nitride film. In the case where the insulating layer 105 has a stacked-layer structure, an oxide is preferably used for at least the side of the insulating layer 105 that is in contact with the semiconductor layer 113, in which case the properties of the interface with the semiconductor layer 113 can be improved.

### Substrate 101

Although there is no particular limitation on a material of the substrate 101, for example, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 101. Alternatively, any of these substrates where a semiconductor element is provided may be used as the substrate 101. A printed circuit board may be used as the substrate 101. Note that the shape of a semiconductor substrate and an insulating substrate may be a circular shape or a shape with corners.

A flexible substrate may be used as the substrate 101, and for example, the transistor 201 may be formed directly on the flexible substrate. Alternatively, a separation layer may be provided between the substrate 101 and the transistor 201 and the like. The separation layer can be used when part or the whole of the touch panel completed thereover is separated from the substrate 101 and transferred onto another substrate. In that case, for example, the transistor 201 can be transferred onto a substrate having low heat resistance or a flexible substrate as well.

### Insulating Layer 218

The insulating layer 218 is preferably formed using a material through which impurities are not easily diffused. In that case, the insulating layer 218 functions as a blocking layer that inhibits diffusion of impurities from the outside into the transistors. Examples of impurities include water and hydrogen. With the insulating layer 218, the reliability of the touch panel can be increased.

The insulating layer 218 can be an insulating layer including an inorganic material or an insulating layer including an organic material. For example, an inorganic material such as an oxide or a nitride can be suitably used for the insulating layer 218. Specifically, one or more of silicon nitride, silicon nitride oxide, silicon oxynitride, aluminum oxide, aluminum oxynitride, aluminum nitride, hafnium oxide, and hafnium aluminate can be used. For example, silicon nitride oxide can be suitably used for the insulating layer 218 because the amount of impurities (e.g., water and hydrogen) released from the silicon nitride oxide itself is small and a layer of silicon nitride oxide can function as a blocking layer that inhibits diffusion of impurities into the transistors from above the transistors. As the organic material, for example, one or more of acrylic resins and polyimide resins can be used. As the organic material, a photosensitive material may be used. A stack including two or more of the above insulating films may also be used. The insulating layer 218 may have a stacked-layer structure of an insulating layer including an inorganic material and an insulating layer including an organic material.

### Insulating Layer 235

The insulating layer 235 has a function of reducing unevenness caused by the transistor 201, the transistor 205, and the like. In this specification and the like, the insulating layer 235 is referred to as a planarization layer in some cases.

An insulating layer including an organic material can be suitably used as the insulating layer 235. As the organic material, a photosensitive organic resin is preferably used, and for example, a photosensitive resin composite including an acrylic resin is preferably used. Note that in this specification and the like, an acrylic resin refers to not only a polymethacrylic acid ester or a methacrylic resin, but also all the acrylic polymer in a broad sense in some cases.

The insulating layer 235 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, the insulating layer 235 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive-type material or a negative-type material may be used.

The insulating layer 235 may have a stacked-layer structure of an organic insulating layer and an inorganic insulating layer. For example, the insulating layer 235 can have a stacked-layer structure of an organic insulating layer and an inorganic insulating layer over the organic insulating layer. An inorganic insulating layer provided as the outermost surface of the insulating layer 235 can function as an etching protective layer. This can inhibit a decrease in the planarity of the insulating layer 235, which is caused by etching of part of the insulating layer 235 in the formation of the pixel electrode 311 or the pixel electrode 312.

The low planarity of the top surface of the insulating layer 235, which is the formation surface of the light-emitting element 61 or the liquid crystal element 62, may cause a connection defect due to step disconnection of the common electrode 316, for example. The low planarity of the top surface of the insulating layer 235 may cause local thinning of the common electrode 316 and an increase in electric resistance. In addition, the low planarity of the top surface of the insulating layer 235 may lower the processing accuracy of the layer to be formed over the insulating layer 235 in some cases. By making the top surface of the insulating layer 235 flat, the processing accuracy of the light-emitting element 61 or the liquid crystal element 62 provided over the insulating layer 235 can be increased, for example; thus, a touch panel including a high-resolution display apparatus can be achieved. Moreover, occurrence of a connection defect due to disconnection of the common electrode 316 and an increase in electric resistance due to local thinning of the common electrode 316 can be inhibited, whereby a touch panel including a display apparatus with high display quality can be achieved.

Note that in some cases, the insulating layer 235 is partly removed when the pixel electrode 311 or the pixel electrode 312 is formed. The insulating layer 235 may have a depressed portion in a region not overlapped by the pixel electrode 311 or the pixel electrode 312.

### Insulating Layer 237

The insulating layer 237 can be an insulating layer including an organic material, and a material that can be used for the insulating layer 235 can be used, for example. Alternatively, the insulating layer 237 can be an insulating layer including an inorganic material, and a material that can be used for the insulating layer 218 can be used, for example. The insulating layer 237 may have a stacked-layer structure of an insulating layer including an inorganic material and an insulating layer including an organic material.

### Insulating Layer 124

For the insulating layer 124, a material similar to the material that can be used for the insulating layer 105 can be used. For the insulating layer 124, one or more of an insulating oxide, an insulating oxynitride, an insulating nitride oxide, and an insulating nitride can be used, for example. For the insulating layer 124, a material similar to the material that can be used for the insulating layer 103 may also be used.

### Insulating Layer 125

The insulating layer 125 can be an insulating layer including an organic material, and a material that can be used for the insulating layer 235 can be used, for example. Note that the insulating layer 125 may be an insulating layer including an inorganic material. In this case, for the insulating layer 125, a material that can be used for the insulating layer 218 can be used, for example. The insulating layer 125 may have a stacked-layer structure of an insulating layer including an inorganic material and an insulating layer including an organic material.

### Insulating Layer 172

For the insulating layer 172, a material similar to the material that can be used for the insulating layer 103 can be used, and for example, a material similar to the material that can be used for the insulating layer 103a can be used. For the insulating layer 172, an inorganic insulating material or an organic insulating material can be used, for example. The insulating layer 172 may have a stacked-layer structure of an inorganic insulating material and an organic insulating material.

### Adhesive Layer 142

For the adhesive layer 142, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. A two-component-mixture-type resin may be used. Alternatively, an adhesive sheet may be used, for example.

### Substrate 152

For the substrate 152, glass, quartz, ceramic, sapphire, a resin, a metal, an alloy, a semiconductor, or the like can be used. When a flexible material is used for the substrate 152, the flexibility of the touch panel can be increased. Furthermore, a polarizing plate may be used as the substrate 152. Alternatively, an attachment film or a base film may be used as the substrate 152.

For the substrate 152, any of the following can be used: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 152.

When a film is used for the substrate and the film absorbs water, the shape of the touch panel might be changed, e.g., creases might be caused. Thus, as the substrate, a film with a low water absorption rate is preferably used. For example, the water absorption rate of the film is preferably 1 % or lower, further preferably 0.1 % or lower, still further preferably 0.01 % or lower.

A variety of optical members can be provided on the outer surface of the substrate 152. Examples of the optical members include a polarizing plate (e.g., a circularly polarizing plate), a retardation plate, a light diffusion layer (e.g., a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer surface of the substrate 152. For example, a glass layer or a silica layer (SiOₓ layer) is preferably provided as the surface protective layer to inhibit the surface contamination and generation of a scratch. The surface protective layer may be formed using DLC (diamond-like carbon), aluminum oxide (AlOₓ), a polyester-based material, a polycarbonate-based material, or the like. For the surface protective layer, a material having a high visible light transmittance is preferably used. The surface protective layer is preferably formed using a material with high hardness.

In the case where a circularly polarizing plate overlaps the touch panel, a highly optically isotropic substrate is preferably used as the substrate included in the touch panel. In other words, a highly optically isotropic substrate has a low birefringence (a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

### Light-Blocking Layer 317

Examples of a material that can be used for the light-blocking layer 317 include carbon black, titanium black, a metal, a metal oxide, and a composite oxide containing a solid solution of a plurality of metal oxides. The light-blocking layer 317 can have a stacked-layer structure of a plurality of layers each including a material of a coloring layer. For example, the light-blocking layer 317 can employ a stacked-layer structure of a layer including a material used for a coloring layer that transmits light of a certain color and a layer including a material used for a coloring layer that transmits light of another color.

The above is the description of the components.

### Manufacturing Method Example 1 of Touch Panel

A method for manufacturing the touch panel of one embodiment of the present invention will be described below with reference to drawings. Here, a method for manufacturing the touch panel 10 having the structure illustrated in FIG. 6 is described as an example.

Note that thin films included in the touch panel (insulating films, semiconductor films, conductive films, and the like) can be formed by a sputtering method, a chemical vapor deposition (CVD) method, a vacuum evaporation method, a pulsed laser deposition (PLD) method, an ALD method, or the like. A CVD method includes a PECVD method, a thermal CVD method, and the like. An example of a thermal CVD method is a metal organic chemical vapor deposition (MOCVD: Metal Organic CVD) method.

The thin films included in the touch panel (insulating films, semiconductor films, conductive films, and the like) can be formed by a method such as spin coating, dipping, spray coating, inkjetting, dispensing, screen printing, offset printing, doctor blade coating, slit coating, roll coating, curtain coating, or knife coating in some cases.

The thin films can be processed by, for example, etching of the thin films in accordance with a pattern of a resist mask that has been formed by a photolithography method. Alternatively, a nanoimprinting method, a sandblasting method, a lift-off method, or the like may be used to process the thin films. An island-shaped thin film may be directly formed by a film formation method using a shielding mask such as a metal mask. A photosensitive thin film can be processed by light exposure and development. That is, the photosensitive thin film can be processed by a photolithography method.

As light used for light exposure in a photolithography method, an i-line (with a wavelength of 365 nm), a g-line (with a wavelength of 436 nm), an h-line (with a wavelength of 405 nm), or light in which these lines are mixed can be used, for example. Besides, ultraviolet rays, KrF laser light, ArF laser light, or the like can be used. Light exposure may be performed by liquid immersion exposure technique. As the light used for light exposure, extreme ultraviolet (EUV) light or X-rays may be used. Instead of the light used for the light exposure, an electron beam can also be used. It is preferable to use extreme ultraviolet light, X-rays, or an electron beam, in which case extremely minute processing is possible. Note that when light exposure is performed by scanning of a beam such as an electron beam, a photomask is not needed.

For the etching of the thin films, a dry etching method, a wet etching method, or the like can be used.

### Formation of Conductive Layer 111

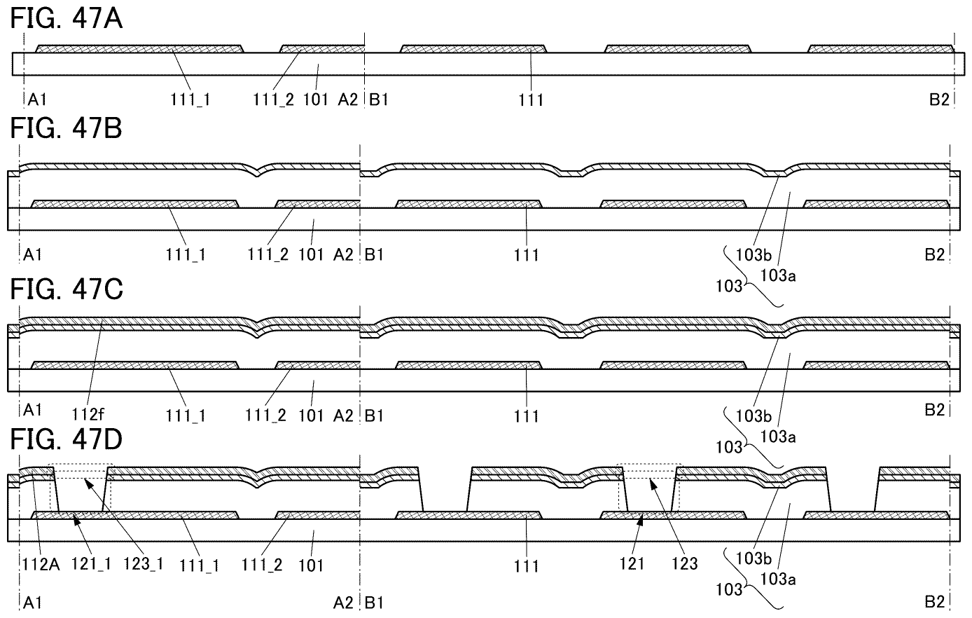

For the manufacture of the touch panel 10 having the structure illustrated in FIG. 6, first, a conductive film to be the conductive layer 111 in a later step is formed over the substrate 101. A sputtering method can be suitably used to form the conductive film, for example. The conductive film is processed after a resist mask is formed over the conductive film by a photolithography step, whereby the island-shaped conductive layer 111 functioning as one of the source electrode and the drain electrode is formed over the substrate 101 (FIG. 47A). For the processing of the conductive film, one or both of a wet etching method and a dry etching method are used.

### Formation of Insulating Layer 103a and Insulating Layer 103b

Next, the insulating layer 103a and the insulating layer 103b are formed over the substrate 101 and the conductive layer 111 (FIG. 47B). A PECVD method can be suitably used to form the insulating layer 103a and the insulating layer 103b, for example. It is preferable that the insulating layer 103b be formed in a vacuum successively after the formation of the insulating layer 103a, without exposure of the surface of the insulating layer 103a to the air. Forming the insulating layer 103a and the insulating layer 103b successively can inhibit impurities derived from the air from being attached to the surface of the insulating layer 103a. Examples of the impurities include water and organic substances.

The substrate temperatures at the time of forming the insulating layer 103a and the insulating layer 103b are each preferably higher than or equal to 180° C. and lower than or equal to 450° C., further preferably higher than or equal to 200° C. and lower than or equal to 450° C., further preferably higher than or equal to 250° C. and lower than or equal to 450° C., still further preferably higher than or equal to 300° C. and lower than or equal to 450° C., yet further preferably higher than or equal to 300° C. and lower than or equal to 400° C., yet still further preferably higher than or equal to 350° C. and lower than or equal to 400° C. When the substrate temperatures at the time of forming the insulating layer 103a and the insulating layer 103b are within such a range, impurities (e.g., water and hydrogen) released from the insulating layer 103a and the insulating layer 103b can be reduced, which inhibits diffusion of the impurities into the semiconductor layer 113, which is to be formed in a later step. Consequently, a transistor having favorable electrical characteristics and high reliability can be manufactured.

As described above, the insulating layer 103a and the insulating layer 103b are formed before the semiconductor layer 113 is formed. Hence, there is no need for concern about release of oxygen from the semiconductor layer 113 due to heat applied at the time of forming the insulating layer 103a and the insulating layer 103b.

Heat treatment may be performed after the insulating layer 103a and the insulating layer 103b are formed. By the heat treatment, water and hydrogen can be released from the surface and inside of the insulating layer 103a and the insulating layer 103b.

The heat treatment temperature is preferably higher than or equal to 150° C. and lower than the strain point of the substrate, further preferably higher than or equal to 200° C. and lower than or equal to 450° C., further preferably higher than or equal to 250° C. and lower than or equal to 450° C., still further preferably higher than or equal to 300° C. and lower than or equal to 450° C., yet further preferably higher than or equal to 300° C. and lower than or equal to 400° C., yet still further preferably higher than or equal to 350° C. and lower than or equal to 400° C.. The heat treatment can be performed in an atmosphere containing one or more of a noble gas, nitrogen, and oxygen. As a nitrogen-containing atmosphere or an oxygen-containing atmosphere, clean dry air (CDA) may be used. Note that the amount of hydrogen, water, and the like contained in the atmosphere is preferably as low as possible. As the atmosphere, a high-purity gas with a dew point of −60° C. or lower, preferably −100° C. or lower is preferably used. With the use of an atmosphere where the amount of hydrogen, water, and the like contained is as low as possible, entry of hydrogen, water, and the like into the insulating layer 103a and the insulating layer 103b can be prevented as much as possible. An oven, a rapid thermal annealing (RTA) apparatus, or the like can be used for the heat treatment. With the RTA apparatus, the heat treatment time can be shortened.

### Formation of Conductive Film 112f

Then, a conductive film 112f to be the conductive layer 112 in a later step is formed over the insulating layer 103b (FIG. 47C). For the formation of the conductive film 112f, a sputtering method can be suitably used, for example.

### Formation of Opening 121 and Opening 123

Next, the conductive film 112f in part of a region that overlaps the conductive layer 111 is removed, whereby a conductive layer 112A including the opening 123 is formed (FIG. 47D). For the formation of the opening 123, one or both of a wet etching method and a dry etching method can be used, for example, and a wet etching method can be suitably used.

Subsequently, the insulating layer 103 (the insulating layer 103a and the insulating layer 103b) in part of a region that overlaps the conductive layer 111 is removed. Thus, the opening 121 reaching the conductive layer 111 is formed in the insulating layer 103 (FIG. 47D). For the formation of the opening 121, one or both of a wet etching method and a dry etching method can be used, for example, and a dry etching method can be suitably used.

The opening 123 can be formed using a resist mask used for the formation of the opening 121, for example. Specifically, a resist mask is formed over the conductive film 112f, the conductive film 112f is removed using the resist mask to form the opening 123, and the insulating layer 103 is removed using the resist mask, whereby the opening 121 can be formed. Thus, the opening 121 can be formed to include a region overlapped by the opening 123. When the opening 123 is processed to have a larger width than the resist mask, the transistor 201 in which the width of the opening 123 is larger than the width of the opening 121 can be manufactured. Here, in the case of manufacturing the transistor 201 in which the width of the opening 123 is different from the width of the opening 121, for example, the opening 121 may be formed using a resist mask different from the resist mask used to form the opening 123.

### Formation of Conductive Layer 112

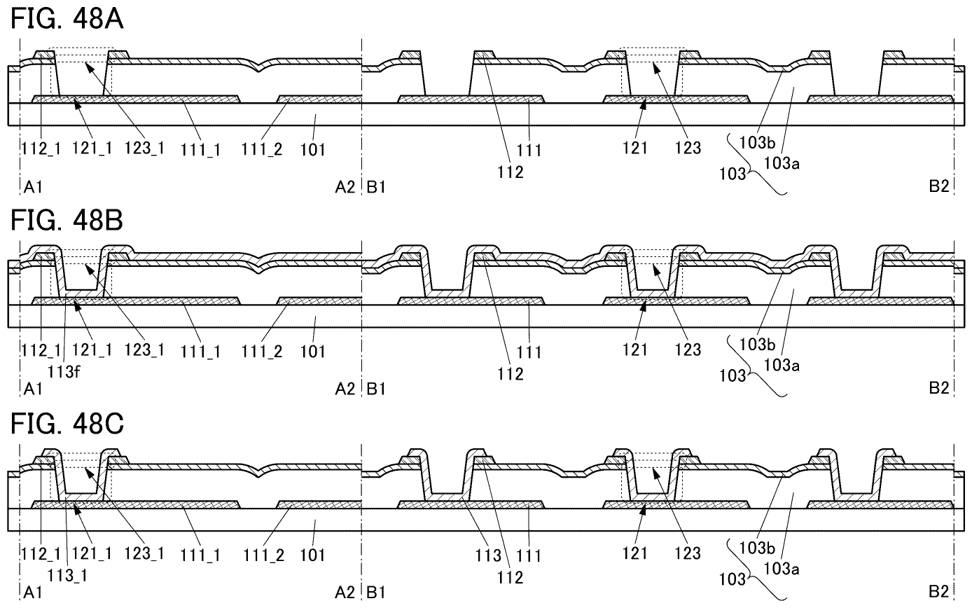

Next, the conductive layer 112A is processed into a desired shape, thereby forming the conductive layer 112 (FIG. 48A). For the formation of the conductive layer 112, one or both of a wet etching method and a dry etching method can be used, for example, and a wet etching method can be suitably used.

### Formation of Semiconductor Layer 113

Subsequently, a semiconductor film 113f to be the semiconductor layer 113 is formed to cover the opening 121 and the opening 123 (FIG. 48B). The semiconductor layer film 113f can be provided to include a region in contact with the top surface and the side surface of the conductive layer 112, the top surface and the side surface of the insulating layer 103, and the top surface of the conductive layer 111 and to include a region positioned in the opening 121 and the opening 123.

The semiconductor film 113f is preferably formed by a sputtering method using a metal oxide target.

The semiconductor film 113f is preferably a dense film with as few defects as possible. The semiconductor film 113f is preferably a highly purified film in which impurities containing hydrogen elements are reduced as much as possible. It is particularly preferable to use a metal oxide film having crystallinity as the semiconductor film 113f.

In forming the semiconductor film 113f, an oxygen gas is preferably used. In the case of using an oxygen gas at the time of forming the semiconductor film 113f, oxygen can be suitably supplied into the insulating layer 103. For example, in the case where an oxide is used for the insulating layer 103a, oxygen can be suitably supplied into the insulating layer 103a by using an oxygen gas at the time of the semiconductor film 113f.

By the supply of oxygen to the insulating layer 103a, oxygen is supplied to the semiconductor layer 113 in a later step, so that oxygen vacancies (Vo) and VoH in the semiconductor layer 113 can be reduced.

When the semiconductor film 113f is formed, an oxygen gas and an inert gas (e.g., a helium gas, an argon gas, or a xenon gas) may be mixed. Note that when the proportion of an oxygen gas in the whole deposition gas (an oxygen flow rate ratio) at the time of forming the semiconductor film 113f is higher, the crystallinity of the semiconductor film 113f can be higher and a highly reliable transistor can be obtained. By contrast, when the oxygen flow rate ratio is lower, the crystallinity of the semiconductor film 113f is lower and a transistor with a high on-state current can be obtained.

With a higher substrate temperature at the time of forming the semiconductor film 113f, the semiconductor film 113f can have higher crystallinity and be denser. By contrast, with a lower substrate temperature, the semiconductor film 113f can have lower crystallinity and higher electric conductivity.

The substrate temperature at the time of forming the semiconductor film 113f is higher than or equal to room temperature and lower than or equal to 250° C., preferably higher than or equal to room temperature and lower than or equal to 200° C., further preferably higher than or equal to room temperature and lower than or equal to 140° C. For example, the substrate temperature is preferably higher than or equal to room temperature and lower than 140° C., in which case high productivity is achieved. When the semiconductor film 113f is formed with the substrate temperature set at room temperature or without heating the substrate, the crystallinity can be made low.

Before the formation of the semiconductor film 113f, it is preferable to perform at least one of treatment for desorbing water, hydrogen, an organic substance, and the like adsorbed onto the surface of the insulating layer 103 and treatment for supplying oxygen into the insulating layer 103. For example, heat treatment can be performed at a temperature higher than or equal to 70° C. and lower than or equal to 200° C. in a reduced-pressure atmosphere. Alternatively, plasma treatment may be performed in an oxygen-containing atmosphere. Alternatively, oxygen may be supplied to the insulating layer 103 by plasma treatment in an atmosphere containing an oxidizing gas such as dinitrogen monoxide (N₂O). Performing plasma treatment containing a dinitrogen monoxide gas can supply oxygen while suitably removing an organic substance on the surface of the insulating layer 103. It is preferable that the semiconductor film 113f be formed successively after such treatment, without exposure of the surface of the insulating layer 103 to the air.

Note that in the case where the semiconductor layer 113 has a stacked-layer structure, an upper metal oxide film is preferably formed successively after the formation of a lower metal oxide film, without exposure of the surface of the lower metal oxide film to the air.

Next, the semiconductor film 113f is processed into an island shape. Thus, the semiconductor layer 113 is formed to include a region in contact with the top surface and the side surface of the conductive layer 112, the side surface of the insulating layer 103, and the top surface of the conductive layer 111 and to include a region positioned in the opening 121 and the opening 123 (FIG. 48C).

For the formation of the semiconductor layer 113, one or both of a wet etching method and a dry etching method can be used, for example, and a wet etching method can be suitably used. At this time, part of the insulating layer 112 in a region not overlapped by the semiconductor layer 113 is etched and thinned in some cases. In a similar manner, part of the insulating layer 103 in a region overlapped by neither the semiconductor layer 113 nor the conductive layer 112 is etched and thinned in some cases. For example, in some cases, the insulating layer 103b of the insulating layer 103 is removed by etching and the surface of the insulating layer 103a is exposed. When a material having high etching selectivity with respect to the semiconductor film 113f is used for the insulating layer 103b, a reduction in the thickness of the insulating layer 103b can be inhibited.

Heat treatment is preferably performed after the semiconductor film 113f is formed or after the semiconductor film 113f is processed into the semiconductor layer 113. The heat treatment can remove hydrogen and water that are contained in the semiconductor film 113f or the semiconductor layer 113 or adsorbed onto the surface of the semiconductor film 113f or the semiconductor layer 113. Furthermore, the film quality of the semiconductor film 113f or the semiconductor layer 113 is improved by the heat treatment in some cases; for example, defects in the semiconductor film 113f or the semiconductor layer 113 are reduced and the crystallinity of the semiconductor film 113f or the semiconductor layer 113 is improved in some cases.

Oxygen can be supplied from the insulating layer 103a to the semiconductor film 113f or the semiconductor layer 113 by heat treatment. In this case, it is further preferable that the heat treatment be performed before the semiconductor film is processed into the semiconductor layer 113. The above description can be referred to for the heat treatment; thus, the detailed description thereof is omitted.

Note that the heat treatment is not necessarily performed when not needed. The heat treatment in this step may be omitted, and heat treatment performed in a later step may also serve as the heat treatment in this step. Treatment at high temperature in a later step, such as a film formation step, can serve as the heat treatment in some cases.

### Formation of Insulating Layer 105

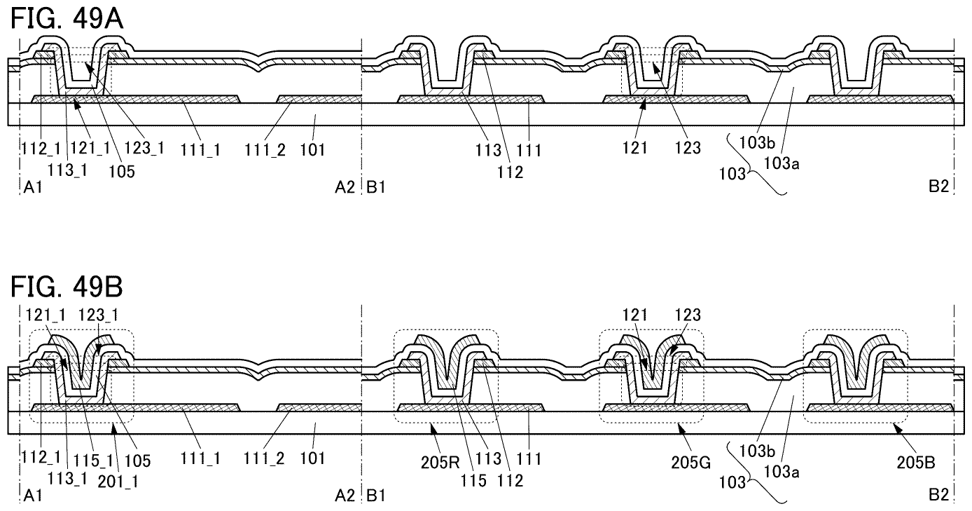

Next, the insulating layer 105 is formed over the semiconductor layer 113, the conductive layer 112, and the insulating layer 103. Specifically, the insulating layer 105 is formed to cover the semiconductor layer 113, the conductive layer 112, and the insulating layer 103 (FIG. 49A). The insulating layer 105 includes a region positioned in the opening 121 and the opening 123 and is formed to cover the opening 121 and the opening 123. For the formation of the insulating layer 105, a PECVD method can be favorably used.

In the case of using a metal oxide for the semiconductor layer 113, the insulating layer 105 preferably functions as a barrier film that inhibits diffusion of oxygen. The insulating layer 105 having a function of inhibiting diffusion of oxygen inhibits diffusion of oxygen into the conductive layer 115 formed in a later step from above the insulating layer 105 and thus can inhibit oxidation of the conductive layer 115. Consequently, the transistor can have favorable electrical characteristics and high reliability.

By increasing the temperature at the time of forming the insulating layer 105 functioning as the gate insulating layer, the insulating layer including a small number of defects can be obtained. However, the high temperature at the time of forming the insulating layer 105 sometimes allows release of oxygen from the semiconductor layer 113, which increases oxygen vacancies (Vo) and VoH in the semiconductor layer 113 in some cases. The substrate temperature at the time of forming the insulating layer 105 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet further preferably higher than or equal to 300° C. and lower than or equal to 450° C., yet still further preferably higher than or equal to 300° C. and lower than or equal to 400° C.. When the substrate temperature at the time of forming the insulating layer 105 is in the above range, release of oxygen from the semiconductor layer 113 can be inhibited while the defects in the insulating layer 105 can be reduced. Consequently, the transistor can have favorable electrical characteristics and high reliability.

Plasma treatment may be performed on the surface of the semiconductor layer 113 before the formation of the insulating layer 105. By the plasma treatment, impurities adsorbed onto the surface of the semiconductor layer 113, such as water, can be reduced. Thus, impurities at the interface between the semiconductor layer 113 and the insulating layer 105 can be reduced, achieving a highly reliable transistor. The plasma treatment is particularly suitable in the case where the surface of the semiconductor layer 113 is exposed to the air after the formation of the semiconductor layer 113 and before the formation of the insulating layer 105. The plasma treatment can be performed in an atmosphere of oxygen, ozone, nitrogen, dinitrogen monoxide, argon, or the like, for example. The plasma treatment and the formation of the insulating layer 105 are preferably performed successively without exposure to the air.

### Formation of Conductive Layer 115

Subsequently, a conductive film to be the conductive layer 115 in a later step is formed over the insulating layer 105. A sputtering method can be suitably used to form the conductive film, for example. After a resist mask is formed over the conductive film by a photolithography step, the conductive film is processed using one or both of a wet etching method and a dry etching method, for example, whereby the island-shaped conductive layer 115 functioning as the gate electrode can be formed over the insulating layer 105 so as to include a region overlapping the semiconductor layer 113 (FIG. 49B). The conductive layer 115 is formed to include a region positioned in the opening 121 and a region positioned in the opening 123, and to include a region facing the insulating layer 105 with the semiconductor layer 113 therebetween.

In the above manner, the transistor 201 and the transistor 205 can be formed.

### Formation of Insulating Layer 218 and Insulating Layer 235

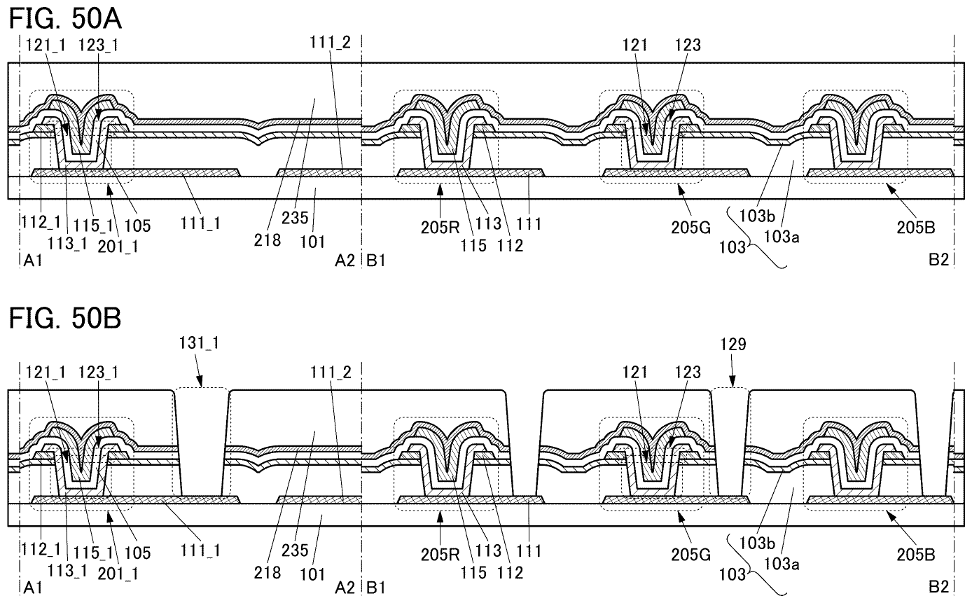

Next, the insulating layer 218 is formed to cover the transistor 201 and the transistor 205, and the insulating layer 235 is formed over the insulating layer 218. Specifically, the insulating layer 218 is formed over the conductive layer 115 and the insulating layer 105, and the insulating layer 235 is formed over the insulating layer 218 (FIG. 50A). As described above, an inorganic material can be used for the insulating layer 218 and an organic material can be used for the insulating layer 235, for example. In this case, the insulating layer 218 can be formed by a CVD method, a sputtering method, a PLD method, or an ALD method, for example. The insulating layer 235 can be formed by spin coating, dipping, spray coating, inkjetting, dispensing, screen printing, offset printing, doctor blade coating, slit coating, roll coating, curtain coating, or knife coating, for example.

### Formation of Opening 129 and Opening 131

Then, the insulating layer 103, the insulating layer 105, the insulating layer 218, and the insulating layer 235 in part of regions that overlap the conductive layer 111 of the transistor 201 are removed. Thus, the opening 131 reaching the conductive layer 111 of the transistor 201 is formed in the insulating layer 103, the insulating layer 105, the insulating layer 218, and the insulating layer 235. Moreover, the insulating layer 103, the insulating layer 105, the insulating layer 218, and the insulating layer 235 in part of regions that overlap the conductive layer 111 of the transistor 205 are removed. Thus, the opening 129 reaching the conductive layer 111 of the transistor 205 is formed in the insulating layer 103, the insulating layer 105, the insulating layer 218, and the insulating layer 235 (FIG. 50B). For the formation of the opening 131 and the opening 129, one or both of a wet etching method and a dry etching method can be used, for example, and a dry etching method can be suitably used. Here, the opening 131 and the opening 129 can be concurrently formed.

Note that the opening 129 and the opening 131 may be formed in the insulating layer 105, the insulating layer 218, and the insulating layer 235 so as to reach the conductive layer 112. Alternatively, the opening 129 may be formed in the insulating layer 103, the insulating layer 105, the insulating layer 218, and the insulating layer 235 so as to reach the conductive layer 111 of the transistor 205, and the opening 131 may be formed in the insulating layer 218 and the insulating layer 235 so as to reach the conductive layer 115 of the transistor 201. Further alternatively, the opening 129 may be formed in the insulating layer 105, the insulating layer 218, and the insulating layer 235 so as to reach the conductive layer 112 of the transistor 205, and the opening 131 may be formed in the insulating layer 218 and the insulating layer 235 so as to reach the conductive layer 115 of the transistor 201.

### Formation of Conductive Layer 166 and Pixel Electrode 311

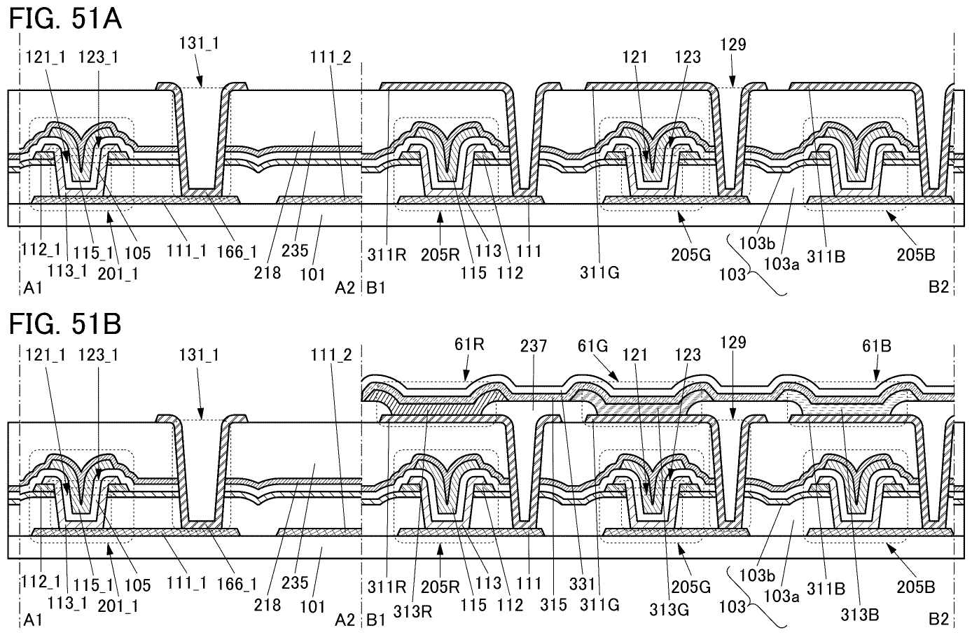

Next, a conductive film to be the conductive layer 166 and the pixel electrode 311 in a later step is formed to cover the opening 131 and the opening 129. A sputtering method or a vacuum evaporation method, for example, can be suitably used to form the conductive film. After a resist mask is formed over the conductive film by a photolithography step, the conductive film is processed using one or both of a wet etching method and a dry etching method, for example, whereby the island-shaped conductive layer 166 and the island-shaped pixel electrode 311 can be formed (FIG. 51A). The conductive layer 166 is formed to include a region in contact with the top surface and the side surface of the insulating layer 235, the side surface of the insulating layer 218, the side surface of the insulating layer 105, the side surface of the insulating layer 103, and the top surface of the conductive layer 111 of the transistor 201 and to include a region positioned in the opening 131. The pixel electrode 311 is formed to include a region in contact with the top surface and the side surface of the insulating layer 235, the side surface of the insulating layer 218, the side surface of the insulating layer 105, the side surface of the insulating layer 103, and the top surface of the conductive layer 111 of the transistor 205 and to include a region positioned in the opening 129.

Note that in the case where the opening 131 is formed to reach the conductive layer 112 of the transistor 201, the conductive layer 166 is formed to include a region in contact with the top surface and the side surface of the insulating layer 235, the side surface of the insulating layer 218, the side surface of the insulating layer 105, and the top surface of the conductive layer 112 of the transistor 201. In the case where the opening 129 is formed to reach the conductive layer 112 of the transistor 205, the pixel electrode 311 is formed to include a region in contact with the top surface and the side surface of the insulating layer 235, the side surface of the insulating layer 218, the side surface of the insulating layer 105, and the top surface of the conductive layer 112 of the transistor 205. In the case where the opening 131 is formed to reach the conductive layer 115 of the transistor 201, the conductive layer 166 is formed to include a region in contact with the top surface and the side surface of the insulating layer 235, the side surface of the insulating layer 218, and the top surface of the conductive layer 115 of the transistor 201. In the case where the opening 129 is formed to reach the conductive layer 115 of the transistor 205, the pixel electrode 311 is formed to include a region in contact with the top surface and the side surface of the insulating layer 235, the side surface of the insulating layer 218, and the top surface of the conductive layer 115 of the transistor 205.

### Formation of Insulating Layer 237

Then, the insulating layer 237 is formed over the pixel electrode 311R, the pixel electrode 311G, the pixel electrode 311B, and the insulating layer 235 (FIG. 51B). As described above, an organic material or an inorganic material can be used for the insulating layer 237. In the case where an organic material is used for the insulating layer 237, the insulating layer 237 can be formed by spin coating, dipping, spray coating, inkjetting, dispensing, screen printing, offset printing, doctor blade coating, slit coating, roll coating, curtain coating, or knife coating, for example. In the case where an inorganic material is used for the insulating layer 237, the insulating layer 237 can be formed by a CVD method, a sputtering method, a PLD method, or an ALD method, for example.

Next, part of the insulating layer 237 is removed. For example, part of the insulating layer 237 is removed by one or both of a wet etching method and a dry etching method. In the above manner, the insulating layer 237 is formed to cover end portions of the pixel electrode 311R, the pixel electrode 311G, and the pixel electrode 311B.

### Formation of Layer 313

Subsequently, the layer 313R, the layer 313G, and the layer 313B are formed over the pixel electrode 311R, the pixel electrode 311G, and the pixel electrode 311B, respectively (FIG. 51B). For example, the light-emitting material included in the layer 313R, the light-emitting material included in the layer 313G, and the light-emitting material included in the layer 313B are separately formed by a vacuum evaporation method using a fine metal mask. In this manner, the layer 313R, the layer 313G, and the layer 313B that emit light of different colors can be formed. Note that a sputtering method using a fine metal mask or an inkjet method may be used to form the layer 313R, the layer 313G, and the layer 313B.

### Formation of Common Electrode 315 and Protective Layer 331

Next, the common electrode 315 is formed over the layer 313R, the layer 313G, the layer 313B, and the insulating layer 237, and the protective layer 331 is formed over the common electrode 315 (FIG. 51B). The common electrode 315 can be formed by a sputtering method, a vacuum evaporation method, or the like. The protective layer 331 can be formed by a vacuum evaporation method, a sputtering method, a CVD method, an ALD method, or the like.

In the above manner, the light-emitting element 61R, the light-emitting element 61G, and the light-emitting element 61B can be formed.

### Formation of Light-Blocking Layer 317

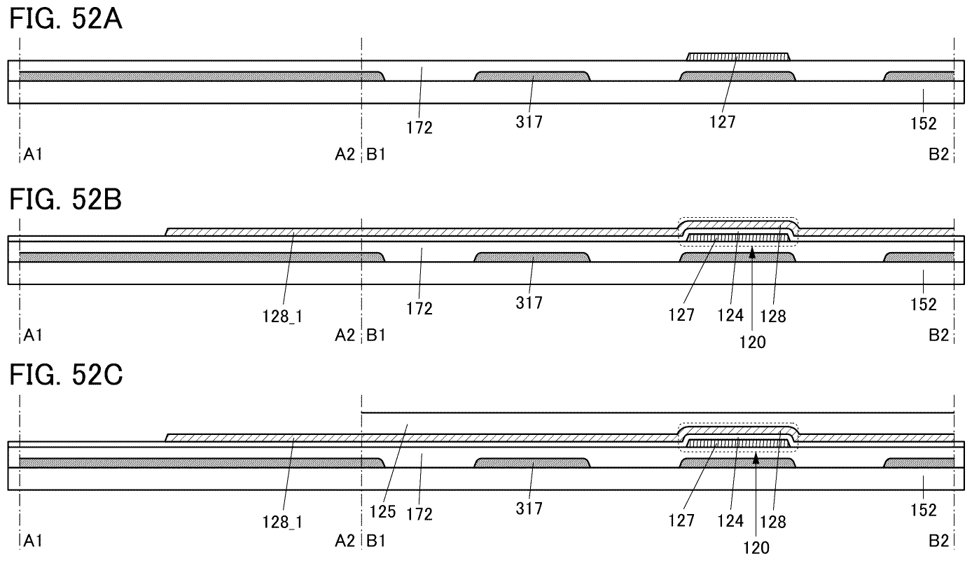

Then, the light-blocking layer 317 is formed over the substrate 152 (FIG. 52A). The light-blocking layer 317 can be formed by a spin coating method or an inkjet method, for example.

### Formation of Insulating Layer 172

Next, the insulating layer 172 is formed over the light-blocking layer 317 and the substrate 152 (FIG. 52A). For formation of the insulating layer 172, a PECVD method can be favorably used, for example.

### Formation of Sensing Element 120

Subsequently, a conductive film to be the electrode 127 in a later step is formed over the insulating layer 172. A sputtering method can be suitably used to form the conductive film, for example. For example, a resist mask is formed over the conductive film by a photolithography step, and then the conductive film is processed, whereby the electrode 127 is formed over the insulating layer 172 (FIG. 52A). For the processing of the conductive film, one or both of a wet etching method and a dry etching method are used.

Next, the insulating layer 124 is formed over the electrode 127 and the insulating layer 172. Specifically, the insulating layer 124 is formed over the electrode 127 and to cover the insulating layer 172 (FIG. 52B). For the formation of the insulating layer 124, a PECVD method can be favorably used.

Then, a conductive film to be the electrode 128 in a later step is formed over the insulating layer 124. A sputtering method can be suitably used to form the conductive film, for example. For example, a resist mask is formed over the conductive film by a photolithography step, and then the conductive film is processed, whereby the electrode 128 is formed over the insulating layer 124 (FIG. 52B). For the processing of the conductive film, one or both of a wet etching method and a dry etching method are used.

In the above manner, the sensing element 120 including the electrode 127 and the electrode 128, which are a pair of electrodes, is formed over the substrate 152.

### Formation of Insulating Layer 125

Next, the insulating layer 125 is formed over the electrode 128 (FIG. 52C). For the formation of the insulating layer 125, a PECVD method can be favorably used, for example.

The insulating layer 125 is formed over the entire surface of the substrate 152 by the above-described method, for example, and then partly removed by a photolithography method and an etching method, or the like. Thus, part of the electrode 128 is exposed. Although not illustrated in FIG. 52C, part of the electrode 127 is also exposed. In the above manner, the insulating layer 125 is formed to overlap part of the electrode 127 and part of the electrode 128.

### Bonding of Substrate 101 and Substrate 152

Subsequently, the substrate 101 and the substrate 152 are bonded to each other with the adhesive layer 142 including the conductive particle 165. Specifically, the protective layer 331, the insulating layer 235, and the conductive layer 166 over the substrate 101 are bonded to the insulating layer 125, the electrode 128, and the insulating layer 124 over the substrate 152 with the adhesive layer 142 including the conductive particle 165. The adhesive layer 142 can be formed by a screen printing method, a dispensing method, or the like.

Here, the conductive particle 165 is included in the adhesive layer 142 so as to include a region positioned in the opening 131 and electrically connect the conductive layer 166 and the electrode 128 to each other, whereby the substrate 101 and the substrate 152 are bonded to each other. Thus, the conductive particle 165 is provided between the conductive layer 166 and the electrode 128 so as to include a region positioned in the opening 131. The conductive particle 165 provided in the opening 131 is more likely to avoid being out of contact with the conductive layer 166, for example, than the conductive particle 165 provided outside the opening 131. For example, even when the conductive particle 165 is provided at a position that is in the vicinity of the opening 131 but does not overlap the conductive layer 166 right after the substrate 101 and the substrate 152 are bonded to each other using the adhesive layer 142 including the conductive particle 165, the position of the conductive particle 165 is shifted owing to a step formed by the opening 131 and the conductive particle 165 enters the opening 131 in some cases. This can sometimes inhibit the conductive particle 165 from being out of contact with the conductive layer 166. In the above manner, the conductive particle 165 can be easily in contact with both the conductive layer 166 and the electrode 128, for example. This facilitates electrical connection between the conductive layer 166 and the electrode 128. Note that like the electrode 128, the electrode 127 can be electrically connected to the conductive layer 166 through the conductive particle 165 including a region positioned in the opening 131.

As described above, the conductive layer 166 is electrically connected to the conductive layer 111. Accordingly, the conductive layer 111 and the electrode 128 are electrically connected to each other through the conductive particle 165.

Through the above steps, the touch panel 10 having the structure illustrated in FIG. 6 can be manufactured. In the above manufacturing method, for example, the transistor 201 provided in the input device driver circuit 15 can be formed in the same steps as the transistor 205 provided in the display portion 20. Thus, the above manufacturing method of the touch panel 10 is a method with a simplified manufacturing process. Accordingly, the above manufacturing method is a method with low cost and high mass productivity.

In the above manufacturing method, the electrode 127 or the electrode 128 can be easily electrically connected to the source electrode, the drain electrode, or the gate electrode of the transistor 201. Thus, the touch panel 10 can be manufactured with a high yield by the above manufacturing method.

### Manufacturing Method Example 2 of Touch Panel

An example of a method for manufacturing the touch panel 10 having the structure illustrated in FIG. 7 will be described below. Note that descriptions overlapping with <Manufacturing method example 1 of touch panel> described above will be omitted as appropriate, and differences will be mainly described.

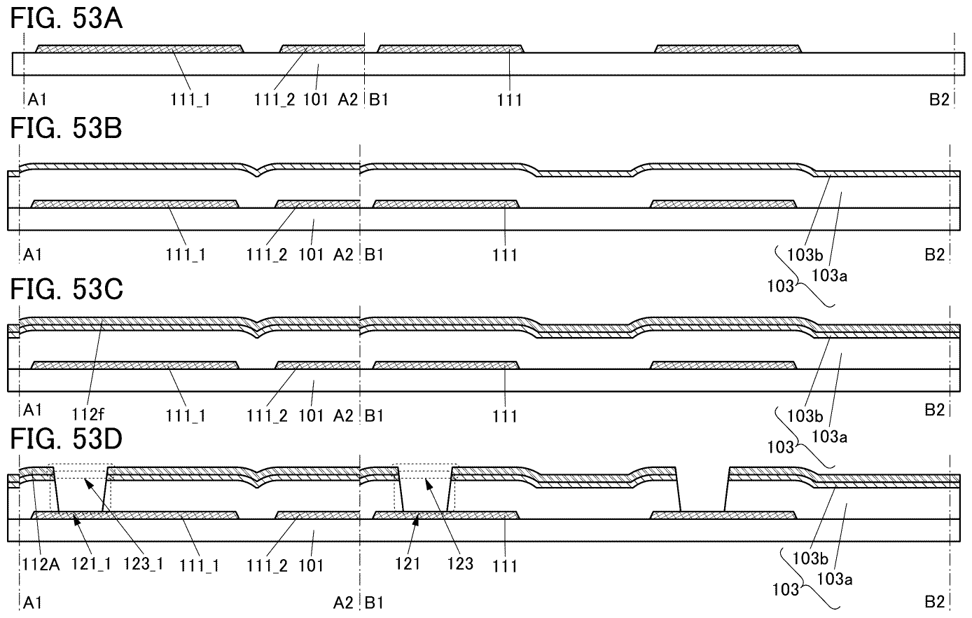

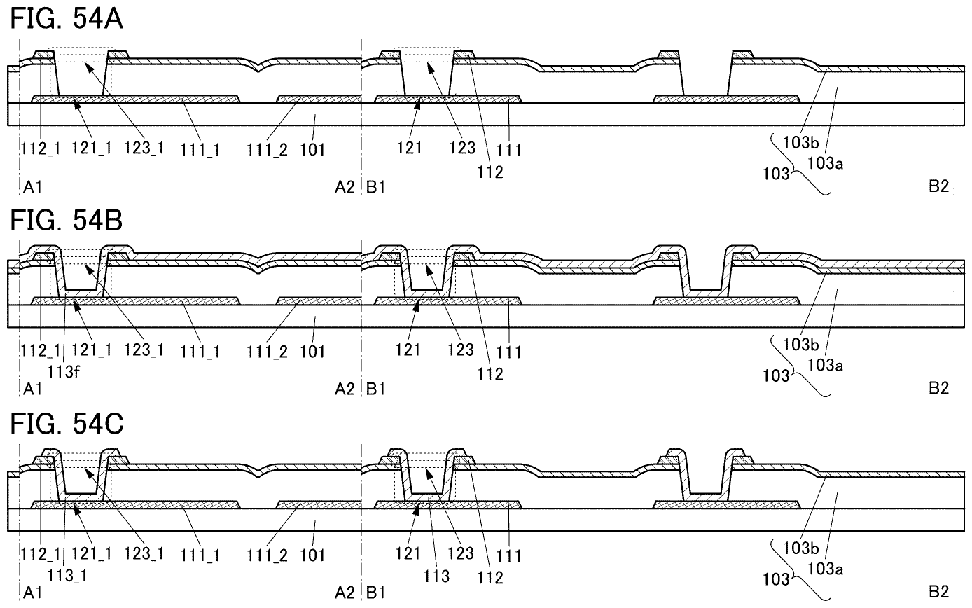

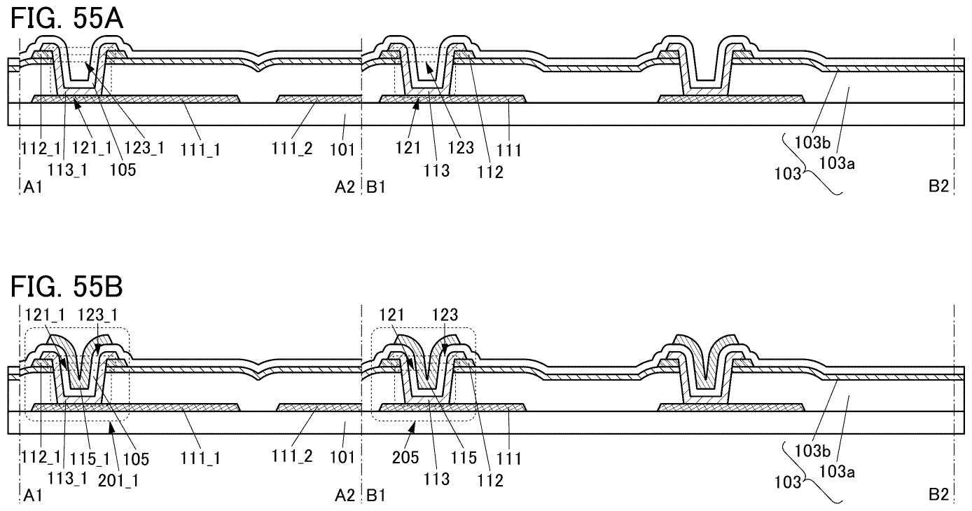

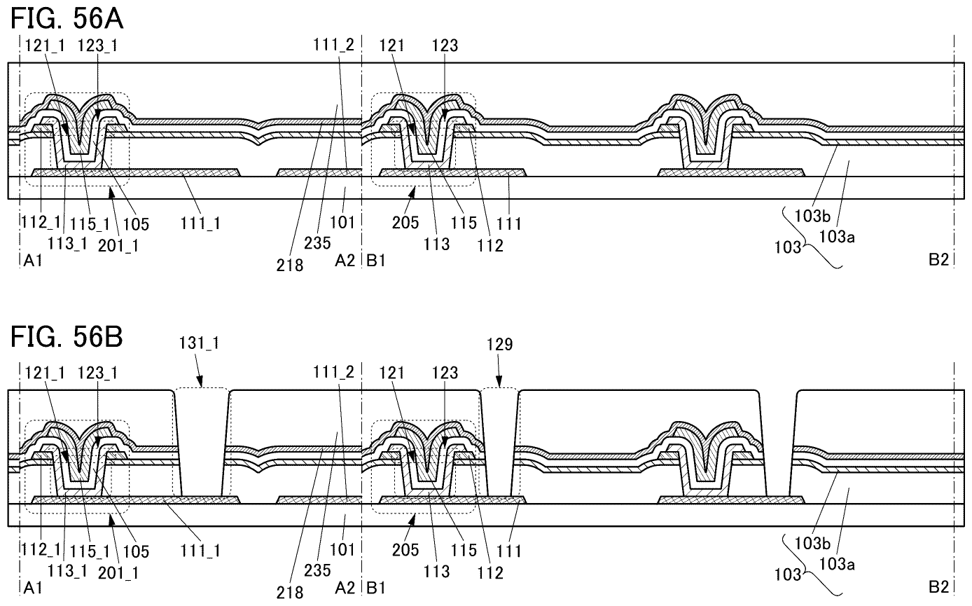

First, the same steps as those illustrated in FIG. 47A to FIG. 50B are performed. FIG. 53A, FIG. 53B, FIG. 53C, FIG. 53D, FIG. 54A, FIG. 54B, FIG. 54C, FIG. 55A, FIG. 55B, FIG. 56A, and FIG. 56B correspond to the steps illustrated in FIG. 47A, FIG. 47B, FIG. 47C, FIG. 47D, FIG. 48A, FIG. 48B, FIG. 48C, FIG. 49A, FIG. 49B, FIG. 50A, and FIG. 50B, respectively.

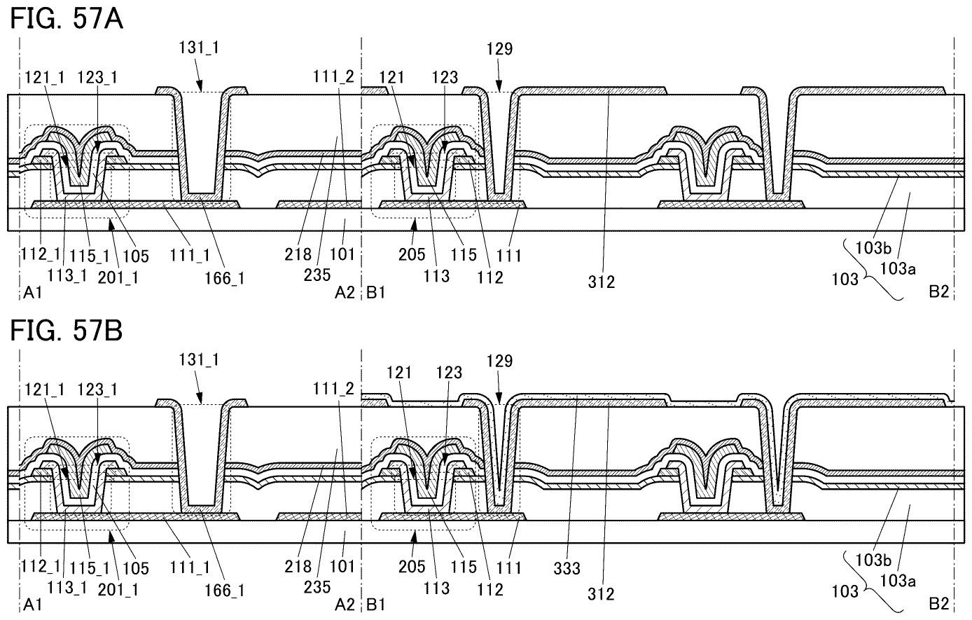

Next, the island-shaped conductive layer 166 and the island-shaped pixel electrode 312 are formed (FIG. 57A). The conductive layer 166 and the pixel electrode 312 can be formed by a method similar to that for the conductive layer 166 and the pixel electrode 311 illustrated in FIG. 51A.

### Formation of Alignment Layer 333

Then, the alignment layer 333 is formed to cover the pixel electrode 312 (FIG. 57B). The alignment layer 333 can be formed by forming a thin film of a resin or the like and then performing rubbing treatment.

The alignment layer 333 is formed over the entire surface of the substrate 101, for example, and then partly removed by a photolithography method and an etching method, or the like. Thus, the surface of the conductive layer 166 is exposed.

### Formation of Light-Blocking Layer 317 and Coloring Layer 183

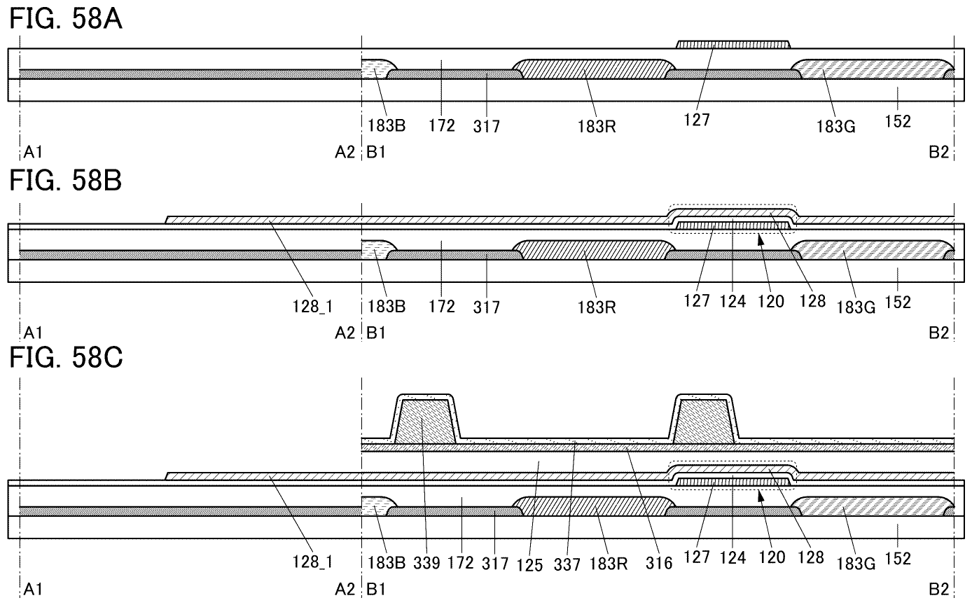

Next, the light-blocking layer 317 and the coloring layer 183 (the coloring layer 183R, the coloring layer 183G, and the coloring layer 183B) are formed over the substrate 152 (FIG. 58A). The light-blocking layer 317 and the coloring layer 183 can be formed by a spin coating method or an inkjet method, for example.

### Formation of Insulating Layer 172

Subsequently, the insulating layer 172 is formed over the light-blocking layer 317, the coloring layer 183, and the substrate 152 (FIG. 58A). For formation of the insulating layer 172, a PECVD method can be favorably used, for example.

Next, by methods similar to those illustrated in FIG. 52A and FIG. 52B, the sensing element 120 is formed (FIG. 58A and FIG. 58B). After that, by a method similar to that illustrated in FIG. 52C, the insulating layer 125 is formed (FIG. 58C).

### Formation of Common Electrode 316

Then, the common electrode 316 is formed over the insulating layer 125 (FIG. 58C). The common electrode 316 can be formed by a sputtering method, a vacuum evaporation method, or the like.

### Formation of Insulating Layer 339

Next, the insulating layer 339 functioning as a spacer is formed over the common electrode 316 (FIG. 58C). The insulating layer 339 can be formed by a dry spraying method or a wet spraying method, for example.

### Formation of Alignment Layer 337

Then, the alignment layer 337 is formed to cover the insulating layer 339 (FIG. 58C). The alignment layer 337 can be formed by a method similar to that for the alignment layer 333.

### Bonding of Substrate 101 and Substrate 152

Subsequently, the substrate 101 and the substrate 152 are bonded to each other with the adhesive layer 142 including the conductive particle 165. Specifically, the insulating layer 235 and the conductive layer 166 over the substrate 101 are bonded to the electrode 128 and the insulating layer 124 over the substrate 152 with the adhesive layer 142 including the conductive particle 165. The substrate 101 and the substrate 152 can be bonded to each other by a method similar to the method described in <Manufacturing method example 1 of touch panel>.

Then, the liquid crystal 335 is provided between the alignment layer 333 illustrated in FIG. 57B and the alignment layer 337 illustrated in FIG. 58C. The liquid crystal 335 can be provided by a liquid crystal injection method or a liquid crystal dropping method, for example. In the case of using a liquid crystal injection method, after the substrate 101 and the substrate 152 are bonded to each other with the adhesive layer 142 including the conductive particle 165, the liquid crystal 335 is injected between the alignment layer 333 and the alignment layer 337. In the case of using a liquid crystal dropping method, first, the adhesive layer 142 including the conductive particle 165 is drawn over the insulating layer 235 and the conductive layer 166 illustrated in FIG. 57B or over the electrode 128 and the insulating layer 124 illustrated in FIG. 58C. Next, the liquid crystal 335 is dropped onto a region surrounded by the adhesive layer 142. After that, the substrate 101 and the substrate 152 are bonded to each other.

Through the above steps, the touch panel 10 having the structure illustrated in FIG. 7 can be manufactured.

### Manufacturing Method Example 3 of Touch Panel

A manufacturing method different from that described in <Manufacturing method example 1 of touch panel> above will be described below. Note that descriptions overlapping with <Manufacturing method example 1 of touch panel> will be omitted as appropriate, and differences will be mainly described.

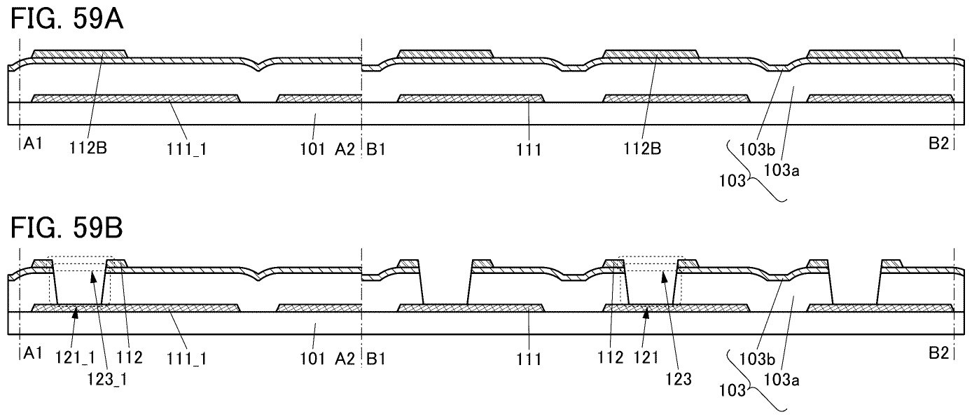

FIG. 59A and FIG. 59B are diagrams illustrating an example of a method for manufacturing the touch panel 10 having the structure illustrated in FIG. 6.

First, as in <Manufacturing method example 1 of touch panel>, the steps up to the formation of the conductive film 112f are performed. The description of FIG. 47A to FIG. 47C can be referred to for the steps up to the formation of the conductive film 112f; thus, the detailed description thereof is omitted.

Next, the conductive film 112f is processed, thereby forming a conductive layer 112B (FIG. 59A). Here, the opening 123 is not necessarily formed in the conductive layer 112B. For the formation of the conductive layer 112B, one or both of a wet etching method and a dry etching method can be used, for example, and a wet etching method can be suitably used.

Then, the conductive layer 112B in part of a region that overlaps the conductive layer 111 is removed, whereby the conductive layer 112 including the opening 123 is formed (FIG. 59B).

Subsequently, the insulating layer 103 (the insulating layer 103a and the insulating layer 103b) in part of a region that overlaps the conductive layer 111 is removed. Thus, the opening 121 is formed in the insulating layer 103 (FIG. 59B).

The description in <Manufacturing method example 1 of touch panel>can be referred to for the formation of the opening 121 and the opening 123; thus, the detailed description thereof is omitted.

Subsequently, the semiconductor film 113f to be the semiconductor layer 113 is formed to cover the opening 121 and the opening 123 (FIG. 48B). The above description in <Manufacturing method example 1 of touch panel> can be referred to for the steps after the formation of the semiconductor film 113f; thus, the detailed description thereof is omitted.

Through the above steps, the touch panel 10 having the structure illustrated in FIG. 6 can be manufactured.

### Manufacturing Method Example 4 of Touch Panel

A manufacturing method different from that described in <Manufacturing method example 2 of touch panel> above will be described below. Note that descriptions overlapping with the above will be omitted as appropriate, and differences will be mainly described.

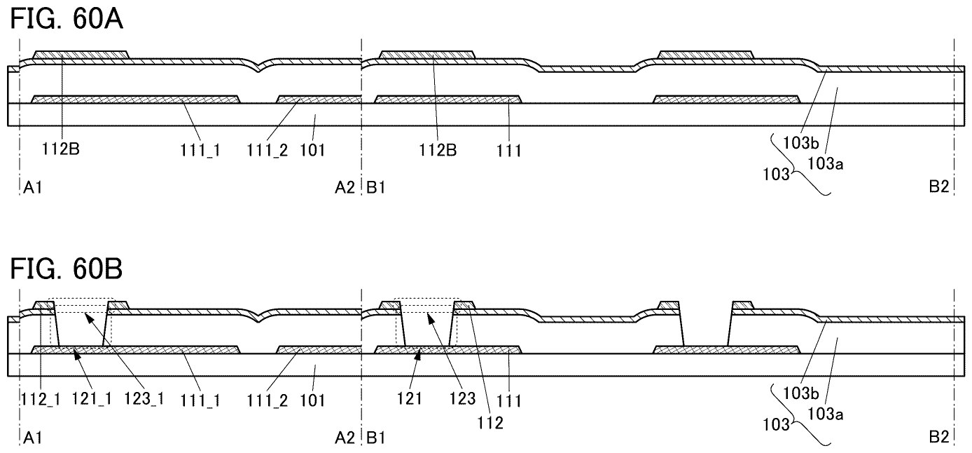

FIG. 60A and FIG. 60B are diagrams illustrating an example of a method for manufacturing the touch panel 10 having the structure illustrated in FIG. 7.

First, as in <Manufacturing method example 2 of touch panel>, the steps up to the formation of the conductive film 112f are performed. Next, by a method similar to that illustrated in FIG. 59A, the conductive layer 112B is formed (FIG. 60A). Then, the conductive layer 112 including the opening 123 is formed by a method similar to that illustrated in FIG. 59B. After that, the opening 121 is formed in the insulating layer 103 (FIG. 60B).

Subsequently, the semiconductor film 113f to be the semiconductor layer 113 is formed to cover the opening 121 and the opening 123 (FIG. 54B). The above description in <Manufacturing method example 2 of touch panel> can be referred to for the steps after the formation of the semiconductor film 113f; thus, the detailed description thereof is omitted.

Through the above steps, the touch panel 10 having the structure illustrated in FIG. 7 can be manufactured.

The plurality of structure examples described in this embodiment can be combined with each other as appropriate. This embodiment can be combined with the other embodiments as appropriate.

### Embodiment 2

In this embodiment, a transistor included in the touch panel of one embodiment of the present invention will be described with reference to drawings. Specifically, structure examples different from those of the transistors described in Embodiment 1 will be described with reference to drawings.

A transistor having a structure that will be described in this embodiment is denoted as a transistor 50. The transistor 50 can be used as a transistor included in the touch panel of one embodiment of the present invention, such as the transistor 201 and the transistor 205 described in Embodiment 1.

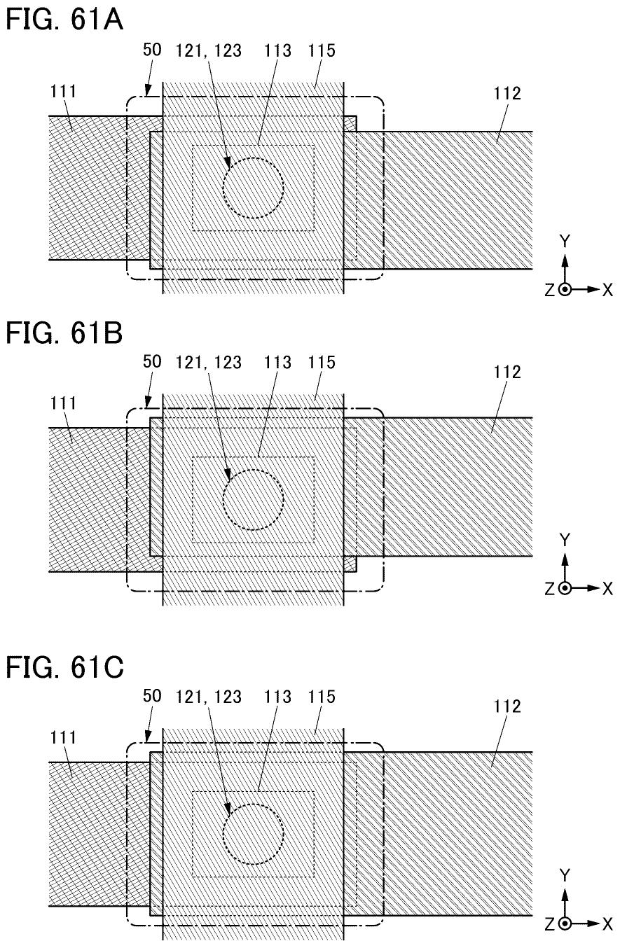

In the transistor illustrated in FIG. 10A, the end portion of the conductive layer 112 in the Y direction and the end portion of the conductive layer 112 in the-Y direction when seen from the opening 123 both include a region overlapping the conductive layer 111 in the plan view. In other words, the end portion of the conductive layer 112 in the Y direction when seen from the opening 123 is positioned inward from the end portion of the conductive layer 111 in the Y direction when seen from the opening 123, and the end portion of the conductive layer 112 in the −Y direction when seen from the opening 123 is positioned inward from the end portion of the conductive layer 111 in the −Y direction when seen from the opening 123; however, one embodiment of the present invention is not limited thereto. FIG. 61A illustrates an example in which the end portion of the conductive layer 112 in the −Y direction when seen from the opening 123 does not overlap the conductive layer 111 in the plan view. In other words, in the example illustrated in FIG. 61A, the end portion of the conductive layer 112 in the −Y direction when seen from the opening 123 is positioned outward from the end portion of the conductive layer 111 in the −Y direction when seen from the opening 123.

FIG. 61B illustrates an example in which the end portion of the conductive layer 112 in the Y direction when seen from the opening 123 does not overlap the conductive layer 111 in the plan view. In other words, in the example illustrated in FIG. 61B, the end portion of the conductive layer 112 in the Y direction when seen from the opening 123 is positioned outward from the end portion of the conductive layer 111 in the Y direction when seen from the opening 123.

In this embodiment, the direction in which the conductive layer 111 extends is referred to as the X direction, and directions perpendicular to the X direction are referred to as the Y direction and the Z direction. The Z direction represents a height direction.

FIG. 61C illustrates an example in which the end portion of the conductive layer 112 in the Y direction and the end portion of the conductive layer 112 in the-Y direction when seen from the opening 123 both do not overlap the conductive layer 111 in the plan view. In other words, in the example illustrated in FIG. 61C, the end portion of the conductive layer 112 in the Y direction when seen from the opening 123 is positioned outward from the end portion of the conductive layer 111 in the Y direction when seen from the opening 123. Moreover, the end portion of the conductive layer 112 in the −Y direction when seen from the opening 123 is positioned outward from the end portion of the conductive layer 111 in the−Y direction when seen from the opening 123.

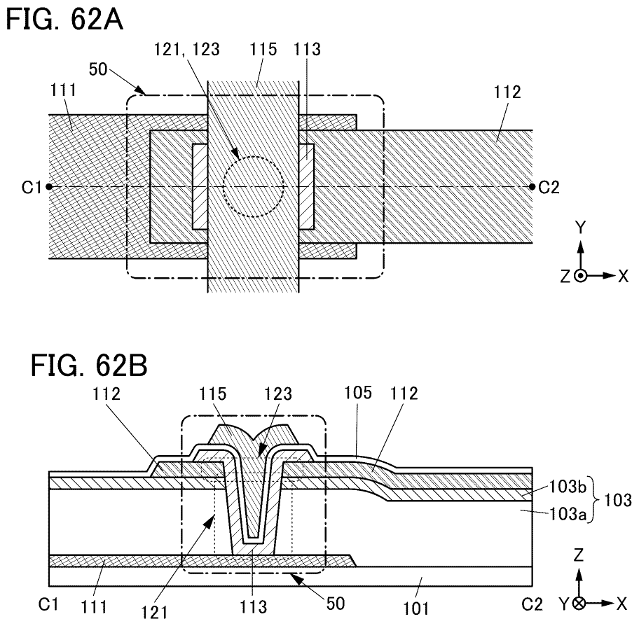

FIG. 10B can be referred to for a cross-sectional structure example of the transistor 50 FIG. 62A shows a variation example of the structure illustrated in FIG. 10A, and FIG. 62B is a cross-sectional view along the dashed-dotted line C1-C2 in FIG. 62A. FIG. 62A and FIG. 62B illustrate an example in which in the X direction, an end portion of the conductive layer 115 is positioned inward from the end portion of the semiconductor layer 113, that is, on the opening 123 side. In the example illustrated in FIG. 62A and FIG. 62B, the semiconductor layer 113 includes a region not overlapped by the conductive layer 115. With such a structure, the area of a region where the conductive layer 115 and the conductive layer 112 overlap each other can be small. Thus, parasitic capacitance can be reduced.

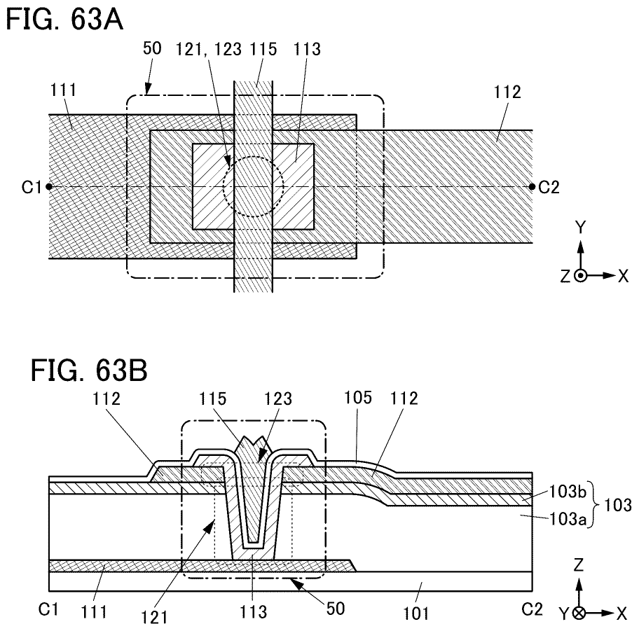

FIG. 63A shows a variation example of the structure illustrated in FIG. 62A, and FIG. 63B is a cross-sectional view along the dashed-dotted line C1-C2 in FIG. 63A. FIG. 63A and FIG. 63B illustrate an example in which in the X direction, the end portion of the conductive layer 115 is positioned inward from the end portion of the conductive layer 112 on the opening 123 side. In the example illustrated in FIG. 63A and FIG. 63B, the opening 121 and the opening 123 each include a region not overlapped by the conductive layer 115. With such a structure, the area of the region where the conductive layer 115 and the conductive layer 112 overlap each other can be further reduced. Thus, parasitic capacitance can be further reduced.

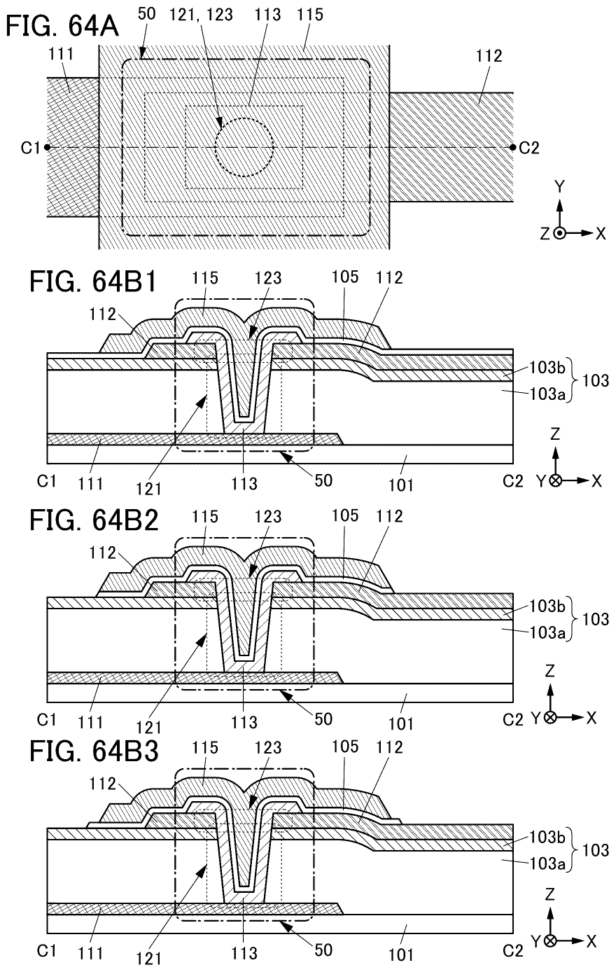

FIG. 64A shows a variation example of the structure illustrated in FIG. 10A, and FIG. 64B1 is a cross-sectional view along the dashed-dotted line C1-C2 in FIG. 64A. FIG. 64A and FIG. 64B1 illustrate an example in which the end portion of the conductive layer 115 in the X direction is positioned outward from the end portion of the conductive layer 112 in a region where the conductive layer 111 and the conductive layer 112 overlap each other. In the example illustrated in FIG. 64A and FIG. 64B1, the conductive layer 115 covers the entire region where the conductive layer 111 and the conductive layer 112 overlap each other. With such a structure, when the conductive layer 115 is formed by a photolithography method and an etching method, for example, the alignment accuracy of a photomask is not necessarily high. Thus, the transistor 50 can be easily manufactured.

FIG. 64B2 shows a variation example of the structure illustrated in FIG. 64B1 and illustrates an example in which an end portion of the top surface of the insulating layer 105 is aligned or substantially aligned with an end portion of the bottom surface of the conductive layer 115. For example, in the case where the conductive layer 115 is formed by a photolithography method and an etching method and the insulating layer 105 has low etching selectivity with respect to the conductive layer 115, the structure illustrated in FIG. 64B2 may be formed.

FIG. 64B3 shows a variation example of the structure illustrated in FIG. 64B2 and illustrates an example in which the end portion of the bottom surface of the conductive layer 115 is positioned inward from the end portion of the top surface of the insulating layer 105, that is, on the conductive layer 112 side. For example, in the case where the etching rate of the conductive layer 115 in the X direction is higher than the etching rate of the insulating layer 105 in the X direction, the structure illustrated in FIG. 64B3 may be formed.

Note that FIG. 64a can be referred to for a plan view of the structures illustrated in FIG. 64B2 and FIG. 64B3.

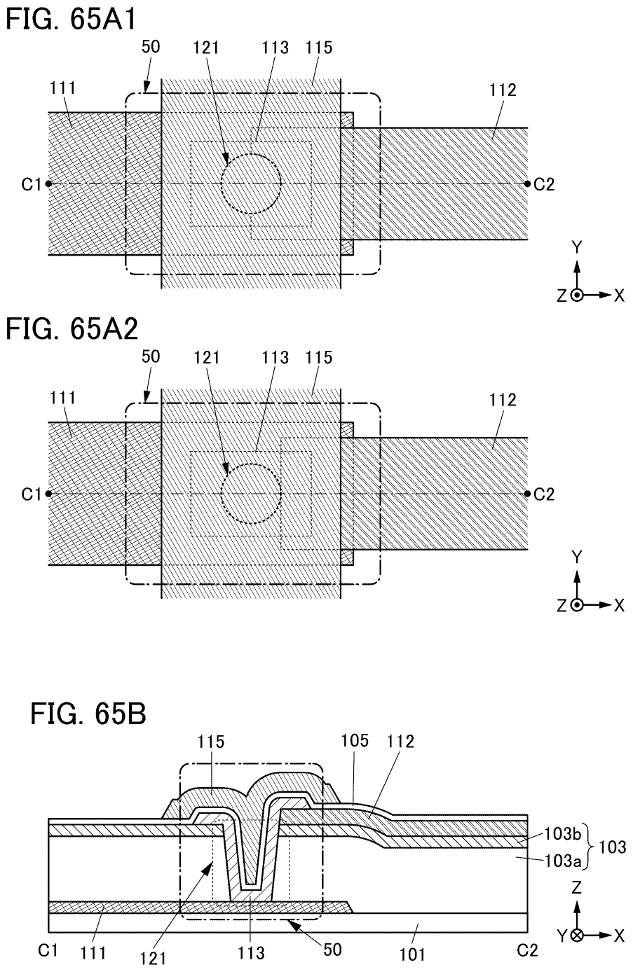

FIG. 65A1 shows a variation example of the structure illustrated in FIG. 10A and illustrates an example in which the conductive layer 112 surrounds the periphery of the opening 121 not entirely but partly in the plan view. FIG. 65A2 shows a variation example of the structure illustrated in FIG. 65A1 and illustrates an example in which the end portion of the conductive layer 112 is in contact with one point of the periphery of the opening 121 in the plan view. In the example illustrated in FIG. 65A2, the opening 121 has a circular shape and one of end portions of the conductive layer 112 extending in the Y direction is a tangent of the opening 121 in the plan view. FIG. 65B is a cross-sectional view along the dashed-dotted line C1-C2 in FIG. 65A1 and FIG. 65A2.

In the examples illustrated in FIG. 65A1, FIG. 65A2, and FIG. 65B, the area of the region where the conductive layer 112 and the conductive layer 115 overlap each other can be small. Thus, parasitic capacitance can be reduced. Meanwhile, in the examples illustrated in FIG. 10A and FIG. 10B and the like, the width of the other of the source region and the drain region can be increased.

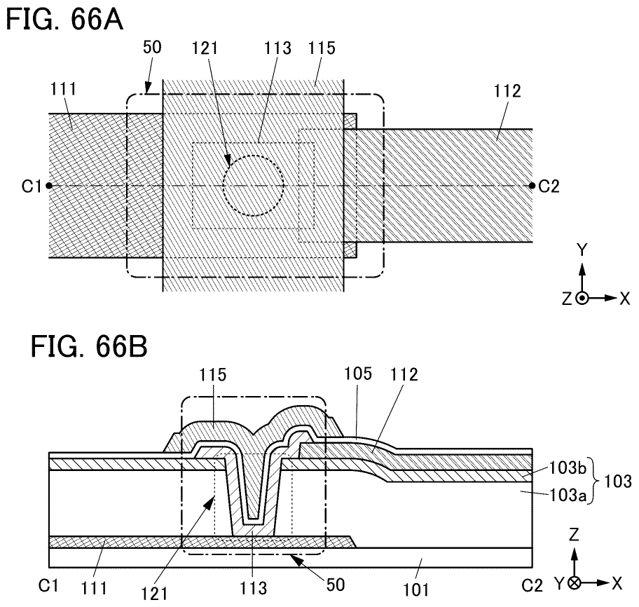

FIG. 66A shows a variation example of the structures illustrated in FIG. 65A1 and FIG. 65A2 and illustrates an example in which the conductive layer 112 does not cover the opening 121 and the conductive layer 112 is not in contact with the opening 121 in the plan view. FIG. 66B is a cross-sectional view along the dashed-dotted line C1-C2 in FIG. 66A.

In the example illustrated in FIG. 66A and FIG. 66B, the area of the region where the conductive layer 112 and the conductive layer 115 overlap each other can be further reduced. Thus, parasitic capacitance can be further reduced.

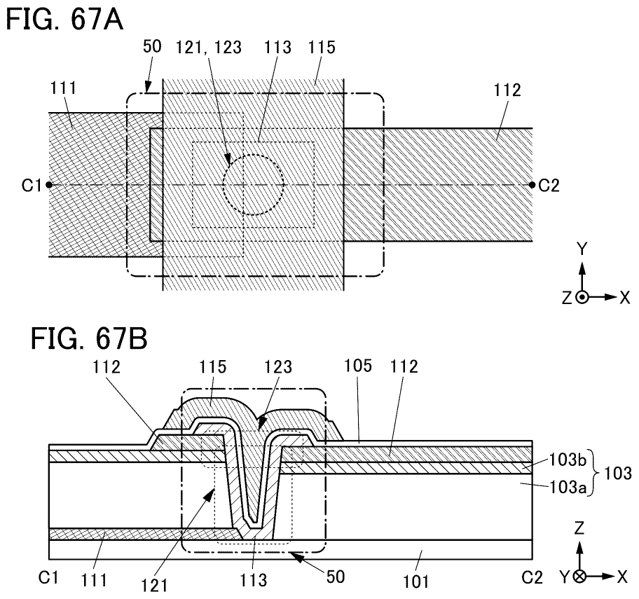

FIG. 67A shows a variation example of the structure illustrated in FIG. 10A and illustrates an example in which the conductive layer 111 is overlapped by not the whole but part of the opening 121. FIG. 67B is a cross-sectional view along the dashed-dotted line C1-C2 in FIG. 67A. In the example illustrated in FIG. 67A and FIG. 67B, the semiconductor layer 113 includes a region not overlapping the conductive layer 111 in the opening 121.

In the example illustrated in FIG. 67A and FIG. 67B, parasitic capacitance between the conductive layer 111 and the conductive layer 115 can be small, for example. Meanwhile, in the examples illustrated in FIG. 10A and FIG. 10B and the like, the width of one of the source region and the drain region can be increased.

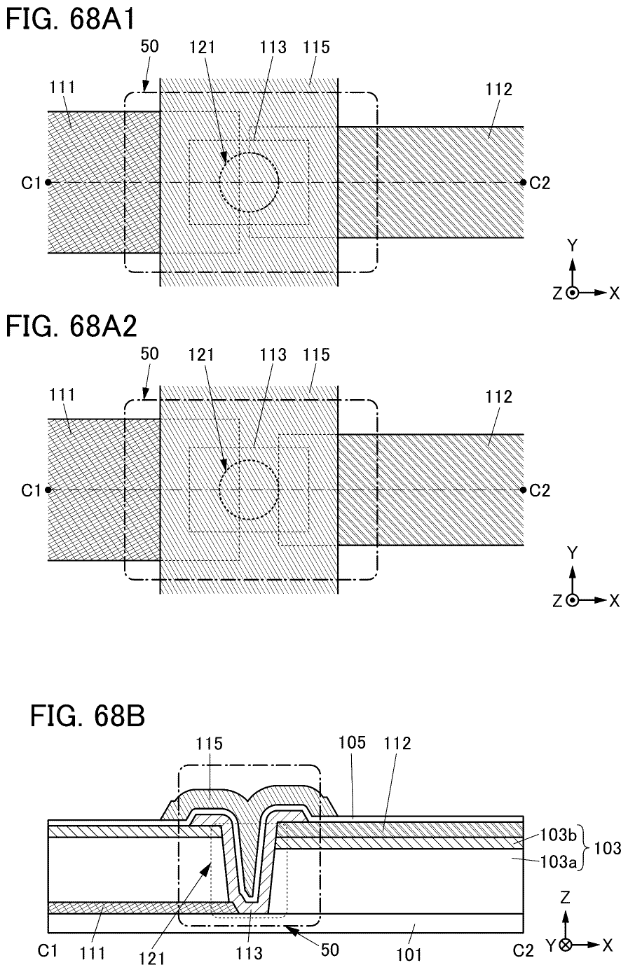

FIG. 68A1 shows a variation example of the structure illustrated in FIG. 67A and illustrates an example in which the conductive layer 112 surrounds the periphery of the opening 121 not entirely but partly in the plan view. FIG. 68A2 shows a variation example of the structure illustrated in FIG. 68A1 and illustrates an example in which the end portion of the conductive layer 112 is in contact with one point of the periphery of the opening 121 in the plan view. In the example illustrated in FIG. 68A2, the opening 121 has a circular shape and one of end portions of the conductive layer 112 extending in the Y direction is a tangent of the opening 121 in the plan view. FIG. 68B is a cross-sectional view along the dashed-dotted line C1-C2 in FIG. 68A1 and FIG. 68A2.

In the examples illustrated in FIG. 68A1, FIG. 68A2, and FIG. 68B, the area of the region where the conductive layer 112 and the conductive layer 115 overlap each other can be small. Thus, parasitic capacitance can be reduced. Meanwhile, in the examples illustrated in FIG. 67A and FIG. 67B and the like, the width of the other of the source region and the drain region can be increased.

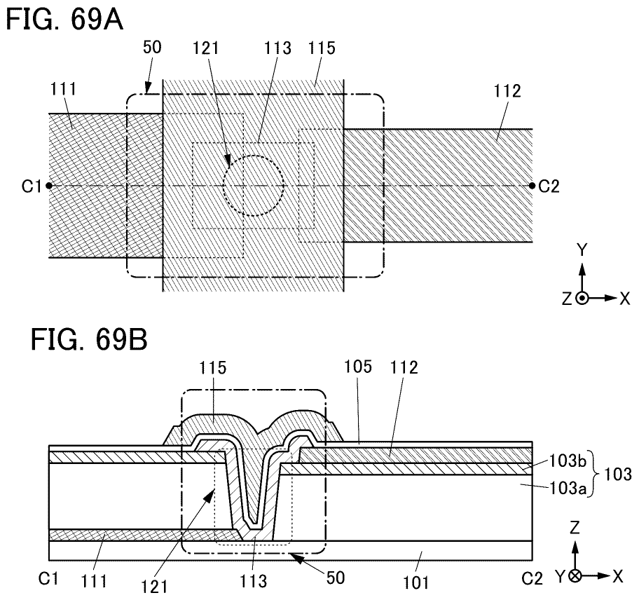

FIG. 69A shows a variation example of the structures illustrated in FIG. 68A1 and FIG. 68A2 and illustrates an example in which the conductive layer 112 does not overlap the opening 121. FIG. 69B is a cross-sectional view along the dashed-dotted line C1-C2 in FIG. 69A.

In the example illustrated in FIG. 69A and FIG. 69B, the area of the region where the conductive layer 112 and the conductive layer 115 overlap each other can be further reduced. Thus, parasitic capacitance can be further reduced.

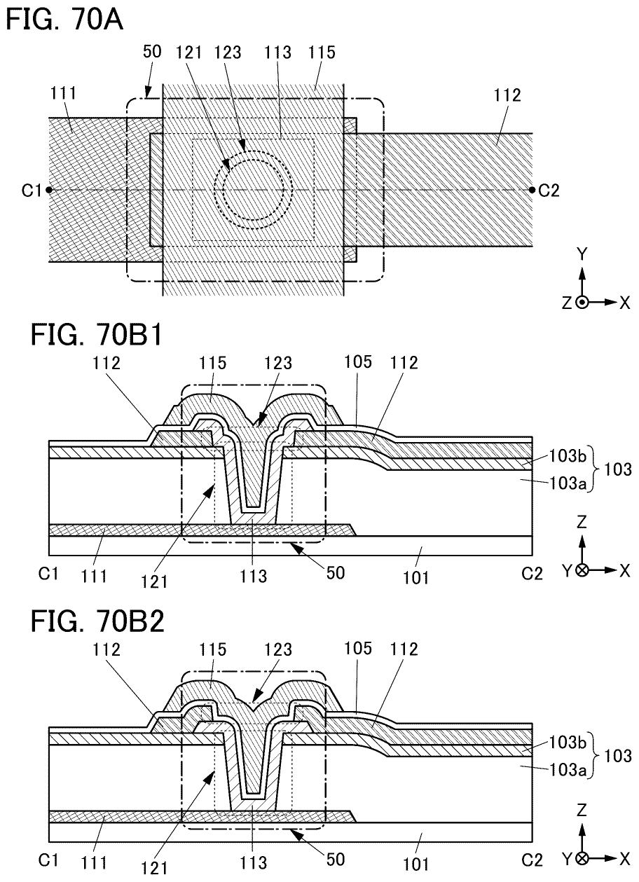

FIG. 70A shows a variation example of the structure illustrated in FIG. 10A and illustrates an example in which the planar shape of the opening 121 and the planar shape of the opening 123 are not the same. In the example illustrated in FIG. 70A, the opening 123 has a circular planar shape with a radius larger than that of the opening 121. Note that one or both of the opening 121 and the opening 123 do not necessarily have a circular planar shape. Specifically, one or both of the opening 121 and the opening 123 can have the above-described planar shape, such as a rectangular planar shape with rounded corners. FIG. 70B1 is a cross-sectional view along the dashed-dotted line C1-C2 in FIG. 70A.

For example, in the case where the opening 121 and the opening 123 are formed in different steps, the opening 121 and the opening 123 may have the shapes illustrated in FIG. 70A and FIG. 70B1. In the case where the opening 121 and the opening 123 are formed in the same step but the etching rate of the conductive layer 112 in the X direction and the Y direction is different from the etching rate of the insulating layer 103 in the X direction and the Y direction, for example, the opening 121 and the opening 123 may have the shapes illustrated in FIG. 70A and FIG. 70B1. For example, in the case where the etching rate of the conductive layer 112 in the X direction and the Y direction is higher than the etching rate of the insulating layer 103 in the X direction and the Y direction, the opening 121 and the opening 123 may have the shapes illustrated in FIG. 70A and FIG. 70B1 even though being formed in the same step.

FIG. 70B2 shows a variation example of the structure illustrated in FIG. 70B1 and illustrates an example in which the top surface of the semiconductor layer 113 includes a region in contact with the conductive layer 112. The structure illustrated in FIG. 70B2 can be formed by, for example, forming the opening 121 in the insulating layer 103, forming the semiconductor layer 113, forming a film to be the conductive layer 112, and then forming the opening 123 in the film.

As described above, the channel width of the transistor 50 can be equal to the perimeter of the opening 123 in the plan view. Thus, when the opening 123 has a larger area than the opening 121, for example, the transistor 50 can have a large channel width in some cases. Meanwhile, when the area of the opening 123 is equal to the area of the opening 121, for example, the transistor 50 can be miniaturized in some cases.

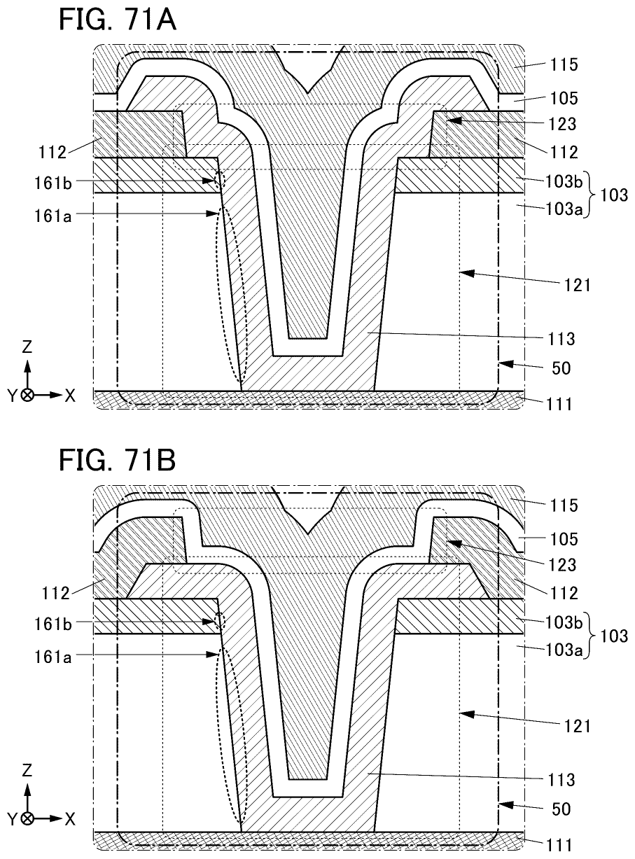

FIG. 71A is an enlarged view illustrating the structure example of the transistor 50 illustrated in FIG. 70B1 and its vicinity, and FIG. 71B is an enlarged view illustrating the structure example of the transistor 50 illustrated in FIG. 70B2 and its vicinity. As illustrated in FIG. 71A and FIG. 71B, the side surface of the insulating layer 103a on the opening 121 side includes a tapered portion 161a, and the side surface of the insulating layer 103b on the opening 121 side includes a tapered portion 161b.

As illustrated in FIG. 71A and FIG. 71B, an end portion of the top surface of the insulating layer 103a on the opening 121 side can be aligned or substantially aligned with an end portion of the bottom surface of the insulating layer 103b on the opening 121 side. Furthermore, the taper angle of the tapered portion 161a can be equal to or substantially equal to the taper angle of the tapered portion 161b. Here, the taper angle of the side surface of the conductive layer 112 on the opening 123 side may be larger or smaller than the taper angles of the tapered portion 161a and the tapered portion 161b. Moreover, the taper angle of the side surface of the conductive layer 112 on the opening 123 side may be equal to or substantially equal to the taper angles of the tapered portion 161a and the tapered portion 161b.

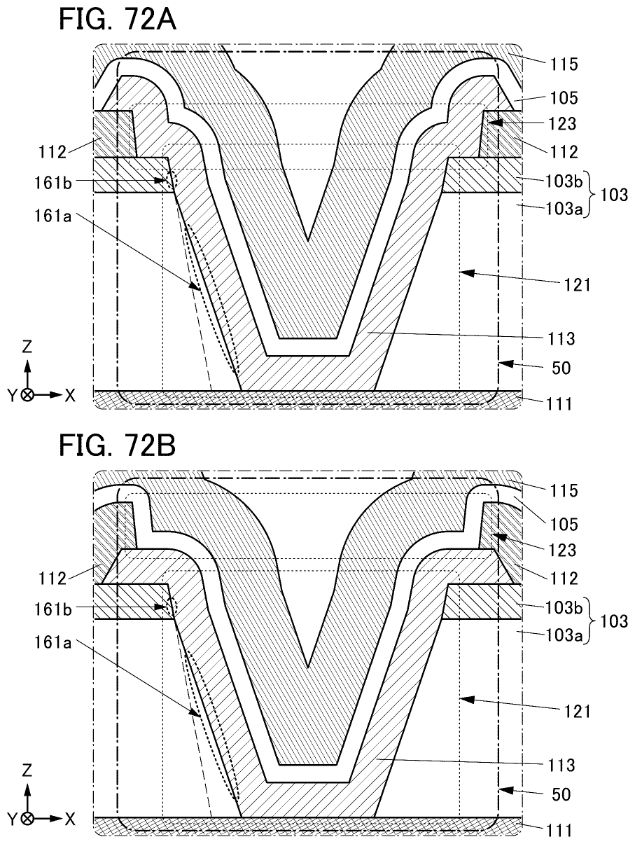

FIG. 72A and FIG. 72B show variation examples of the structures illustrated in FIG. 71A and FIG. 71B, respectively, and illustrate examples in which the tapered portion 161a and the tapered portion 161b have different taper angles. In FIG. 72A and FIG. 72B, a straight line that extends from the tapered portion 161b to the insulating layer 103a side is indicated by a dashed line. For example, in the case where the insulating layer 103a and the insulating layer 103b include different materials and thus have different processabilities, the tapered portion 161a and the tapered portion 161b have different taper angles in some cases.

FIG. 72A and FIG. 72B illustrate examples in which the taper angle of the tapered portion 161a is smaller than the taper angle of the tapered portion 161b. The taper angle of the tapered portion 161a may be larger than the taper angle of the tapered portion 161b. Here, the taper angle of the side surface of the conductive layer 112 on the opening 123 side may be larger or smaller than the taper angle of the tapered portion 161a and may be larger or smaller than the taper angle of the tapered portion 161b. Furthermore, the taper angle of the side surface of the conductive layer 112 on the opening 123 side may be equal to or substantially equal to the taper angle of the tapered portion 161a and may be equal to or substantially equal to the taper angle of the tapered portion 161b.

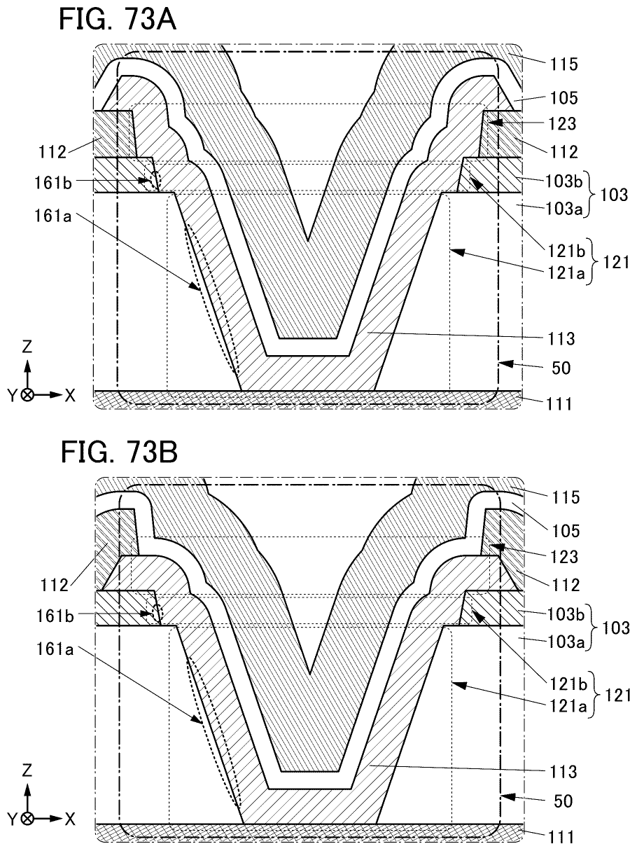

FIG. 73A and FIG. 73B show variation examples of the structures illustrated in FIG. 71A and FIG. 71B, respectively, and illustrate examples in which the end portion of the top surface of the insulating layer 103a is not aligned with the end portion of the bottom surface of the insulating layer 103b, specifically, examples in which an end portion of the insulating layer 103b on the opening 121 side is positioned outward from an end portion of the insulating layer 103a on the opening 121 side. In FIG. 73A and FIG. 73B, the opening 121 provided in the insulating layer 103a is denoted as an opening 121a, and the opening 121 provided in the insulating layer 103b is denoted as an opening 121b.

For example, in the case where the etching rate of the insulating layer 103a in the X direction is different from the etching rate of the insulating layer 103b in the X direction, the end portion of the top surface of the insulating layer 103a is sometimes not aligned with the end portion of the bottom surface of the insulating layer 103b. Specifically, in the case where the etching rate of the insulating layer 103b in the X direction is higher than the etching rate of the insulating layer 103a in the X direction, the structure illustrated in FIG. 73A or FIG. 73B may be formed. Here, the taper angle of the tapered portion 161a and the taper angle of the tapered portion 161b may be equal to, substantially equal to, or different from each other. In addition, the taper angle of the side surface of the conductive layer 112 on the opening 123 side may be larger or smaller than the taper angle of the tapered portion 161a and may be larger or smaller than the taper angle of the tapered portion 161b. The taper angle of the side surface of the conductive layer 112 on the opening 123 side may be equal to or substantially equal to the taper angle of the tapered portion 161a and may be equal to or substantially equal to the taper angle of the tapered portion 161b.

The taper angles of the tapered portion 161a, the tapered portion 161b, and the side surface of the conductive layer 112, the positional relation between the end portions of the insulating layer 103a, the insulating layer 103b, and the conductive layer 112, and the like described with reference to FIG. 71A to FIG. 73B are applicable to all the structures described in this specification and the like.

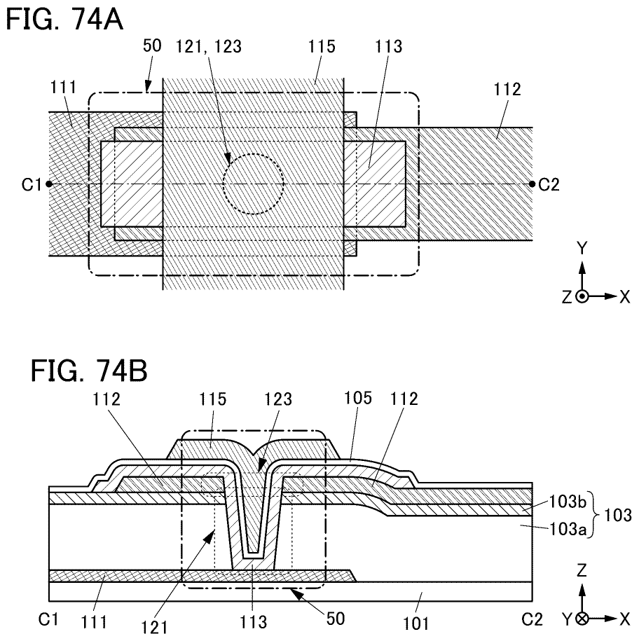

FIG. 74A shows a variation example of the structure illustrated in FIG. 10A and illustrates an example in which the semiconductor layer 113 extends in the X direction beyond an end portion of the conductive layer 112 that does not face the opening 123. FIG. 74B is a cross-sectional view along the dashed-dotted line C1-C2 in FIG. 74A.

In the example illustrated in FIG. 74B, when seen from the XZ plane, the semiconductor layer 113 covers the end portion of the conductive layer 112 that does not face the opening 123. The semiconductor layer 113 can include a region in contact with the top surface of the insulating layer 103.

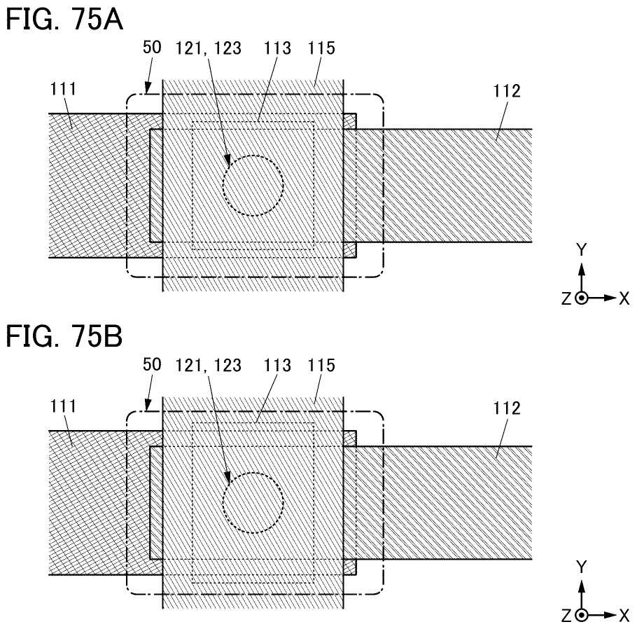

FIG. 75A shows a variation example of the structure illustrated in FIG. 10A and illustrates an example in which the end portion of the semiconductor layer 113 is positioned outward from the end portion of the conductive layer 112 and inward from the end portion of the conductive layer 111 in the Y direction. In the example illustrated in FIG. 75A, the end portion of the semiconductor layer 113 overlaps the conductive layer 111 but does not overlap the conductive layer 112 in the Y direction.

FIG. 75B shows a variation example of the structure illustrated in FIG. 10A and illustrates an example in which the end portion of the semiconductor layer 113 is positioned outward from the end portion of the conductive layer 112 and the end portion of the conductive layer 111 in the Y direction. In the example illustrated in FIG. 75B, the end portion of the semiconductor layer 113 overlaps neither the conductive layer 111 nor the conductive layer 112 in the Y direction.

FIG. 10B can be referred to for a cross-sectional structure example of the transistor 50 illustrated in FIG. 75A and FIG. 75B.

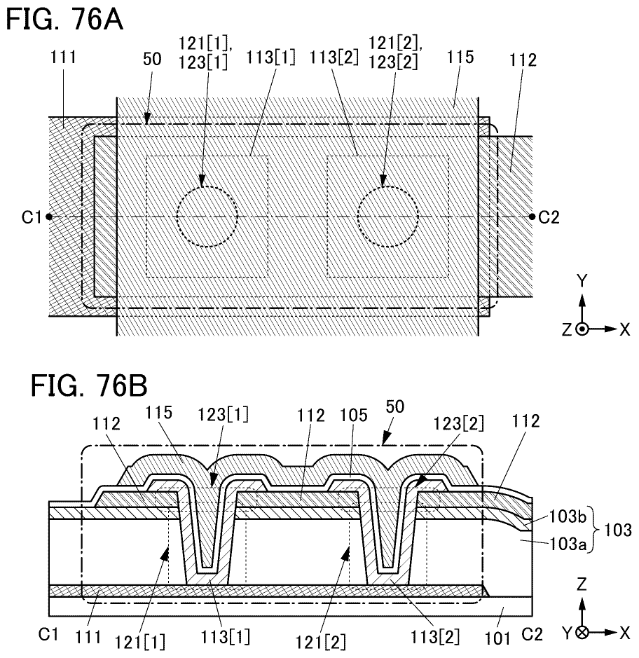

FIG. 76A illustrates an example in which the transistor 50 includes two openings 121 and two openings 123 that are arranged in the X direction. FIG. 76B is a cross-sectional view along the dashed-dotted line C1-C2 in FIG. 76A. Here, in the description of the structure in which one transistor 50 includes a plurality of openings 121 and a plurality of openings 123, the X direction and the Y direction are respectively referred to as the row direction and the column direction in some cases.

In FIG. 76A and FIG. 76B, the two openings 121 are denoted as an opening 121[1] and an opening 121[2] to be distinguished from each other, and the two openings 123 are denoted as an opening 123[1] and an opening 123[2] to be distinguished from each other. In the example illustrated in FIG. 76A and FIG. 76B, the semiconductor layer 113 provided in the opening 121[1] and the opening 123[1] is different from the semiconductor layer 113 provided in the opening 121[2] and the opening 123[2], and the two semiconductor layers 113 are denoted as a semiconductor layer 113[1] and a semiconductor layer 113[2] to be distinguished from each other. The same applies to the following drawings in some cases.

When the number of openings 121 and openings 123 provided in the transistor 50 is increased, the total of the perimeters of the openings 121 and the openings 123 in a plan view can be increased in some cases. As described above, the channel width of the transistor 50 can be equal to the perimeter of the opening 123 in a plan view, for example. Thus, the transistor 50 including a plurality of openings 121 and a plurality of openings 123 can have a large channel width in some cases. Meanwhile, the transistor 50 including a small number of openings 121 and openings 123 can be easily manufactured and miniaturized in some cases.

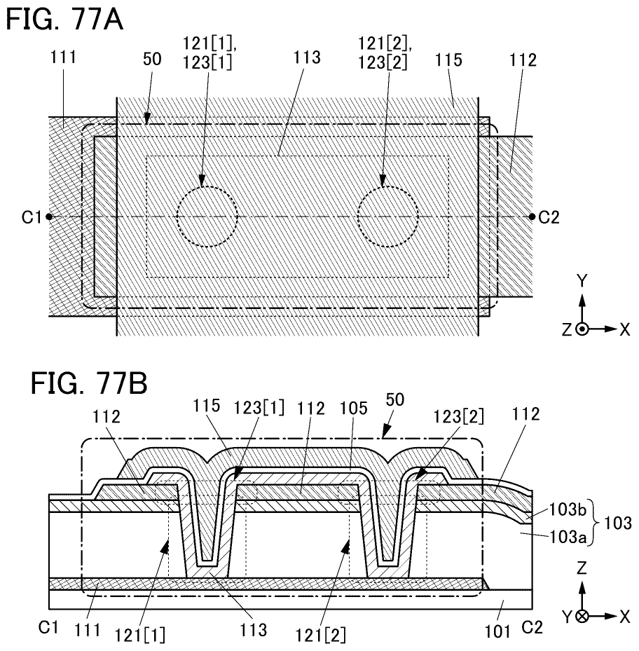

FIG. 77A shows a variation example of the structure illustrated in FIG. 76A and illustrates an example in which the semiconductor layer 113 provided in the opening 121[1] and the opening 123[1] is the same as the semiconductor layer 113 provided in the opening 121[2] and the opening 123[2]. That is, in the example illustrated in FIG. 77A, the transistor 50 includes two openings 121, two openings 123, and one semiconductor layer 113. FIG. 77B is a cross-sectional view along the dashed-dotted line C1-C2 in FIG. 77A.

In the structure illustrated in FIG. 77A and FIG. 77B, for example, when the semiconductor layer 113 is formed by a photolithography method and an etching method, the alignment accuracy of a photomask can be low. Thus, the transistor 50 can be easily manufactured. Meanwhile, in the structure illustrated in FIG. 76A and FIG. 76B, the surface area of the semiconductor layer 113 can be reduced; hence, entry of impurities into the semiconductor layer 113 can be inhibited in some cases.

Note that the transistor 50 illustrated in FIG. 76A or FIG. 77A may include three or more openings 121 and three or more openings 123. A plurality of the openings 121 and a plurality of the openings 123 are not necessarily arranged in the X direction and may be arranged in the Y direction or in a zigzag manner, for example.

The plurality of structure examples described in this embodiment can be combined with each other as appropriate. This embodiment can be combined with the other embodiments as appropriate.

### Embodiment 3

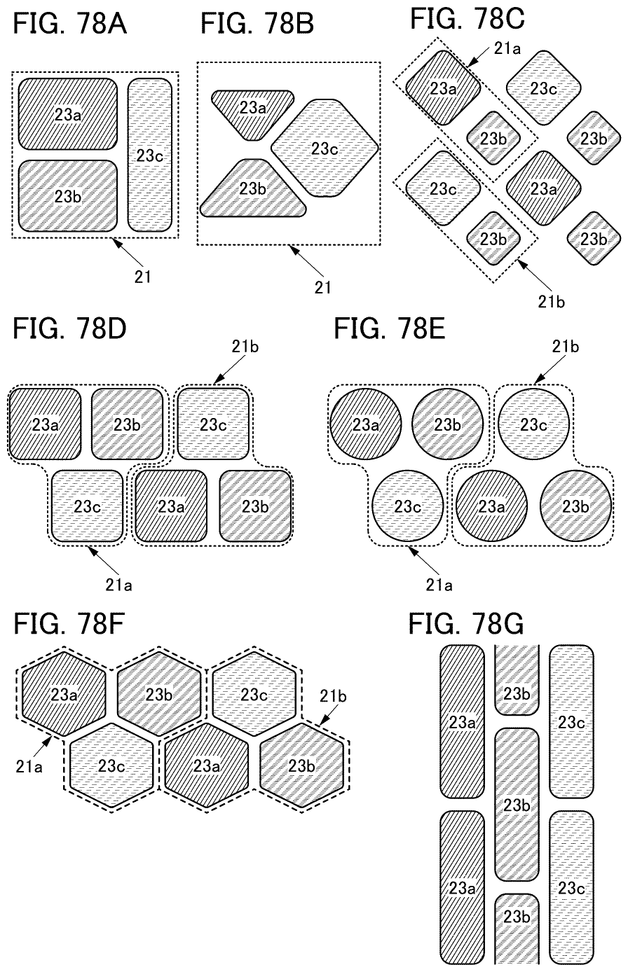

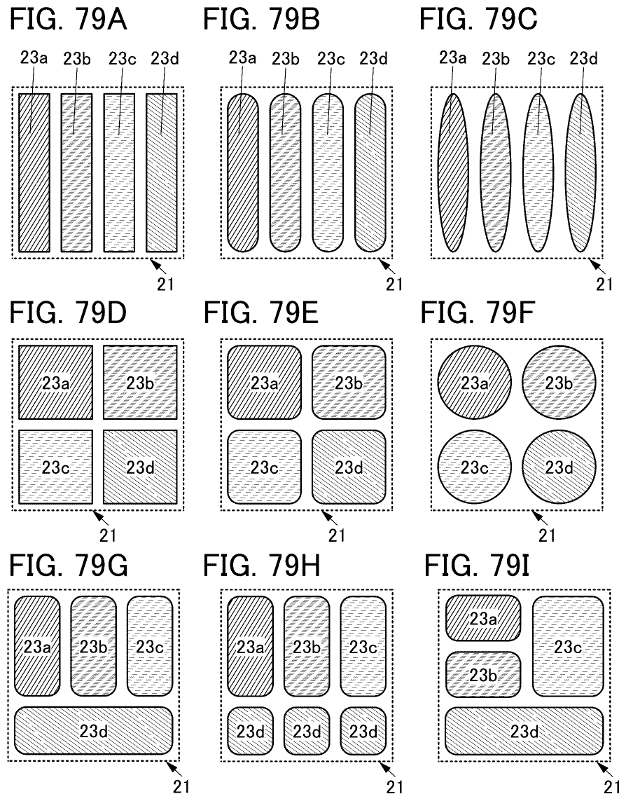

In this embodiment, structure examples of pixels included in the touch panel of one embodiment of the present invention will be described with reference to FIG. 78A to FIG. 78G and FIG. 79A to FIG. 79I.

There is no particular limitation on the arrangement of subpixels included in a pixel, and a variety of methods can be employed. Examples of the arrangement of the subpixels include stripe arrangement, S-stripe arrangement, matrix arrangement, delta arrangement, Bayer arrangement, and PenTile arrangement.

The planar shape of a subpixel illustrated in a diagram in this embodiment corresponds to the planar shape of a display region (or a light-receiving region).

Examples of the planar shape of the subpixel include polygons such as a triangle, a tetragon (including a rectangle and a square), and a pentagon; polygons with rounded corners; an ellipse; and a circle.

The circuit constituting the subpixel is not necessarily placed within the dimensions of the subpixel illustrated in a diagram and may be placed outside the subpixel.

The pixel 21 illustrated in FIG. 78A employs S stripe arrangement. The pixel 21 illustrated in FIG. 78A is composed of three kinds of subpixels: a subpixel 23a, a subpixel 23b, and a subpixel 23c.

The pixel 21 illustrated in FIG. 78B includes the subpixel 23a and the subpixel 23b whose planar surfaces have a rough trapezoidal or rough triangle shape with rounded corners and the subpixel 23c whose planar surface has a rough tetragonal or rough hexagonal shape with rounded corners. The subpixel 23b has a larger display area than the subpixel 23a. In this manner, the shapes and sizes of the subpixels can be determined independently.

A pixel 21a and a pixel 21b illustrated in FIG. 78C employ PenTile arrangement. FIG. 78C illustrates an example where the pixel 21a including the subpixel 23a and the subpixel 23b and the pixel 21b including the subpixel 23b and the subpixel 23c are alternately arranged.

The pixel 21a and the pixel 21b illustrated in FIG. 78D to FIG. 78F employ delta arrangement. The pixel 21a includes two subpixels (the subpixel 23a and the subpixel 23b) in the upper row (first row) and one subpixel (the subpixel 23c) in the lower row (second row). The pixel 21b includes one subpixel (the subpixel 23c) in the upper row (first row) and two subpixels (the subpixel 23a and the subpixel 23b) in the lower row (second row).

FIG. 78D illustrates an example where the planar surface of each subpixel has a rough tetragonal shape with rounded corners, FIG. 78E illustrates an example where the planar surface of each subpixel is circular, and FIG. 78F illustrates an example where the planar surface of each subpixel has a rough hexagonal shape with rounded corners.

In FIG. 78F, subpixels are placed in respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 23a, the subpixel 23a is surrounded by three subpixels 23b and three subpixels 23c that are alternately arranged.

FIG. 78G illustrates an example where subpixels of different colors are arranged in a zigzag manner. Specifically, the positions of the top sides of two subpixels arranged in the column direction (e.g., the subpixel 23a and the subpixel 23b or the subpixel 23b and the subpixel 23c) are not aligned in a plan view.

For example, in each pixel illustrated in FIG. 78A to FIG. 78G, it is preferable that the subpixel 23a be a subpixel R that emits red light, the subpixel 23b be a subpixel G that emits green light, and the subpixel 23c be a subpixel B that emits blue light. Note that the structure of the subpixels is not limited to this, and the colors and arrangement order of the subpixels can be determined as appropriate. For example, the subpixel 23b may be the subpixel R that emits red light and the subpixel 23a may be the subpixel G that emits green light.

In a photolithography method, as a pattern to be processed becomes finer, the influence of light diffraction becomes more difficult to ignore; accordingly, fidelity in transferring a photomask pattern by light exposure is degraded, and it becomes difficult to process a resist mask into a desired shape. Thus, a pattern with rounded corners is likely to be formed even with a rectangular photomask pattern. Consequently, the planar surface of a subpixel may have a polygonal shape with rounded corners, an elliptical shape, a circular shape, or the like.

To obtain a desired planar shape of the subpixel, a technique of correcting a mask pattern in advance so that a transferred pattern matches with a design pattern (an optical proximity correction (OPC) technique) may be used. Specifically, with the OPC technique, a pattern for correction is added to a corner portion of a figure on a mask pattern, for example.

As illustrated in FIG. 79A to FIG. 79I, the pixel can include four types of subpixels.

The pixels 21 illustrated in FIG. 79A to FIG. 79C employ stripe arrangement.

FIG. 79A illustrates an example where each subpixel has a rectangular planar shape, FIG. 79B illustrates an example where each subpixel has a planar shape formed by combining two half circles and a rectangle, and FIG. 79C illustrates an example where each subpixel has an elliptical planar shape.

The pixels 21 illustrated in FIG. 79D to FIG. 79F employ matrix arrangement.

FIG. 79D illustrates an example where each subpixel has a square planar shape, FIG. 79E illustrates an example where each subpixel has a substantially square planar shape with rounded corners, and FIG. 79F illustrates an example where each subpixel has a circular planar shape.

FIG. 79G and FIG. 79H each illustrate an example where one pixel 21 is composed of two rows and three columns.

The pixel 21 illustrated in FIG. 79G includes three subpixels (the subpixel 23a, the subpixel 23b, and the subpixel 23c) in the upper row (first row) and one subpixel (the subpixel 23d) in the lower row (second row). In other words, the pixel 21 includes the subpixel 23a in the left column (first column), the subpixel 23b in the center column (second column), the subpixel 23c in the right column (third column), and the subpixel 23d across these three columns.

The pixel 21 illustrated in FIG. 79H includes three subpixels (the subpixel 23a, the subpixel 23b, and the subpixel 23c) in the upper row (first row) and three subpixels 23d in the lower row (second row). In other words, the pixel 21 includes the subpixel 23a and the subpixel 23d in the left column (first column), the subpixel 23b and the subpixel 23d in the center column (second column), and the subpixel 23c and the subpixel 23d in the right column (third column). Matching the positions of the subpixels in the upper row and the lower row as illustrated in FIG. 79H enables efficient removal of dust that would be produced in the manufacturing process, for example. Thus, a touch panel including a display apparatus with high display quality can be provided.

FIG. 79I illustrates an example where one pixel 21 is composed of three rows and two columns.

The pixel 21 illustrated in FIG. 79I includes the subpixel 23a in the upper row (first row), the subpixel 23b in the center row (second row), the subpixel 23c across the first and second rows, and one subpixel (the subpixel 23d) in the lower row (third row). In other words, the pixel 21 includes the subpixel 23a and the subpixel 23b in the left column (first column), the subpixel 23c in the right column (second column), and the subpixel 23d across these two columns.

The pixels 21 illustrated in FIG. 79A to FIG. 79I are each composed of four subpixels: the subpixel 23a, the subpixel 23b, the subpixel 23c, and the subpixel 23d.

The subpixel 23a, the subpixel 23b, the subpixel 23c, and the subpixel 23d can be configured to emit light of different colors. Examples of the subpixel 23a, the subpixel 23b, the subpixel 23c, and the subpixel 23d include subpixels of four colors of R, G, B, and white (W), subpixels of four colors of R, G, B, and Y, and subpixels of R, G, B, and infrared light (IR).

In the pixels 21 illustrated in FIG. 79A to FIG. 79I, it is preferable that the subpixel 23a be the subpixel R that emits red light, the subpixel 23b be the subpixel G that emits green light, the subpixel 23c be the subpixel B that emits blue light, and the subpixel 23d be any of a pixel W that emits white light, a pixel Y that emits yellow light, and a subpixel IR that emits near-infrared light, for example. In the case of such a structure, stripe arrangement is employed as the layout of R, G, and B in the pixels 21 illustrated in FIG. 79G and FIG. 79H, leading to higher display quality. In the pixel 21 illustrated in FIG. 79I, what is called S stripe arrangement is employed as the layout of R, G, and B, leading to higher display quality.

As described above, the pixel composed of the subpixels each including a display element can employ any of a variety of layouts in the touch panel of one embodiment of the present invention.

The plurality of structure examples described in this embodiment can be combined with each other as appropriate. This embodiment can be combined with the other embodiments as appropriate.

### Embodiment 4

In this embodiment, electronic devices of one embodiment of the present invention will be described.

In an electronic device in this embodiment, a display portion includes the touch panel of one embodiment of the present invention. Examples of electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display apparatus included in the touch panel of one embodiment of the present invention can have high resolution, and thus can be suitably used for an electronic device including a relatively small display portion. Examples of such an electronic device include watch-type and bracelet-type information terminals (wearable devices) and wearable devices that can be worn on a head, such as a VR device like a head-mounted display, a glasses-type AR device, and an MR device.

The definition of the display apparatus included in the touch panel of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320), for example. In particular, the definition is preferably 4K, 8K, or higher. The pixel density (resolution) of the display apparatus included in the touch panel of one embodiment of the present invention is preferably 100 ppi or higher, further preferably 300 ppi or higher, further preferably 500 ppi or higher, still further preferably 1000 ppi or higher, still further preferably 2000 ppi or higher, yet further preferably 3000 ppi or higher, yet further preferably 5000 ppi or higher, yet still further preferably 7000 ppi or higher. Providing such a display apparatus having one or both of high definition and high resolution in a touch panel can further increase realistic sensation, sense of depth, and the like. There is no particular limitation on the screen ratio (aspect ratio) of the display apparatus included in the touch panel of one embodiment of the present invention. For example, the display apparatus included in the touch panel of one embodiment of the present invention is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic devices in this embodiment can have a variety of functions. For example, the electronic devices can have a function of displaying a variety of information (a still image, a moving image, a text image, and the like) on the display portion, a function of displaying a calendar, date, time, and the like, a function of controlling processing with use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may each be provided with a camera or the like and have a function of taking a still image or a moving image and storing the taken image in a storage medium (an external storage medium or a storage medium incorporated in the camera), a function of displaying the taken image on the display portion, and the like.

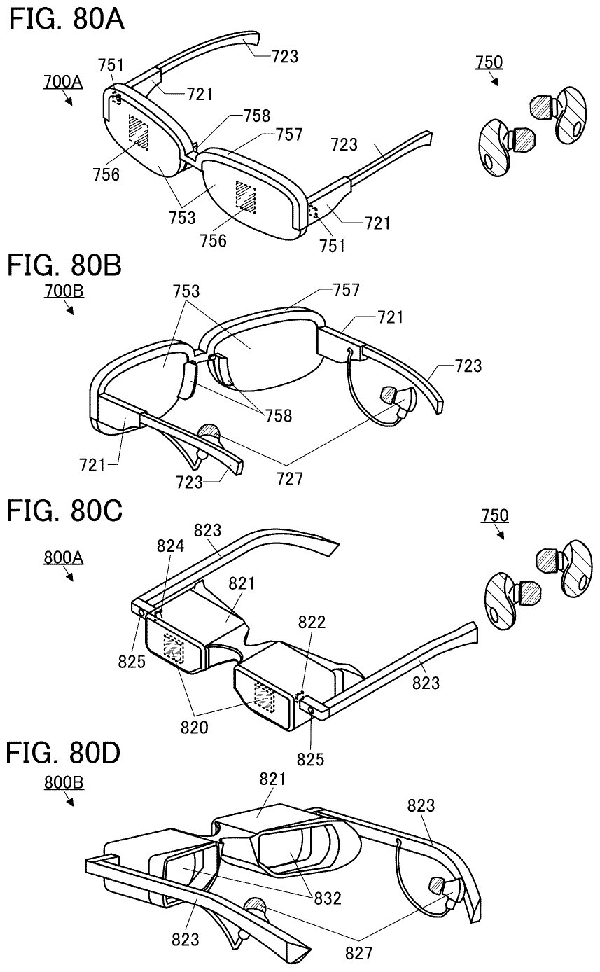

Examples of a wearable device that can be worn on a head are described with reference to FIG. 80A to FIG. 80D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 80A and an electronic device 700B illustrated in FIG. 80B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The electronic device 700A and the electronic device 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

The touch panel of one embodiment of the present invention can be used for the display panel 751, the display region 756, and the like. Thus, the electronic devices can be inexpensive. Moreover, the electronic devices are capable of performing display with extremely high resolution.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector to which a cable for supplying a video signal and a power supply potential can be connected may be provided.

The electronic device 700A and the electronic device 700B are each provided with a battery so that they can be charged wirelessly and/or by wire.

An electronic device 800A illustrated in FIG. 80C and an electronic device 800B illustrated in FIG. 80D each include a pair of display portions 820, a housing 821, a communication portion 822, a pair of wearing portions 823, a control portion 824, a pair of image capturing portions 825, and a pair of lenses 832.

The touch panel of one embodiment of the present invention can be used for the display portions 820. Thus, the electronic devices can be inexpensive. Moreover, the electronic devices are capable of performing display with extremely high resolution and enable the user to feel a high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the wearing portions 823. FIG. 80C illustrate an example where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portions 825 are provided is described here, a range sensor capable of measuring a distance from an object (hereinafter also referred to as a sensing portion) just needs to be provided. In other words, the image capturing portion 825 is one embodiment of the sensing portion. As the sensing portion, an image sensor or a distance image sensor such as LIDAR (Light Detection and Ranging) can be used, for example. By using images obtained by the camera and images obtained by the range image sensor, more information can be obtained and a gesture operation with higher accuracy is possible.

The electronic device 800A may include a vibration mechanism that functions as a bone-conduction earphone. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, for example, a cable supplying a video signal from a video output device, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 80A has a function of transmitting information to the earphones 750 with the wireless communication function. As another example, the electronic device 800A illustrated in FIG. 80C has a function of transmitting information to the earphones 750 with the wireless communication function.

The electronic device may include an earphone portion. The electronic device 700B in FIG. 80B includes earphone portions 727. For example, the earphone portions 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 80D includes earphone portions 827. For example, the earphone portions 827 and the control portion 824 can be connected to each other by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

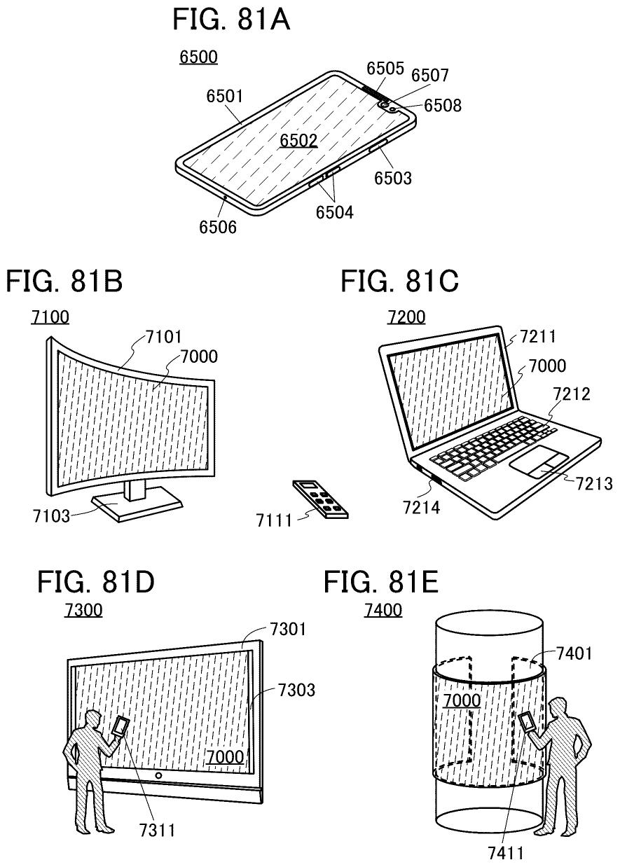

An electronic device 6500 illustrated in FIG. 81A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like.

The touch panel of one embodiment of the present invention can be used for the display portion 6502. Thus, the electronic device can be inexpensive.

FIG. 81B illustrates an example of a television device. In a television device 7100, a display portion 7000 is incorporated in a housing 7101. Here, the housing 7101 is supported by a stand 7103.

The touch panel of one embodiment of the present invention can be used for the display portion 7000. Thus, the television device can be inexpensive.

Operation of the television device 7100 illustrated in FIG. 81B can be performed with an operation switch provided in the housing 7101 and a separate remote controller 7111. The remote controller 7111 may be provided with a display portion for displaying information output from the remote controller 7111. With operation keys or a touch panel provided in the remote controller 7111, channels and volume can be operated and videos displayed on the display portion 7000 can be operated.

Note that the television device 7100 includes a receiver, a modem, and the like. A general television broadcast can be received with the receiver. When the television device is connected to a communication network with or without wires via the modem, one-way (from a transmitter to a receiver) or two-way (between a transmitter and a receiver or between receivers, for example) information communication can be performed.

FIG. 81C illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The touch panel of one embodiment of the present invention can be used for the display portion 7000. Thus, the laptop personal computer can be inexpensive.

FIG. 81D and FIG. 81E illustrate examples of digital signage.

Digital signage 7300 illustrated in FIG. 81D includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 81E illustrates digital signage 7400 mounted on a cylindrical pillar 7401. The digital signage 7400 includes the display portion 7000 provided along a curved surface of the pillar 7401.

The touch panel of one embodiment of the present invention can be used for the display portion 7000 in FIG. 81D and FIG. 81E. Thus, the digital signage can be inexpensive.

A larger area of the display portion 7000 can increase the amount of information that can be provided at a time. The larger display portion 7000 attracts more attention, so that the effectiveness of the advertisement can be increased, for example.

A touch panel is preferably used for the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 81D and FIG. 81E, it is preferable that the digital signage 7300 or the digital signage 7400 can work with an information terminal 7311 or an information terminal 7411, such as a smartphone a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

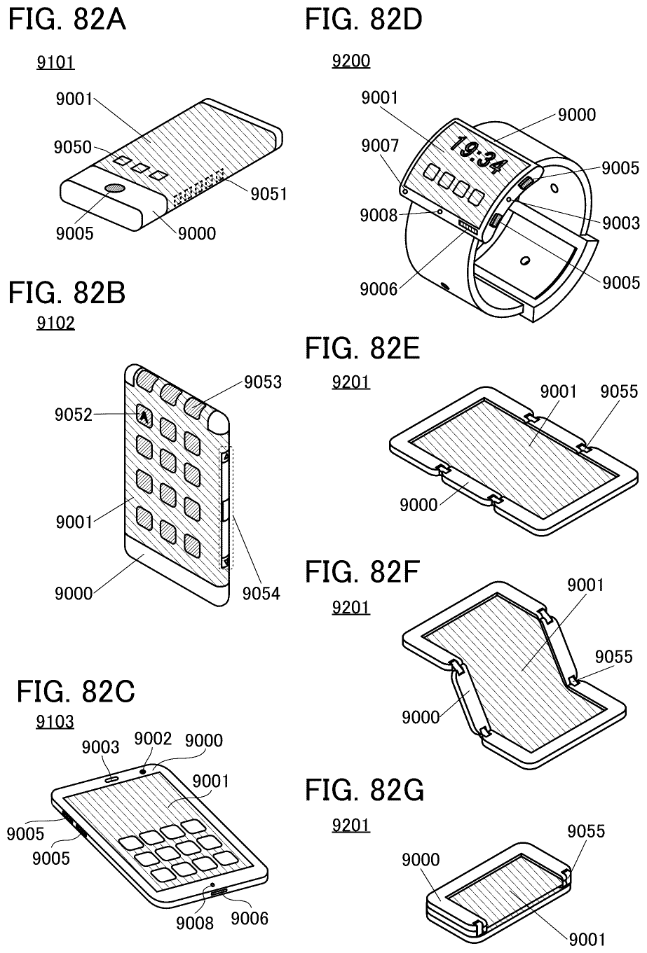

Electronic devices illustrated in FIG. 82A to FIG. 82G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like. The touch panel of one embodiment of the present invention can be used for the display portion 9001. Thus, the electronic devices can be inexpensive.

The electronic devices illustrated in FIG. 82A to FIG. 82G will be described in detail below.

FIG. 82A is a perspective view of a portable information terminal 9101. The portable information terminal 9101 can be used as a smartphone, for example. Note that the portable information terminal 9101 may be provided with the speaker 9003, the connection terminal 9006, the sensor 9007, and the like. The portable information terminal 9101 can display letters and image information on its plurality of surfaces. FIG. 82A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 82B is a perspective view of a portable information terminal 9102. The portable information terminal 9102 has a function of displaying information on three or more surfaces of the display portion 9001. In the example shown here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 82C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface.

FIG. 82D is a perspective view of a watch-type portable information terminal 9200. The portable information terminal 9200 can be used as a Smartwatch (registered trademark), for example. The display surface of the display portion 9001 is curved, and an image can be displayed on the curved display surface. Mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 82E to FIG. 82G are perspective views of a foldable portable information terminal 9201. FIG. 82E is a perspective view illustrating the portable information terminal 9201 that is opened. FIG. 82G is a perspective view illustrating the portable information terminal 9201 that is folded. FIG. 82F is a perspective view illustrating the portable information terminal 9201 that is shifted from one of the states in FIG. 82E and FIG. 82G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

The plurality of structure examples described in this embodiment can be combined with each other as appropriate. This embodiment can be combined with the other embodiments as appropriate.

### REFERENCE NUMERALS

10: touch panel, 11: display apparatus, 12: input device, 13: scan line driver circuit, 14: signal line driver circuit, 15a: circuit, 15b: circuit, 15: input device driver circuit, 16: FPC, 17: connection portion, 18a: connection portion, 18b: connection portion, 18: connection portion, 19a: FPC, 19b: FPC, 19: FPC, 20: display portion, 21a: pixel, 21b: pixel, 21: pixel, 23_1: subpixel, 23_2: subpixel, 23a: subpixel, 23B: subpixel, 23b: subpixel, 23c: subpixel, 23d: subpixel, 23G: subpixel, 23R: subpixel, 23: subpixel, 30: demultiplexer circuit group, 31: demultiplexer circuit, 40: pixel circuit, 41: wiring, 43: wiring, 45: wiring, 47: wiring, 50: transistor, 51: transistor, 52: transistor, 57: capacitor, 58: capacitor, 61B: light-emitting element, 61G: light-emitting element, 61R: light-emitting element, 61W: light-emitting element, 61: light-emitting element, 62: liquid crystal element, 101: substrate, 103a: insulating layer, 103b: insulating layer, 103: insulating layer, 105: insulating layer, 106: conductive layer, 111_1: conductive layer, 111_2: conductive layer, 111: conductive layer, 112_1: conductive layer, 112_2: conductive layer, 112A: conductive layer, 112B: conductive layer, 112f: conductive film, 112: conductive layer, 113[1]: semiconductor layer, 113[2]: semiconductor layer, 113_1: semiconductor layer, 113_2: semiconductor layer, 113f: semiconductor film, 113: semiconductor layer, 115_1: conductive layer, 115_2: conductive layer, 115: conductive layer, 120: sensing element, 121[1]: opening, 121[2]: opening, 121_1: opening, 121_2: opening, 121a: opening, 121b: opening, 121: opening, 123[1]: opening, 123[2]: opening, 123_1: opening, 123_2: opening, 123: opening, 124: insulating layer, 125: insulating layer, 126: intersection portion, 127: electrode, 128_1: electrode, 128_2: electrode, 128: electrode, 129: opening, 130a: polarizing plate, 130b: polarizing plate, 131_1: opening, 131_2: opening, 131: opening, 132_1: opening, 132_2: opening, 132: opening, 133_1: opening, 133_2: opening, 133: opening, 134_1: opening, 134_2: opening, 134: opening, 137: wiring, 138_1: wiring, 138_2: wiring, 138: wiring, 141: capacitor, 142: adhesive layer, 152: substrate, 161a: tapered portion, 161b: tapered portion, 165_1: conductive particle, 165_2: conductive particle, 165a: conductive particle, 165: conductive particle, 166_1: conductive layer, 166_2: conductive layer, 166a: conductive layer, 166a_1: conductive layer, 166a_2: conductive layer, 166b: conductive layer, 166b_1: conductive layer, 166b_2: conductive layer, 166: conductive layer, 172: insulating layer, 183B: coloring layer, 183G: coloring layer, 183R: coloring layer, 183: coloring layer, 201_1: transistor, 201_2: transistor, 201: transistor, 205B: transistor, 205G: transistor, 205R: transistor, 205W: transistor, 205: transistor, 211: conductive layer, 213i: channel formation region, 213n: low-resistance region, 213: semiconductor layer, 215: conductive layer, 218: insulating layer, 222a: conductive layer, 222b: conductive layer, 235: insulating layer, 237: insulating layer, 311B: pixel electrode, 311Ba: pixel electrode, 311Bb: pixel electrode, 311G: pixel electrode, 311Ga: pixel electrode, 311Gb: pixel electrode, 311R: pixel electrode, 311Ra: pixel electrode, 311Rb: pixel electrode, 311W: pixel electrode, 311: pixel electrode, 312a: pixel electrode, 312b: pixel electrode, 312: pixel electrode, 313B: layer, 313G: layer, 313R: layer, 313W: layer, 313: layer, 314: common layer, 315: common electrode, 316: common electrode, 317: light-blocking layer, 318B: mask layer, 318G: mask layer, 318R: mask layer, 318: mask layer, 319: slit, 324B: conductive layer, 324G: conductive layer, 324R: conductive layer, 324: conductive layer, 325: insulating layer, 326B: conductive layer, 326G: conductive layer, 326R: conductive layer, 326: conductive layer, 327: insulating layer, 328: layer, 329B: conductive layer, 329G: conductive layer, 329R: conductive layer, 329: conductive layer, 331: protective layer, 333: alignment layer, 334: insulating layer, 335: liquid crystal, 337: alignment layer, 339: insulating layer, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A touch panel comprising:
a first transistor;
a sensing element;
a first insulating layer;
a second insulating layer; and
a conductive particle,
the first transistor comprising:
first conductive layer;
a second conductive layer;
a third conductive layer;
a first semiconductor layer; and
a third insulating layer,
wherein the sensing element comprises a pair of electrodes,
wherein the first insulating layer is over the first conductive layer,
wherein the second conductive layer is over the first insulating layer,
wherein the first insulating layer comprises a first opening reaching the first conductive layer,
wherein the second conductive layer comprises a second opening comprising a region overlapping the first opening,
wherein the first semiconductor layer is provided to comprise a region in contact with the first conductive layer and a region in contact with the second conductive layer, and to comprise a region positioned in the first opening and the second opening,
wherein the third insulating layer is over the first semiconductor layer and the first insulating layer to comprise a region positioned in the first opening and the second opening,
wherein the third conductive layer is provided to comprise a region positioned in the first opening and a region positioned in the second opening, and to comprise a region facing the first semiconductor layer with the third insulating layer therebetween,
wherein the second insulating layer is over the third conductive layer and the first insulating layer,
wherein the first insulating layer, the second insulating layer, and the third insulating layer comprise a third opening reaching the first conductive layer,
wherein one of the pair of electrodes comprises a region overlapping the third opening,
wherein the first conductive layer and the one of the pair of electrodes are electrically connected to each other through the conductive particle, and
wherein the conductive particle is between the first conductive layer and the one of the pair of electrodes to comprise a region positioned in the third opening.

2. The touch panel according to claim 1, further comprising a fourth conductive layer,
wherein the fourth conductive layer is provided to comprise a region in contact with the first conductive layer and a region positioned in the third opening.

3. The touch panel according to claim 2, further comprising:
a second transistor; and
light-emitting element,
the second transistor comprising:
fifth conductive layer;
a sixth conductive layer;
a seventh conductive layer;
a second semiconductor layer; and
the third insulating layer,
the light-emitting element comprising:
a pixel electrode;
an EL layer over the pixel electrode; and
a common electrode over the EL layer,
wherein the first insulating layer is over the fifth conductive layer,
wherein the sixth conductive layer is over the first insulating layer,
wherein the first insulating layer comprises a fourth opening reaching the fifth conductive layer,
wherein the sixth conductive layer comprises a fifth opening comprising a region overlapping the fourth opening,
wherein the second semiconductor layer is provided to comprise a region in contact with the fifth conductive layer and a region in contact with the sixth conductive layer and to comprise a region positioned in the fourth opening and the fifth opening,
wherein the third insulating layer is over the second semiconductor layer to comprise a region positioned in the fourth opening and the fifth opening,
wherein the seventh conductive layer is provided to comprise a region positioned in the fourth opening and a region positioned in the fifth opening and to comprise a region facing the second semiconductor layer with the third insulating layer therebetween,
wherein the second insulating layer is over the seventh conductive layer,
wherein the first insulating layer, the second insulating layer, and the third insulating layer comprise a sixth opening reaching the fifth conductive layer, and
wherein the pixel electrode is in a same layer as the fourth conductive layer to comprise a region in contact with the fifth conductive layer and a region positioned in the sixth opening.

4. The touch panel according to claim 1, further comprising an adhesive layer comprising the conductive particle, between the one of the pair of electrodes and the first conductive layer.

5. A touch panel comprising:
a first transistor;
a sensing element;
a first insulating layer;
a second insulating layer;
a third insulating layer;
a first conductive layer; and
a conductive particle,
the first transistor comprising:
third conductive layer;
a fourth conductive layer;
a first semiconductor layer; and
a fourth insulating layer,
wherein the sensing element comprises a pair of electrodes,
wherein the first insulating layer is over the second conductive layer,
wherein the third conductive layer is over the first insulating layer,
wherein the first insulating layer comprises a first opening reaching the second conductive layer,
wherein the third conductive layer comprises a second opening comprising a region overlapping the first opening,
wherein the first semiconductor layer is provided to comprise a region in contact with the second conductive layer and a region in contact with the third conductive layer, and to comprise a region positioned in the first opening and the second opening,
wherein the fourth insulating layer is over the first semiconductor layer and the first insulating layer to comprise a region positioned in the first opening and the second opening,
wherein the fourth conductive layer is provided to comprise a region positioned in the first opening and a region positioned in the second opening, and to comprise a region facing the first semiconductor layer with the fourth insulating layer therebetween,
wherein the second insulating layer is provided over the fourth conductive layer and the first insulating layer,
wherein the first conductive layer is over the second insulating layer and electrically connected to the second conductive layer,
wherein the third insulating layer is over the first conductive layer,
wherein the third insulating layer comprises a third opening reaching the first conductive layer,
wherein one of the pair of electrodes comprises a region overlapping the third opening,
wherein the first conductive layer and the one of the pair of electrodes are electrically connected to each other through the conductive particle, and
wherein the conductive particle is between the first conductive layer and the one of the pair of electrodes to comprise a region positioned in the third opening.

6. The touch panel according to claim 5, further comprising:
a second transistor; and
light-emitting element,
the second transistor comprising:
a fifth conductive layer;
a sixth conductive layer;
a seventh conductive layer;
a second semiconductor layer; and
the fourth insulating layer,
the light-emitting element comprising:
a pixel electrode;
an EL layer over the pixel electrode; and
a common electrode over the EL layer,
wherein the first insulating layer is over the fifth conductive layer,
wherein the sixth conductive layer is over the first insulating layer,
wherein the first insulating layer comprises a fourth opening reaching the fifth conductive layer,
wherein the sixth conductive layer comprises a fifth opening comprising a region overlapping the fourth opening,
wherein the second semiconductor layer is provided to comprise a region in contact with the fifth conductive layer and a region in contact with the sixth conductive layer and to comprise a region positioned in the fourth opening and the fifth opening,
wherein the fourth insulating layer is over the second semiconductor layer to comprise a region positioned in the fourth opening and the fifth opening,
wherein the seventh conductive layer is provided to comprise a region positioned in the fourth opening and a region positioned in the fifth opening and to comprise a region facing the second semiconductor layer with the fourth insulating layer therebetween,
wherein the second insulating layer is over the seventh conductive layer,
wherein the pixel electrode is in a same layer as the first conductive layer to be electrically connected to the fifth conductive layer, and
wherein the third insulating layer is provided to cover an end portion of the pixel electrode.

7. The touch panel according to claim 5, further comprising an adhesive layer comprising the conductive particle, between the one of the pair of electrodes and the first conductive layer.

8. The touch panel according to claim 1,
wherein the first semiconductor layer comprises a metal oxide,
wherein the metal oxide comprises indium, zinc, and M, and
wherein M is one or more kinds selected from aluminum, titanium, gallium, germanium, tin, yttrium, zirconium, lanthanum, cerium, neodymium, and hafnium.

9. The touch panel according to claim 3,
wherein the first semiconductor layer and the second semiconductor layer each comprise a metal oxide,
wherein the metal oxide comprises indium, zinc, and M, and
wherein M is one or more kinds selected from aluminum, titanium, gallium, germanium, tin, yttrium, zirconium, lanthanum, cerium, neodymium, and hafnium.

10. A method for manufacturing a touch panel, comprising the steps of:
forming a first conductive layer over a first substrate;
forming a first insulating layer over the first conductive layer;
forming a conductive film over the first insulating layer;
forming a first opening reaching the first conductive layer in the first insulating layer, forming a second opening comprising a region overlapping the first opening in the conductive film, and forming a second conductive layer by processing the conductive film;
forming a first semiconductor layer to comprise a region in contact with the first conductive layer and a region in contact with the second conductive layer and to comprise a region positioned in the first opening and the second opening;
forming a second insulating layer over the first semiconductor layer and the first insulating layer to comprise a region positioned in the first opening and the second opening;
forming a third conductive layer to comprise a region positioned in the first opening and the second opening and to comprise a region facing the first semiconductor layer with the second insulating layer therebetween;
forming a third insulating layer over the third conductive layer and the first insulating layer;
forming a third opening reaching the first conductive layer in the first insulating layer, the second insulating layer, and the third insulating layer
forming, over a second substrate, a sensing element comprising a pair of electrodes; and
bonding the first substrate and the second substrate to each other using an adhesive layer comprising a conductive particle so that the conductive particle comprises a region positioned in the third opening and so that the first conductive layer and one of the electrodes of the sensing element are electrically connected to each other through the conductive particle.

11. The method for manufacturing a touch panel, according to claim 10, further comprising the step of:
after forming the third opening, forming a fourth conductive layer to comprise a region in contact with the first conductive layer and to a region positioned in the third opening.

12. The method for manufacturing a touch panel, according to claim 11, comprising the steps of:
forming a fifth conductive layer concurrently with formation of the first conductive layer;
forming the first insulating layer over the fifth conductive layer;
forming a fourth opening reaching the fifth conductive layer in the first insulating layer concurrently with formation of the first opening, and forming a fifth opening comprising a region overlapping the fourth opening in the conductive film concurrently with formation of the second opening;
forming a sixth conductive layer by processing the conductive film;
forming a second semiconductor layer to comprise a region in contact with the fifth conductive layer and a region in contact with the sixth conductive layer and to comprise a region positioned in the fourth opening and the fifth opening, concurrently with formation of the first semiconductor layer;
forming the second insulating layer over the second semiconductor layer to comprise a region positioned in the fourth opening and the fifth opening;
forming a seventh conductive layer to comprise a region positioned in the fourth opening and the fifth opening and to comprise a region facing the second semiconductor layer with the second insulating layer therebetween, concurrently with formation of the third conductive layer;
forming the third insulating layer over the seventh conductive layer;
forming a sixth opening reaching the fifth conductive layer in the first insulating layer, the second insulating layer, and the third insulating layer, concurrently with formation of the third opening;
forming a pixel electrode to comprise a region in contact with the fifth conductive layer and to comprise a region positioned in the sixth opening, concurrently with formation of the fourth conductive layer; and
forming an EL layer over the pixel electrode and a common electrode over the EL layer, thereby forming a light-emitting element comprising the pixel electrode, the EL layer, and the common electrode.
